(19) United States
(12) Patent Application Publication
(10) Pub. No.: US 2026/0247859 A1
(43) Pub. Date: Aug. 20, 2026

(54) ORGANIC ELECTROLUMINESCENT DEVICE AND DISPLAY DEVICE

(71) Applicant: Xiamen Tianma Display Technology Co., Ltd., Xiamen (CN)

(72) Inventors: Wei Gao, Xiamen (CN); Yepeng Xiang, Xiamen (CN); Jinghua Niu, Xiamen (CN); Long Chen, Xiamen (CN); Wenpeng Dai, Xiamen (CN); Lilian Kuang, Xiamen (CN)

(73) Assignee: Xiamen Tianma Display Technology Co., Ltd., Xiamen (CN)

(21) Appl. No.: 19/537,534

(22) Filed: Feb. 12, 2026

(30) Foreign Application Priority Data
Feb. 12, 2025 (CN) 202510156829.9

(51) Int. Cl. H10K 85/60; H10K 50/15

(52) U.S. Cl. CPC H10K 85/6572; H10K 50/15; H10K 85/615; H10K 85/626; H10K 85/657; H10K 85/6576

(57) ABSTRACT

An organic electroluminescent device and a display device are provided. The organic electroluminescent device comprises a substrate, an anode, an organic light-emitting layer and a cathode disposed in sequence, wherein the organic light-emitting layer comprises a host material, a guest light-emitting material and an exciton utilizing agent, and the host material comprises a hole-type host material and an electron-type host material, and the minimum values of bond dissociation energies of the electron-type host material and the exciton utilizing agent in an anionic state, an electrically neutral state and a cationic state are each independently ≥2.6 eV, and the HOMO energy level of the guest light-emitting material is H₁, the HOMO energy level of the exciton utilizing agent is H₂, and H₁ and H₂ satisfy the relationship: 0 eV≤H₂−H₁≤0.5 eV. The present application can improve luminous efficiency and lifetime of OLED device.

### CROSS-REFERENCE TO RELATED APPLICATIONS

This application claims priority to Chinese Patent Application No. 202510156829.9, filed on Feb. 12, 2025, which is hereby incorporated by reference in its entirety.

### TECHNICAL FIELD

The present application relates to the technical field of display devices, and more particularly, to an organic electroluminescent device and a display device.

### BACKGROUND

Under electrical excitation, according to the law of spin statistics, the recombination of electrons and holes will produce 25% of singlet excitons (S₁) and 75% of triplet excitons (T₁), while different light-emitting materials in the device have different exciton (including S₁ and T₁) utilization rate. For traditional fluorescent materials, triplet excitons cannot emit light through radiative transition due to spin forbidden, but can only be dissipated through non-radiative transition, so the exciton utilization rate is only 25%.

In order to utilize 75% of T₁ for luminescence, MA Yuguang and Forrest et al. have successively proposed to accelerate the Inter-System Crossing (ISC) process from S₁ to T₁ through the spin-orbit coupling effect of heavy metal atoms, while allowing the radiative transition process from T₁ to S₀, which is originally spin-forbidden, to occur, thereby realizing the emission of phosphorus light, and theoretically the exciton utilization rate can reach 100%.

Red and green phosphorescent materials have been mass-produced in commercial OLED display panels, but blue phosphorescent materials still have problems such as low color purity and poor stability. Due to the consideration of the lifetime of the display, blue fluorescent materials with low exciton utilization are still commonly used in the current commercial OLED displays. The luminous efficiency of blue fluorescent materials is relatively low, resulting in the blue part of OLED screens usually accounting for a high proportion of power consumption, even half or more of the total power consumption.

In recent years, thermally activated delayed fluorescence materials have attracted widespread attention from the industry and scientific research communities. The T₁ and S₁ energy levels of thermally activated delayed fluorescent materials are close (the energy level difference between the singlet and triplet states is defined as ΔE_{ST}, ΔE_{ST}=S₁−T₁), so T₁ can absorb heat in the environment to overcome the ΔE_{ST} energy barrier and convert to S₁ (i.e., the reverse intersystem crossing process), achieving efficient utilization of T₁. The luminescence of TADF materials comes from the charge transfer excited state radiation transition, so the spectrum of TADF materials is wide, usually with the Full Width at Half Maximum (FWHM) of from 60 nm to 100 nm, which limits its application in display fields with high requirements for color purity.

On this basis, it is of great significance to research and develop a blue organic electroluminescent device with high efficiency, narrow emission spectrum and long lifetime to reduce the power consumption of OLED display devices.

### SUMMARY

A main object of the present application is to provide an organic light-emitting device and a display device, so as to solve the problems of low utilization rate of triplet excitons of blue light-emitting materials in the prior art, resulting in the problems including low OLED luminous efficiency and high power consumption of OLED display devices.

In order to achieve the above object, one aspect of the present application provides an organic electroluminescent device comprising a substrate, an anode, an organic light-emitting layer and a cathode disposed in sequence, wherein the organic light-emitting layer comprises a host material, a guest light-emitting material and an exciton utilizing agent, and the host material comprises a hole-type host material and an electron-type host material, and the minimum values of bond dissociation energies of the electron-type host material and the exciton utilizing agent in an anionic state, an electrically neutral state and a cationic state are each independently ≥2.6 eV, and the HOMO energy level of the guest light-emitting material is H₁, the HOMO energy level of the exciton utilizing agent is H₂, and H₁ and H₂ satisfy the relationship: 0 eV≤H₂−H₁≤0.5 eV.

In order to achieve the above object, another aspect of the present application further provides a display device comprising the organic electroluminescent device provided in the present application, and the display device is selected from the group consisting of a tablet phone, a wearable display device, a tablet computer, a laptop computer, a medical display device, a foldable display device, a vehicle-mounted display device, a virtual reality display device or an augmented reality display device.

According to the embodiments of the present application, compared with other ranges, by limiting the minimum value of bond dissociation energy of the three materials in the organic light-emitting layer within the specific range described above, the stability of molecules in anionic state, electrically neutral state and cationic state can be enhanced, and the degradation pathway of each material in triplet-triplet annihilation and triplet-polaron annihilation process can be effectively inhibited, thereby improving the stability of each material in the working process of the organic electroluminescent device and achieving a longer lifetime of the device.

Compared with other ranges, limiting the HOMO energy level difference (H₂−H₁) between the exciton utilizing agent and the guest light-emitting material within the specific range as described above can effectively inhibit the physical process of the guest light-emitting material becoming a hole potential well, reduce the chance of triplet-triplet annihilation and triplet-polaron annihilation of excitons on the guest light-emitting material, thereby improving the utilization ratio of triplet excitons of the blue light-emitting material, further improving the luminous efficiency and lifetime of the OLED device, and significantly reducing the power consumption when applied to the OLED display device.

### DESCRIPTION OF THE DRAWINGS

The accompanying drawings, which form a part of this application, are intended to provide a further understanding of the present application, and the schematic embodiments of the present application and the description thereof are intended to explain the present application, and do not constitute an unduly limiting of the present application. In the drawings:

FIG. 1 shows a schematic view of stack structure of an OLED device in a preferred embodiment;

FIG. 2 shows a schematic diagram of an energy transfer mode in a preferred embodiment;

FIG. 3 shows a schematic view of stack structure of an OLED device in another preferred embodiment;

FIG. 4 shows a schematic view of stack structure of an OLED device in yet another preferred embodiment;

FIG. 5 shows a schematic view of stack structure of an OLED device in yet another further preferred embodiment.

In the above figures, the following reference numerals are included:
10, substrate; 20, anode 30, organic light-emitting layer; 40, cathode; 50, hole transport layer; 60, electron transport layer; 70, A hole injection layer; 80, electron injection layer; 90, optical cover layer.

### DETAILED DESCRIPTION

It should be noted that the embodiments of the present application and features in the embodiments of the present application may be combined with each other as long as there is no conflict. The present application will now be described in detail with reference to embodiments.

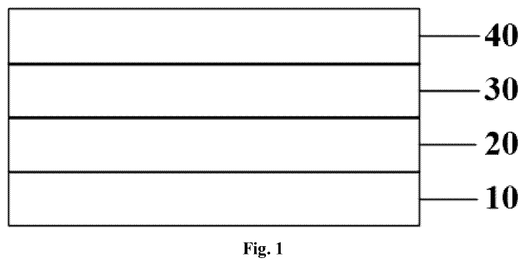

As described in the BACKGROUND, the existing blue light-emitting materials suffer from low utilization rate of triplet excitons, resulting in the problems including low OLED luminous efficiency and high power consumption of OLED display devices. In order to solve the above technical problem, the present application provides an organic electroluminescent device as shown FIG. 1, the organic electroluminescent device comprising a substrate 10, an anode 20, an organic light-emitting layer 30 and a cathode 40 disposed in sequence, wherein the organic light-emitting layer 30 comprises a host material, a guest light-emitting material and an exciton utilizing agent, and the host material comprises a hole-type host material and an electron-type host material, and the minimum values of bond dissociation energies of the electron-type host material and the exciton utilizing agent in an anionic state, an electrically neutral state and a cationic state are each independently ≥2.6 eV, and the HOMO energy level of the guest light-emitting material is H₁, the HOMO energy level of the exciton utilizing agent is H₂, and H₁ and H₂ satisfy the relationship: 0 eV≤H₂−H₁≤0.5 eV.

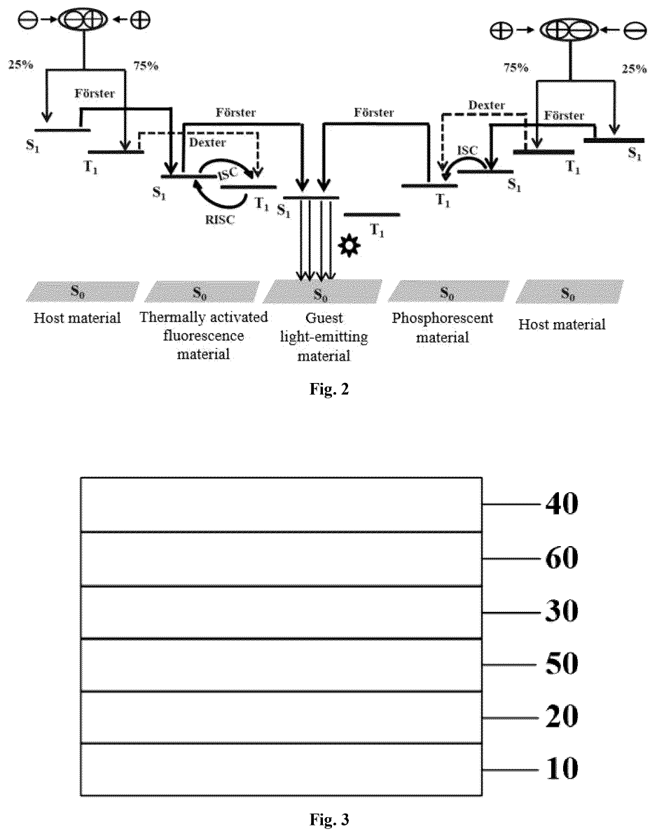

During the process of powering on the organic electroluminescent device, holes are injected from the anode 20 and electrons are injected from the cathode 40, and the injected holes and electrons are recombined in the organic light-emitting layer 30 to form excitons. As shown in FIG. 2, when the exciton utilizing agent is a thermally activated delayed fluorescent material, the host material is excited to generate an excited state, and the energy is transferred to the exciton utilizing agent through energy transfer. The triplet excitons of the exciton utilizing agent are transformed into singlet excitons through the RISC process, and then transferred to the guest light-emitting material through energy transfer. The singlet excitons of the guest light-emitting material are de-excited back to the ground state by mode of radiative transition, thereby realizing blue light emission. When the exciton utilizing agent is a phosphorescent material, the difference between its luminescence mechanism and the above mode is that: energy is transferred through the Forster energy transfer process from the triplet energy level T₁ of the phosphorescent material to the singlet energy level of the guest light-emitting material, and the singlet excitons of the guest light-emitting material are de-excited back to the ground state by mode of radiative transition, thus realizing blue light emission. The organic light-emitting layer 30 containing the above material can fully utilize the singlet state and triplet state excitons of the host material to sensitize the guest light-emitting material by energy transfer, thereby improving the exciton utilization rate.

Bond Dissociation Energy (BDE) refers to the energy required to break a chemical bond in a molecule. Bond dissociation energy is one of the important molecular parameters to evaluate the stability of materials. Compared with other ranges, by limiting the minimum value of bond dissociation energy of the three materials in the organic light-emitting layer 30 within the specific range described above, the stability of molecules in anionic state, electrically neutral state and cationic state can be enhanced, and the degradation pathway of each material in triplet-triplet annihilation and triplet-polaron annihilation process can be effectively inhibited, thereby improving the stability of each material in the working process of the organic electroluminescent device and achieving a longer lifetime of the device.

When the HOMO energy level of the guest light-emitting material becomes shallower than the HOMO of the exciton utilizing agent, the guest light-emitting material will become a strong hole potential well and hinder the transport of holes, thereby improving the triplet exciton group on the guest light-emitting material and increasing the chance of triplet-triplet annihilation and triplet-polaron annihilation of excitons on the guest light-emitting material, thereby further leading to a decrease in luminous efficiency and a shorter lifetime of the OLED device. Compared with other ranges, limiting the HOMO energy level difference (H₂−H₁) between the exciton utilizing agent and the guest light-emitting material within the specific range as described above can effectively inhibit the physical process of the guest light-emitting material becoming a hole potential well, reduce the chance of triplet-triplet annihilation and triplet-polaron annihilation of excitons on the guest light-emitting material, thereby improving the utilization ratio of triplet excitons of the blue light-emitting material, further improving the luminous efficiency and lifetime of the OLED device, and significantly reducing the power consumption when applied to the OLED display device.

It should be noted that both the HOMO energy level and the LUMO energy level in this application are well-known concepts in the art, wherein the HOMO energy level refers to the highest occupied molecular orbital energy level, and the LUMO energy level refers to the lowest unoccupied molecular orbital energy level.

In a preferred embodiment, H₁ and H₂ satisfy the relationship: 0.1 eV≤H₂−H₁≤0.4 eV. Compared with other ranges, limiting the HOMO energy level difference (H₂−H₁) between the exciton utilizing agent and the guest light-emitting material within the specific range as described above is beneficial for inhibiting the physical process of the guest light-emitting material becoming a hole potential well, reducing the chance of triplet-triplet annihilation and triplet-polaron annihilation of excitons on the guest light-emitting material, thus is beneficial for improving the utilization ratio of triplet excitons of the blue light-emitting material, further beneficial for improving the luminous efficiency of the OLED device, and beneficial for reducing the power consumption when applied to the OLED display device.

In order to further improve the utilization rate of triplet excitons of the blue light-emitting material and further improve the luminous efficiency of the OLED device, preferably, H₁ and H₂ satisfy the relationship: 0.15 eV≤H₂−H₁≤0.35 eV.

In a preferred embodiment, the LUMO energy level of the guest light-emitting material is L₁, the LUMO energy level of the exciton utilizing agent is L₂, and L₁ and L₂ satisfy the relationship: 0.10 eV≤L₂−L₁≤0.50 eV. Compared with other ranges, limiting the LUMO energy level difference (L₂−L₁) between the exciton utilizing agent and the guest light-emitting material within the specific range as described above is beneficial for inhibiting the physical process of the guest light-emitting material becoming an electron potential well, reducing the chance of triplet-triplet annihilation and triplet-polaron annihilation of excitons on the guest light-emitting material, thus is beneficial for improving the utilization ratio of triplet excitons of the blue light-emitting material, further beneficial for improving the luminous efficiency of the OLED device, and beneficial for reducing the power consumption when applied to the OLED display device.

In order to further suppress the physical process of the guest light-emitting material becoming an electron potential well, reduce the opportunities for triplet-triplet annihilation and triplet-polaron annihilation of excitons on the guest light-emitting material, and further improve the utilization rate of triplet excitons of the blue light-emitting material and further improve the luminous efficiency of the OLED device, preferably, L₁ and L₂ satisfy the relationship: 0.20 eV≤L₂−L₁≤0.40 eV.

In order to more further suppress the physical process of the guest light-emitting material becoming an electron potential well, reduce the opportunities for triplet-triplet annihilation and triplet-polaron annihilation of excitons on the guest light-emitting material, and more further improve the utilization rate of triplet excitons of the blue light-emitting material and more further improve the luminous efficiency of the OLED device, preferably, L₁ and L₂ satisfy the relationship: 0.25 eV≤L₂−L₁≤0.35 eV.

In a preferred embodiment, the singlet energy level S₁ of the guest light-emitting material and the triplet energy level T₁ of the exciton utilizing agent satisfy the relationship equation: T₁>S₁. The triplet energy level T₁ of the exciton utilizing agent is larger than the singlet energy level S₁ of the guest light-emitting material, which is beneficial for converting the triplet excitons of the exciton utilizing agent into the singlet excitons through the RISC process, and then transferring to the guest light-emitting material through energy transfer, thereby improving the utilization rate of the exciton, and further improving the luminous efficiency of the OLED device.

In a preferred embodiment, the HOMO energy level of the hole-type host material is H₃, and H₁, H₂, and H₃ satisfy the relationship: H₁−H₃≥0 eV, H₂−H₃≥0.15 eV. HOMO energy level H₁ of guest light-emitting material is higher than the HOMO energy level H₃ of the hole-type host material, the HOMO energy level H₂ of the exciton utilizing agent is higher than the HOMO energy level H₃ of the hole-type host material, which is conducive to better realizing energy transfer among the host material, the exciton utilizing agent and the guest light-emitting material, and thus beneficial for improve the exciton utilizing rate and improve the luminous efficiency of the OLED device.

In order to further improve the exciton utilization rate and enhance the luminous efficiency of OLED devices, preferably, H₁, H₂, and H₃ satisfy the relationship: H₁−H₃≥0.05 eV, H₂−H₃≥0.20 eV.

In a preferred embodiment, the bond dissociation energies of the electron-type host material and the exciton utilizing agent in the anionic state, the electrically neutral state and the cationic state are each independently ≥2.8 eV. Compared with other ranges, by limiting the minimum value of bond dissociation energy of the three materials in the organic light-emitting layer 30 within the specific range described above, it is beneficial for enhancing the stability of molecules in anionic state, triplet excited state and cationic state, and can effectively inhibit the degradation pathway of each material in triplet-triplet annihilation and triplet-polaron annihilation process, thereby improving the stability of each material in the working process of the OLED device and achieving a longer lifetime of the device.

In order to improve the stability of the host material in anionic state, electrically neutral state, and cationic state, further suppress the degradation pathway of the host material in triplet triplet annihilation and triplet polaron annihilation processes, and thereby enhance the stability of the host material in the operation of organic electroluminescent devices, it is preferred that the minimum bond dissociation energy of electron-type host materials in anionic, electrically neutral, and cationic states be ≥3.0 eV.

In order to improve the stability of the exciton utilizing agent in the anionic state, the electrically neutral state and the cationic state, further suppress the degradation pathway of the exciton utilizing agent in the triplet-triplet annihilation and the triplet-polaron annihilation process, and thereby improve the stability of the exciton utilizing agent in the operation process of the organic electroluminescent device, preferably, the minimum value of the bond dissociation energy of the exciton utilizing agent in the anionic state, the electrically neutral state and the cationic state is ≥3.0 eV.

In a preferred embodiment, the hole-type host material includes but not limited to one or more of the compounds represented by general formulae (I) and (II):

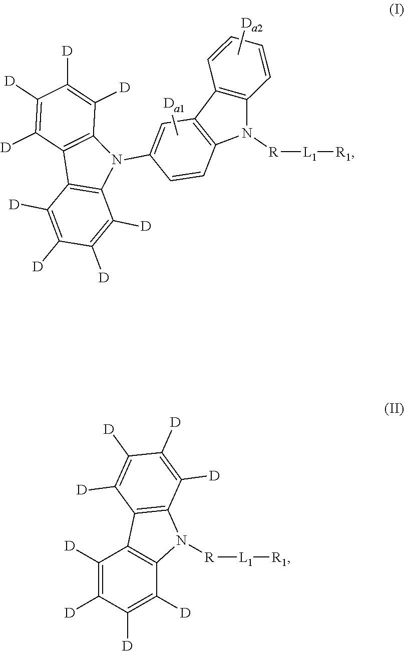

wherein R includes but not limited to a connecting bond or a phenylene group substituted by at least one deuterium atom, and L₁ includes but not limited to a connecting bond, a phenylene group, or a phenylene group substituted by at least one deuterium atom, R₁ includes but not limited to

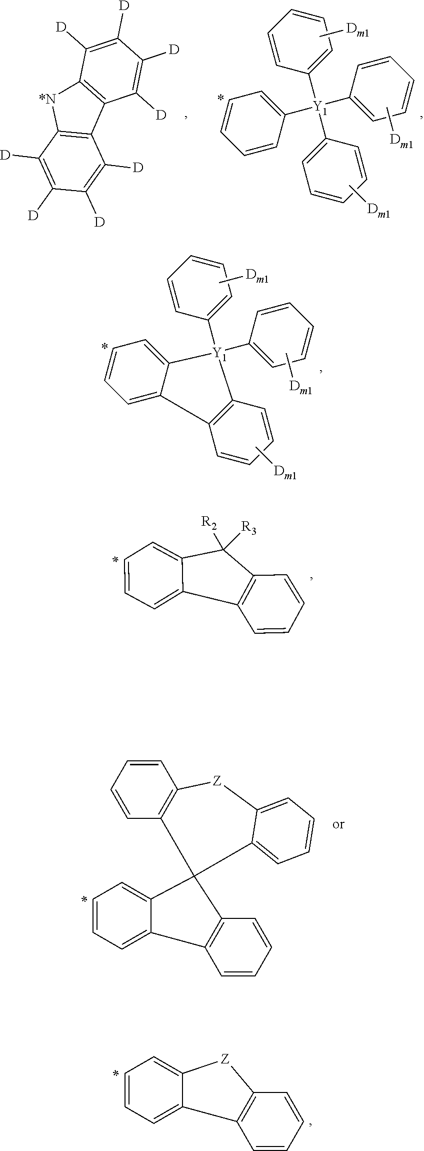

wherein Y₁ includes but not limited to Si or Ge, and m1 represents a substitution by any one of 0 to 5 integer deuterium atoms in the corresponding benzene ring structure, m2 represents a substitution by any one of 0 to 4 integer deuterium atoms in the corresponding benzene ring structure, R₂ and R₃ each independently include but not limited to C₁-C₆ alkyl or C₆-C₂₀ aryl groups, Z includes but not limited to a connecting bond, O or S; n1 represents a substitution by any one of 0 to 3 integer deuterium atoms in the corresponding benzene ring structure, and n2 and n3 represent a substitution by any one of 0 to 4 integer deuterium atoms in the corresponding benzene ring structure.

Compared with other types, adopting the hole-type host material having the structure represented by the general formulae (I) to (V) is advantageous in improving the triplet energy level and bond dissociation energy of the hole-type host material, thus improving the luminous efficiency of the OLED device and prolonging the lifetime of the OLED device, and the application of the hole-type host material to an OLED display device is advantageous in reducing power consumption and improving the stability of the display device.

In order to further improve the triplet energy level and bond dissociation energy of the hole-type host material, further improve the luminous efficiency of the OLED device and prolong the lifetime of the OLED device, preferably, R includes but not limited to a connecting bond,

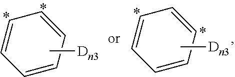

and n3 represents a substitution by any one of 0 to 4 integer deuterium atoms in the corresponding benzene ring structure, preferably 0 or 4 deuterium atoms.

In a preferred embodiment, the hole-type host material has one or more of the compounds represented by general formulae (Ia), (Ib), (Ic), (Id) and (IIa):

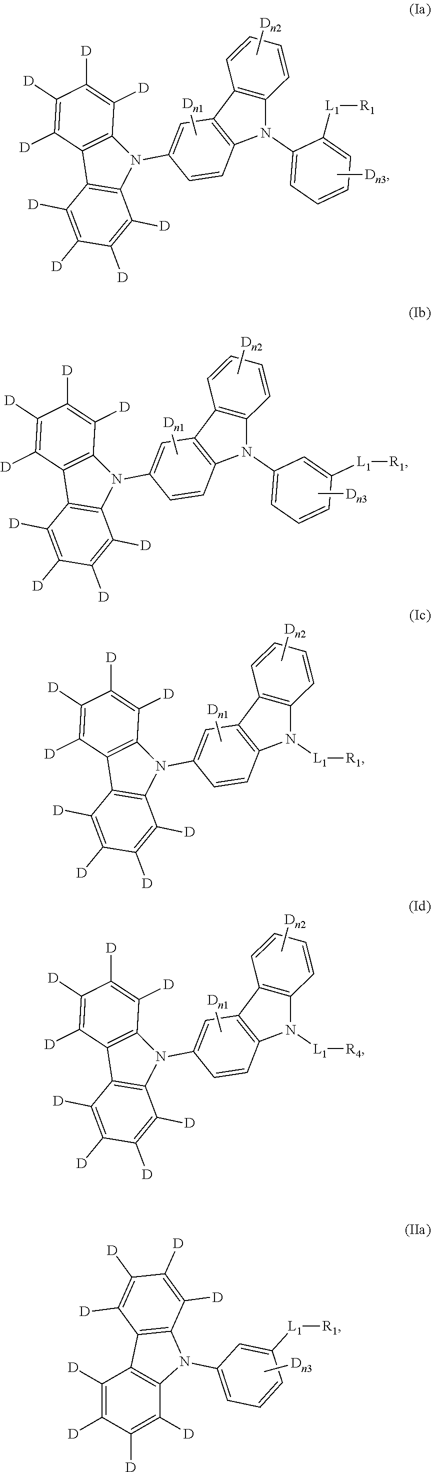

wherein R₁ includes but not limited to

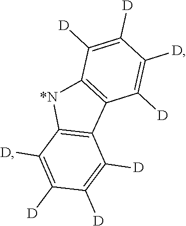

R₄ includes but not limited to

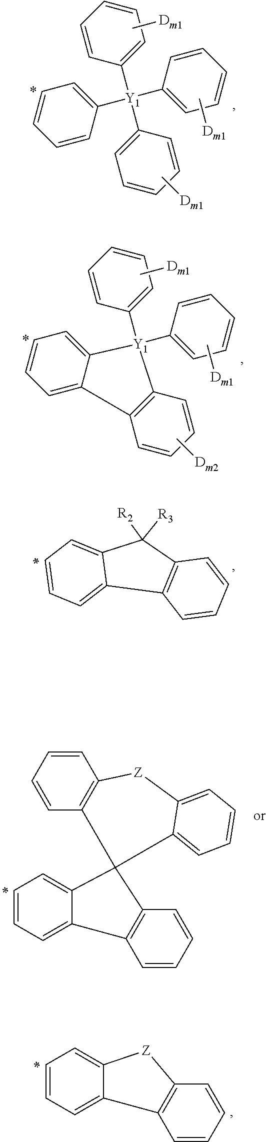

Compared with other types, adopting the hole-type host material having the structure represented by the general formulae (I) to (V) is advantageous in improving the triplet energy level and bond dissociation energy of the hole-type host material, thus improving the luminous efficiency of the OLED device and prolonging the lifetime of the OLED device, and the application of the hole-type host material to an OLED display device is advantageous in reducing power consumption and improving the stability of the display device.

In a preferred embodiment, L₁ includes but not limited to a connecting bond, a phenylene group, or a phenylene group substituted with 4 deuterium atoms, and n1 represents a substitution by 0 or 3 deuterium atoms in the corresponding benzene ring structure, and n2 and n3 each independently represent a substitution by 0 or 4 deuterium atoms in the corresponding benzene ring structure, and R₂ and R₃ each independently include but not limited to methyl or phenyl. Compared with other types, adopting the hole-type host material with the above structure is beneficial to further improving the bond dissociation energy of the hole-type host material and improving the optical stability, electrical stability and chemical stability of the hole-type host material; meanwhile, the hole transport capacity of the hole-type host material is further regulated and matched with the electron-type host material, so as to better regulate the exciton recombination region of the light-emitting layer, thereby being beneficial to further improving the luminous efficiency and the lifetime of the OLED device.

In a preferred embodiment, the hole-type host material includes but not limited to one or more of Compound HH1 to Compound HH29:

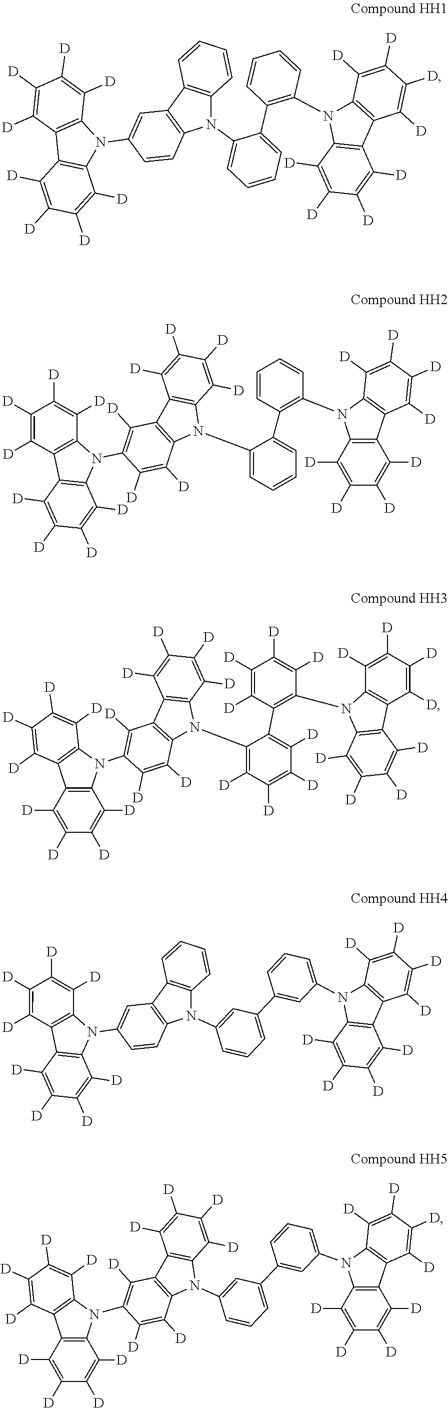

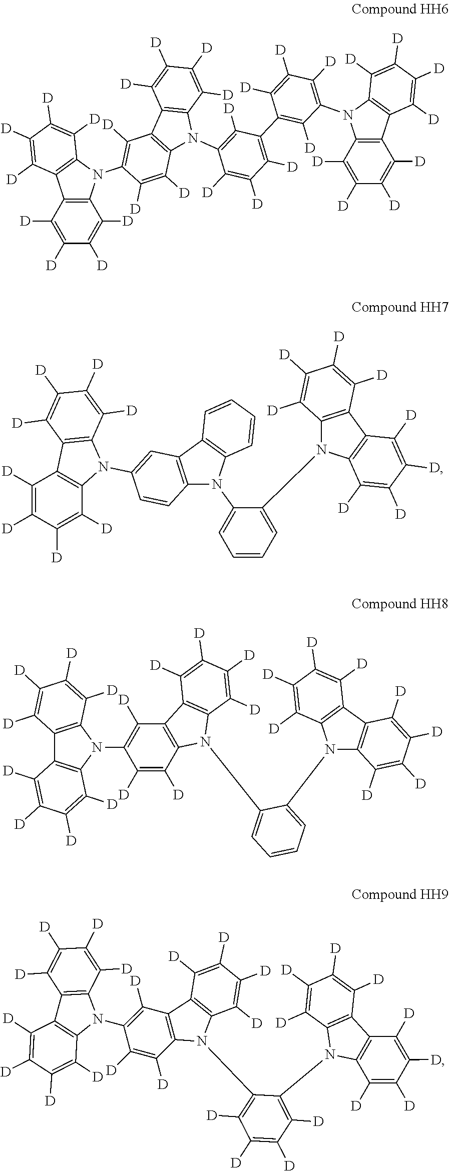

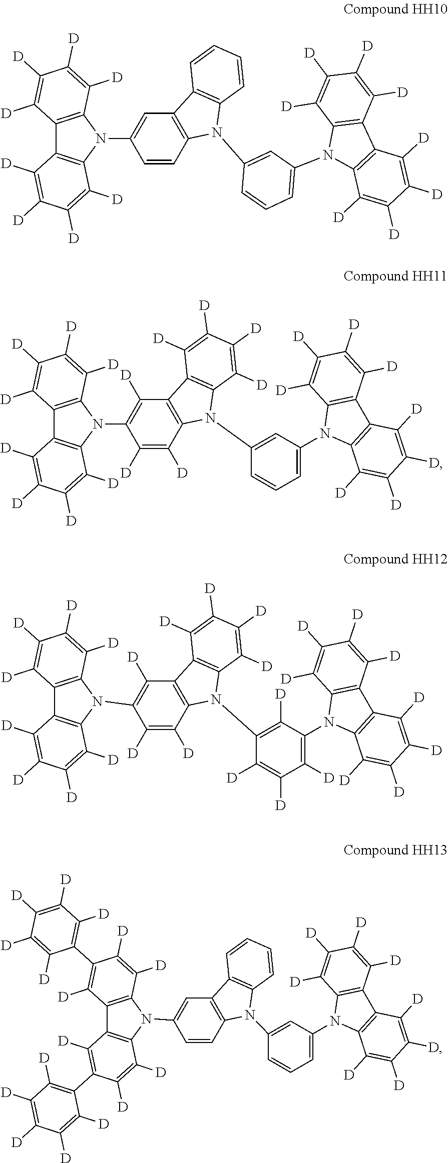

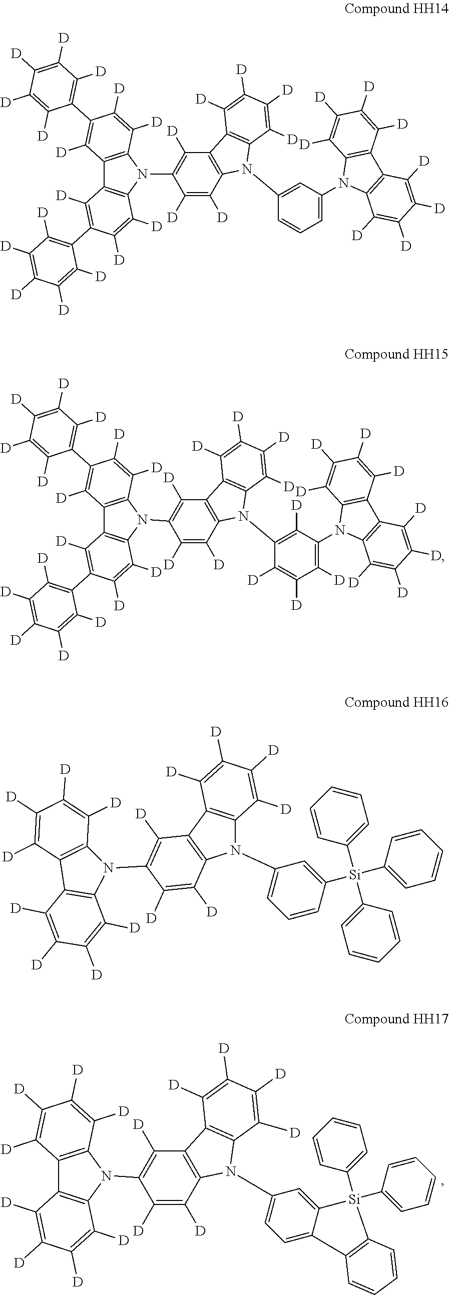

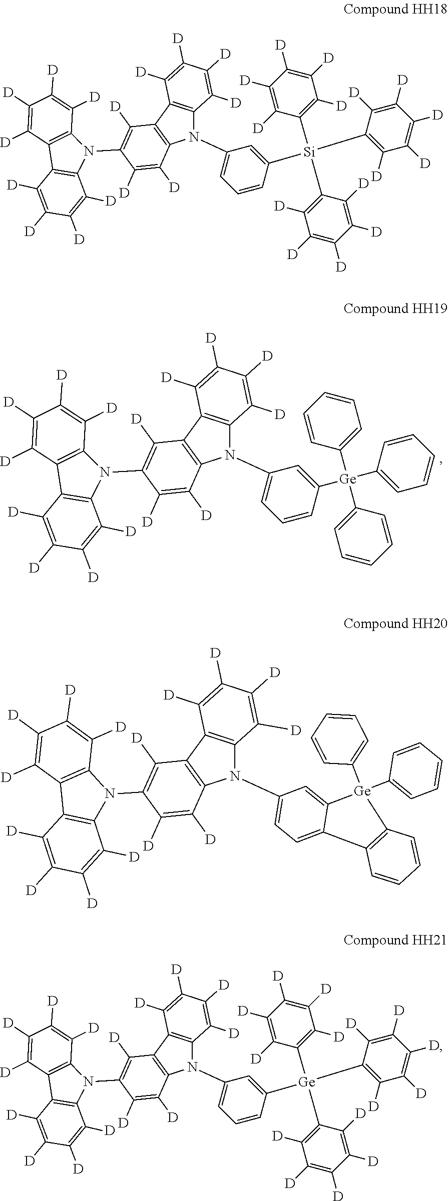

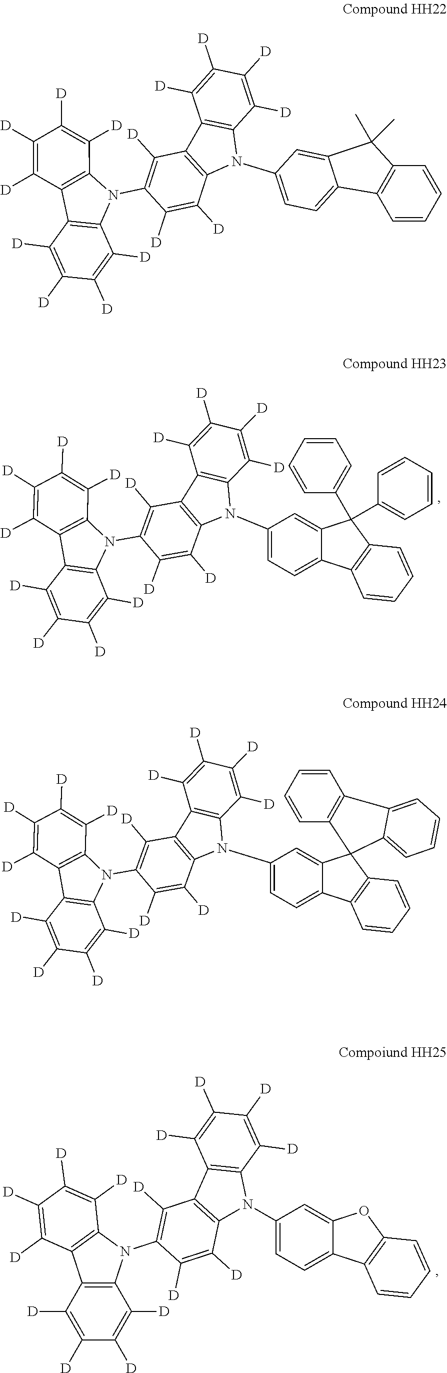

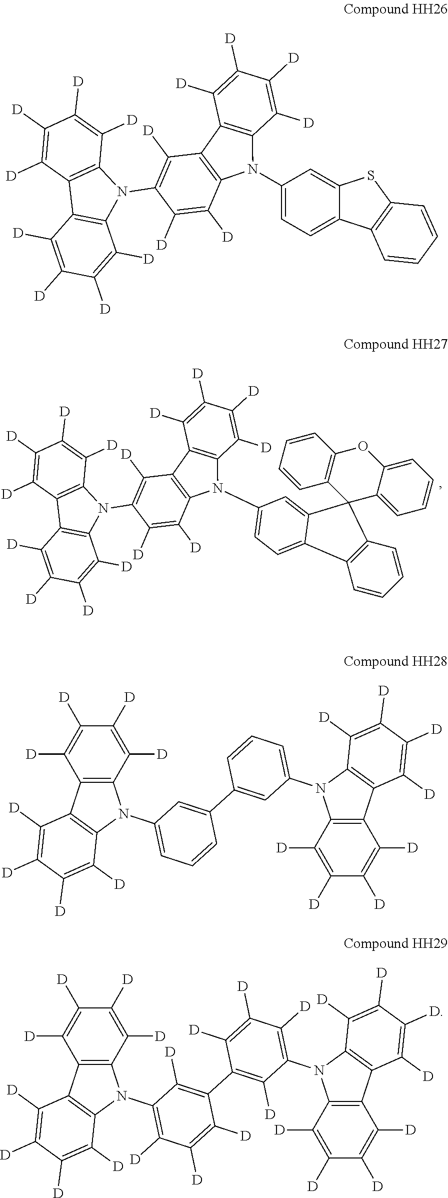

The present application also provides a synthetic route of the compound represented by the above general formula (Ia), which is as follows:

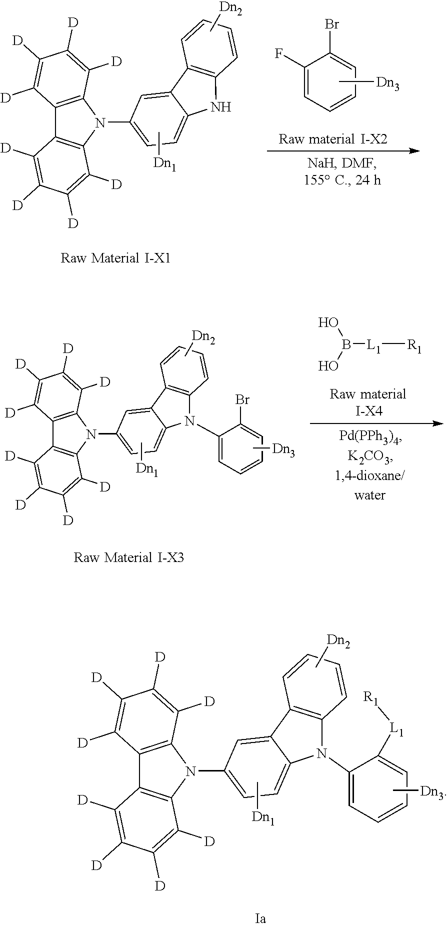

The present application also provides a synthetic route of the compound represented by the above general formula (Ib), which is as follows:

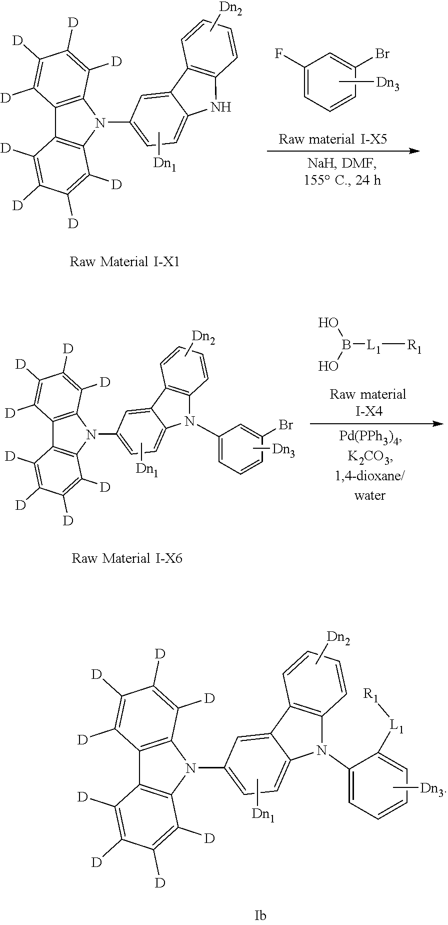

The present application also provides a synthetic route of the compound represented by the above general formula (Ic), which is as follows:

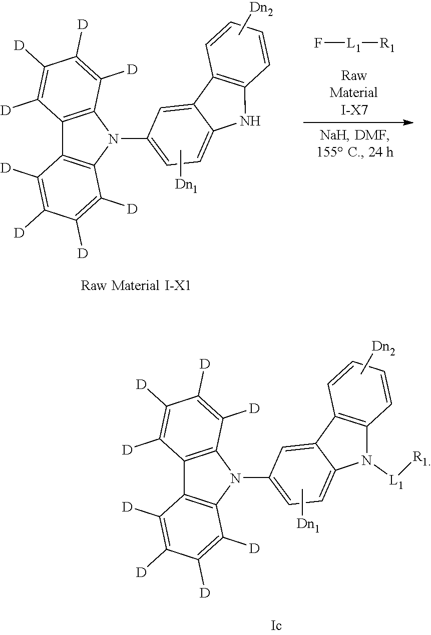

The present application also provides a synthetic route of the compound represented by the above general formula (Id), which is as follows:

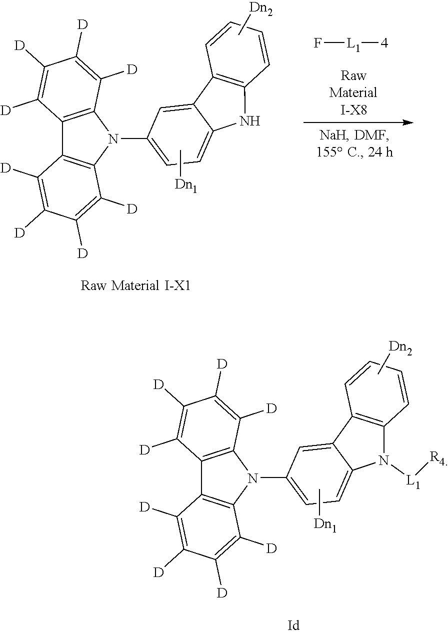

The present application also provides a synthetic route of the compound represented by the above general formula (IIa), which is as follows:

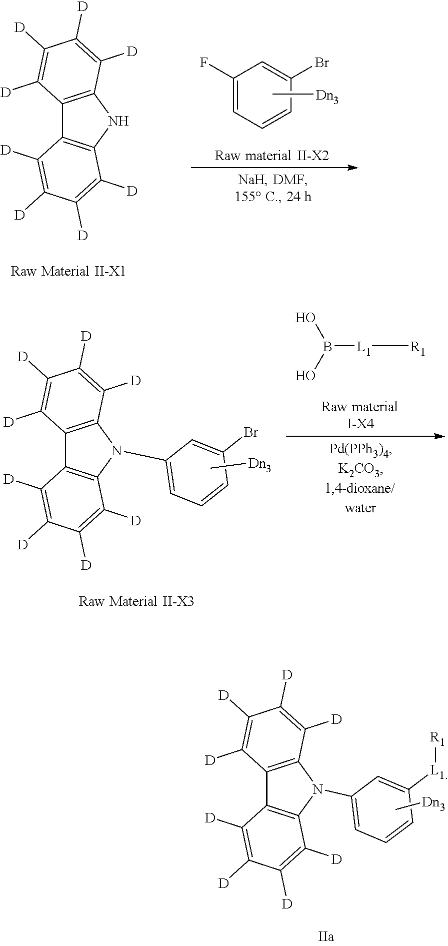

In a preferred embodiment, the electron-type host material includes but not limited to one or more of the compounds represented by general formulae (III) and (XIV):

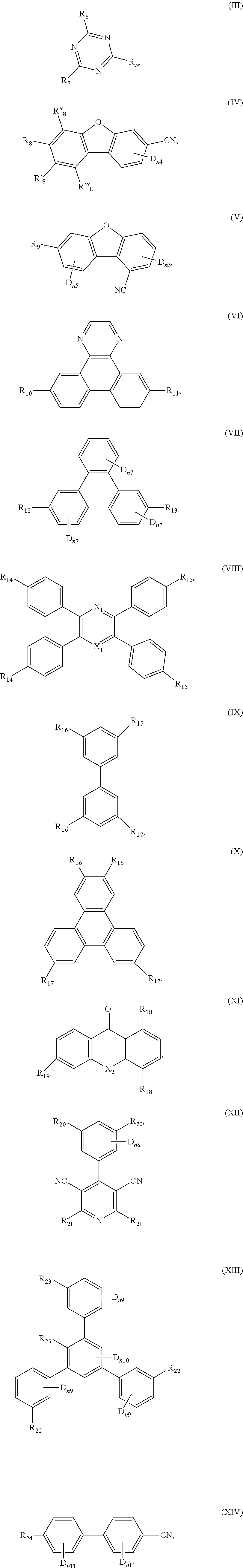

wherein R₅, R₆, and R₇ each independently include but not limited to C₆-C₂₀ aryl, C₆-C₂₀ aryl substituted with at least one deuterium atom,

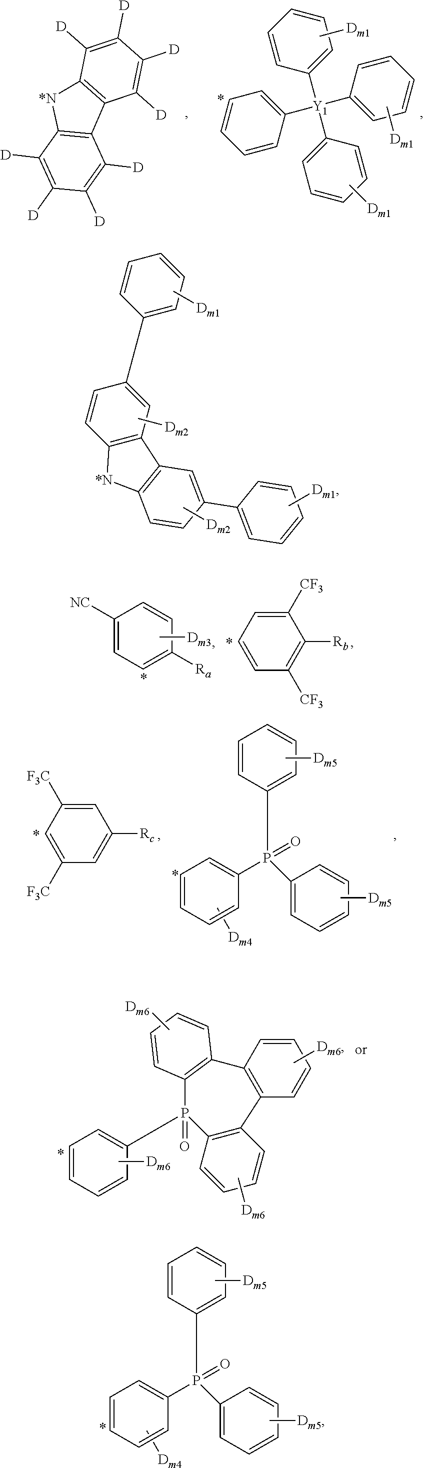

wherein Y₂ includes but not limited to Si or Ge, wherein Rₐ includes but not limited to

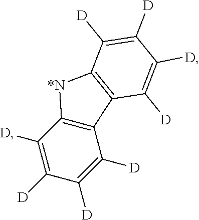

R_{b} and R_{c} each independently include but not limited to hydrogen,

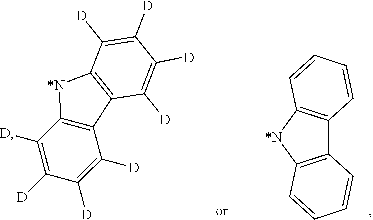

and m1 and m5 represent a substitution by any one of 0 to 5 integer deuterium atoms in the corresponding benzene ring structure, m2 and m3 represent a substitution by any one of 0 to 3 integer deuterium atoms in the corresponding benzene ring structure, and m4 and m6 represent a substitution by any one of 0 to 4 integer deuterium atoms in the corresponding benzene ring structure; R₈, R′₈, R″₈, and R′″₈ each independently comprise but not limited to hydrogen, deuterium, or

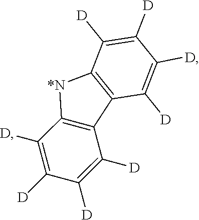

and R₈, R′₈, R″₈, and R′″₈ are not

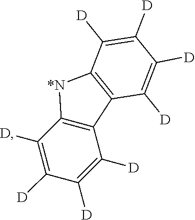

at the same time, n4 represents a substitution by any one of 0 to 3 integer deuterium atoms in the corresponding benzene ring structure; R₉ includes but not limited to hydrogen, deuterium, or

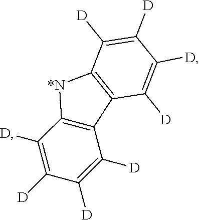

n5 and n6 represent substitution by any one of 0 to 3 integer deuterium atoms in the corresponding benzene ring structure; R₁₀ and R₁₁ each independently include but not limited to

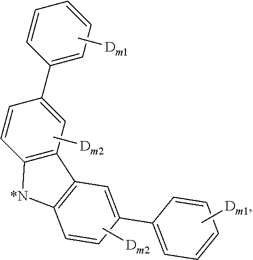

preferably

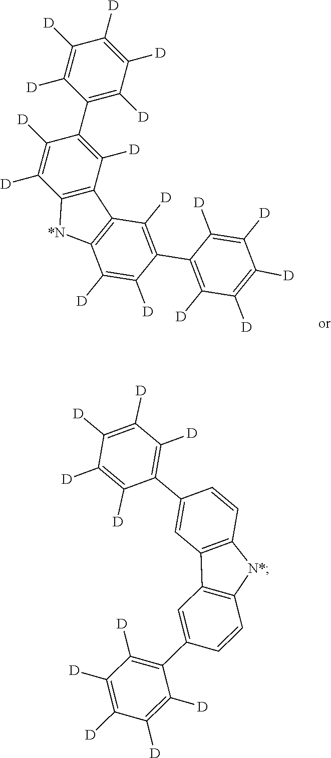

R₁₂ and R₁₃ each independently include but not limited to

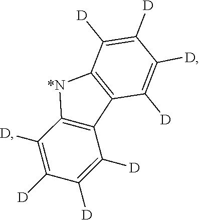

n7 represents a substitution by any one of 0 to 4 integer deuterium atoms in the corresponding benzene ring structure; X₁ includes but not limited to C or N, and R₁₄ and R₁₅ each independently include but not limited to —CF₃, —CN, or

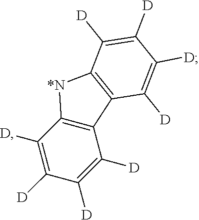

R₁₆ and R₁₇ each independently include but not limited to —CN or

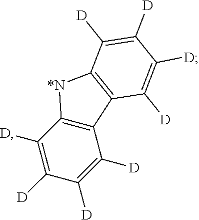

X₂ includes but not limited to O, S, or *C═O, and R₁₈ includes but not limited to

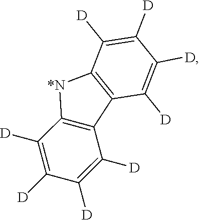

and R₁₉ includes but not limited to hydrogen,

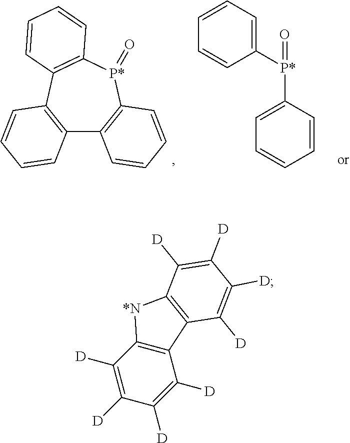

R₂₀ includes but not limited to

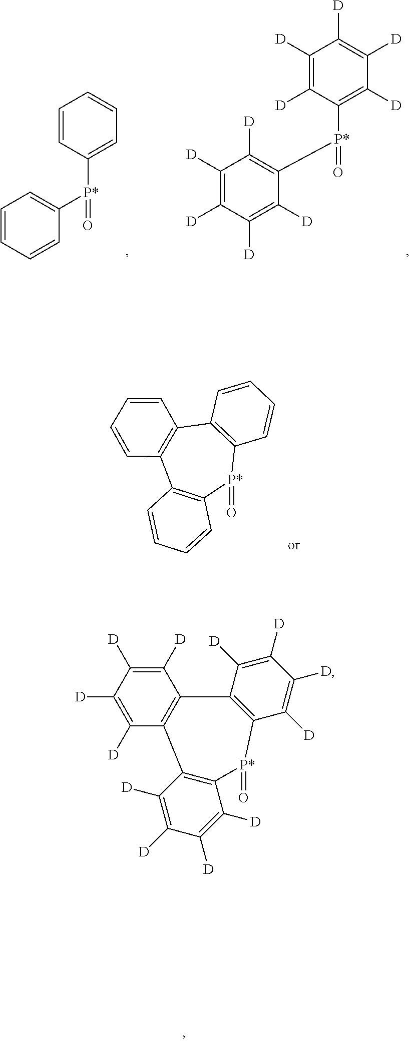

R₂₁ includes but not limited to

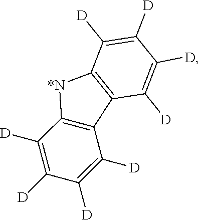

and n8 represents a substitution by any one of 0 to 3 integer deuterium atoms in the corresponding benzene ring structure; R₂₂ includes but not limited to

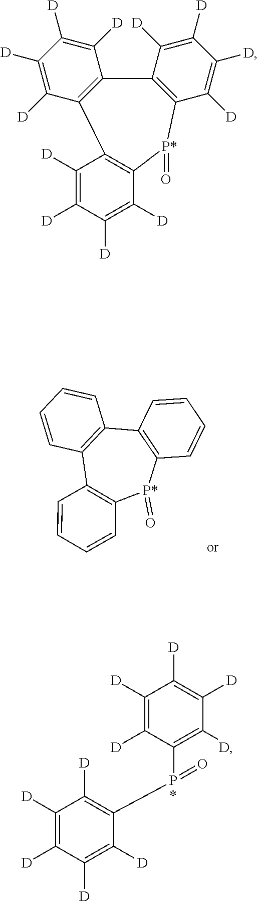

R₂₃ includes but not limited to hydrogen, —CN, or deuterium, n9 represents a substitution by any one of 0 to 4 integer deuterium atoms in the corresponding benzene ring structure, n10 represents a substitution by any one of 0 to 2 integer deuterium atoms in the corresponding benzene ring structure; R₂₄ includes but not limited to

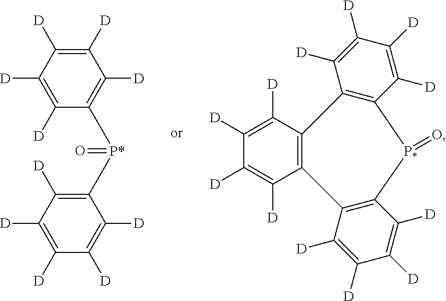

and n11 represents a substitution by any one of 0 to 2 integer deuterium atoms in the corresponding benzene ring structure.

Compared with other types, adopting the above-mentioned type of electron-type host material is beneficial to improving its triplet energy level and its electron transmission ability, thereby being beneficial to more effectively regulating the exciton recombination region; meanwhile, the above-mentioned electron-type host material has high bond dissociation energy and high stability, thereby being beneficial to improving the luminous efficiency and lifetime of OLED devices.

In a preferred embodiment, the electron-type host material includes but not limited to one or more of Compound EH1 to Compound EH80:

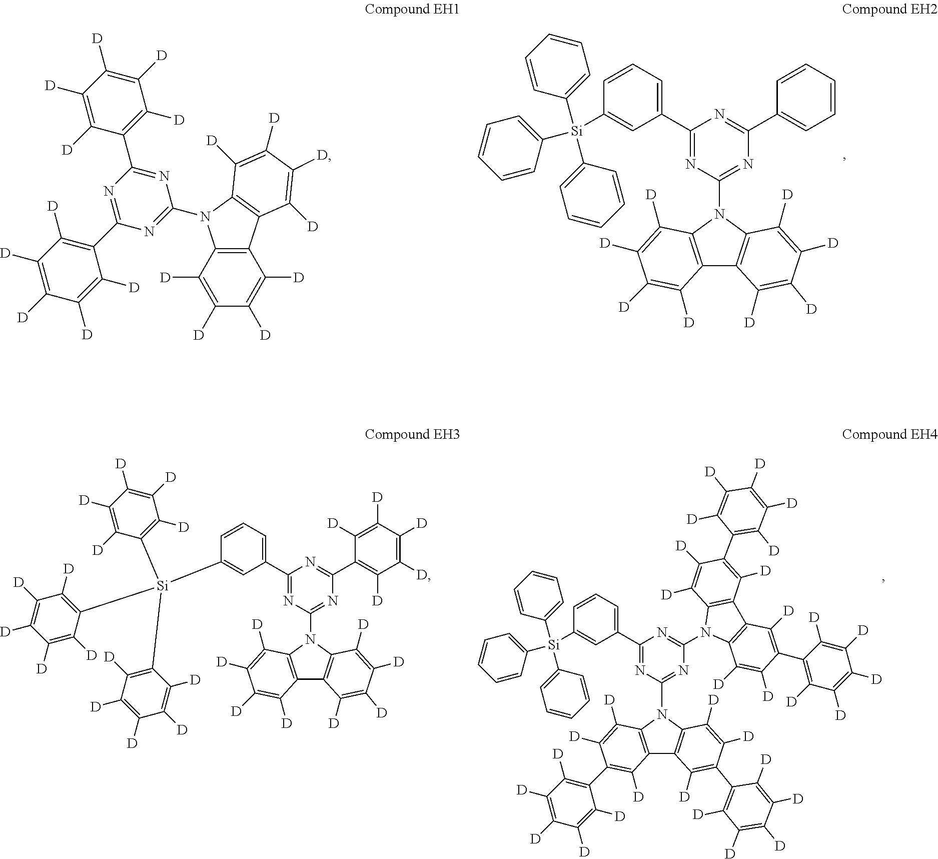

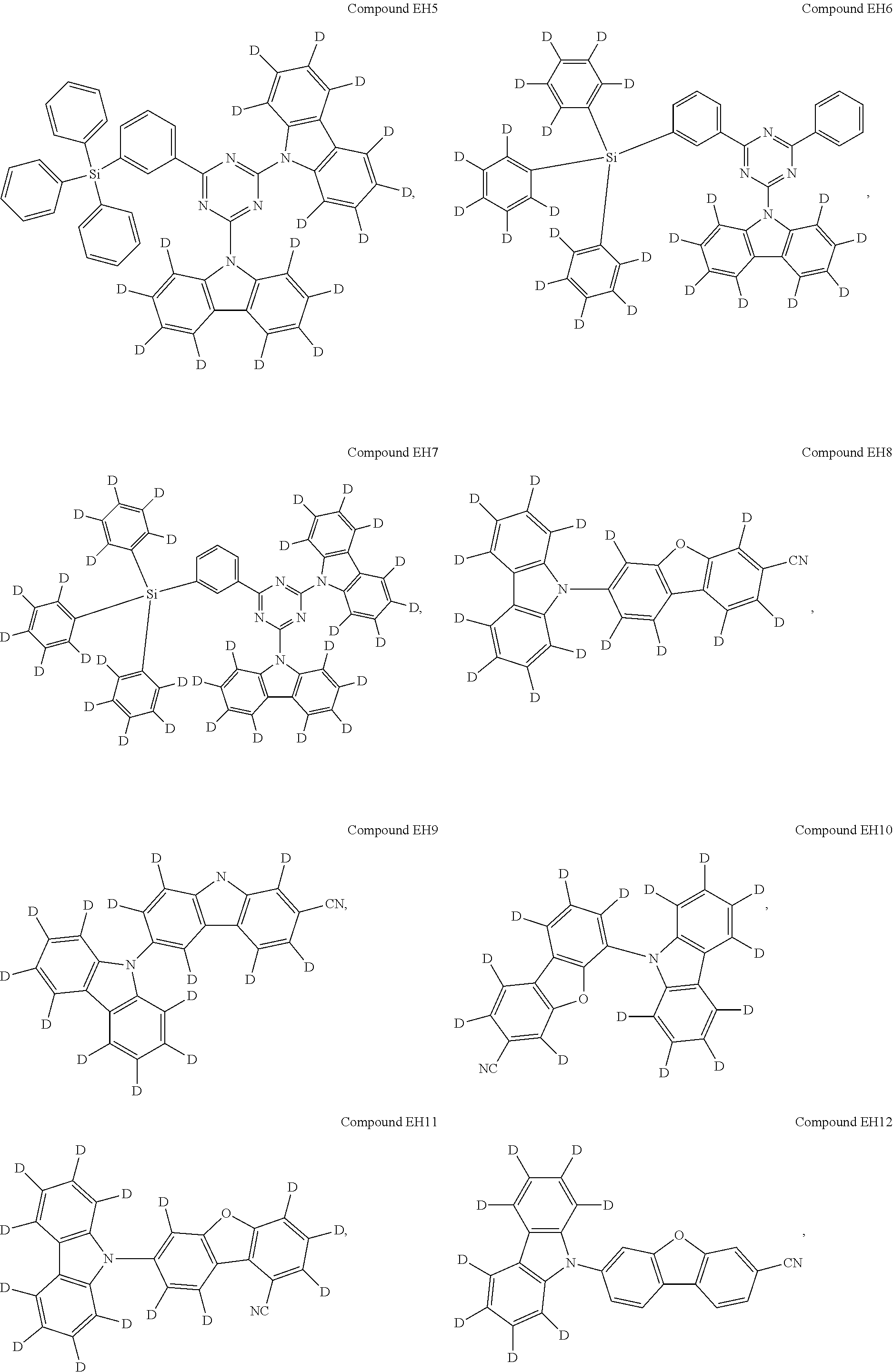

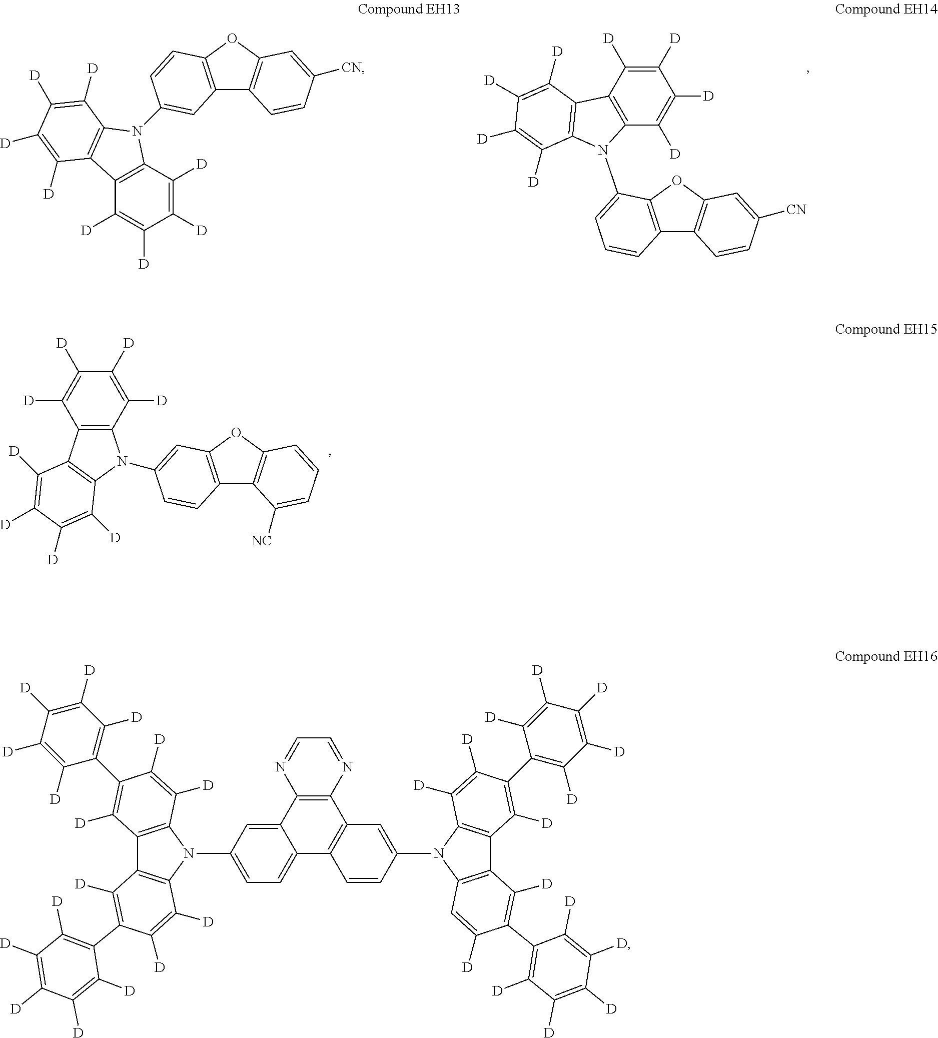

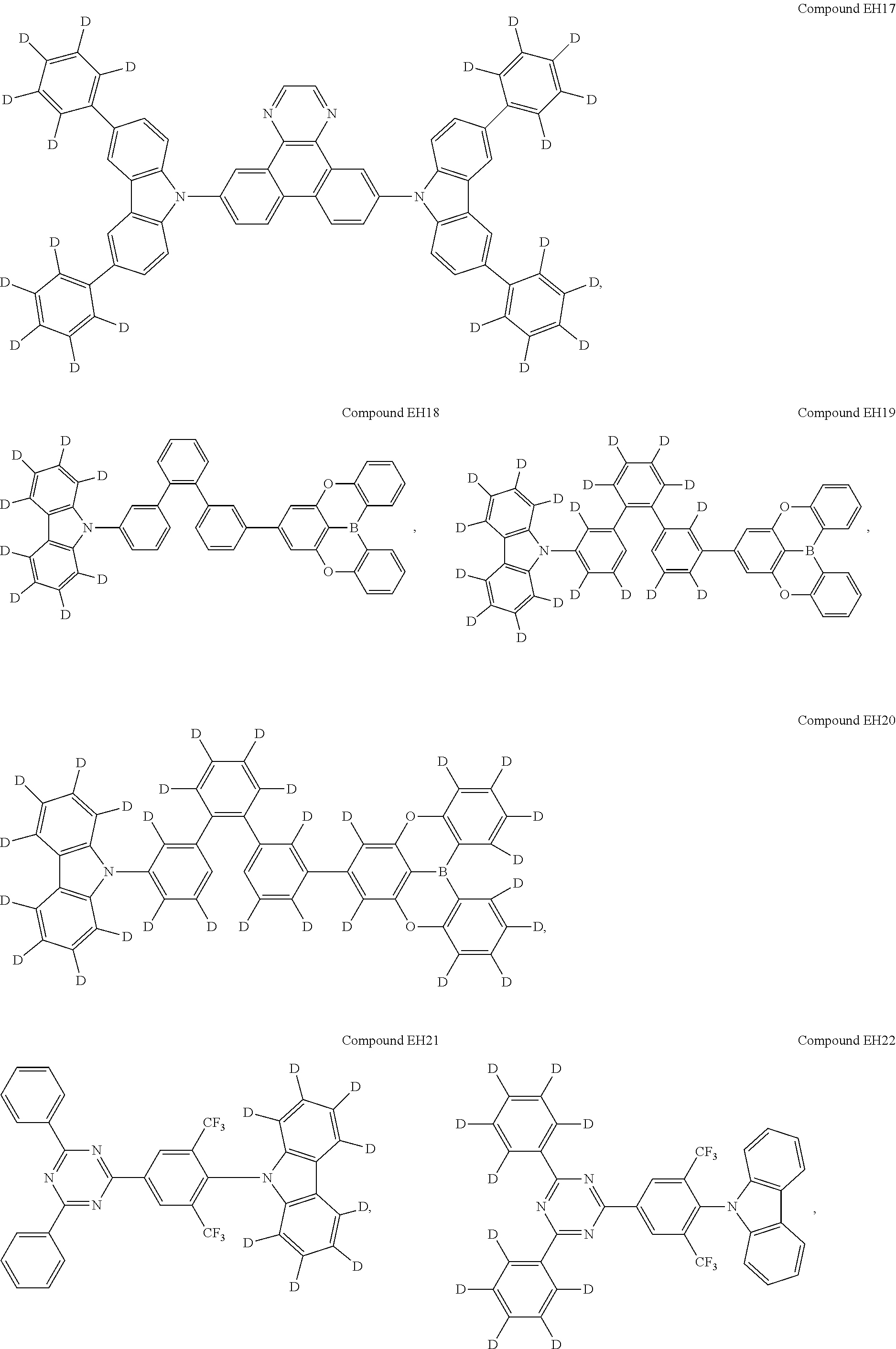

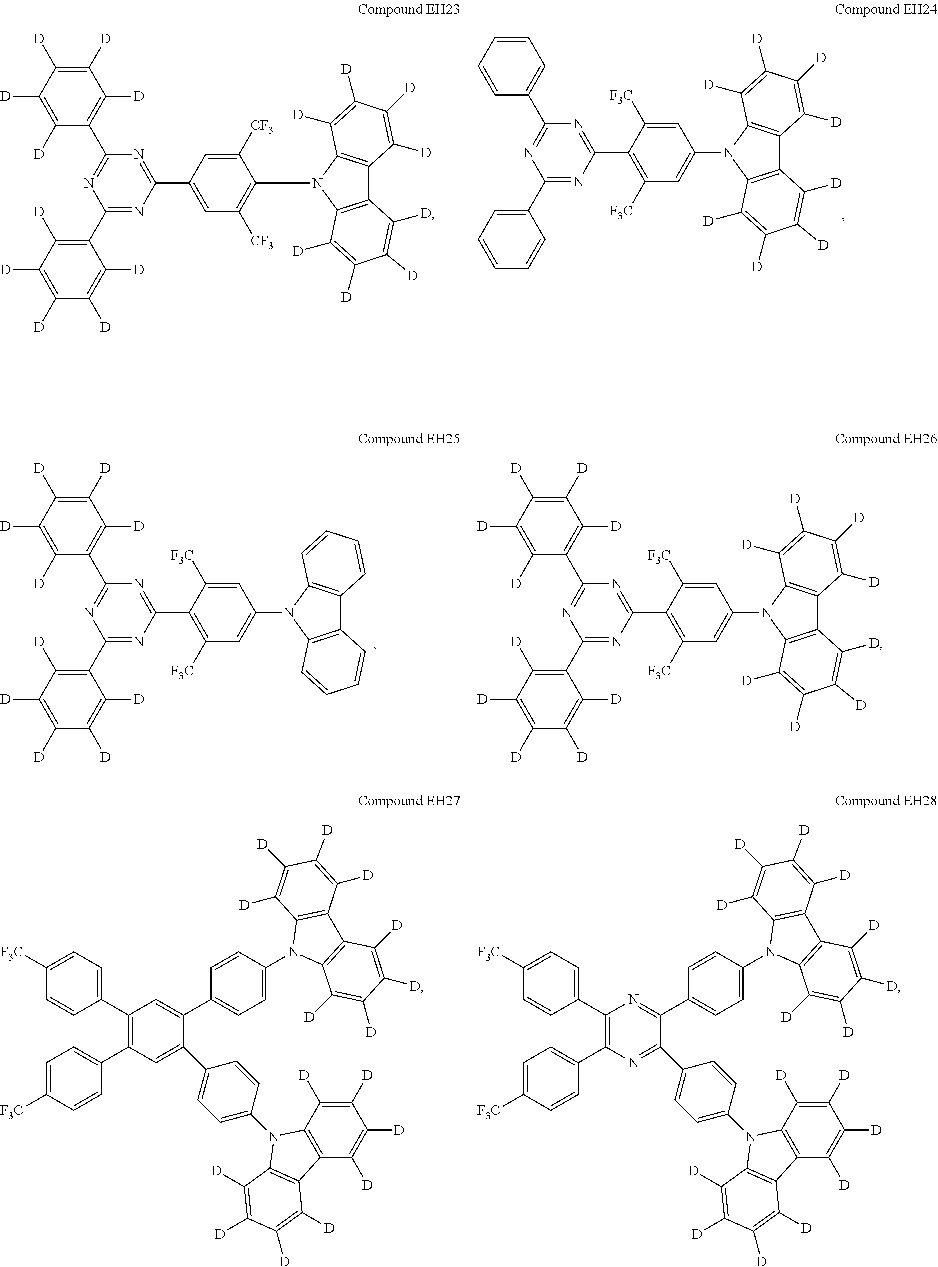

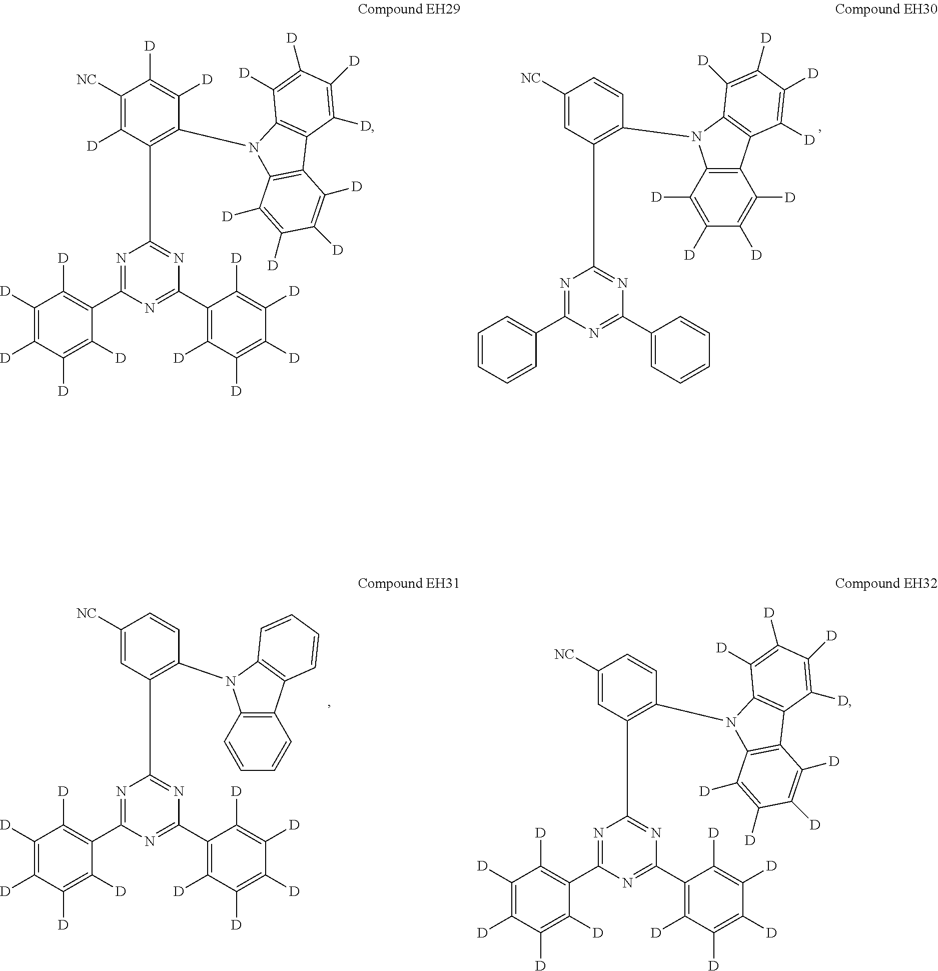

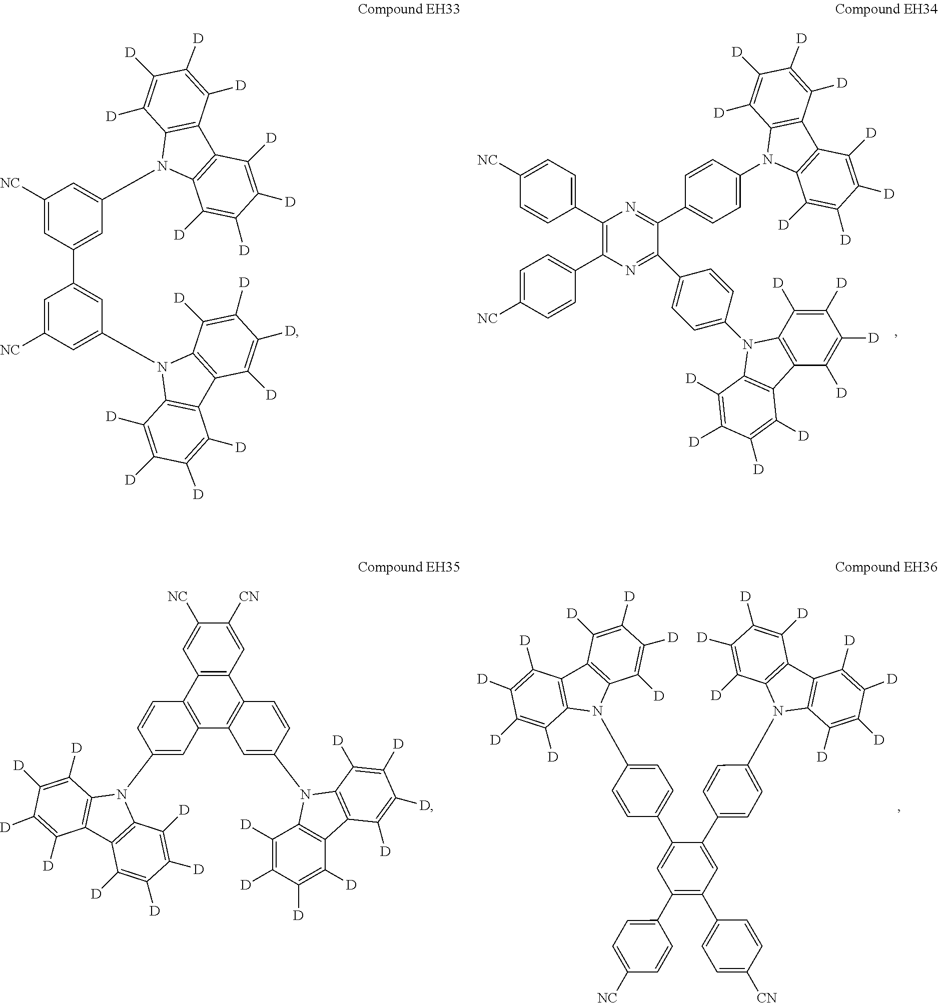

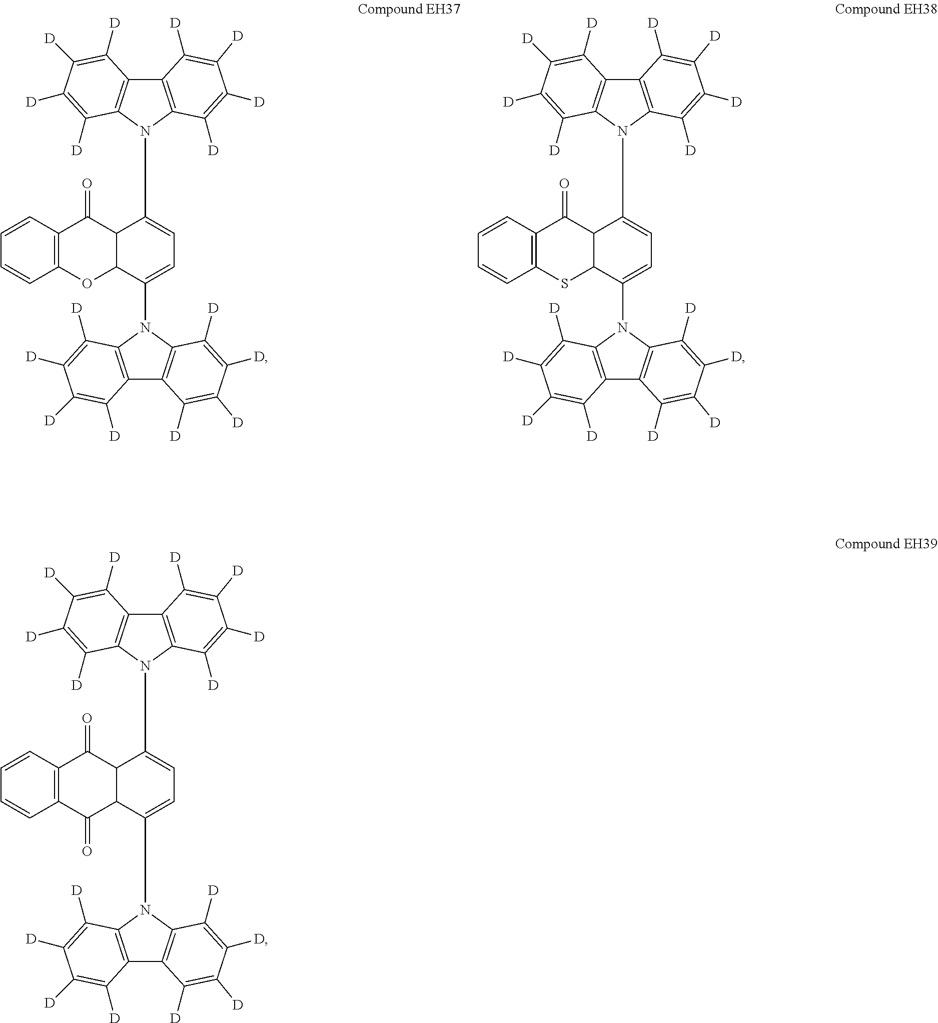

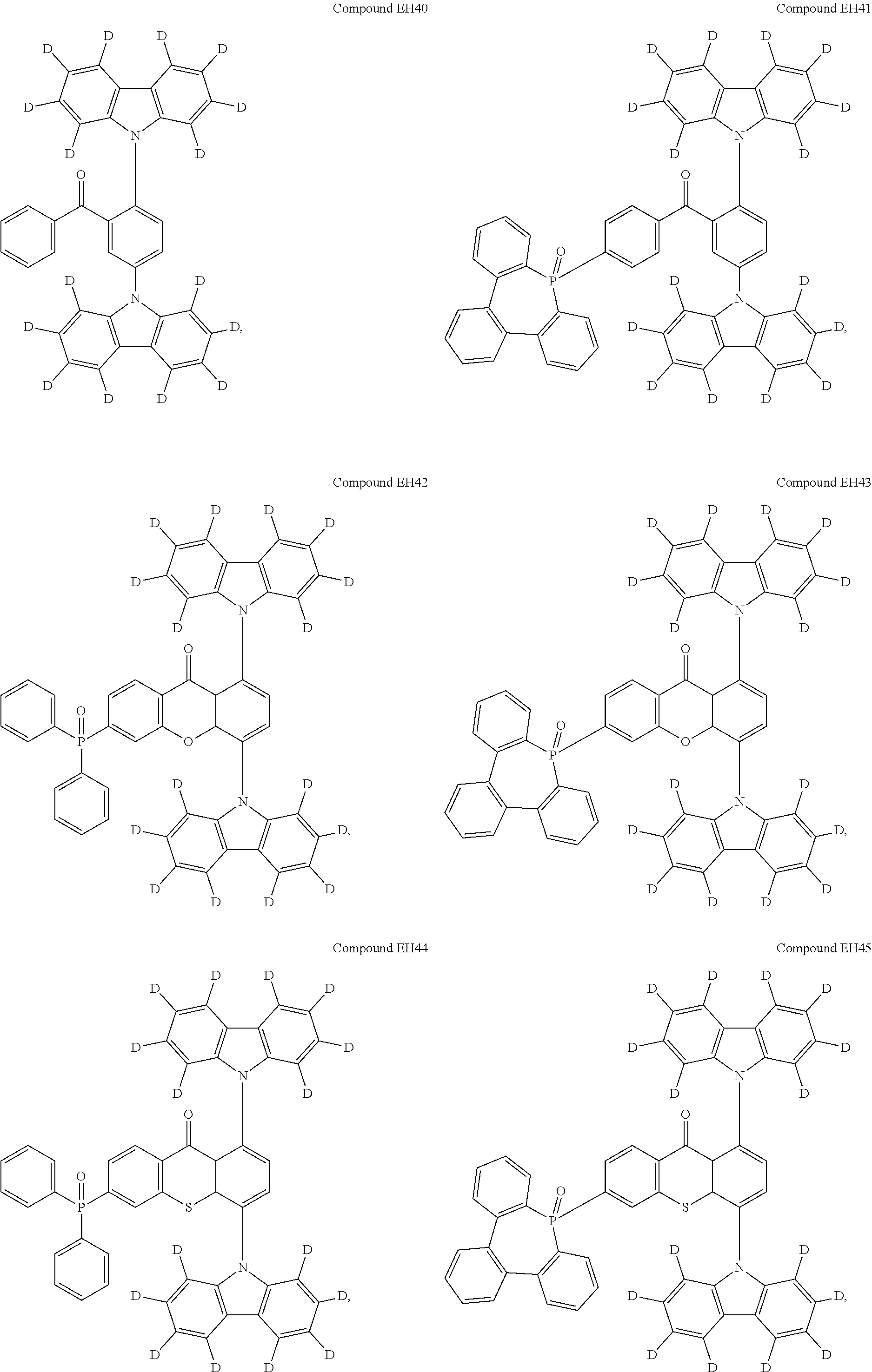

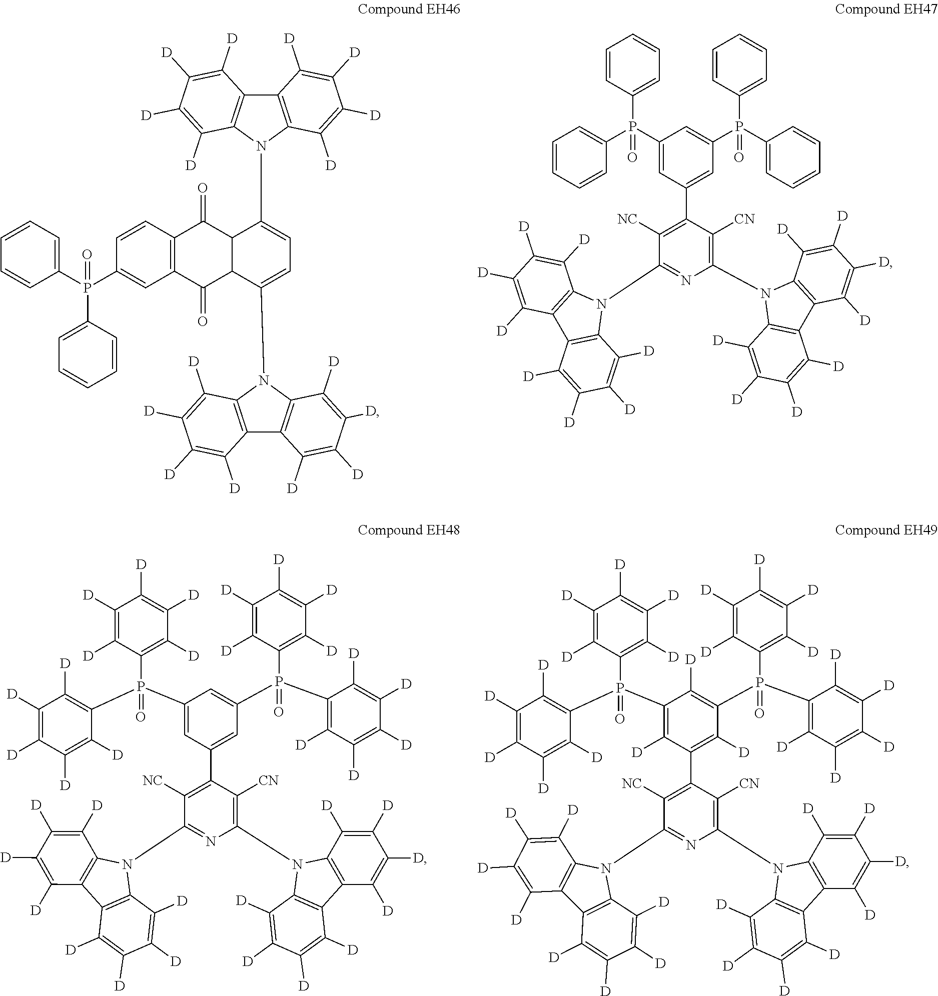

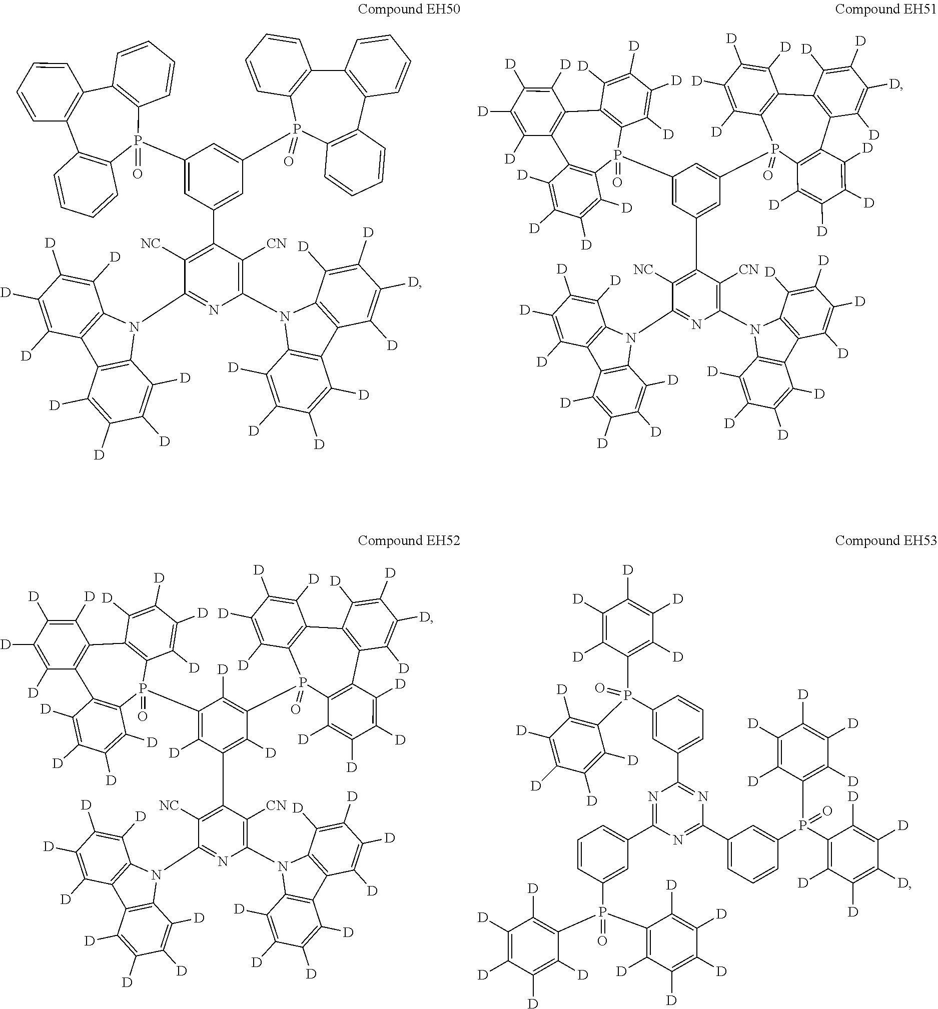

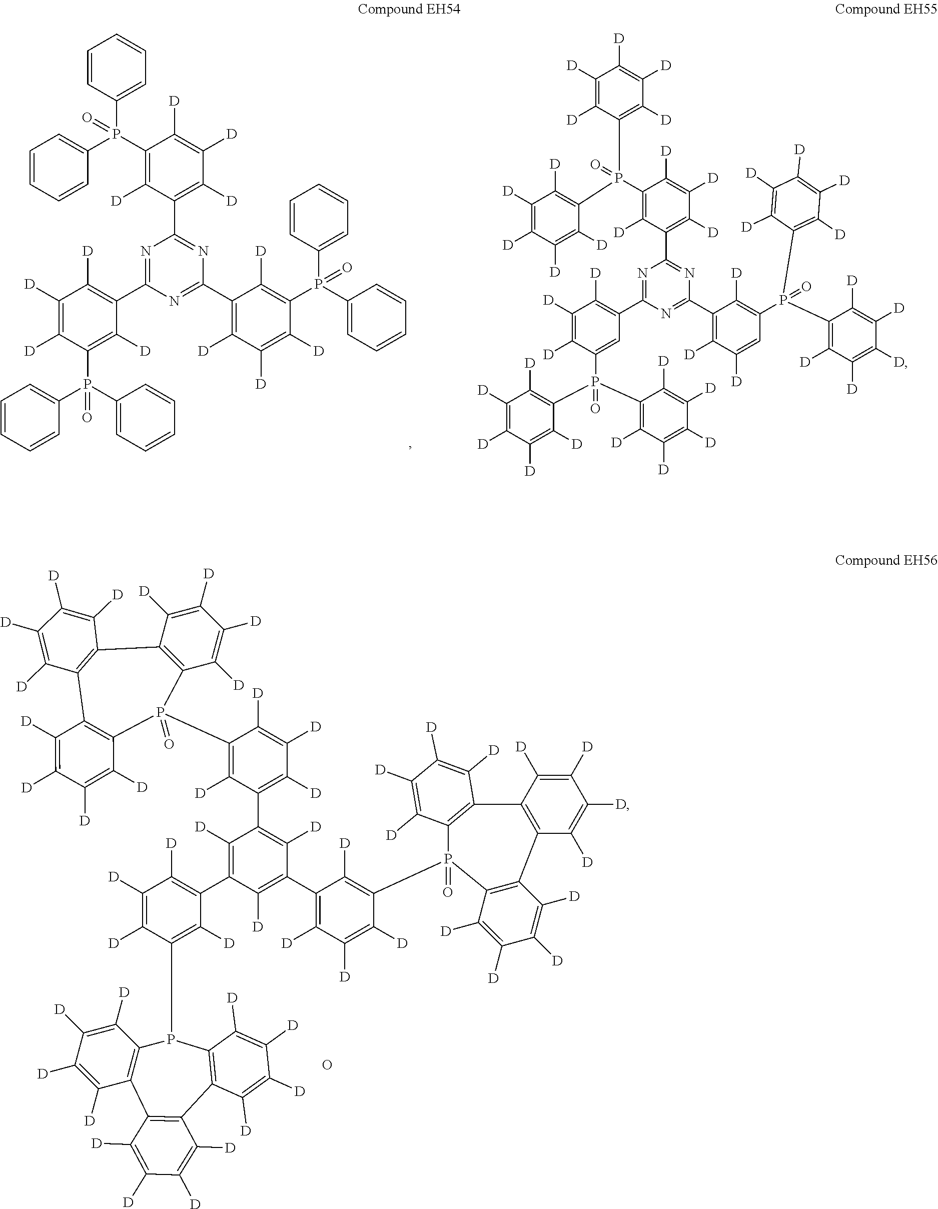

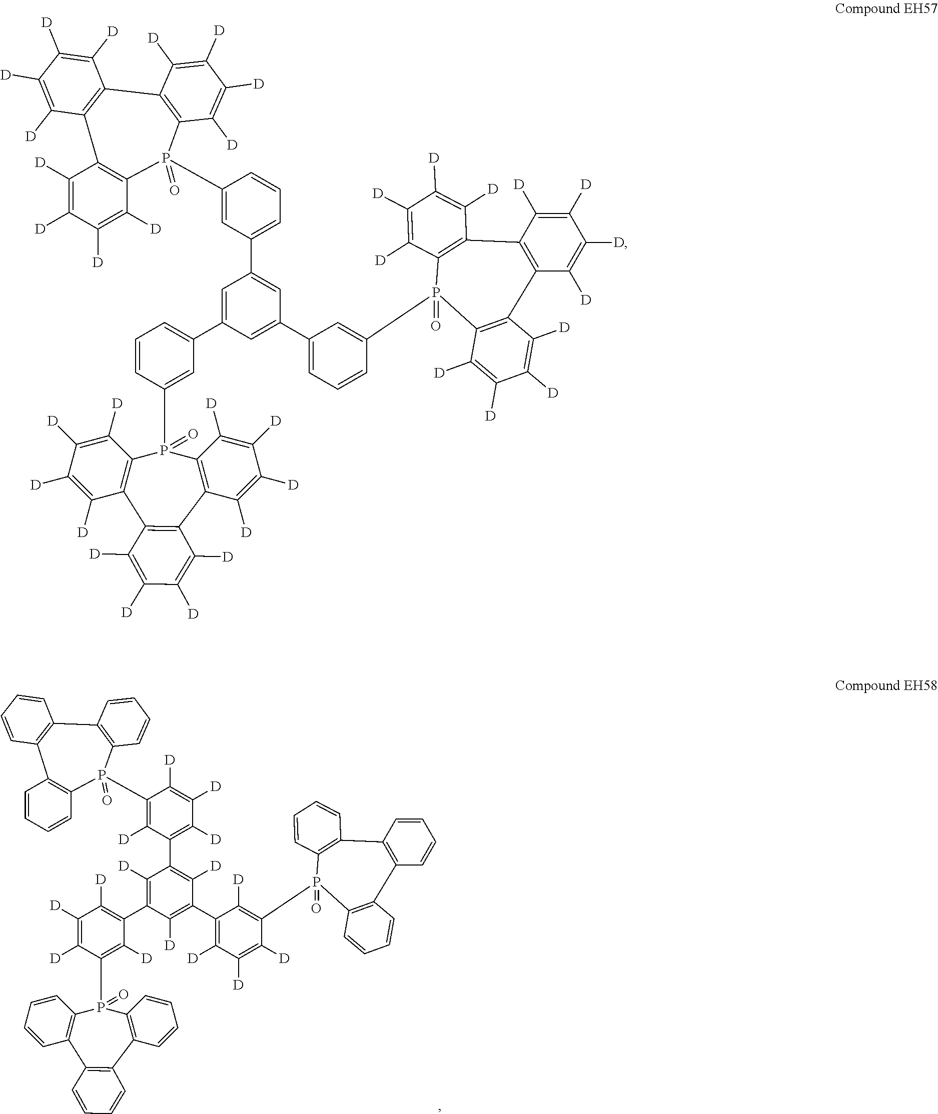

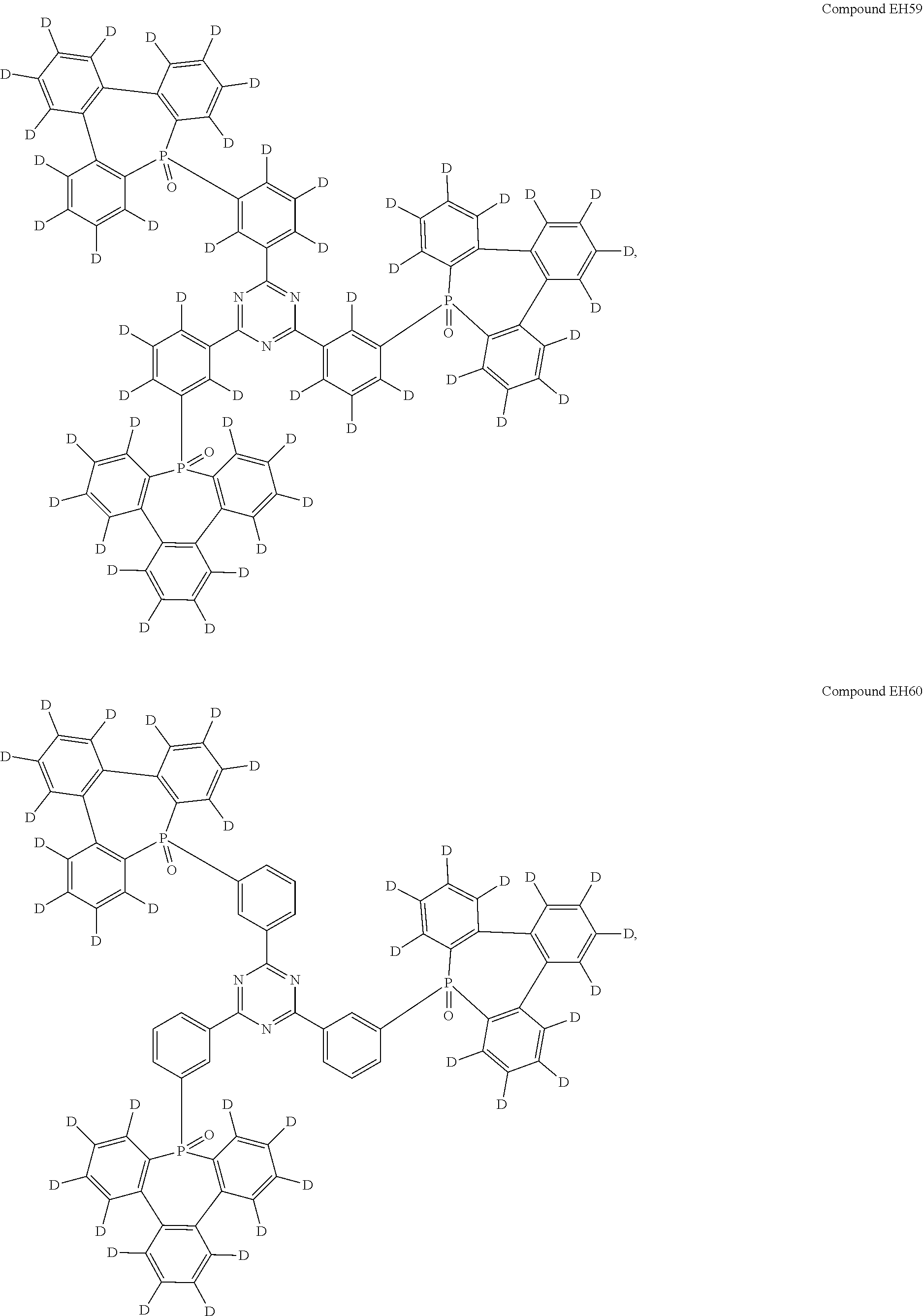

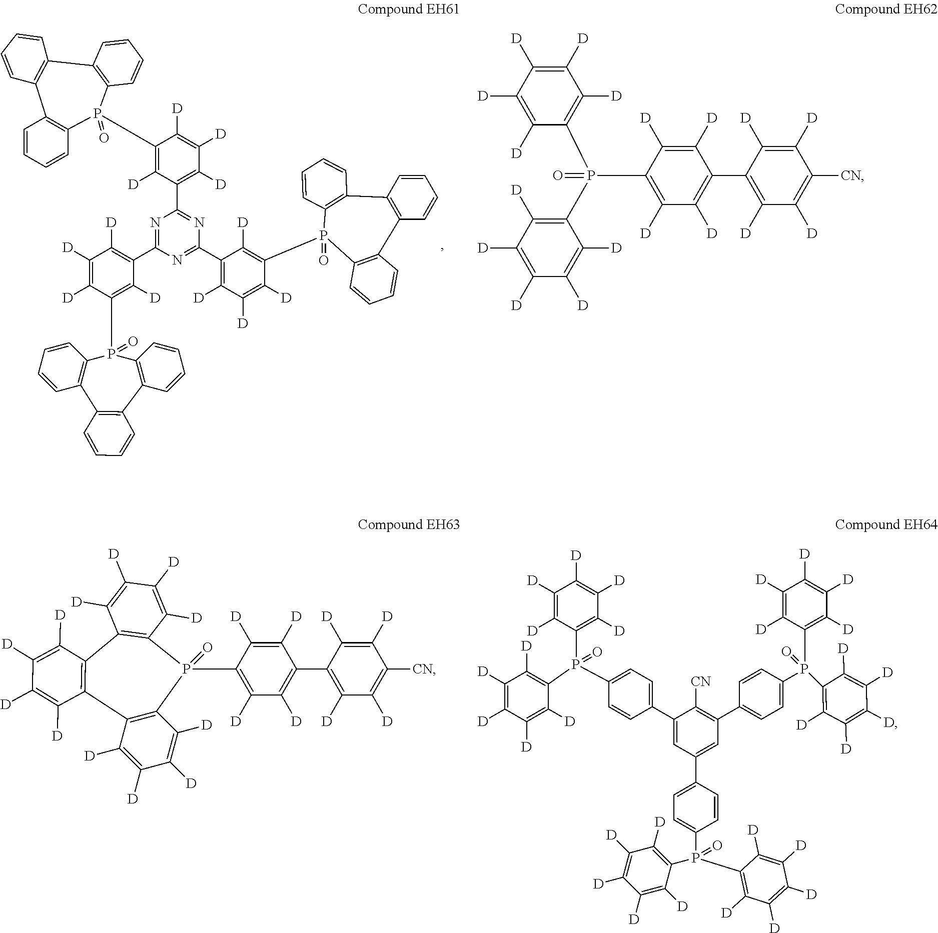

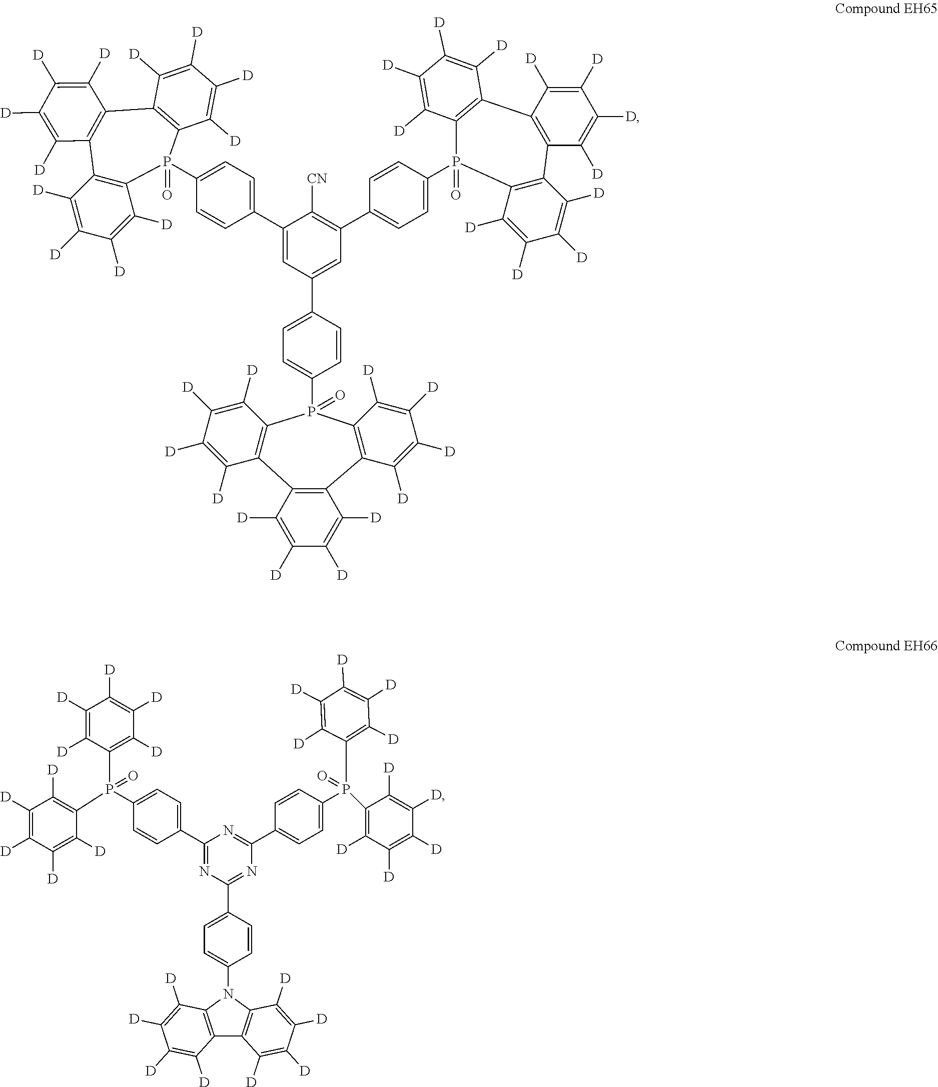

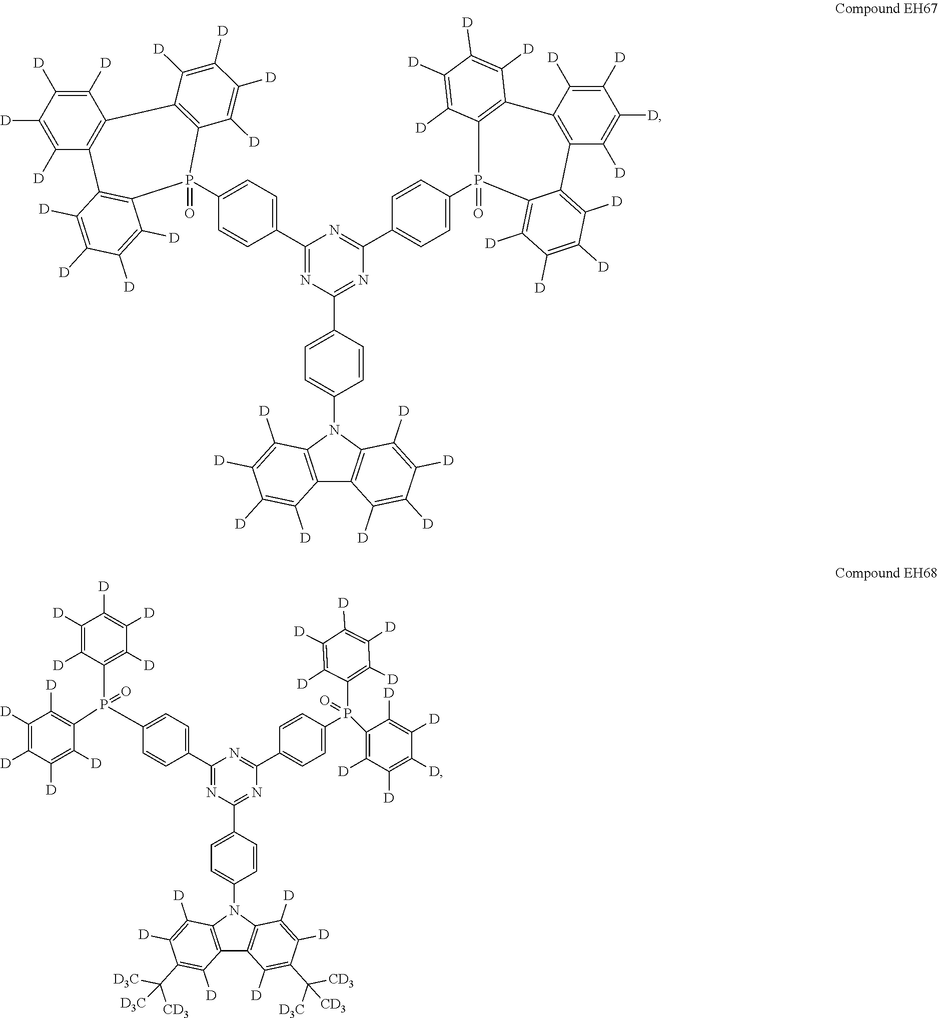

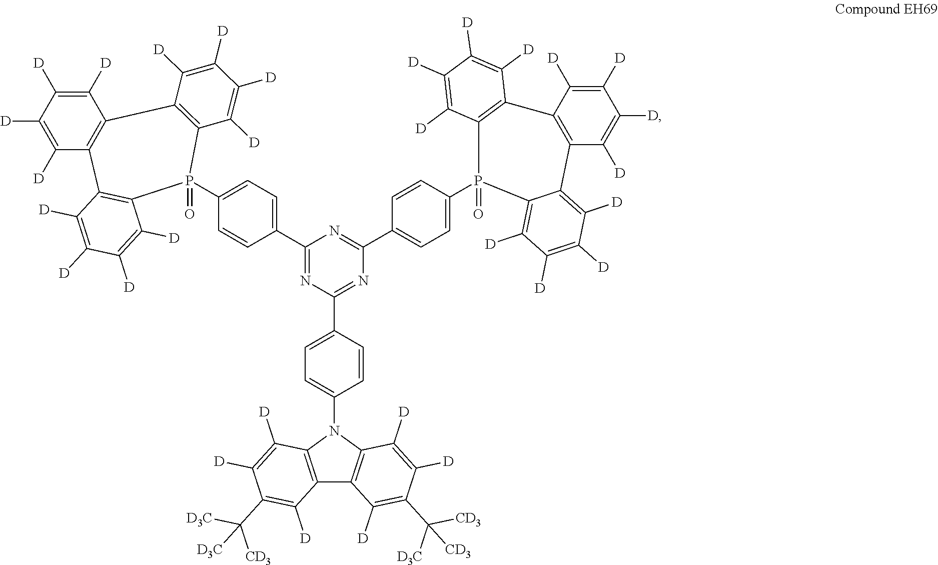

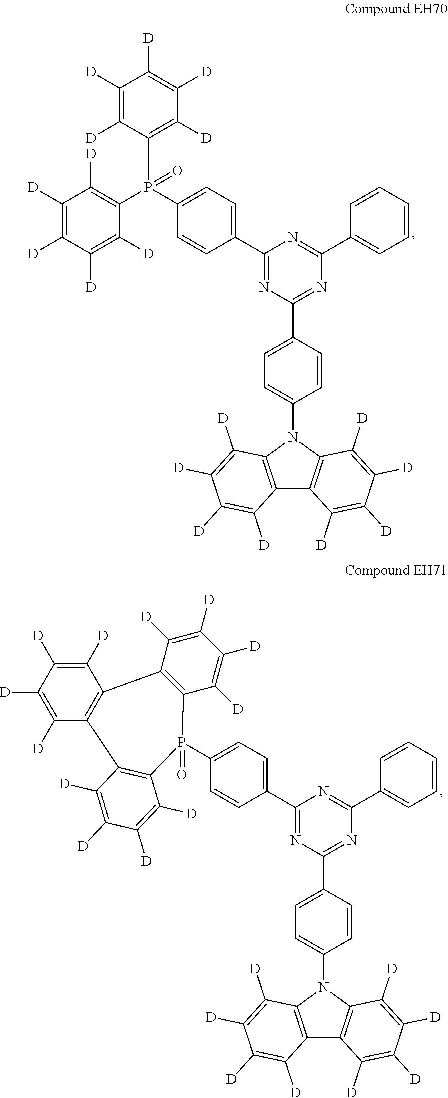 [SMILES: [2H]c1c([2H])c([2H])c(P(=O)(c2ccc(-c3nc(-c4ccccc4)nc(-c4ccc(-n5c6c([2H])c([2H])c([2H])c([2H])c6c6c([2H])c([2H])c([2H])c([2H])c65)cc4)n3)cc2)c2c([2H])c([2H])c([2H])c([2H])c2[2H])c([2H])c1[2H] ; [2H]c1c([2H])c([2H])c2c(c1[2H])-c1c([2H])c([2H])c([2H])c([2H])c1P(=O)(c1ccc(-c3nc(-c4ccccc4)nc(-c4ccc(-n5c6c([2H])c([2H])c([2H])c([2H])c6c6c([2H])c([2H])c([2H])c([2H])c65)cc4)n3)cc1)c1c([2H])c([2H])c([2H])c([2H])c1-2]

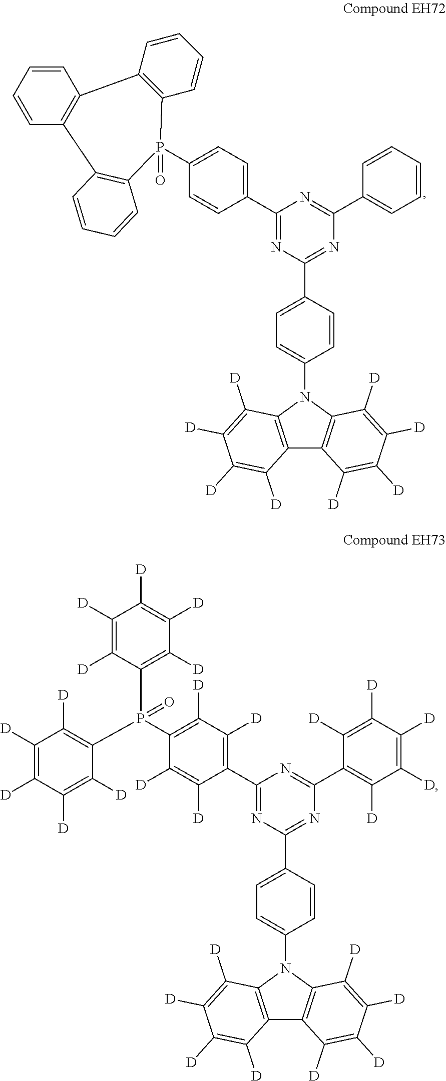

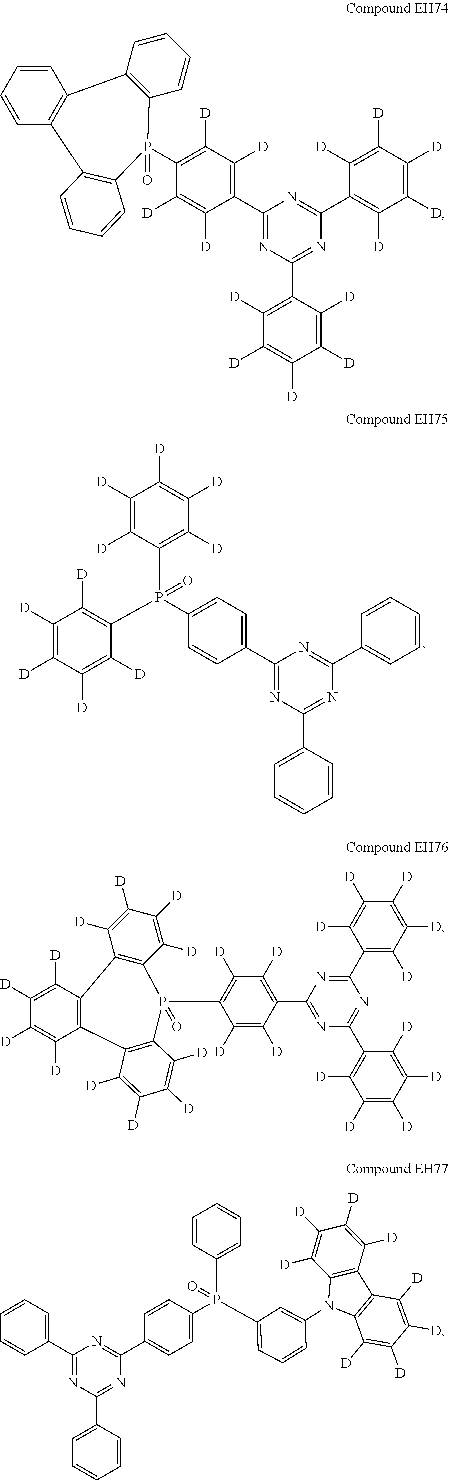

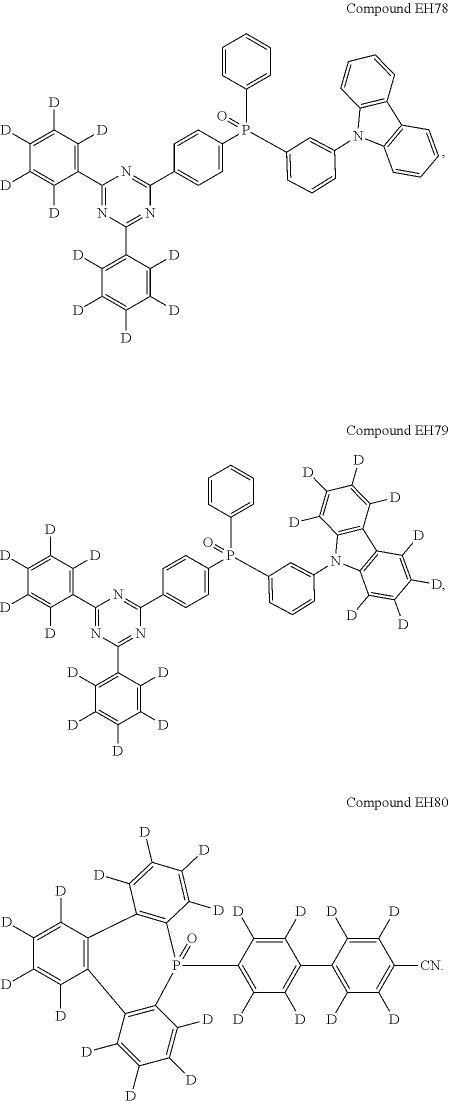

In a preferred embodiment, the guest light-emitting material includes but not limited to a fluorescent luminescent material.

In a preferred embodiment, the guest light-emitting material is a multiple resonance organic compound, preferably a boron-nitrogen multiple resonance organic compound and/or an indolocarbazole multiple resonance organic compound. Compared with other types, adopting the above-mentioned types of guest light-emitting material is advantageous in improving the luminous efficiency of the OLED device, and the application of the above-mentioned types of guest light-emitting material to an OLED display device is advantageous in reducing power consumption.

The present application also provides a synthetic route of the compound represented by the above general formula (III), which is as follows:

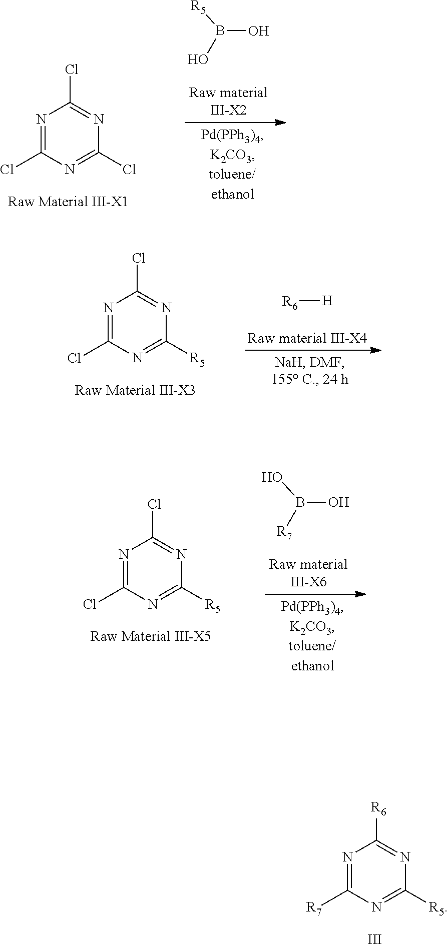

The present application also provides a synthetic route of the compound represented by the above general formula (IV), taking R₈ as a substituent and R′₈, R″₈, and R′″₈ being hydrogen or deuterium as examples, which is as follows:

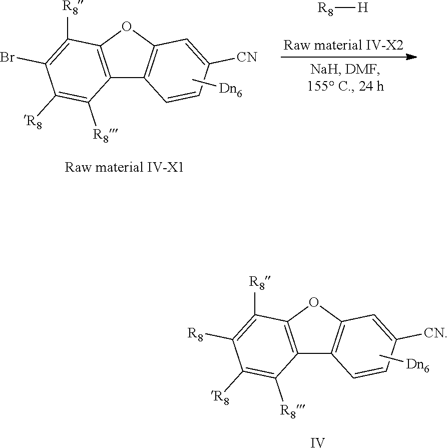

The present application also provides a synthetic route of the compound represented by the above general formula (V), which is as follows:

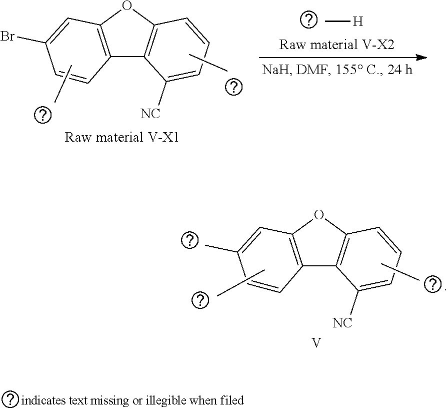

The present application also provides a synthetic route of the compound represented by the above general formula (VI), which is as follows:

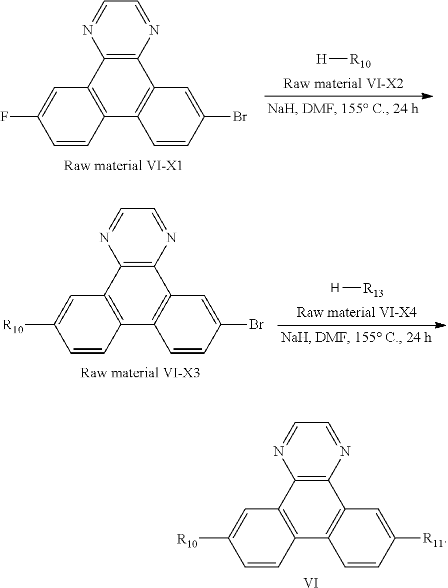

The present application also provides a synthetic route of the compound represented by the above general formula (VII), which is as follows:

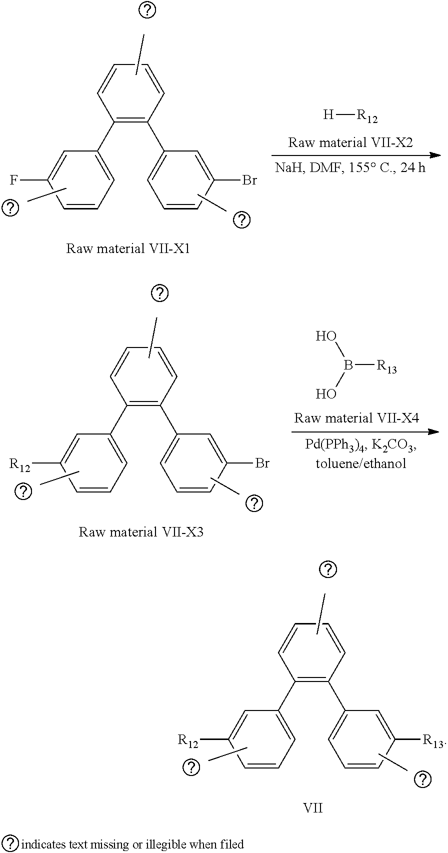

The present application also provides a synthetic route of the compound represented by the above general formula (VIII), which is as follows:

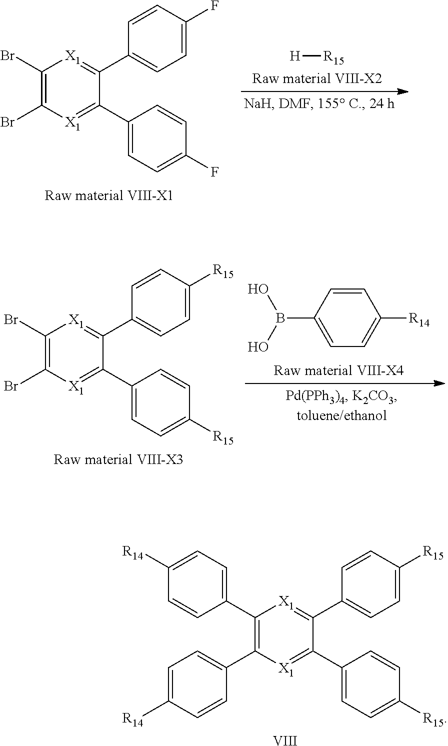

The present application also provides a synthetic route of the compound represented by the above general formula (IX), taking R₁₆ as the cyanide group as an example, which is as follows:

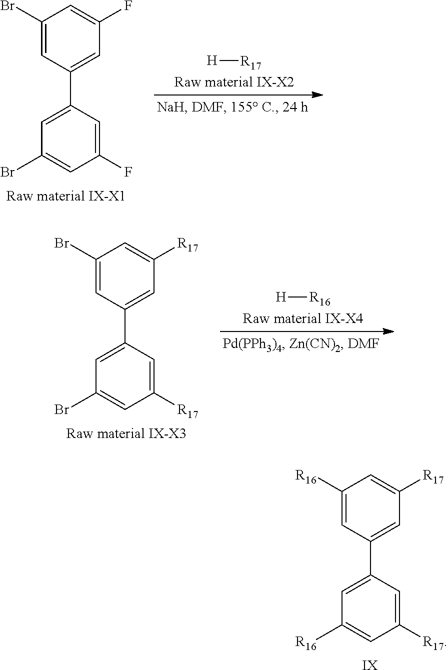

The present application also provides a synthetic route of the compound represented by the above general formula (X), which is as follows:

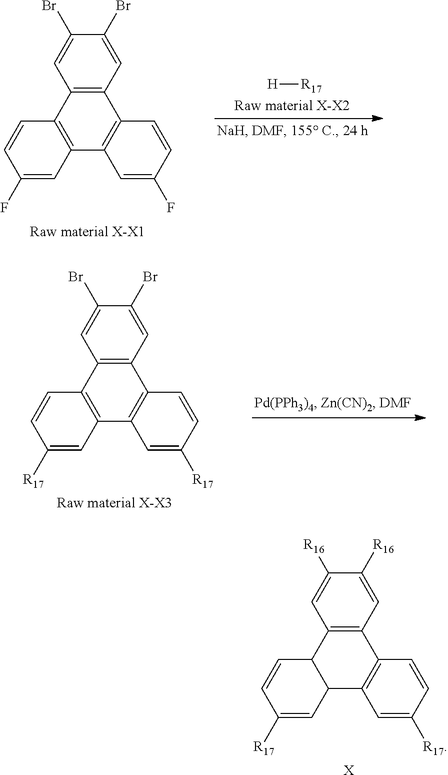

The present application also provides a synthetic route of the compound represented by the above general formula (XI), taking R₁₉ as a phosphine oxygen containing group as an example, which is as follows:

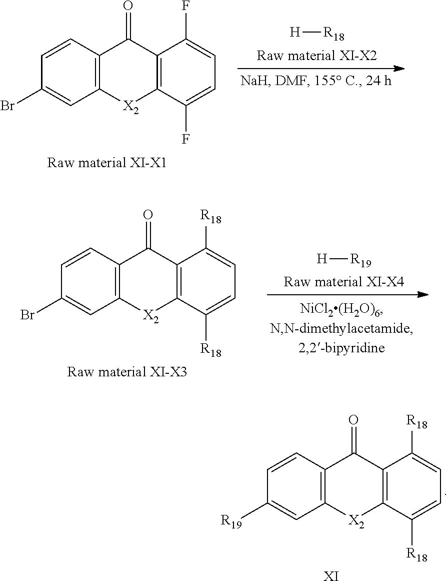

The present application also provides a synthetic route of the compound represented by the above general formula (XII), taking R₂₀ as a phosphine oxygen containing group and R₂₁ as a carbazole group as an example, which is as follows:

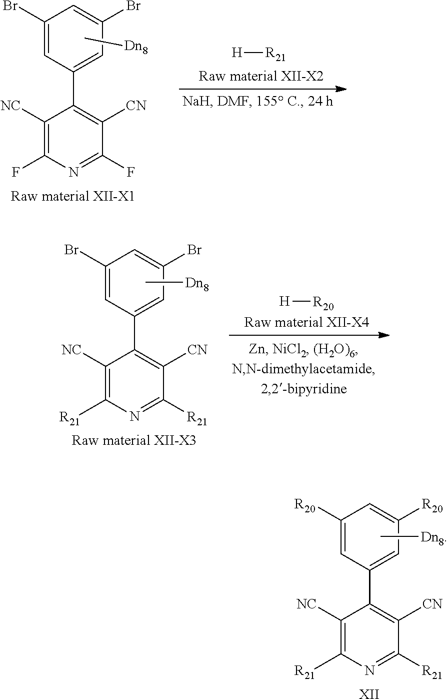

The present application also provides a synthetic route of the compound represented by the above general formula (XIII), which is as follows:

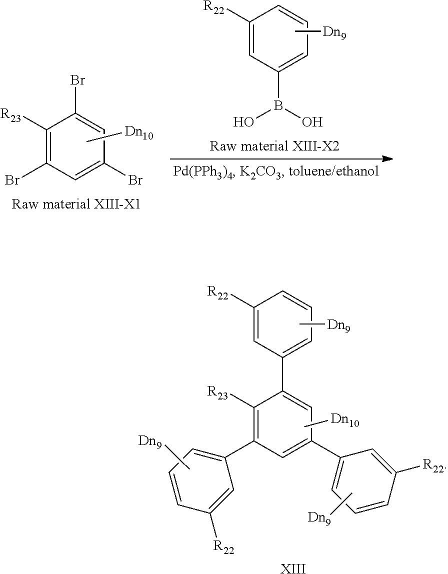

The present application also provides a synthetic route of the compound represented by the above general formula (XIV), which is as follows:

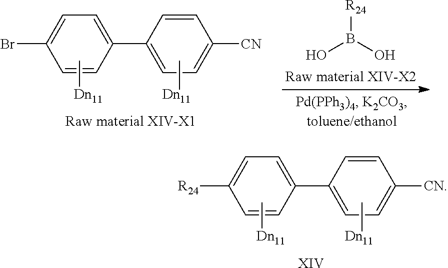

In a preferred embodiment, the guest light-emitting material includes but not limited to one or more of the compounds represented by general formula (XV):

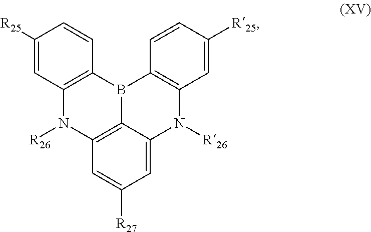

wherein R₂₅ and R′₂₅ include but not limited to

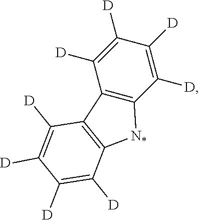

R₂₆ and R′₂₆ include but not limited to

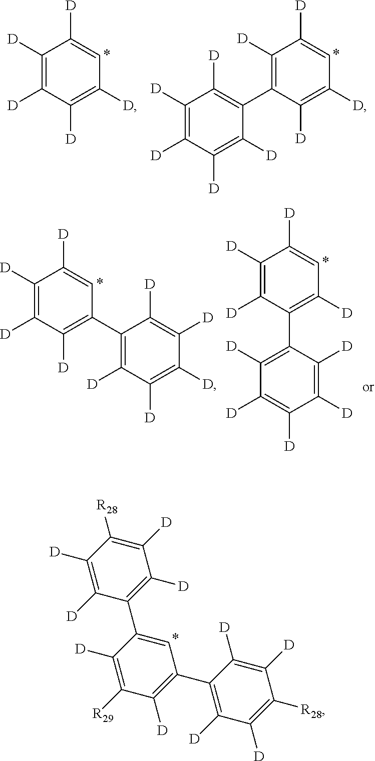

wherein R₂₈ and R₂₉ each independently include but not limited to deuterium or

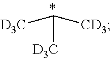 [SMILES: [2H]C([2H])([2H])C(C([2H])([2H])[2H])C([2H])([2H])[2H]]

R₂₇ includes but not limited to hydrogen or

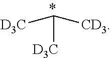 [SMILES: [2H]C([2H])([2H])C(C([2H])([2H])[2H])C([2H])([2H])[2H]]

Compared with other types, adopting the above-mentioned types of guest light-emitting material is advantageous in improving the luminous efficiency of the OLED device, and the application of the above-mentioned types of guest light-emitting material to an OLED display device is advantageous in reducing power consumption.

In order to further improve the luminous efficiency of the OLED device, preferably, R₂₆ and R′₂₆ includes but not limited to

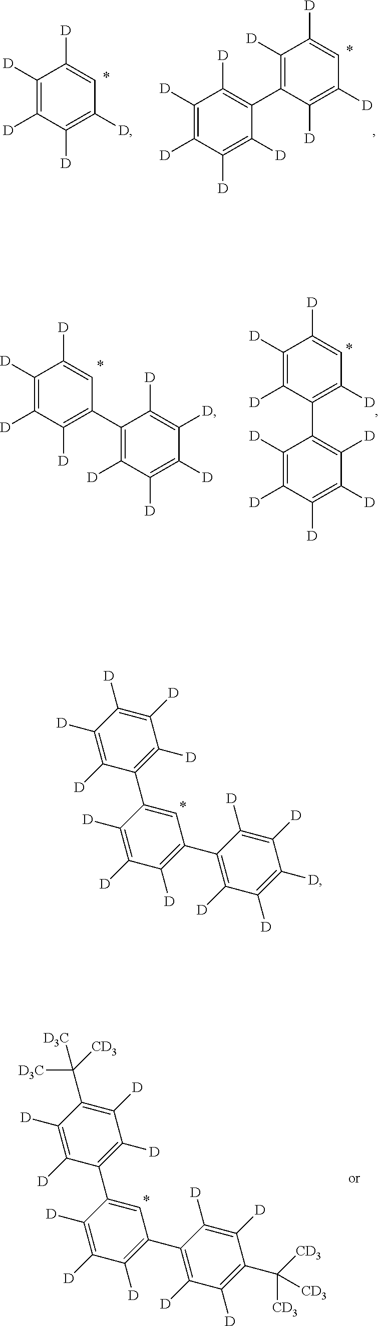

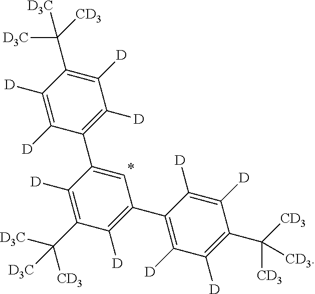 [SMILES: [2H]c1c([2H])c(C(C([2H])([2H])[2H])(C([2H])([2H])[2H])C([2H])([2H])[2H])c([2H])c([2H])c1-c1cc(-c2c([2H])c([2H])c(C(C([2H])([2H])[2H])(C([2H])([2H])[2H])C([2H])([2H])[2H])c([2H])c2[2H])c([2H])c(C(C([2H])([2H])[2H])(C([2H])([2H])[2H])C([2H])([2H])[2H])c1[2H]]

In a preferred embodiment, the guest light-emitting material includes but not limited to one or more of Compound E1 to Compound E9:

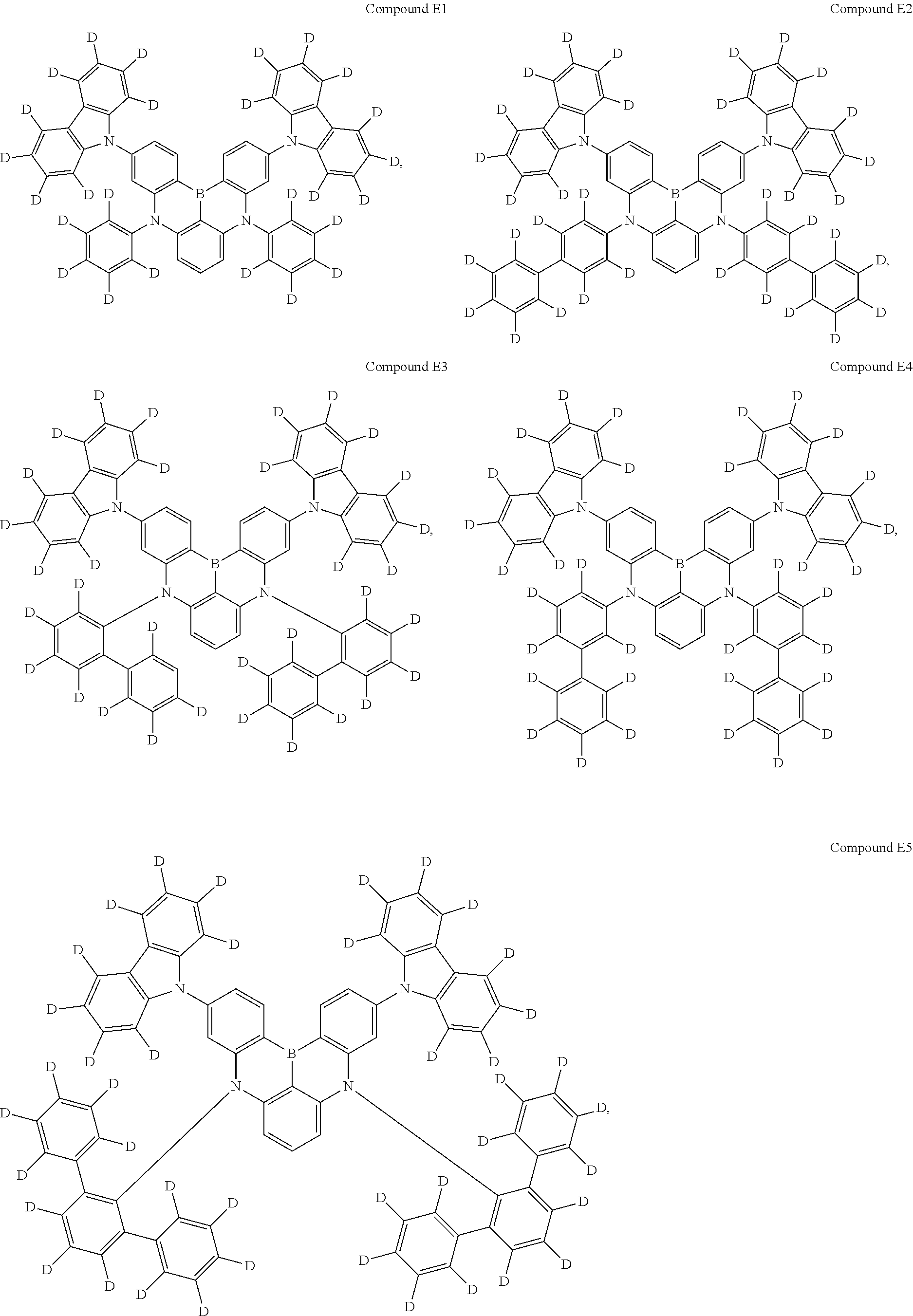

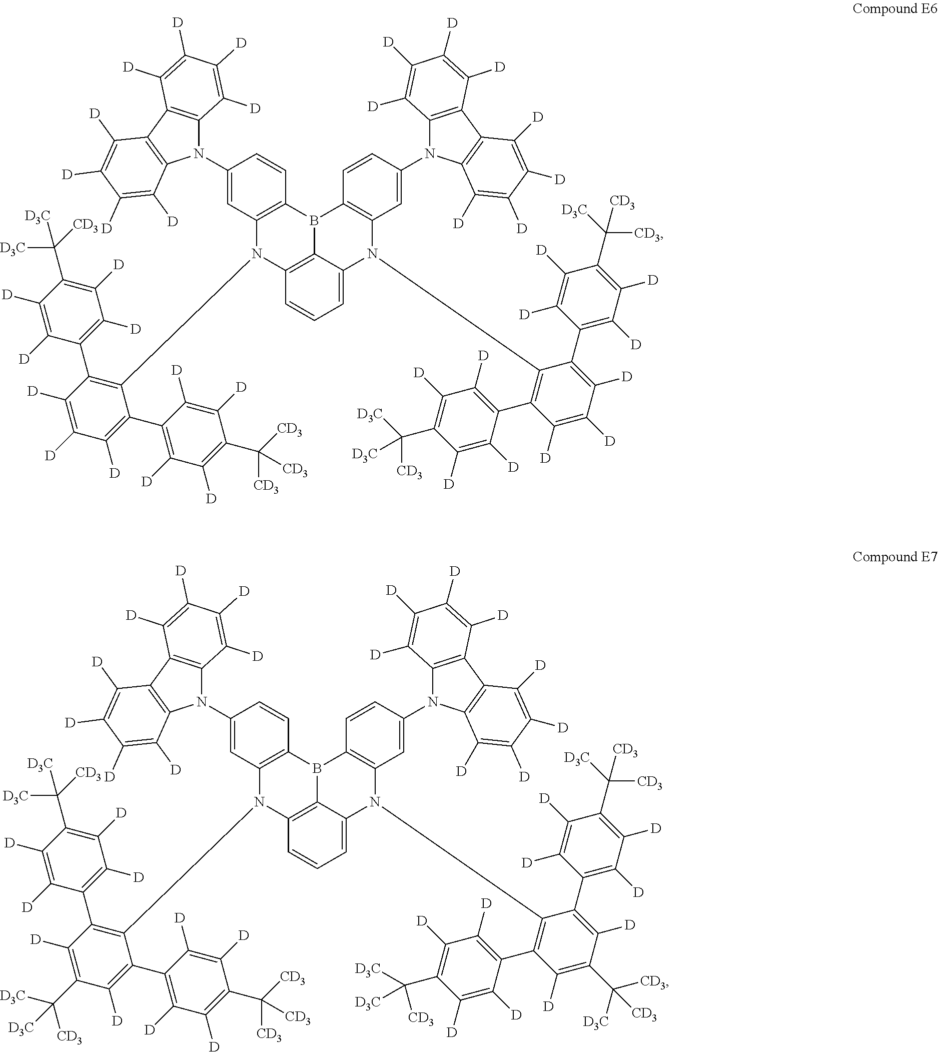

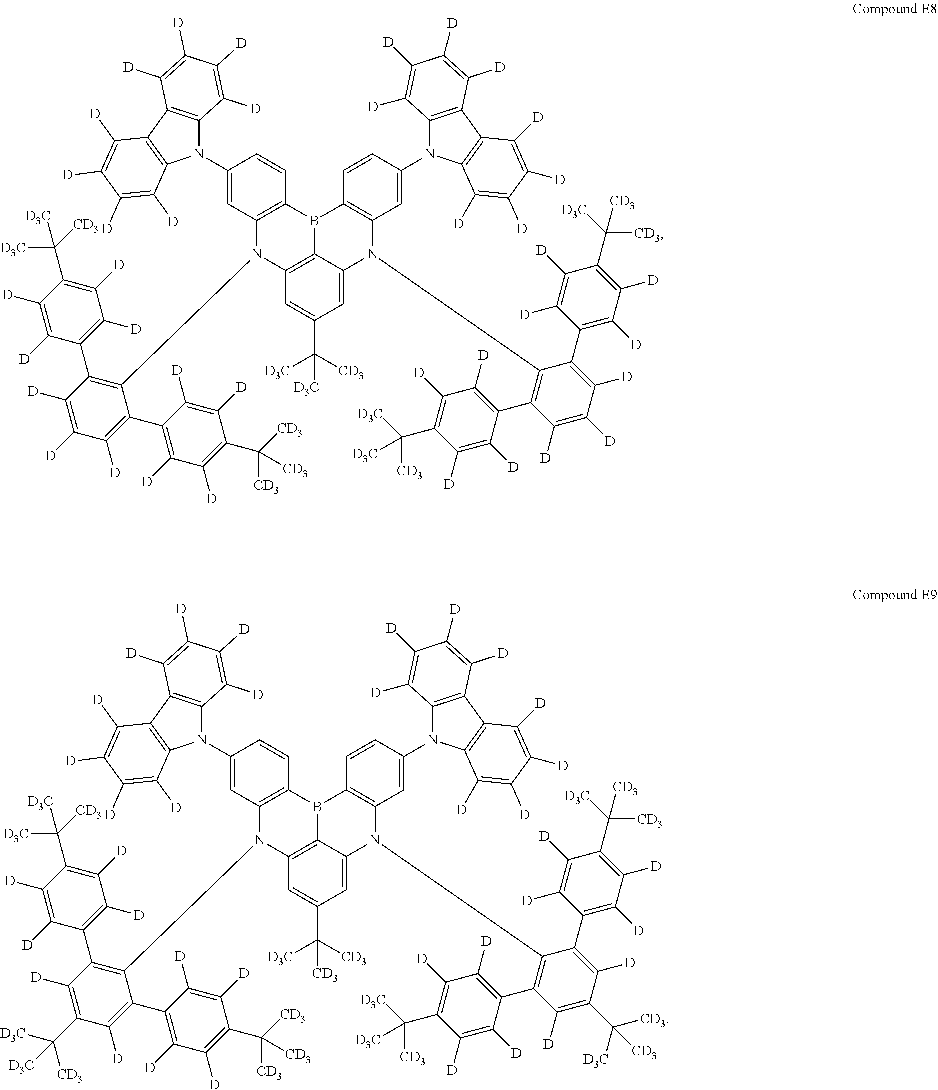

Compared with other types, adopting the above-mentioned types of guest light-emitting material is advantageous in improving the luminous efficiency of the OLED device, and the application of the above-mentioned types of guest light-emitting material to an OLED display device is advantageous in reducing power consumption.

The present application also provides a synthetic route of the compound represented by the above general formula (XV), which is as follows:

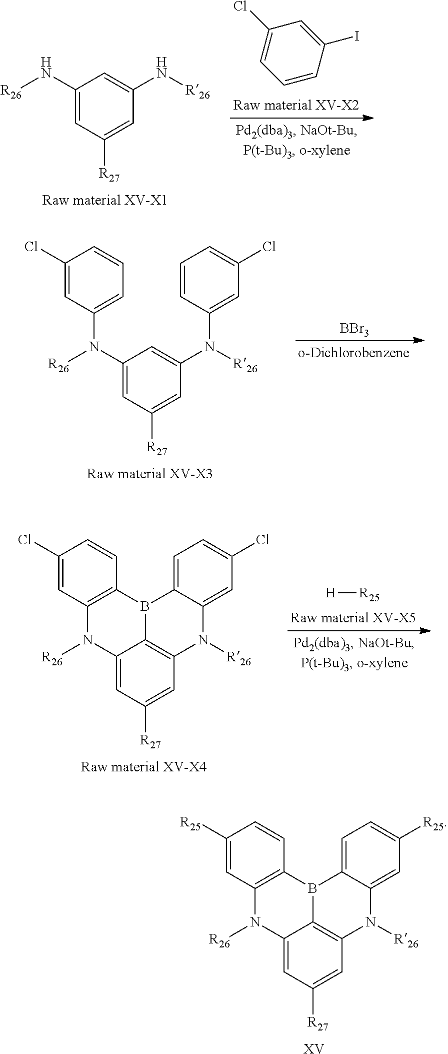

In a preferred embodiment, the exciton utilizing agent includes but not limited to a metal complex and/or a thermally activated delayed fluorescence material (TADF). Compared with other types, adopting the above types of exciton utilizing agents is beneficial to better exerting its sensitizing effect, improving the exciton utilization rate, and thus improving the luminous efficiency of OLED devices, and also improving the color purity of blue light.

In order to further improve the exciton utilization rate, further improve the luminous efficiency of the OLED device and the color purity of blue light, the exciton utilizing agent preferably includes but not limited to an iridium organic complex and/or a platinum organic complex.

In a preferred embodiment, the exciton utilizing agent includes but not limited to one or more of the compounds represented by general formulae (XVI) and (XVII):

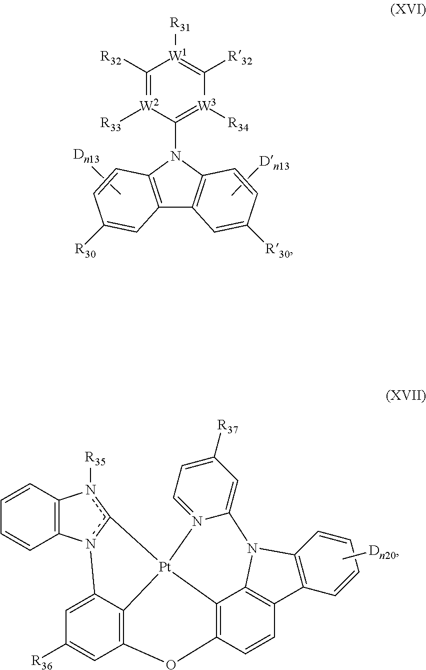

wherein in formula (XVI), W¹, W², and W³ each independently include but not limited to C or N, and when W¹ is N, R₃₁ is empty, and when W² is N, R₃₃ is empty, and when W³ is N, R₃₄ is empty; wherein R₃₀ and R′₃₀ each independently include but not limited to deuterium, hydrogen, C₆-C₂₀ aryl, C₆-C₂₀ aryl substituted with at least one deuterium atom, C₁-C₁₀ alkyl substituted with at least one deuterium atom, or

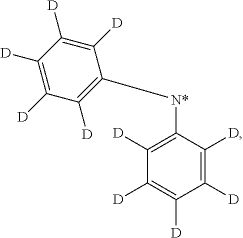

R₃₁ includes but not limited to hydrogen, cyano,

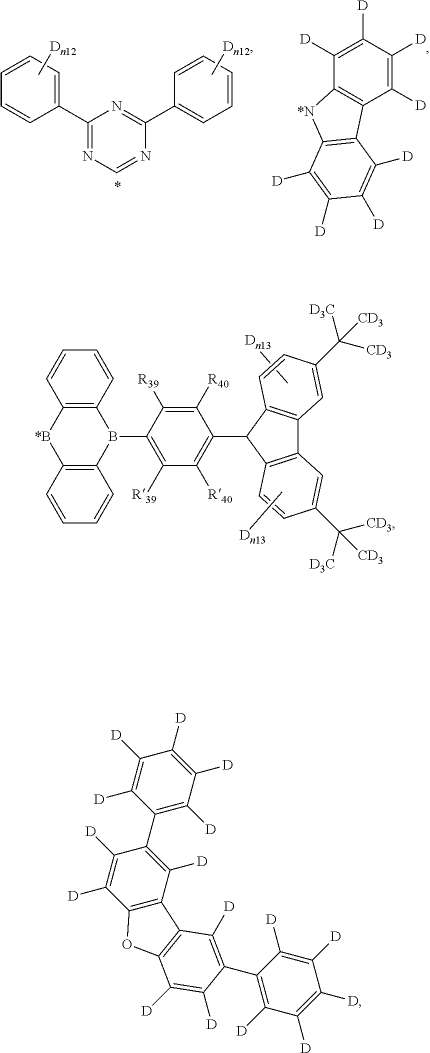

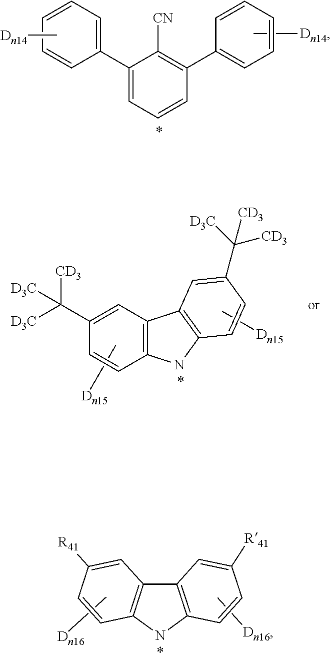

wherein n12 and n14 represent substitution by any one of 0 to 5 integer deuterium atoms in the corresponding benzene ring structure, preferably 0 or 5; n13, n′13, n15 and n16 represent that substitution by any one of 0 to 3 integer deuterium atoms in the corresponding benzene ring structure, preferably 0 or 3; R₃₉ and R′₃₉ each independently include but not limited to C₁-C₁₀ alkyl groups, or C₁-C₁₀ alkyl groups substituted with at least one deuterium atom, preferably deuterated methyl or methyl; R₄₀ and R′₄₀ each independently include but not limited to hydrogen or deuterium; R₄₁ and R′₄₁ include but not limited to C₆-C₂₀ aryl, C₆-C₂₀ aryl substituted with at least one deuterium atom, C₁-C₁₀ alkyl, or C₁-C₁₀ alkyl substituted with at least one deuterium atom, preferably phenyl, deuterated phenyl, methyl, deuterated methyl or deuterated tert-butyl; R₃₂ and R′₃₂ each independently include but not limited to hydrogen, deuterium, cyano, C₁-C₁₀ alkyl, C₁-C₁₀ alkyl substituted with at least one deuterium atom, C₆-C₂₀ aryl, C₆-C₂₀ aryl substituted with at least one deuterium atom, C₆-C₂₀ aryl substituted with a cyano group, or phenyl substituted with C₁-C₁₀ alkyl,

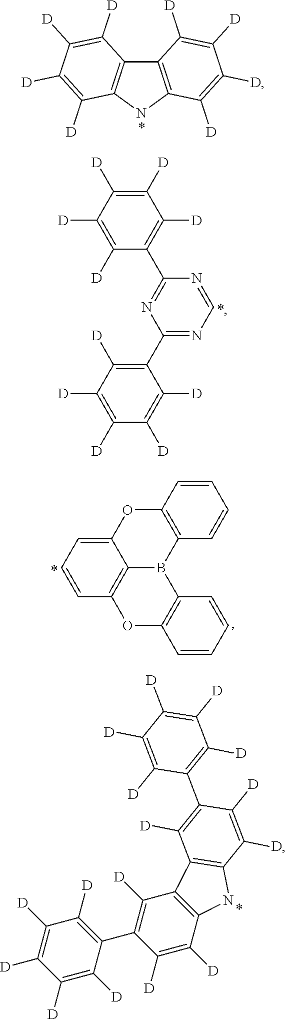

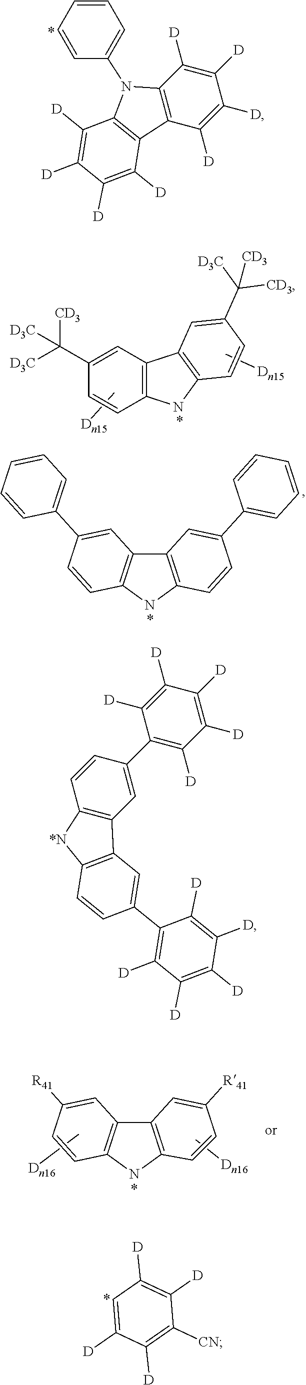

R₃₃ and R₃₄ include but not limited to hydrogen, cyano, C₆-C₂₀ aryl, cyano substituted C₆-C₂₀ aryl,

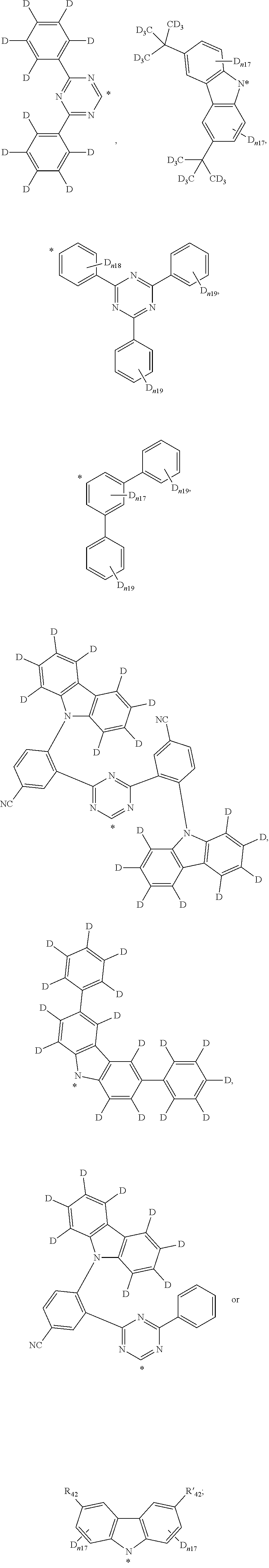

wherein n17 represents a substitution by any one of 0 to 3 integer deuterium atoms in the corresponding benzene ring, n18 represents a substitution by any one of 0 to 4 integer deuterium atoms in the corresponding benzene ring, n19 represents a substitution by any one of 0 to 5 integer deuterium atoms in the corresponding benzene ring, and R₄₂ and R′₄₂ each independently include but not limited to C₆-C₂₀ aryl, C₆-C₂₀ aryl substituted with at least one deuterium atom, C₁-C₁₀ alkyl, or C₁-C₁₀ alkyl substituted with at least one deuterium atom, R₄₂ and R′₄₂ are preferably phenyl, deuterated phenyl, methyl, deuterated methyl, or deuterated tert-butyl; R₃₅ includes but not limited to

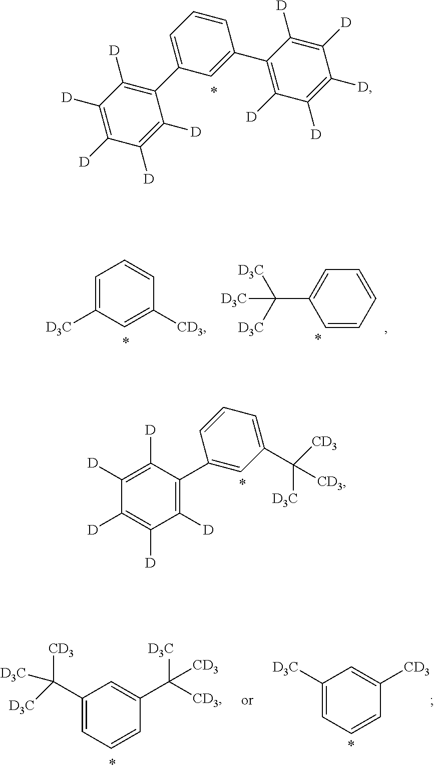

In general formula (XVII), R₃₆ includes but not limited to *CD₃,

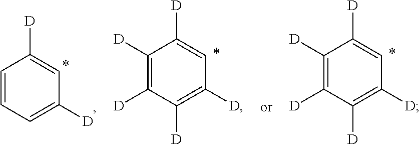

R₃₇ includes but not limited to

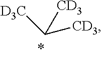 [SMILES: [2H]C([2H])([2H])C(C([2H])([2H])[2H])C([2H])([2H])[2H]]

n20 represents a substitution by any one of 0 to 4 integer deuterium atoms in the corresponding benzene ring, preferably 0 or 4.

Adopting the above types of exciton utilizing agents is beneficial to better exerting its sensitizing effect, improving the exciton utilization rate, and thus improving the luminous efficiency of OLED devices, and also improving the color purity of blue light.

In order to further better exert the sensitizing effect of the exciton utilizing agent, improve the exciton utilization rate, and improve the luminous efficiency of the OLED device and the color purity of blue light, preferably, R₃₀ and R′₃₀ each independently include but not limited to a deuterium atom, a hydrogen atom, a phenyl group

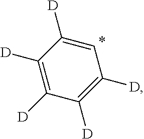

*CD₃, deuterated tert-butyl,

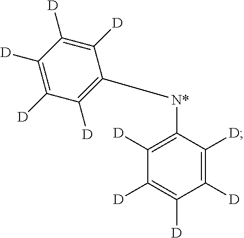

R₃₁ includes but not limited to a hydrogen atom, a cyano group,

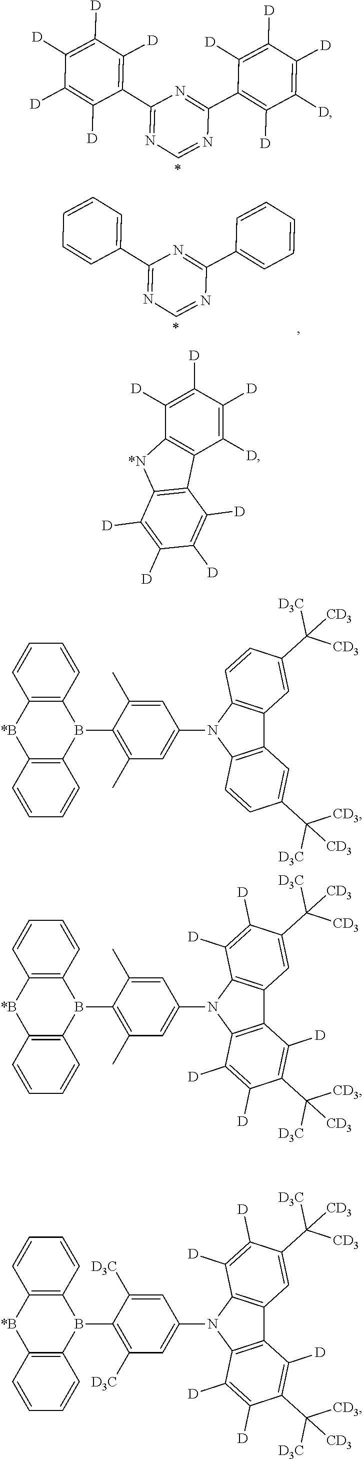

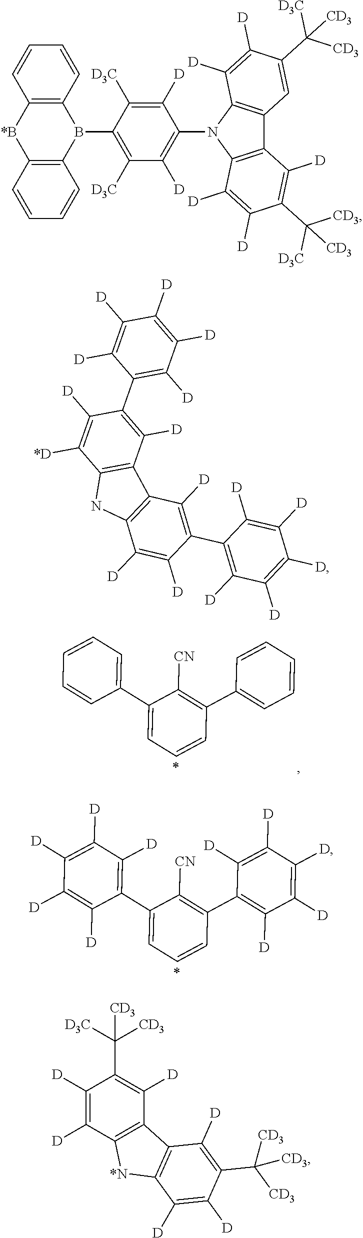

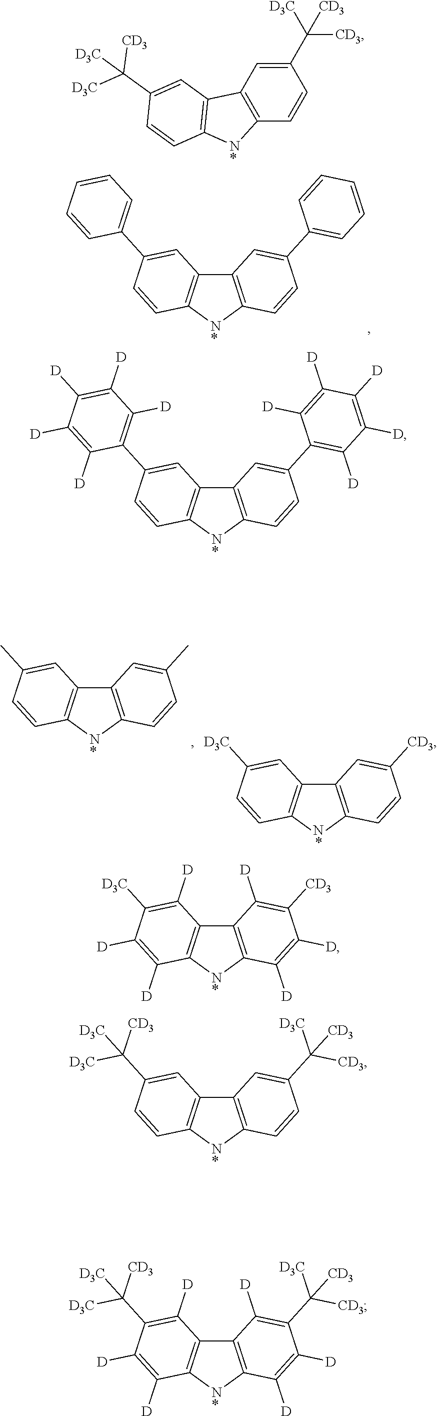

R₃₂ and R′₃₂ each independently include but not limited to a hydrogen atom, a deuterium atom, a cyano group, a methyl group, a deuterated methyl group, a phenyl group, a deuterated phenyl group, a cyano-substituted phenyl group, a tert-butyl-substituted phenyl group,

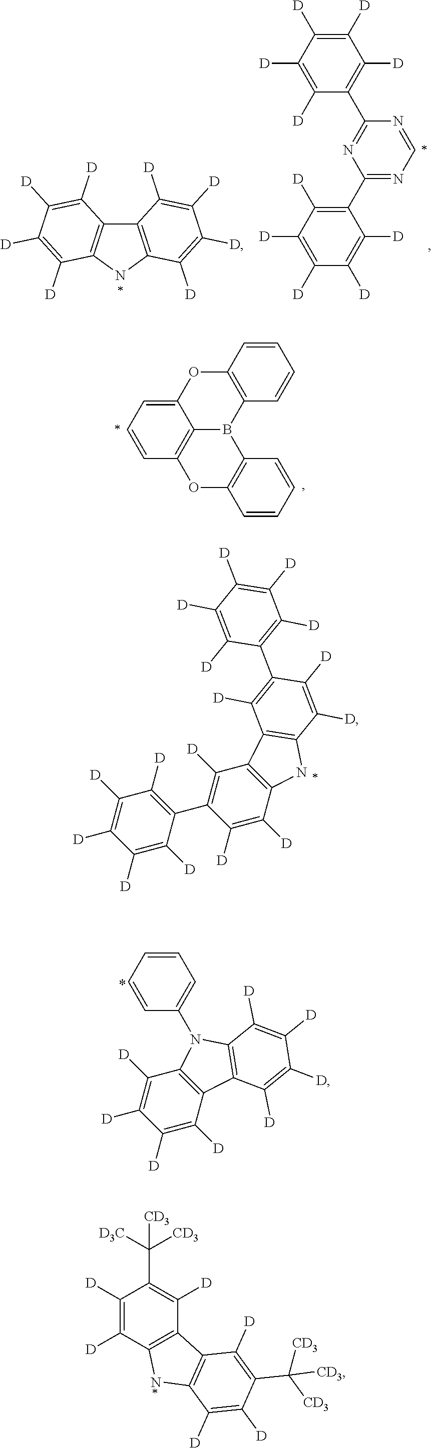

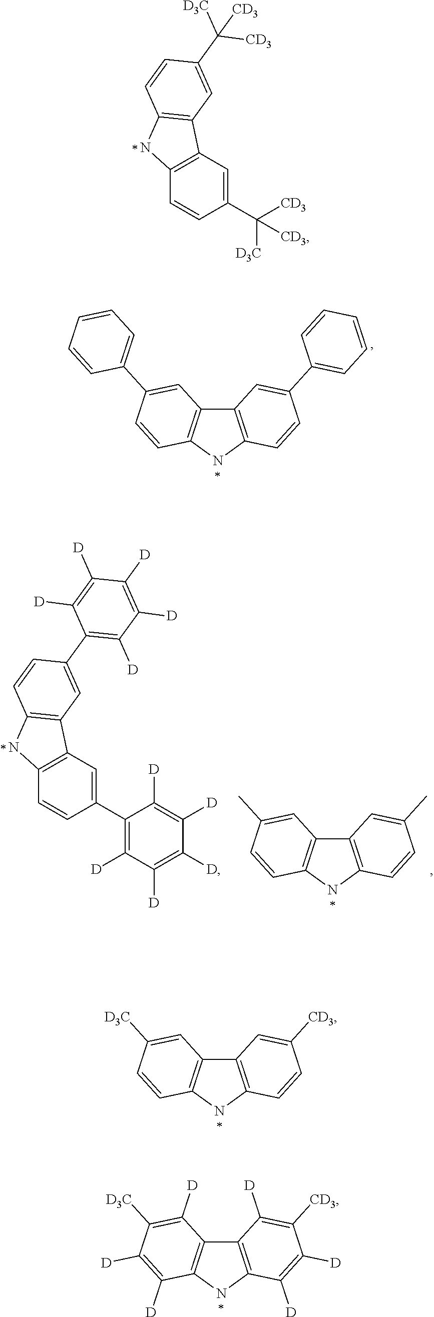

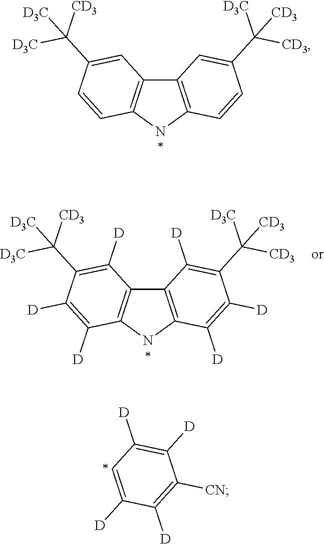 [SMILES: [2H]C([2H])([2H])C(c1ccc2[nH]c3ccc(C(C([2H])([2H])[2H])(C([2H])([2H])[2H])C([2H])([2H])[2H])cc3c2c1)(C([2H])([2H])[2H])C([2H])([2H])[2H] ; [2H]c1c(C(C([2H])([2H])[2H])(C([2H])([2H])[2H])C([2H])([2H])[2H])c([2H])c2c([nH]c3c([2H])c([2H])c(C(C([2H])([2H])[2H])(C([2H])([2H])[2H])C([2H])([2H])[2H])c([2H])c32)c1[2H] ; "or" ; [2H]c1cc([2H])c([2H])c(C#N)c1[2H]]

R₃₃ and R₃₄ include but not limited to hydrogen, cyano, phenyl, cyano-substituted phenyl,

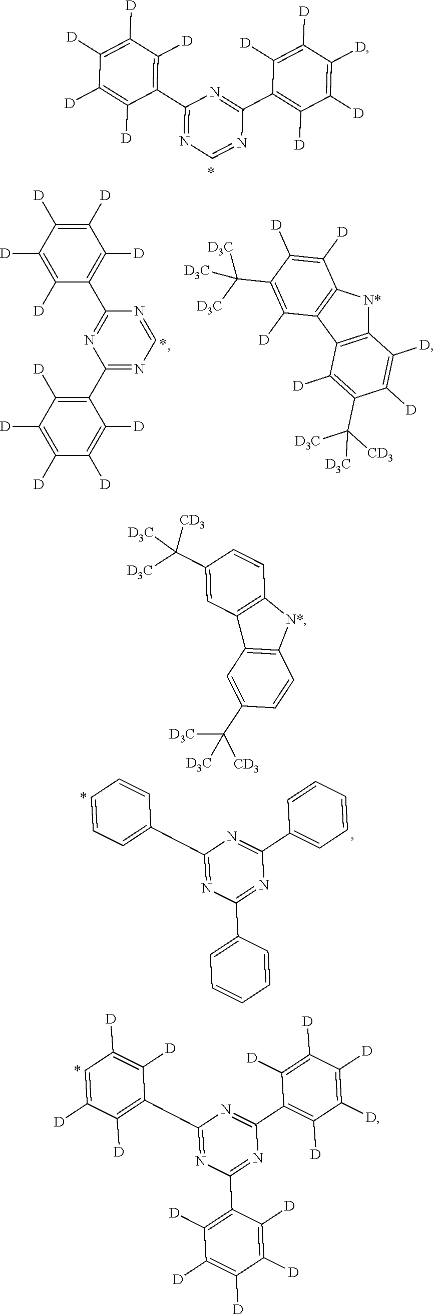

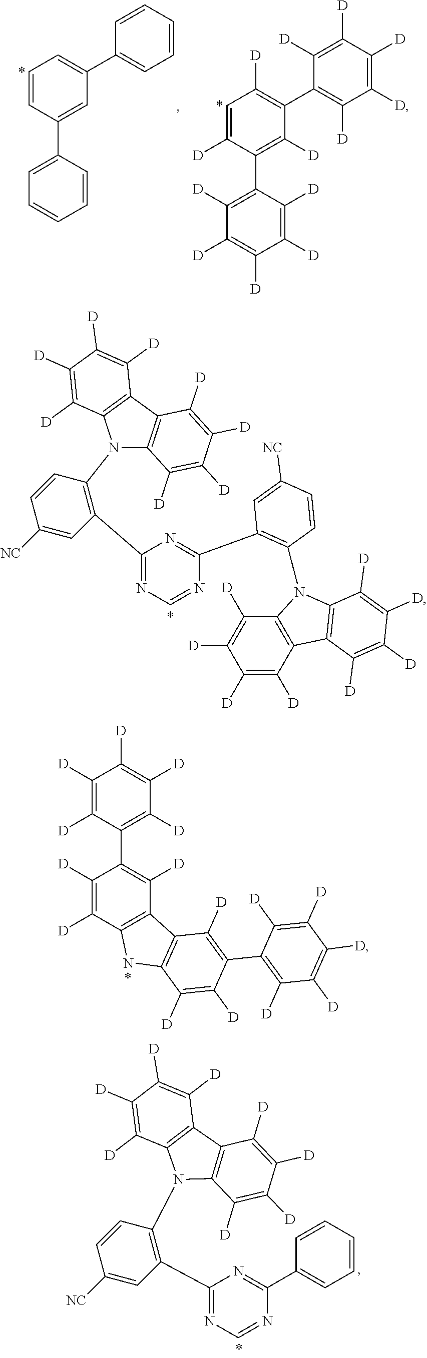

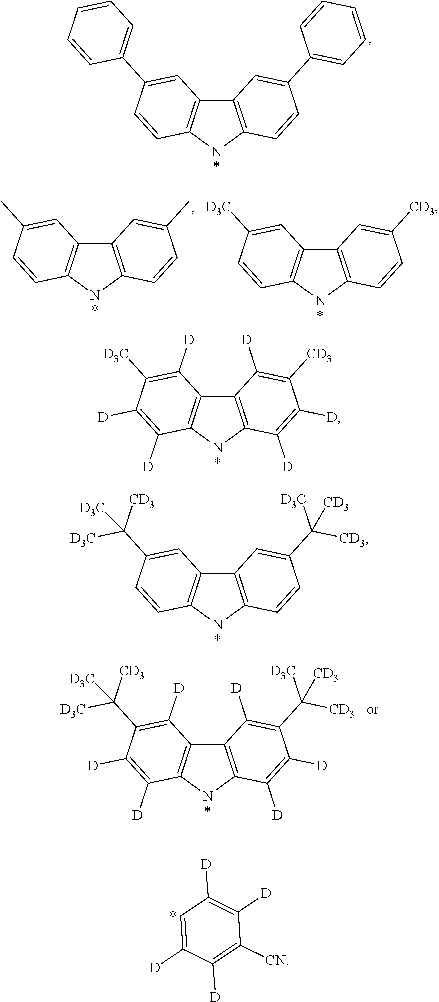

In a preferred embodiment, the exciton utilizing agent includes but not limited to one or more of Compound X1 to Compound X90:

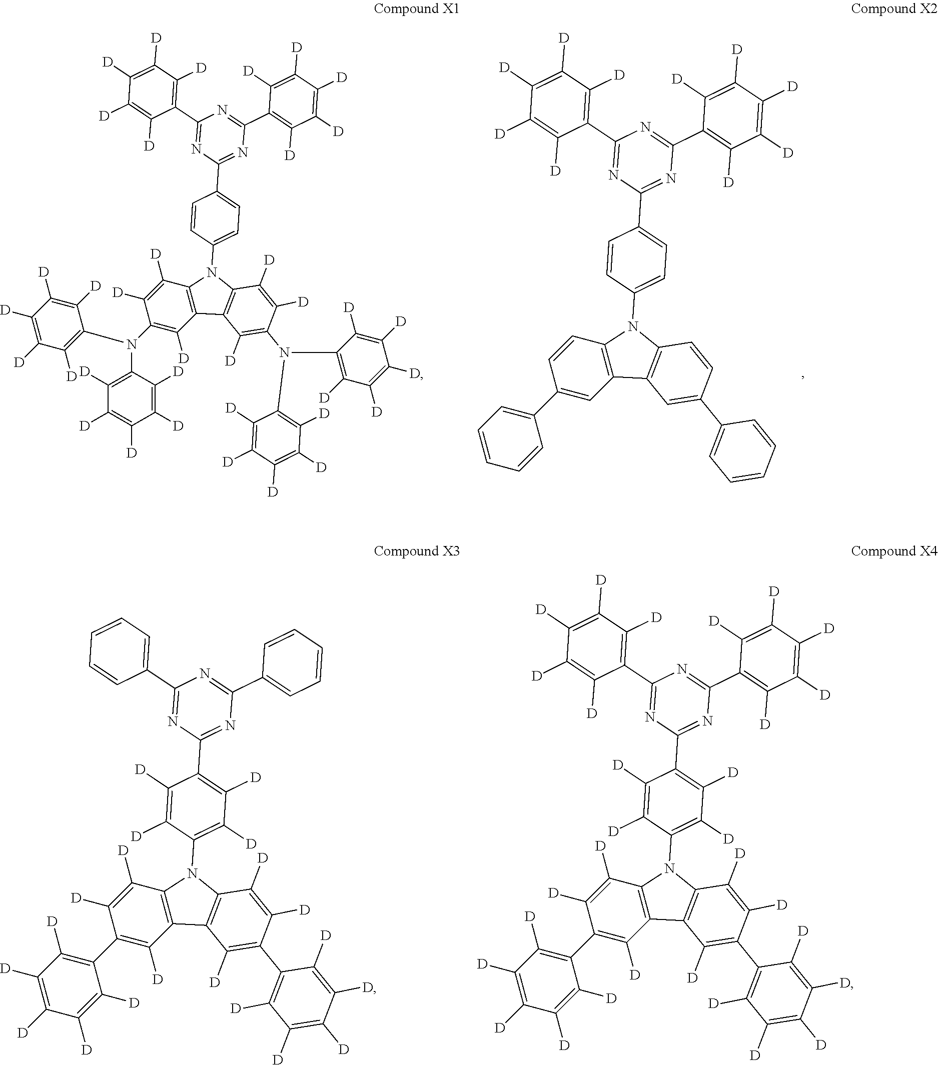

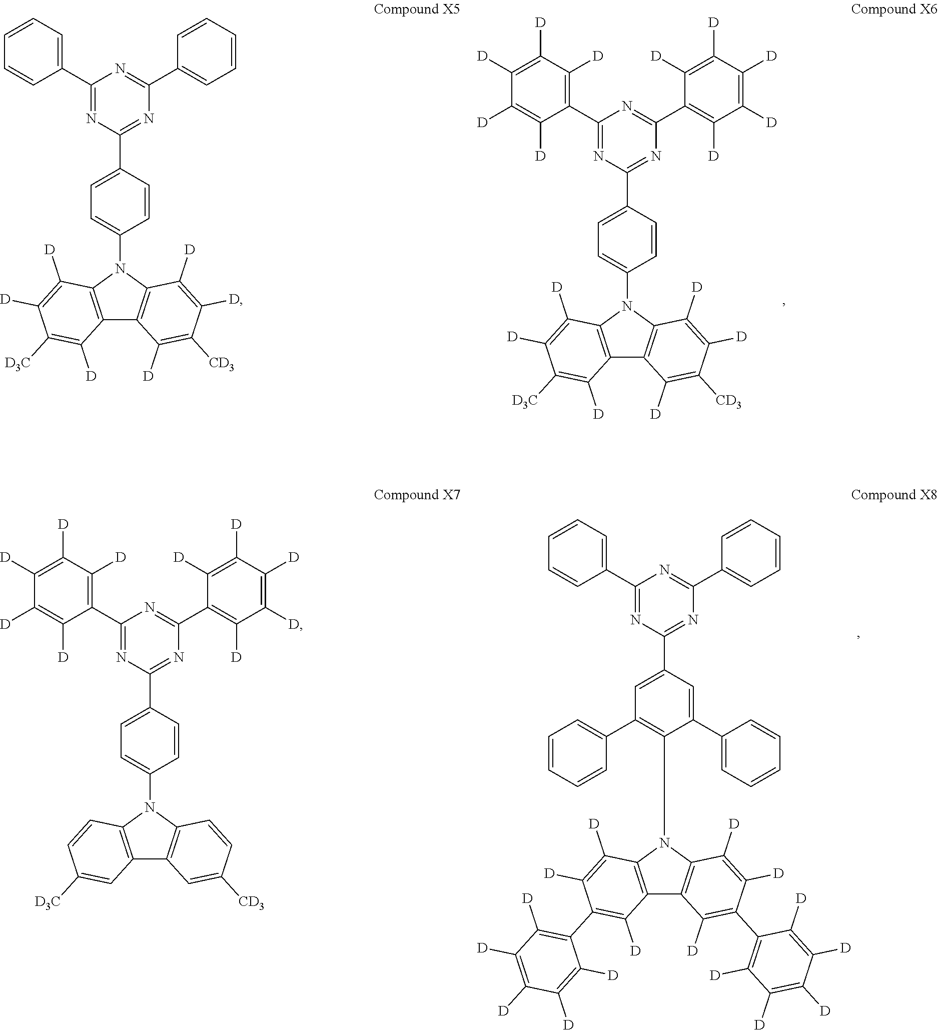

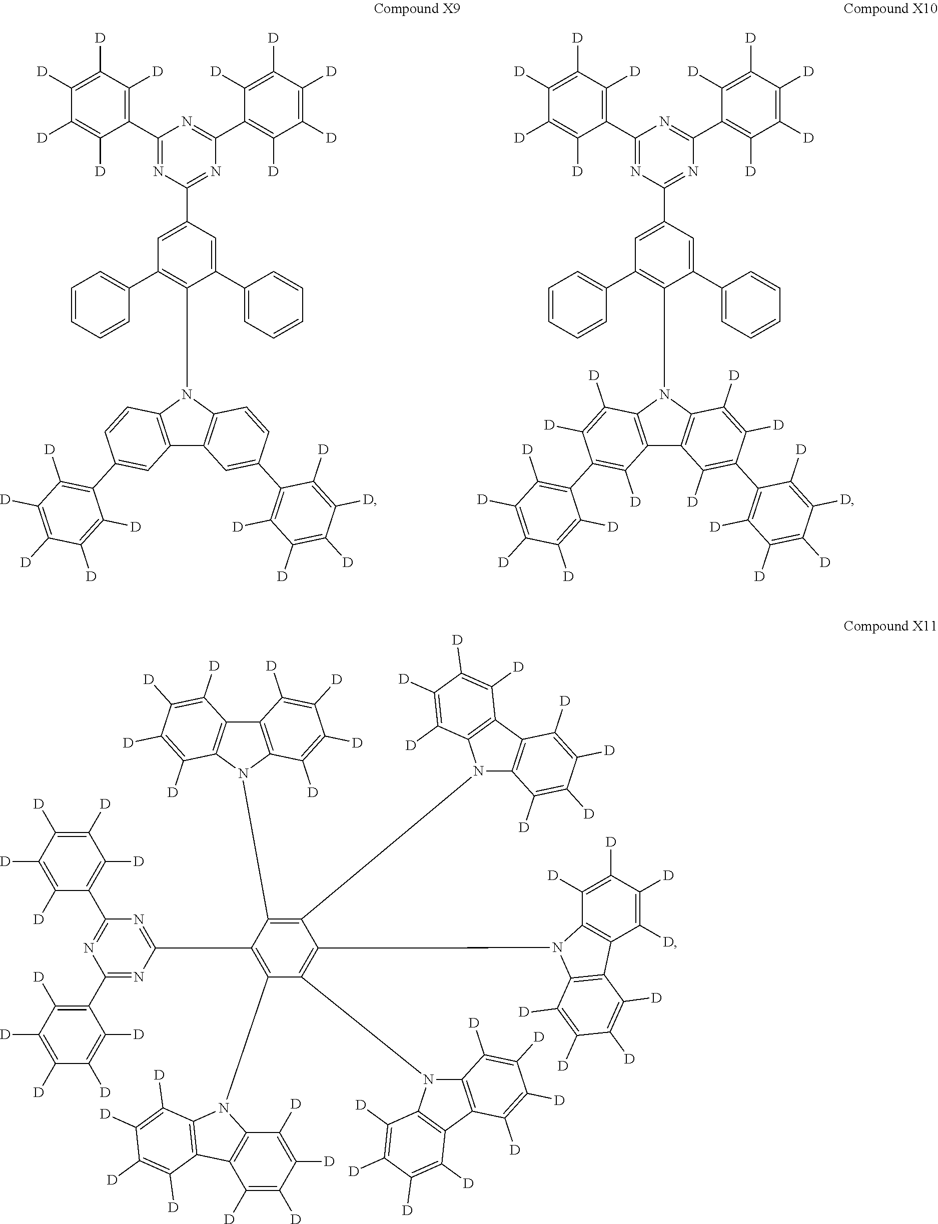

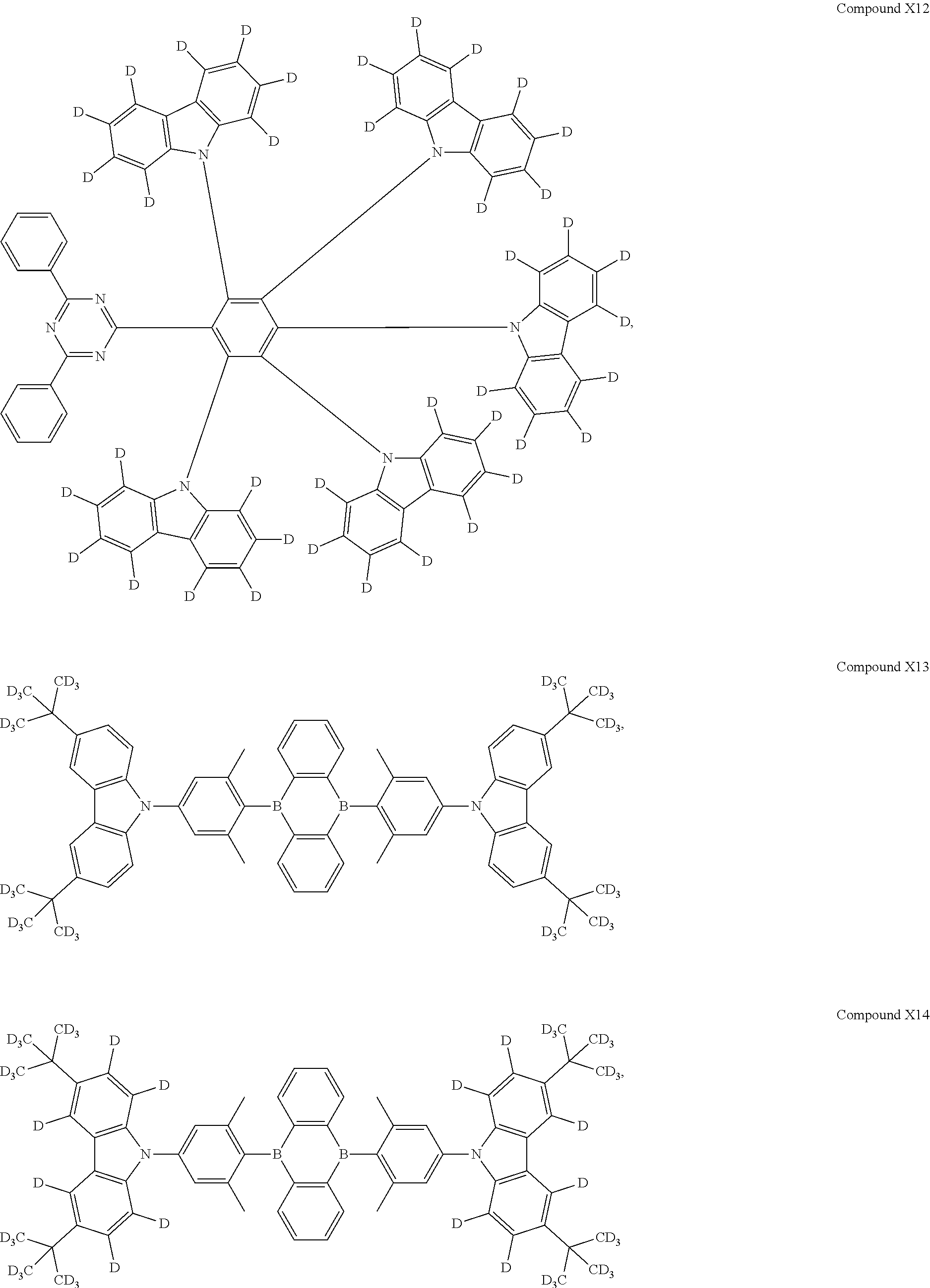

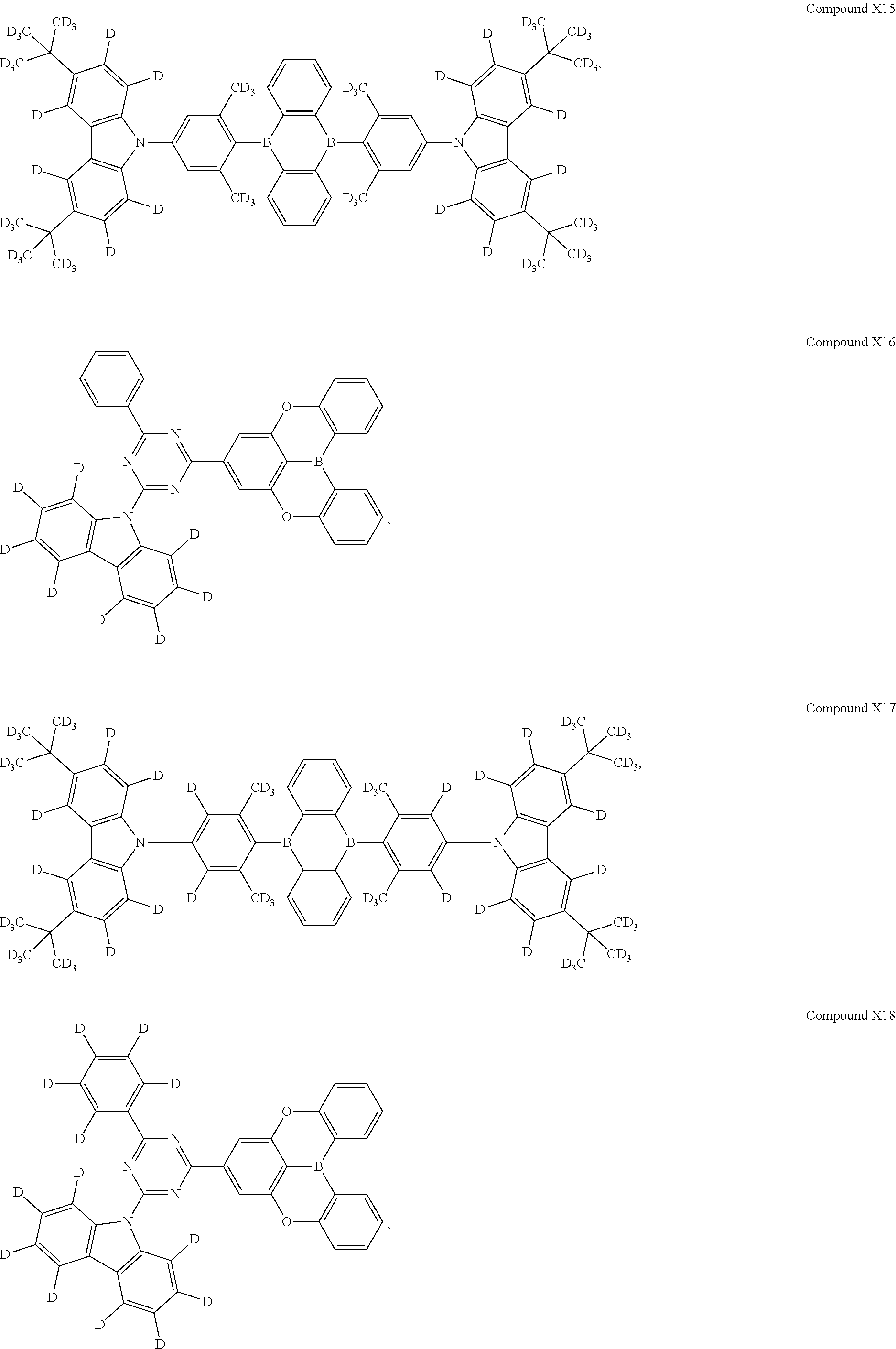

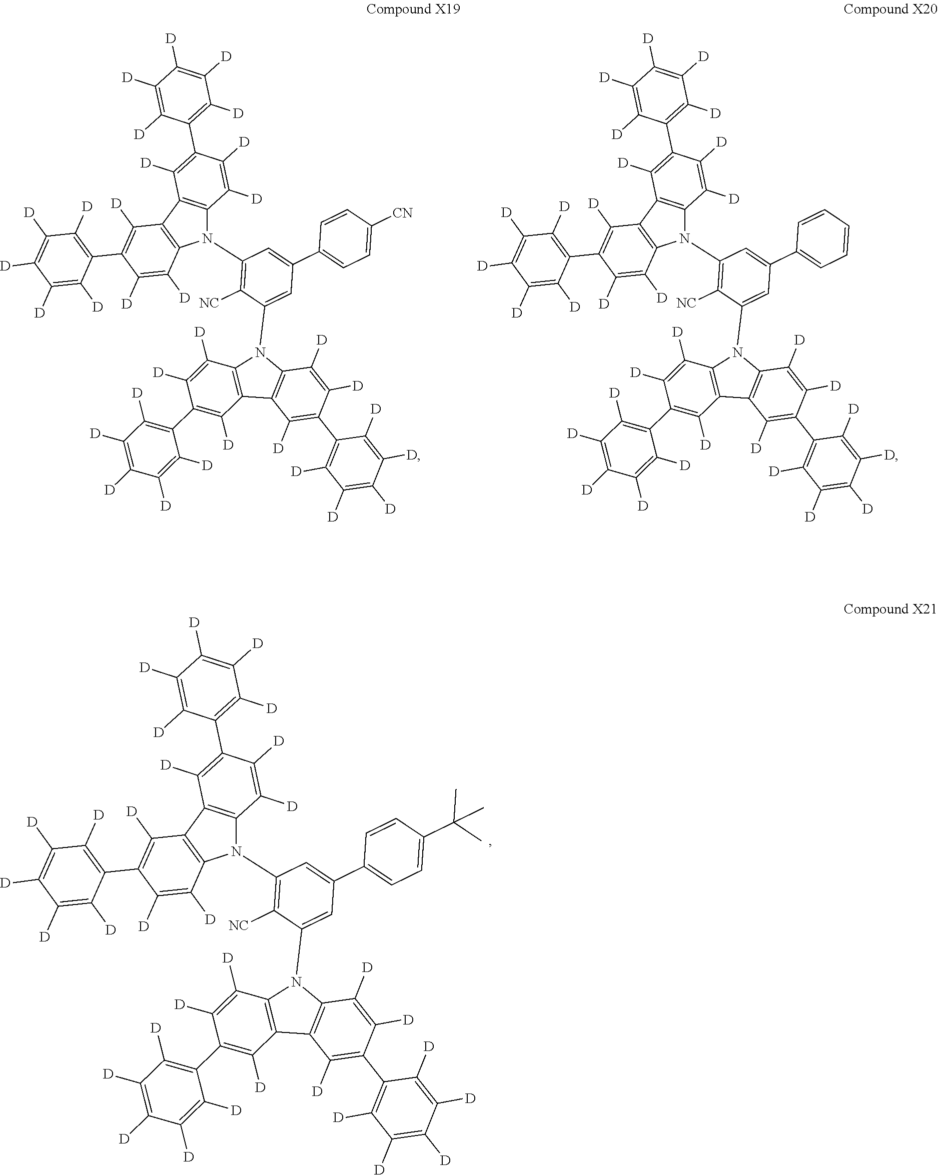

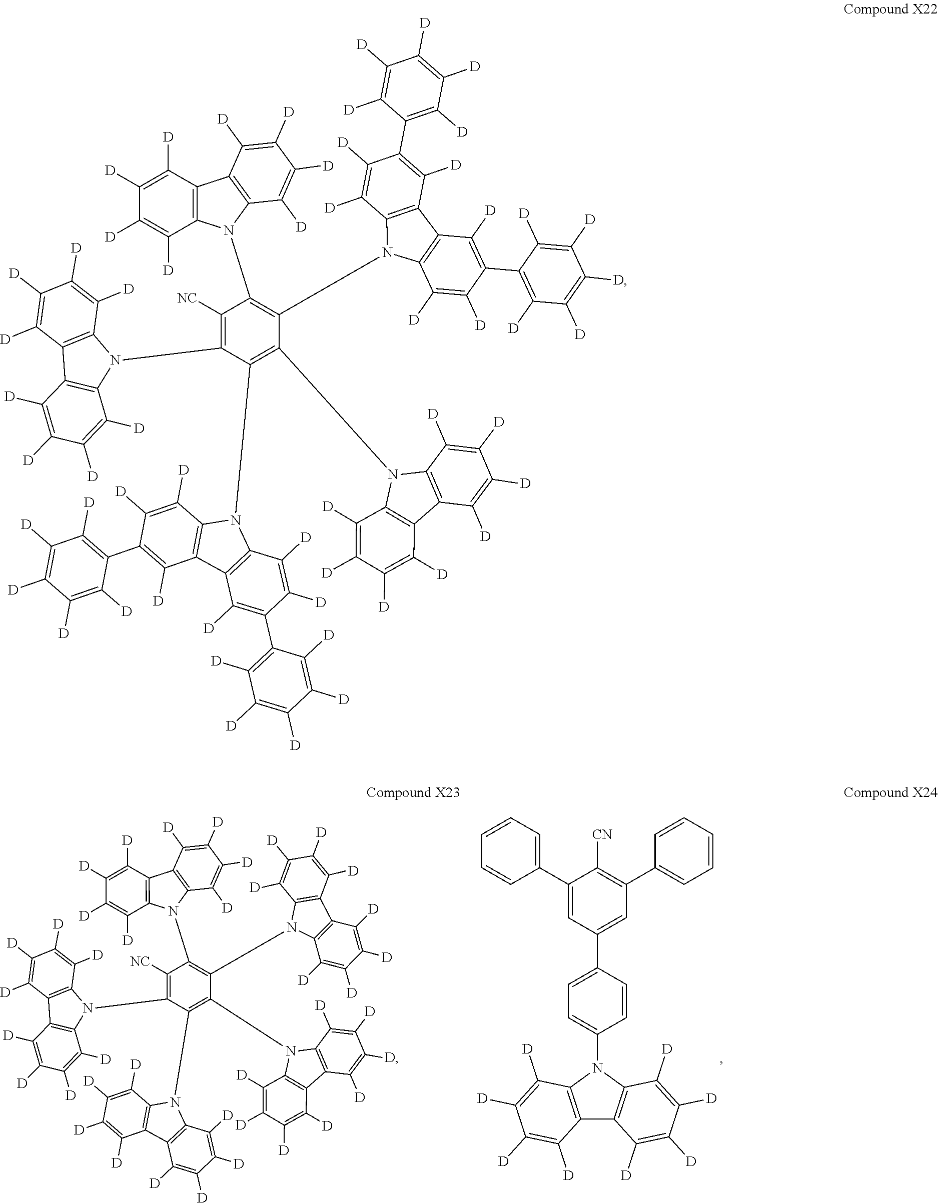

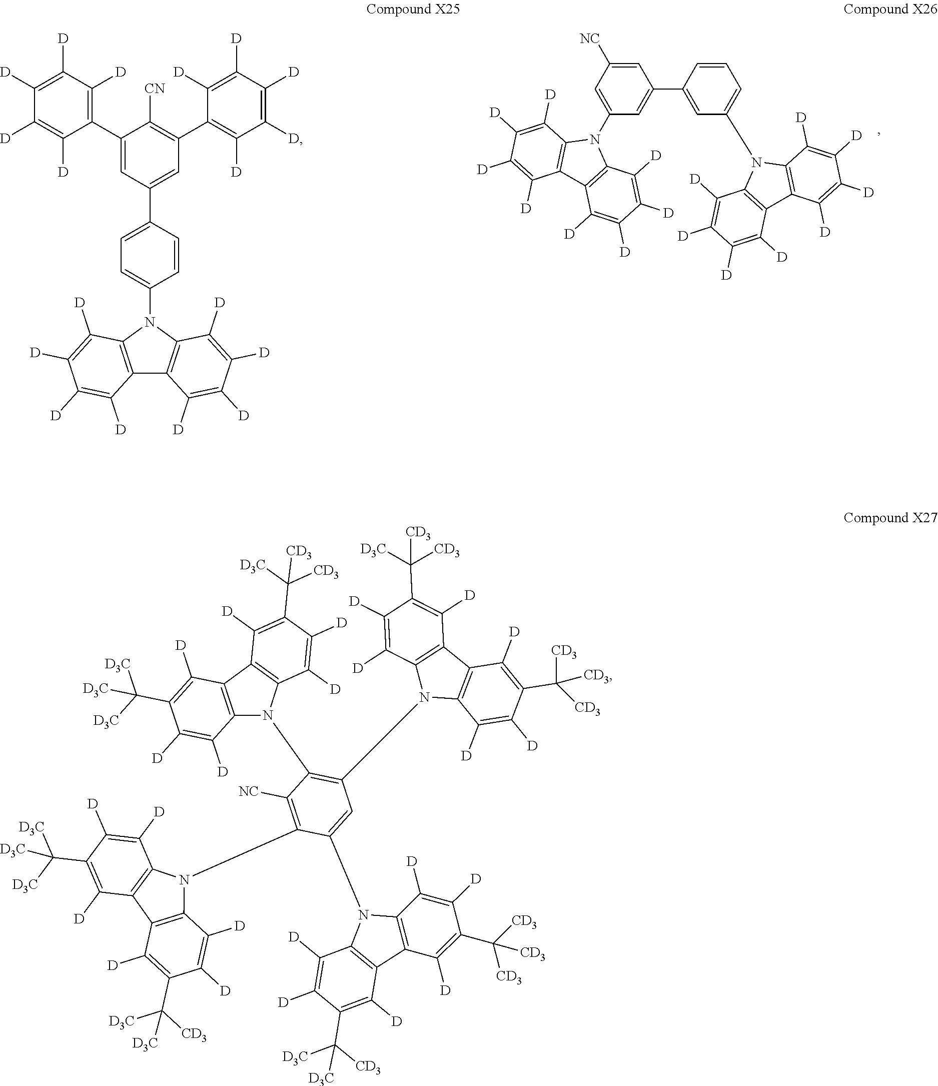

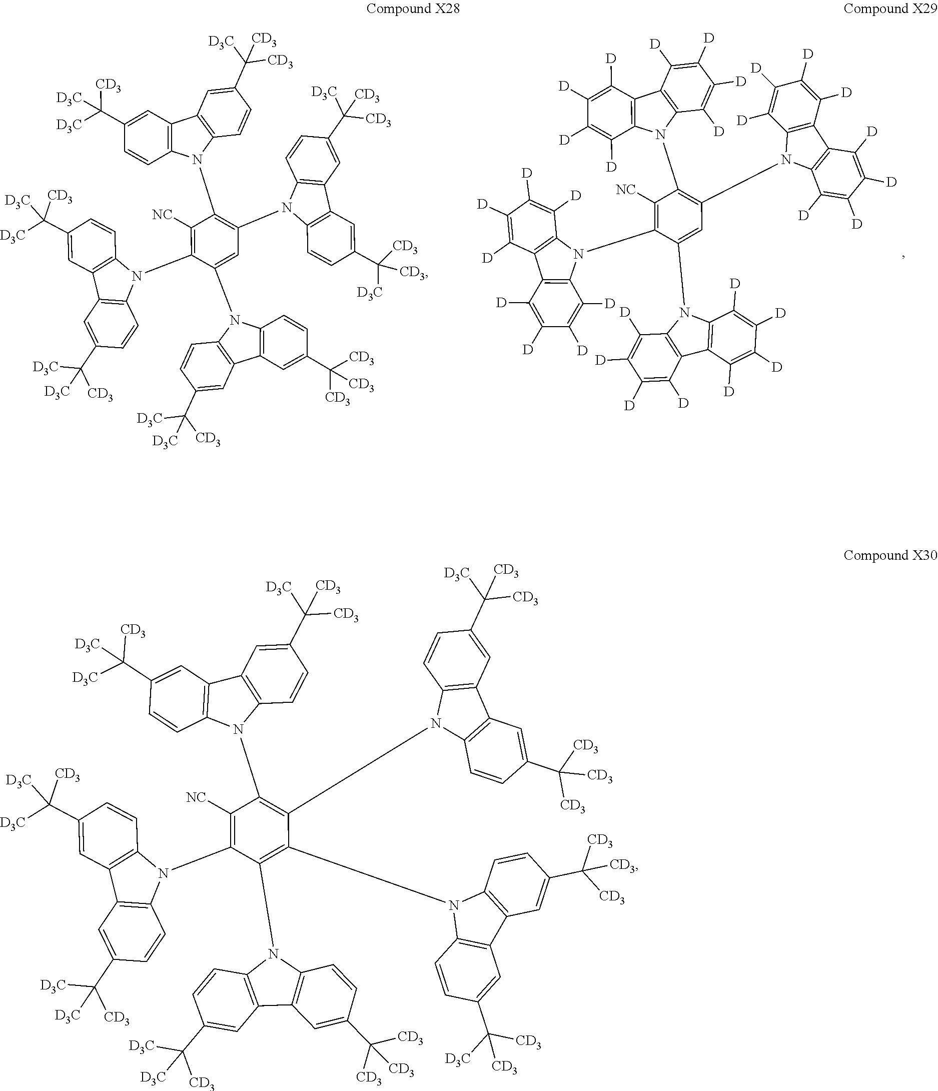

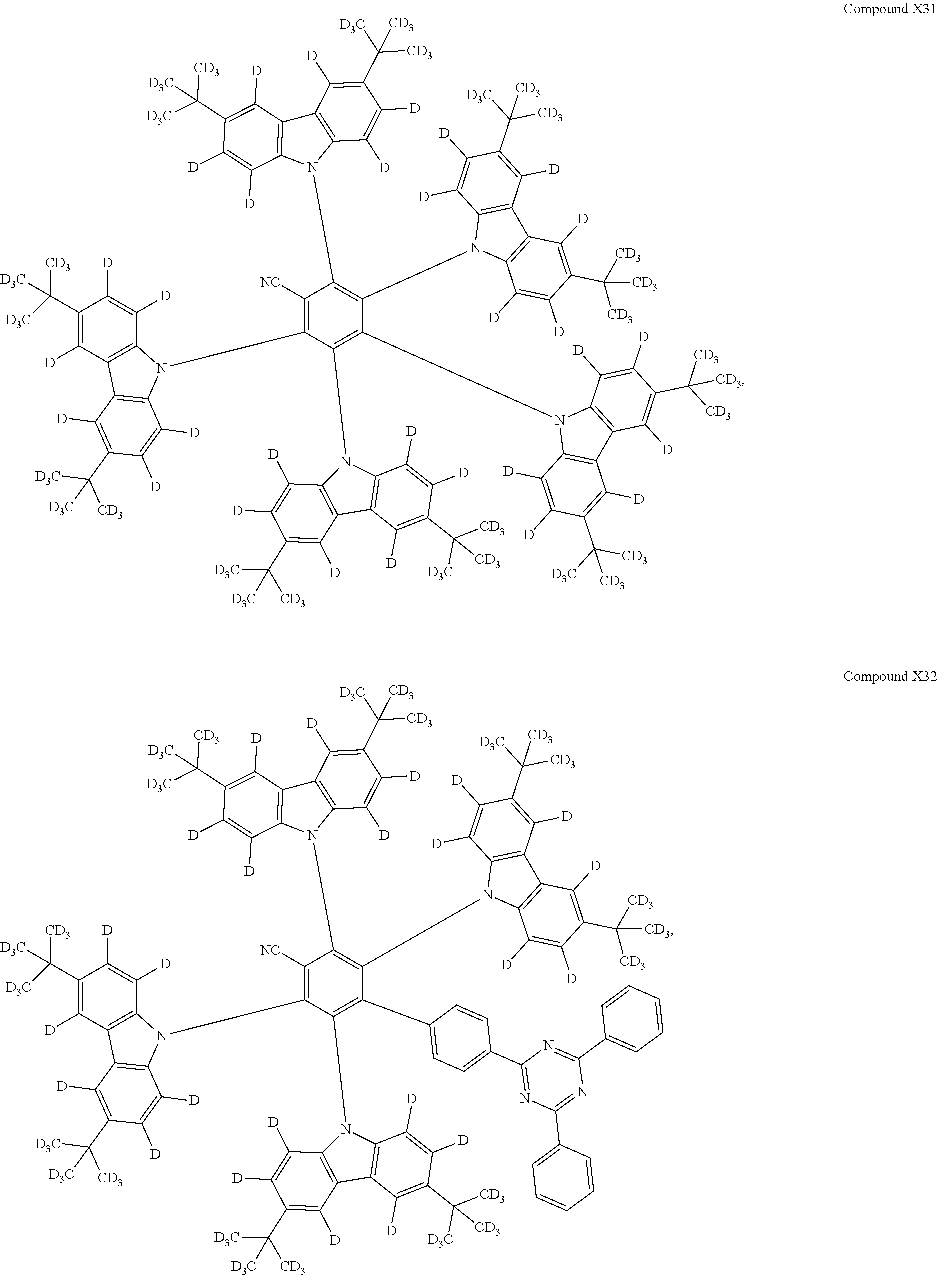

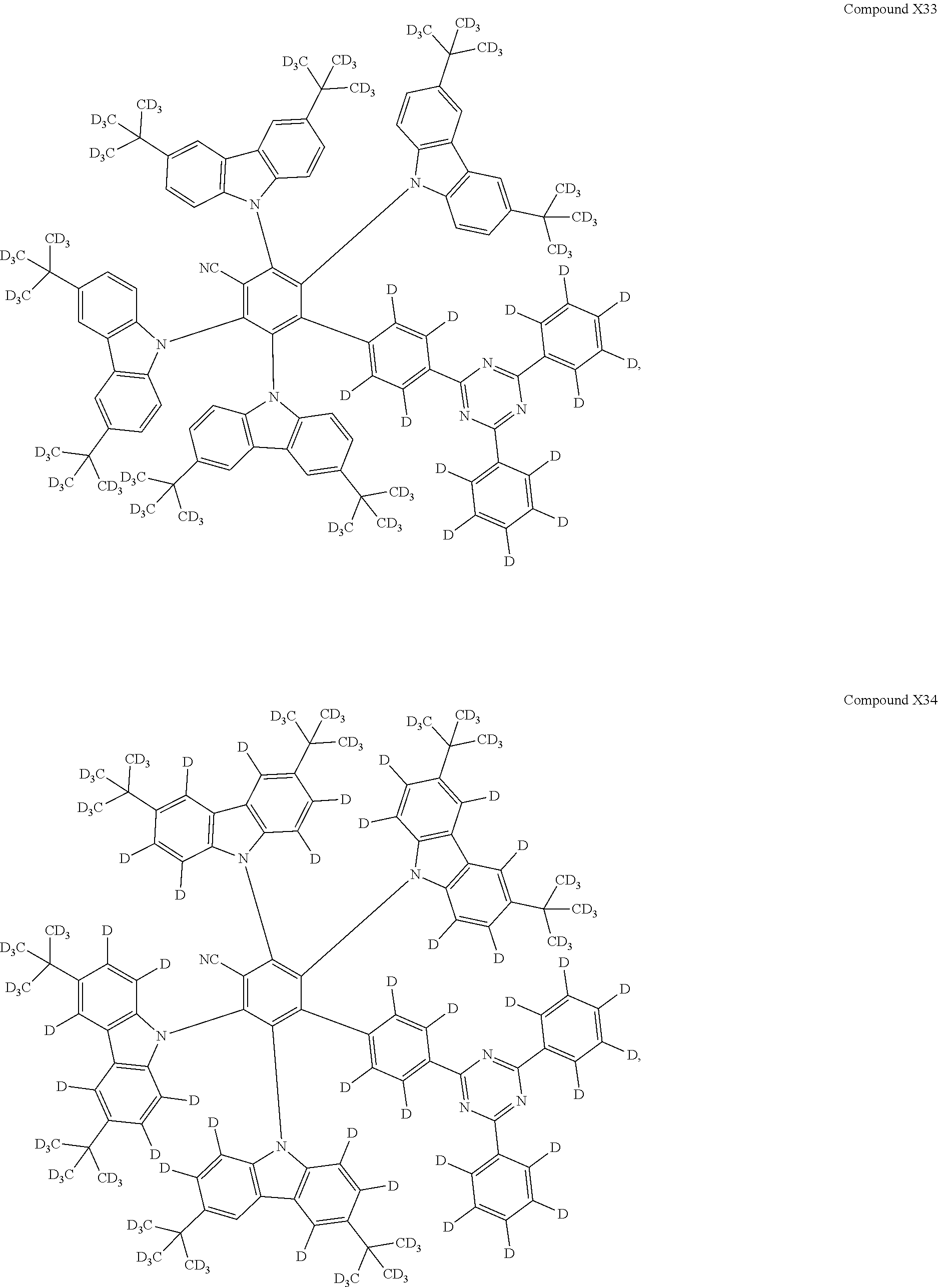

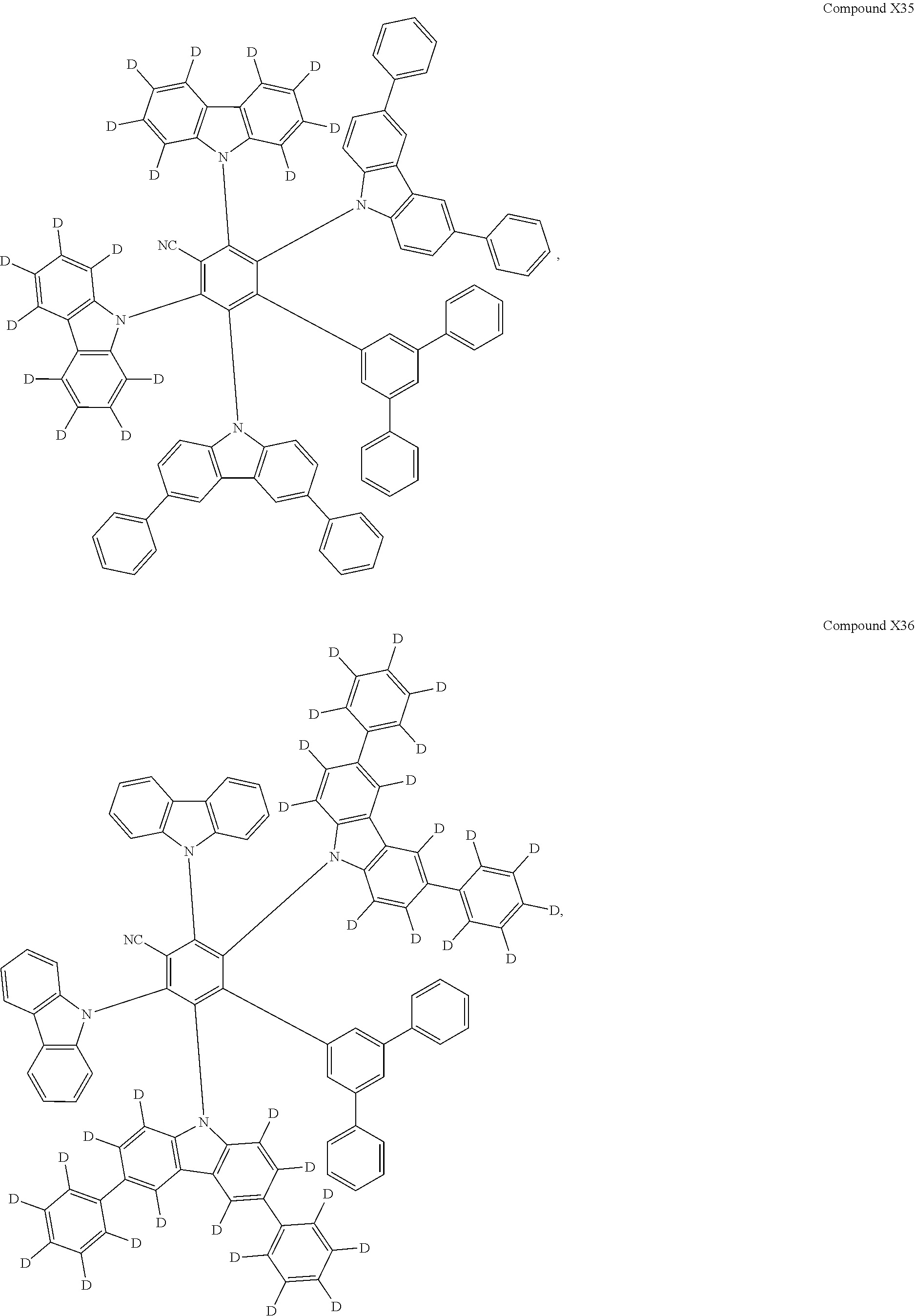

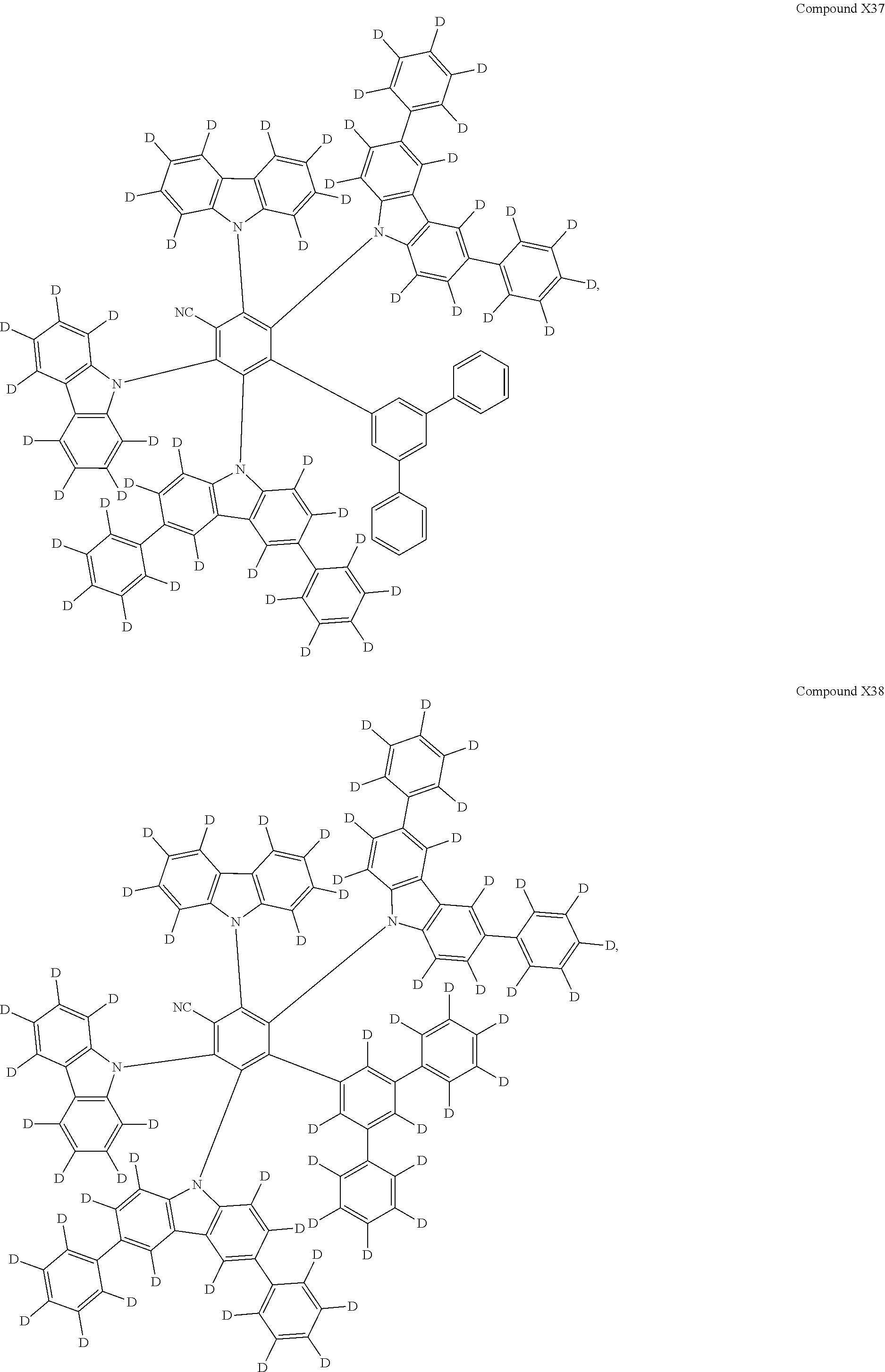

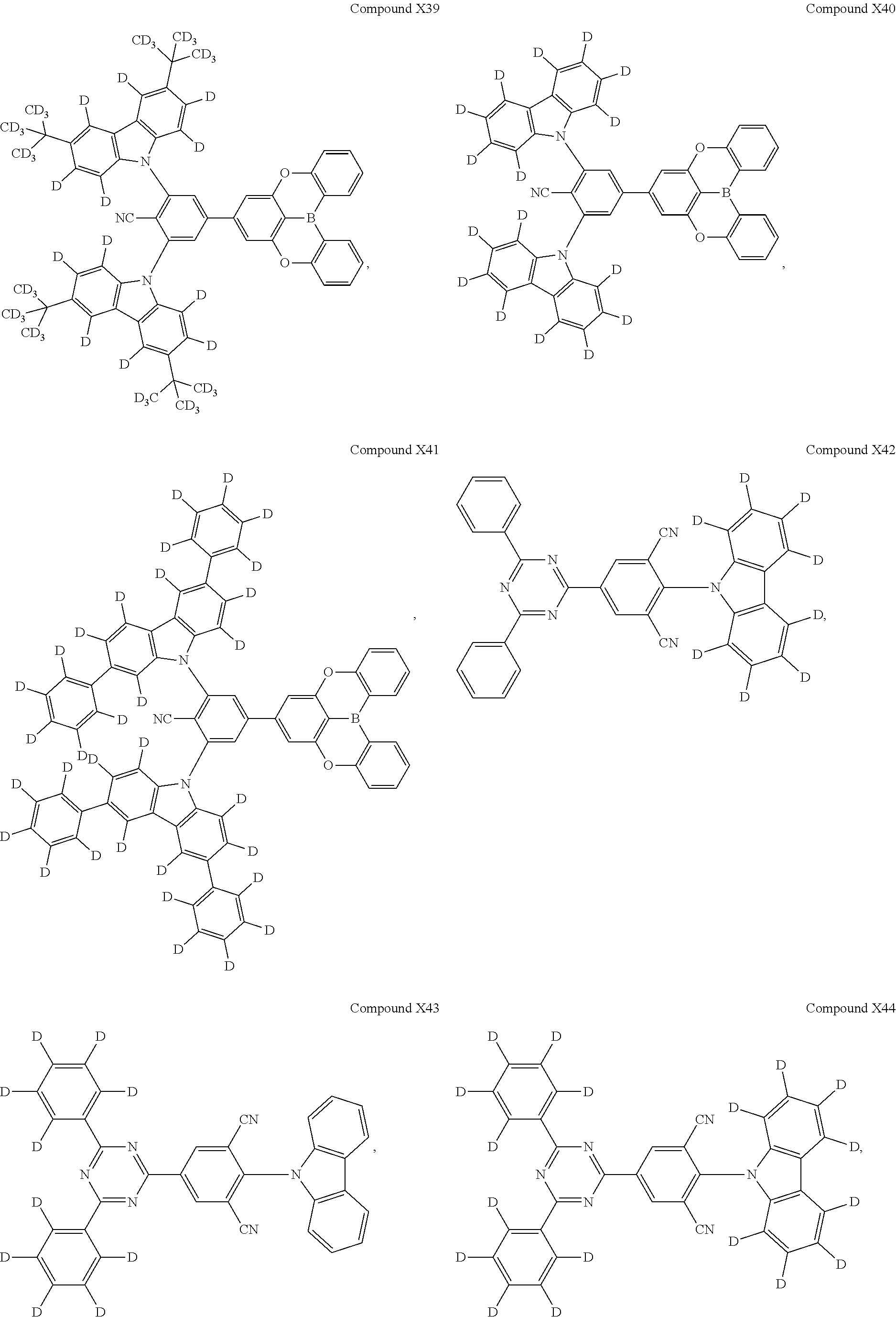

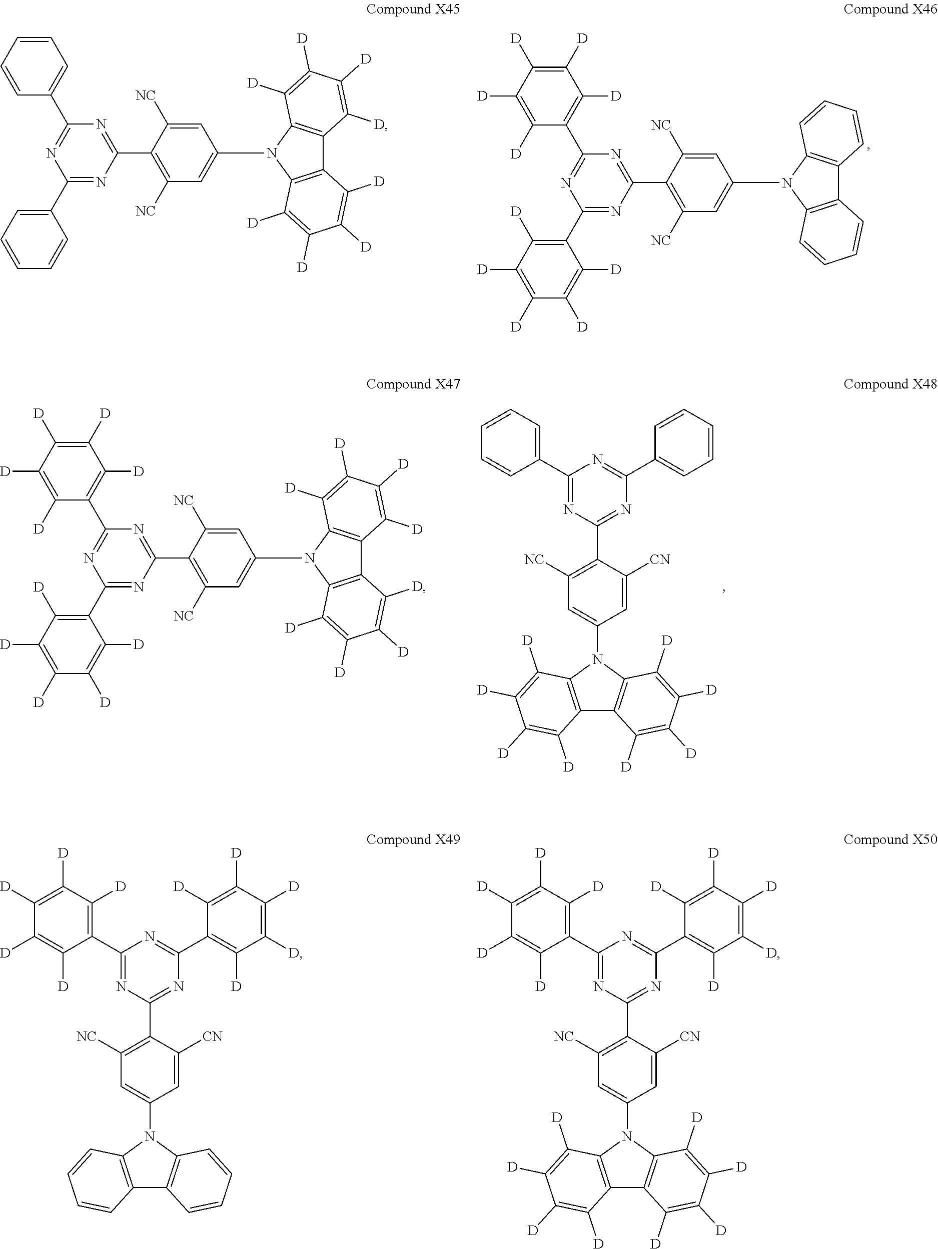

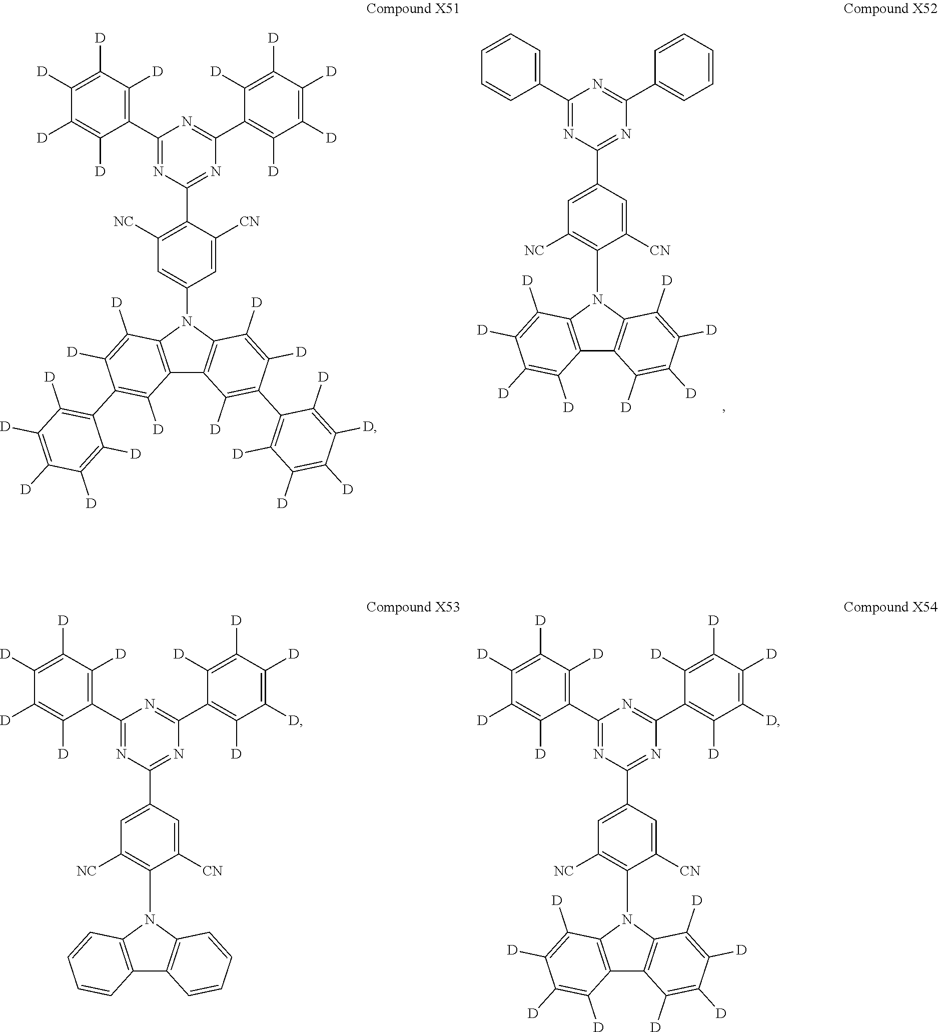

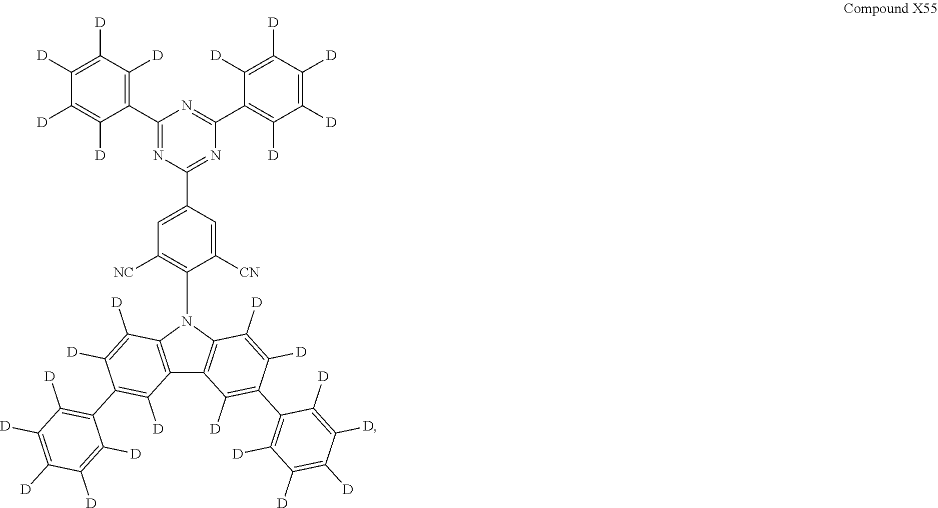

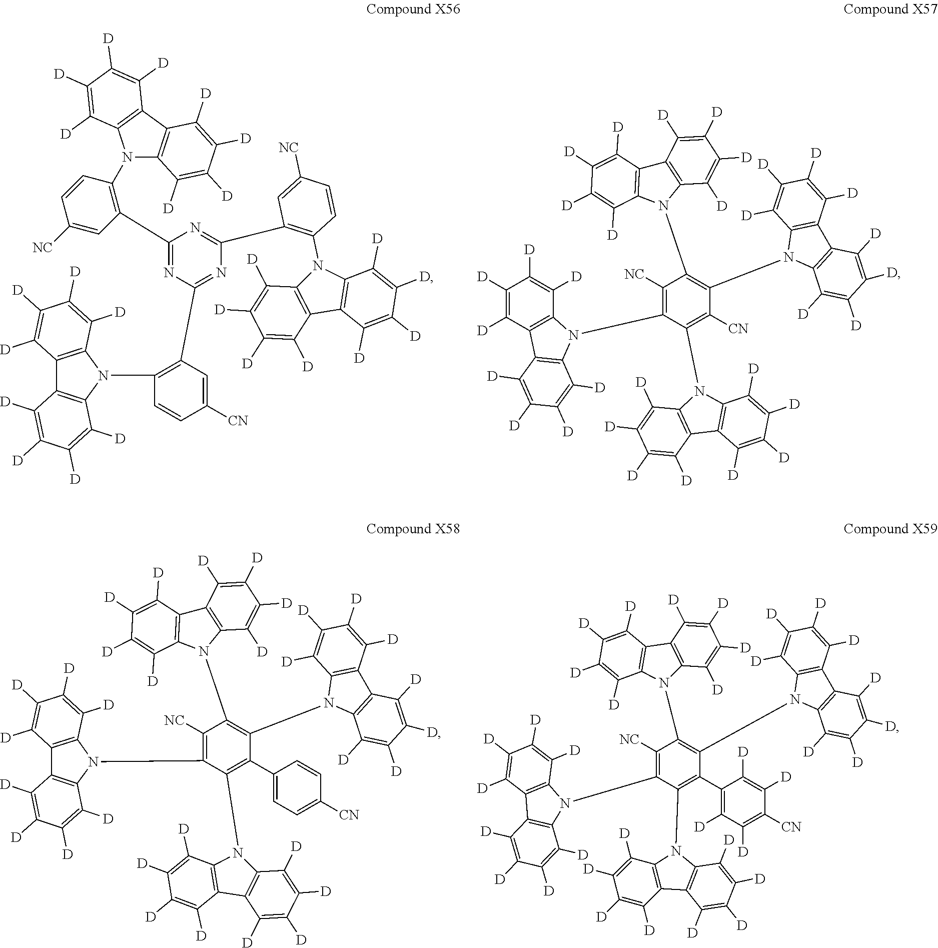

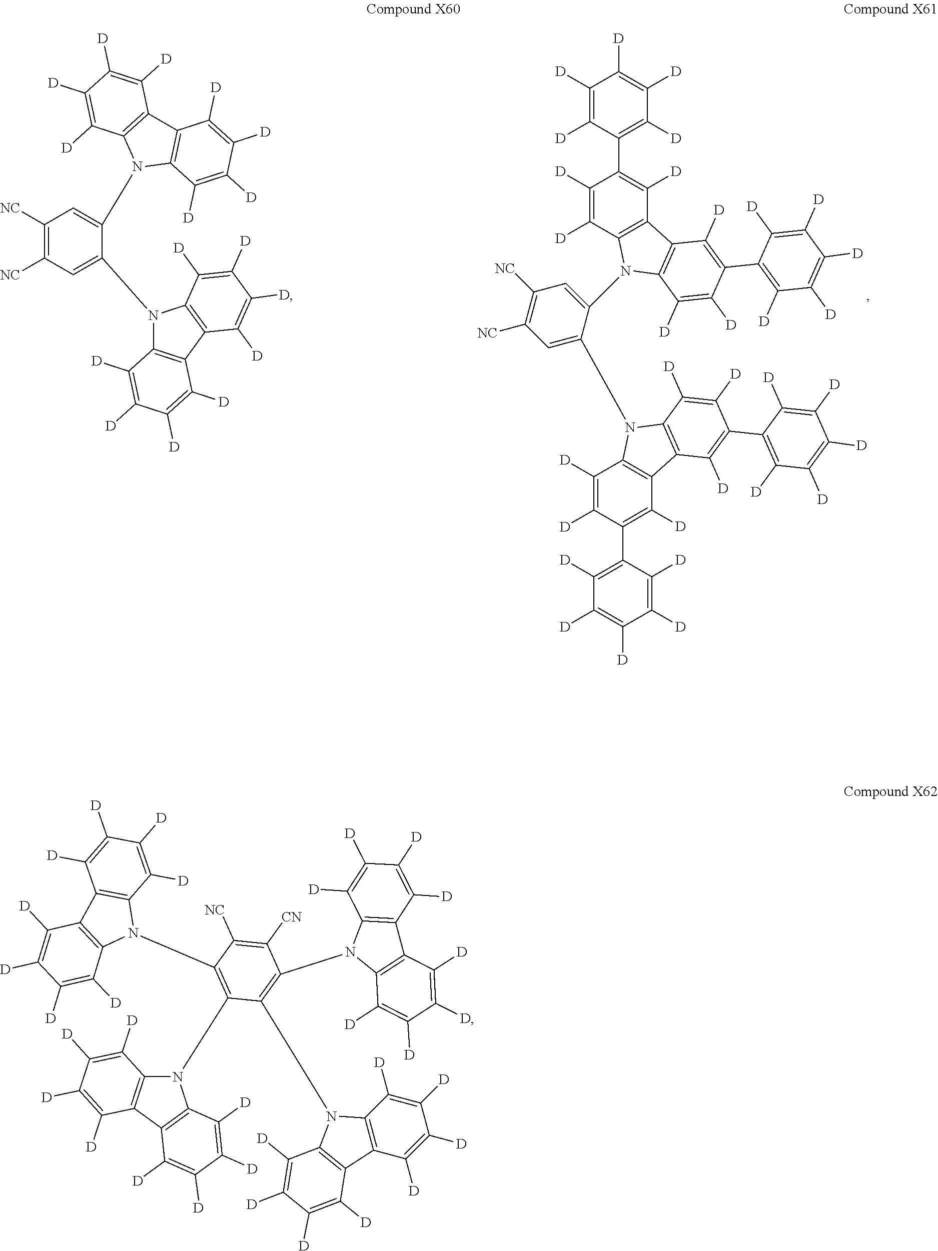

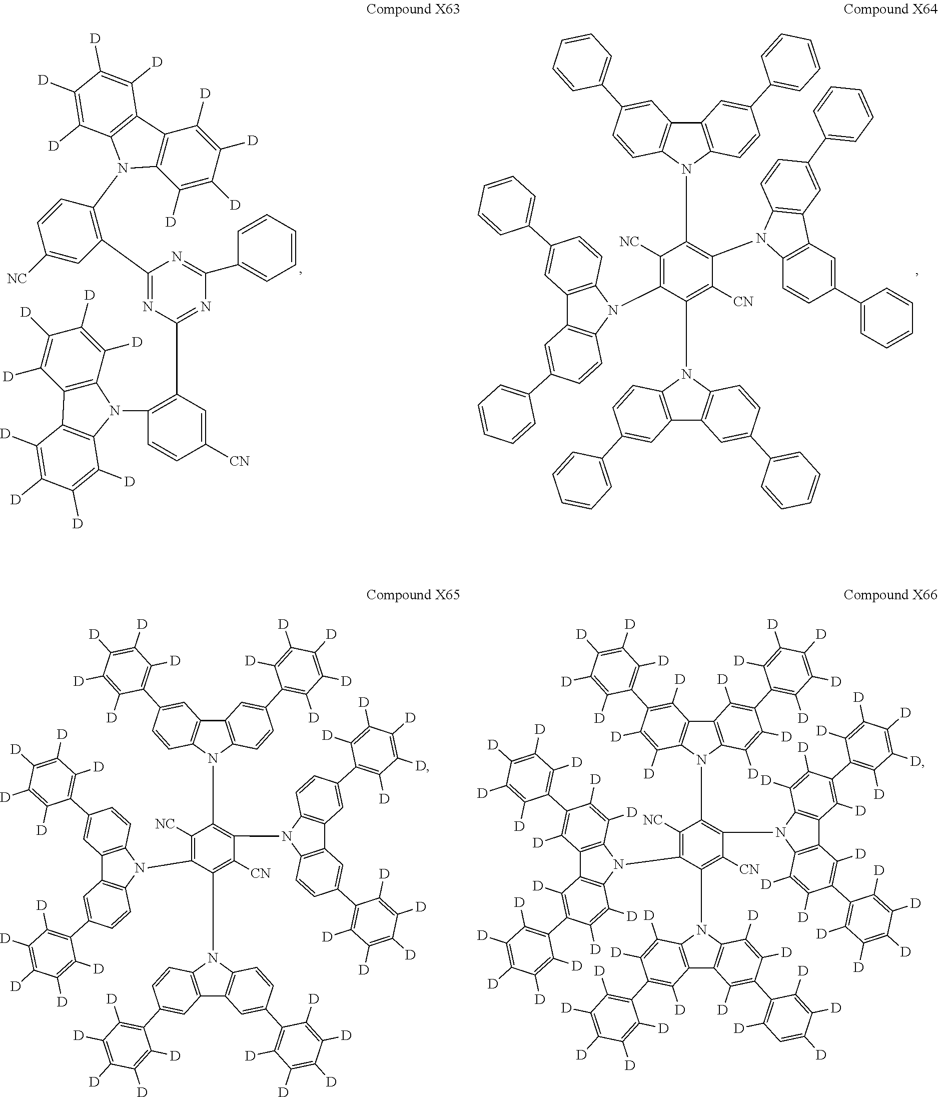

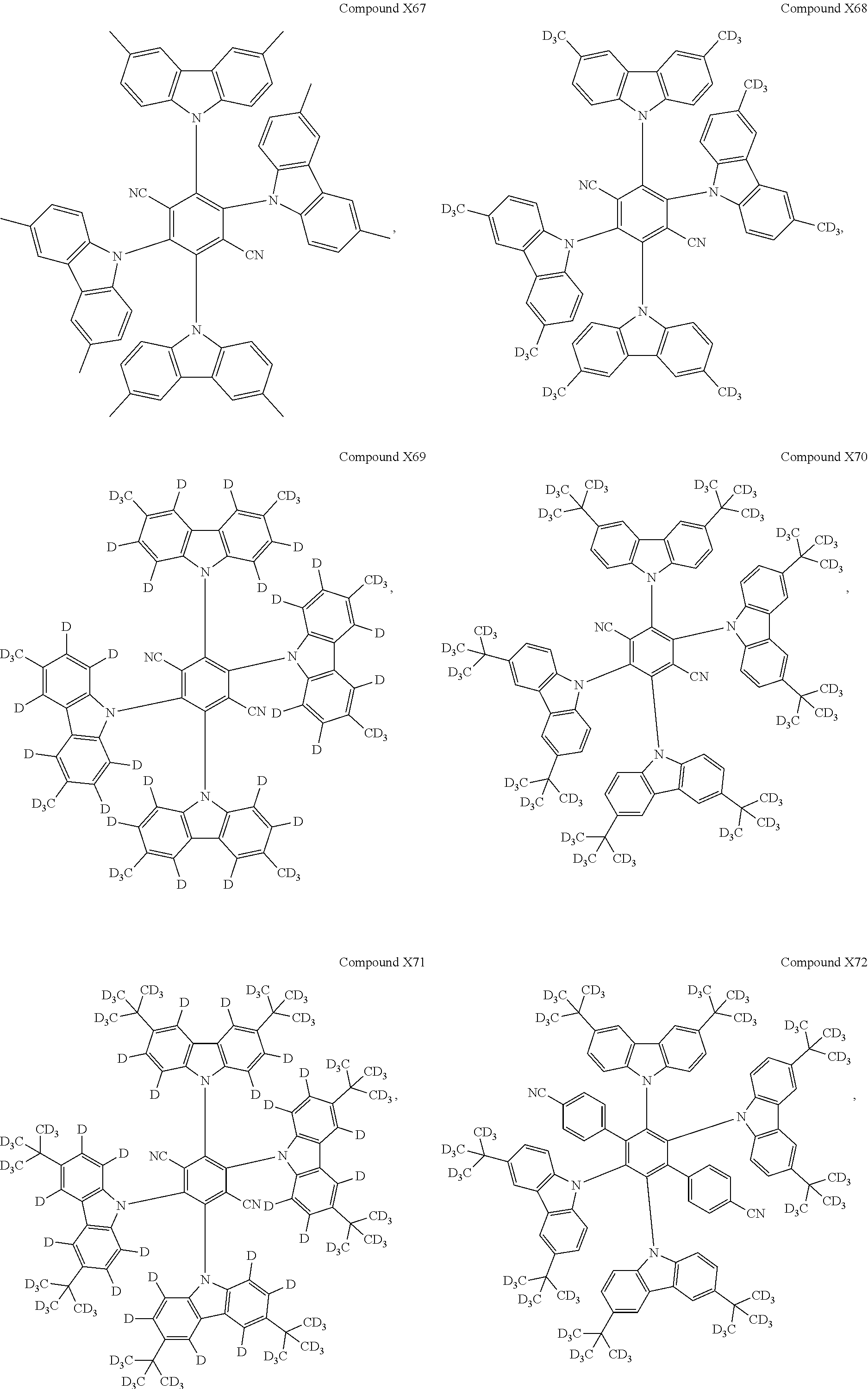

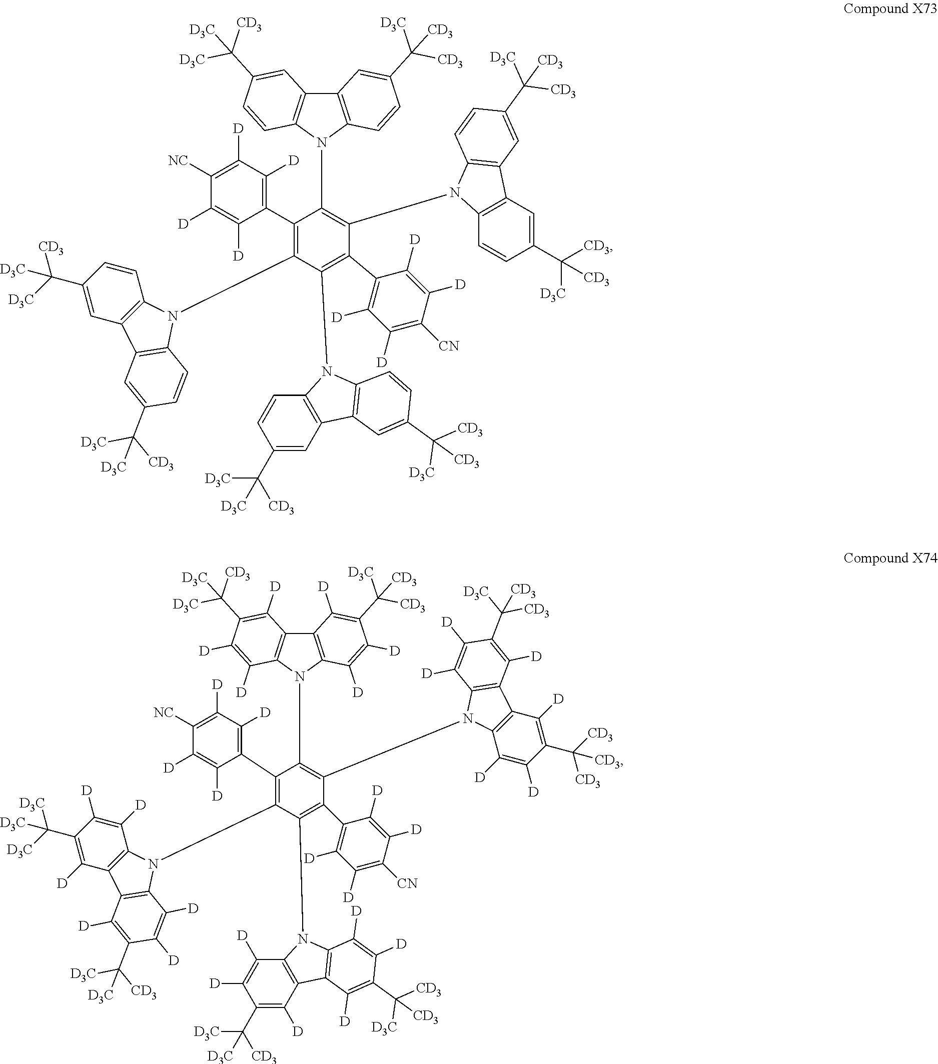

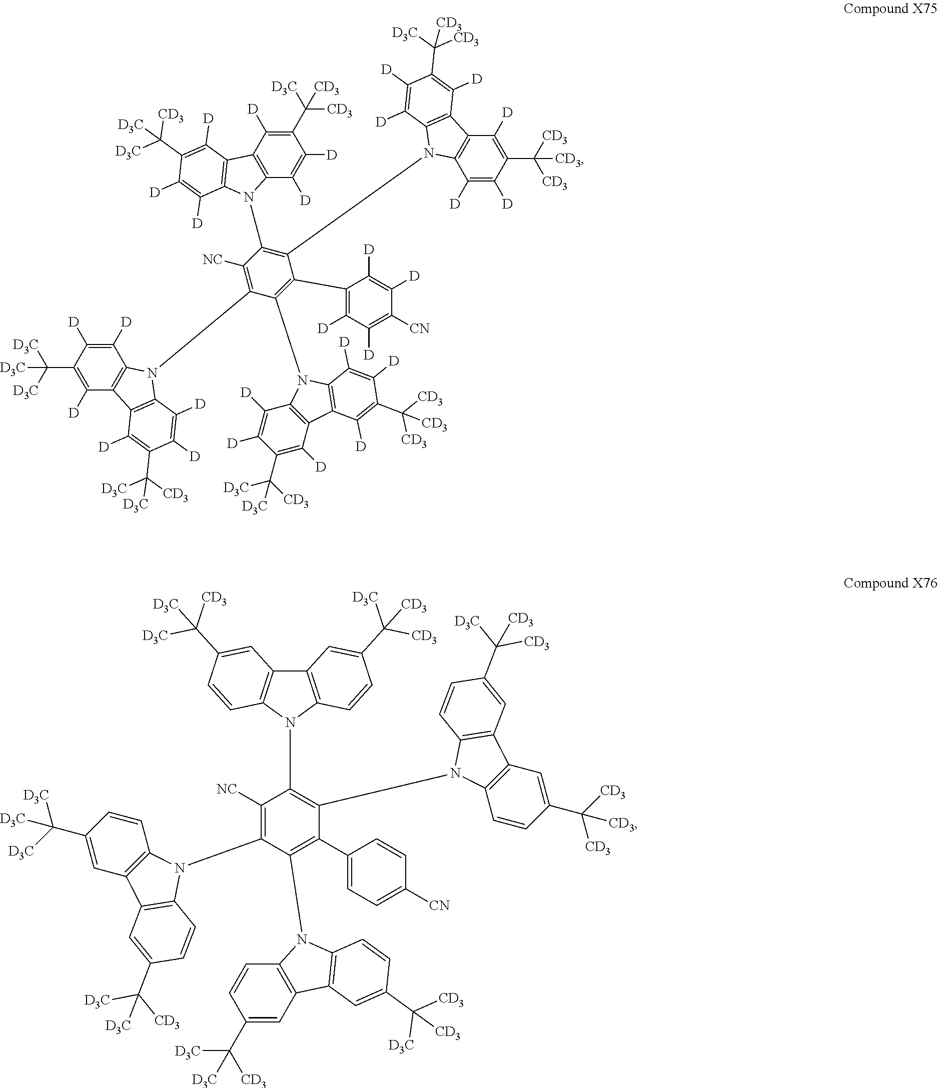

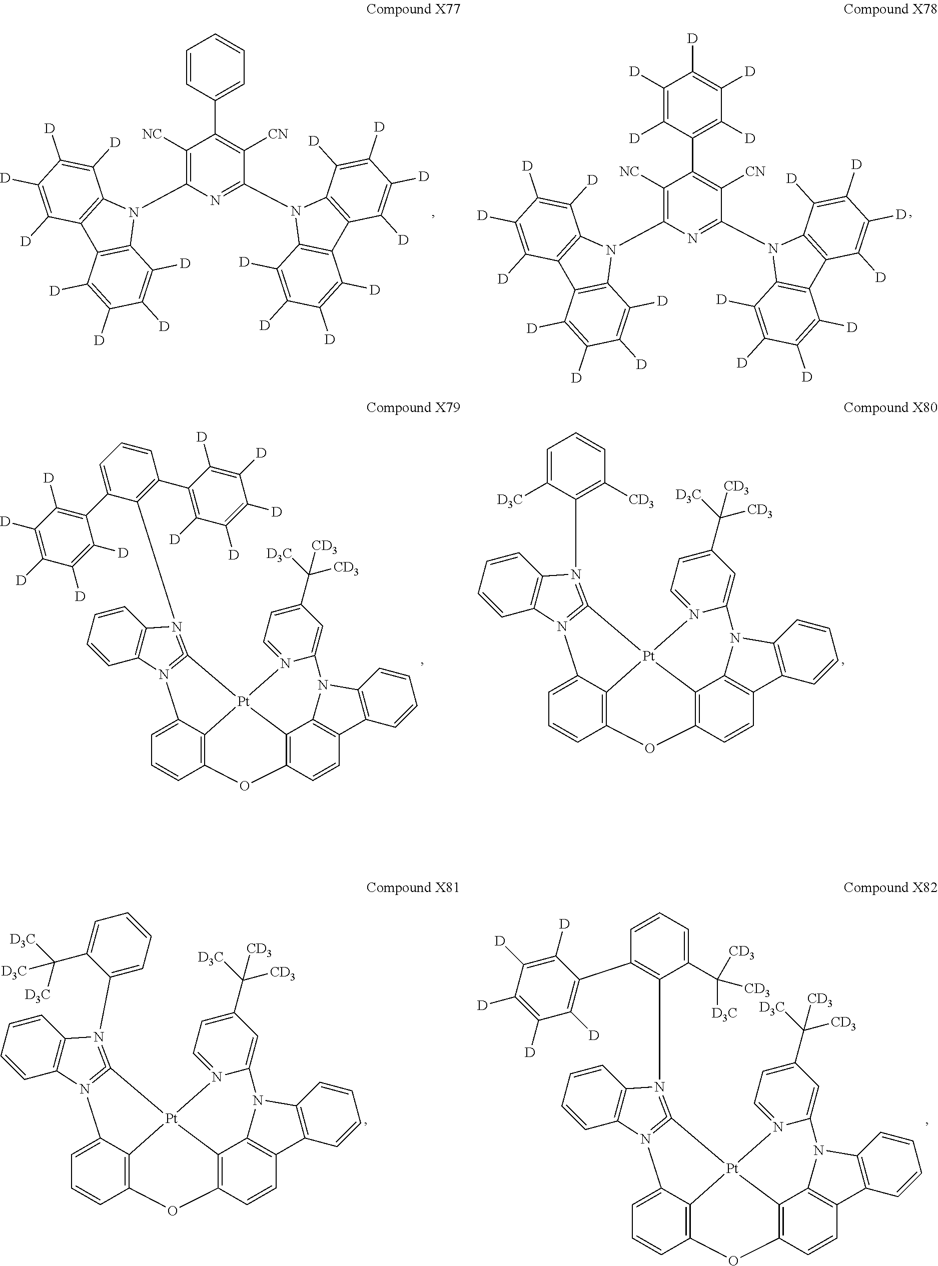

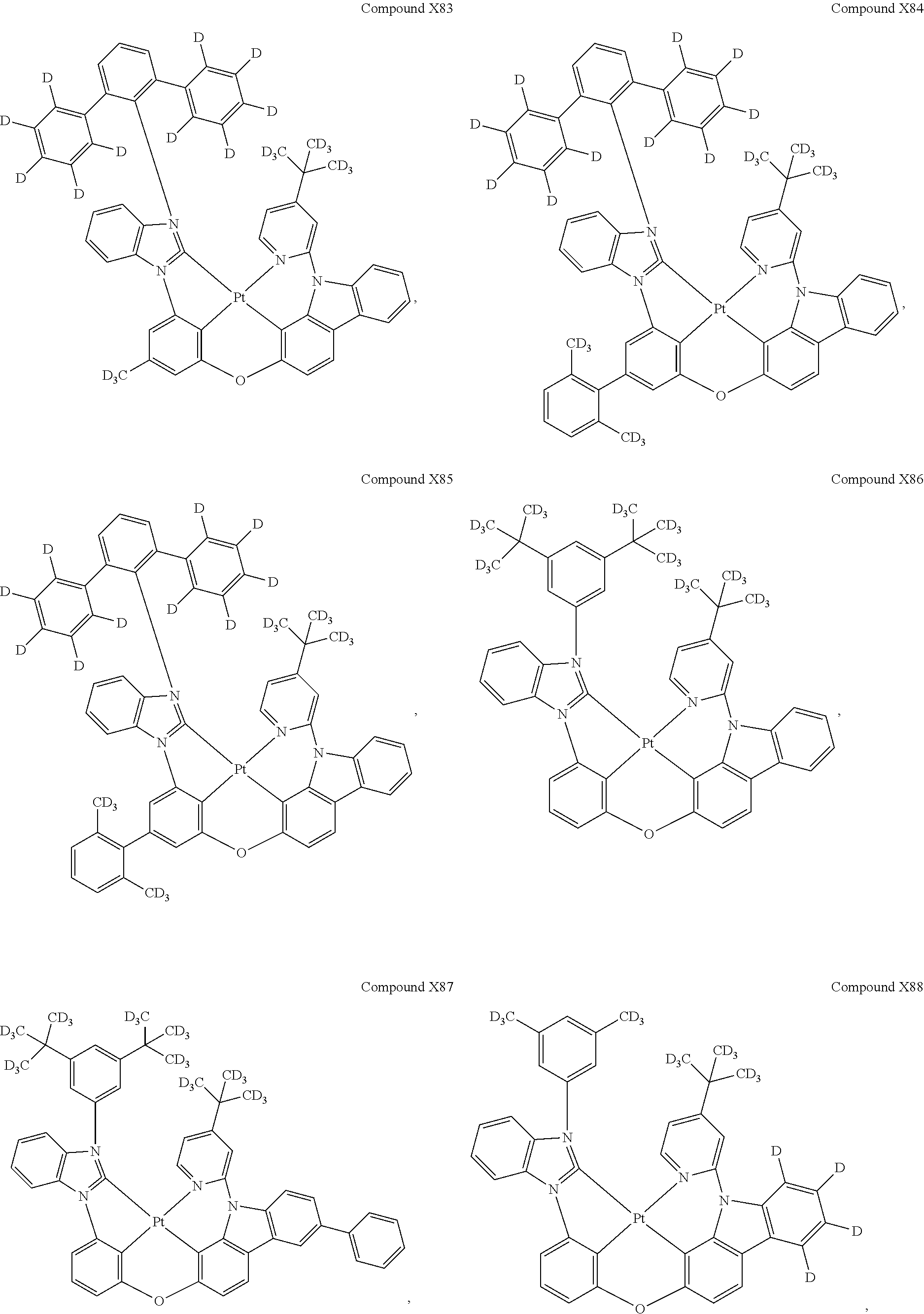

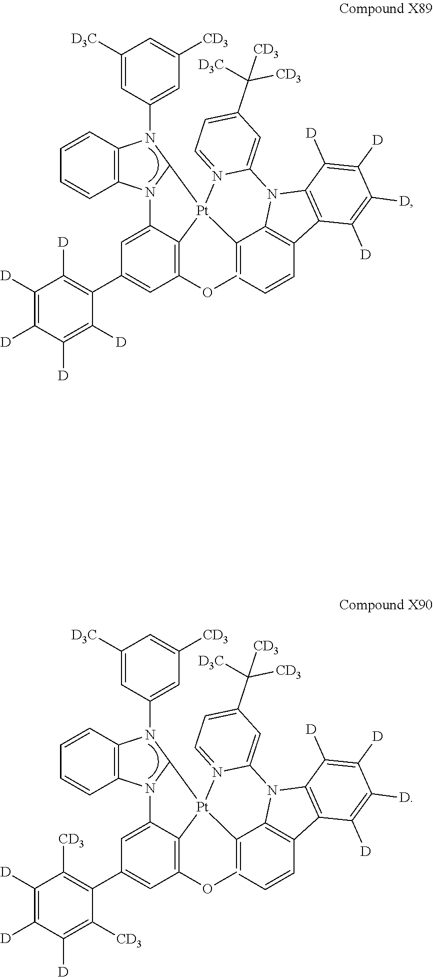

Adopting the above types of exciton utilizing agents is beneficial to better exerting its sensitizing effect, improving the exciton utilization rate, and thus improving the luminous efficiency of OLED devices, and also improving the color purity of blue light.

The present application also provides a synthetic route of the compound represented by the above general formula (XVI), which is as follows:

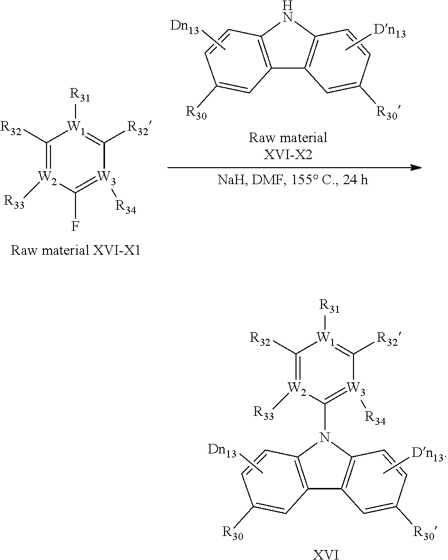

The compounds represented by the above general formula (XVII) in the present application can be synthesized with reference to the following documents: Sun J, Ahn H, Kang S, et al. Exceptionally Stable Blue Phosphorescent Organic Light-Emitting Diodes [J]. Nature Photonics, 2022, 16 (3): 212-218.

In a preferred embodiment, in first light-emitting functional layer composed of the exciton utilizing agent and the host material, the doping concentration of the exciton utilizing agent is 1 to 30 wt %, corresponding to an electroluminescence spectrum having a maximum luminous intensity denoted as E1, and a wavelength on short wavelength side corresponding to a luminous intensity of 60% E1 is λ_{EL}, corresponding to a photoluminescence spectrum having a maximum luminous intensity denoted as E₁′, and a wavelength on short wavelength side corresponding to a luminous intensity of 60% E1′ is λ_{PL}; in second luminescent functional layer composed of the host material and the guest light-emitting material, the doping concentration of the guest light-emitting material is 0.1 to 3 wt %, corresponding to an electroluminescence spectrum having a maximum luminous intensity denoted as E₂, and a wavelength on short wavelength side corresponding to a luminous intensity of 60% E₂ is λ_{EL}′, corresponding to a photoluminescence spectrum having a maximum luminous intensity denoted as E₂′, and a wavelength on short wavelength side corresponding to a luminous intensity of 60% E₂′ is λ_{EL}′; wherein λ_{EL} and λ_{EL}′ satisfy the following relationship: λ_{EL}≤λ_{EL}′, and λ_{PL} and λ_{PL}′ satisfy the following relationship: λ_{PL}≤λ_{PL}′.

The first light-emitting functional layer composed of exciton utilizing agent and host material with specific doping concentration has the above-mentioned luminescent spectral characteristics, and the second light-emitting functional layer composed of host material and guest light-emitting material with specific doping concentration has the above-mentioned luminescent spectral characteristics, and limiting λ_{EL}<λ_{E}′ and λ_{PL}<λ_{PL}′, and applying host materials, guest light-emitting materials, and exciton utilizing agents that meet the above requirements to the organic light-emitting layer 30, are beneficial for improving the utilization efficiency of triplet excitons and thus improving the luminous efficiency of OLED devices.

In a preferred embodiment, as shown in FIG. 3, at least one hole transport layer 50 is further provided between the anode 20 and the organic light-emitting layer 30, and at least one electron transport layer 60 is further provided between the cathode 40 and the organic light-emitting layer 30. The organic electroluminescent device comprises a substrate 10, an anode 20, a hole transport layer 50, an organic light-emitting layer 30, an electron transport layer 60, and a cathode 40 stacked in sequence. In the OLED device having the above-described stacked structure, the transmission efficiency of holes and electrons is high, which is beneficial to improving the luminous efficiency.

In a preferred embodiment, the material of the hole transport layer 50 includes but not limited to one or more of the group consisting of aromatic amine derivatives, carbazole derivatives, and spirocyclic derivatives. Compared with other types, adopting the above types of materials of the hole transport layer 50 is beneficial to improving the hole transmission efficiency, and thus improving the luminous efficiency of OLED devices.

In a preferred embodiment, the material of the electron transport layer 60 includes but not limited to one or more of the group consisting of azine compounds, benzimidazole compounds, phenanthrimidazole compounds, ortho phenanthroline compounds, polyfused ring compounds, spirofluorene compounds, and phosphine oxide compounds. Preferably, azine compounds include pyridine compounds, pyrimidine compounds, triazine compounds, pyridazine compounds; The polyfused ring compounds include anthracene compounds, pyrene compounds, pyrene compounds, and benzophenanthrene compounds. Compared with other types, adopting the above types of materials of the electron transport layer 60 is beneficial to improving the electron transmission efficiency, and thus improving the luminous efficiency of OLED devices.

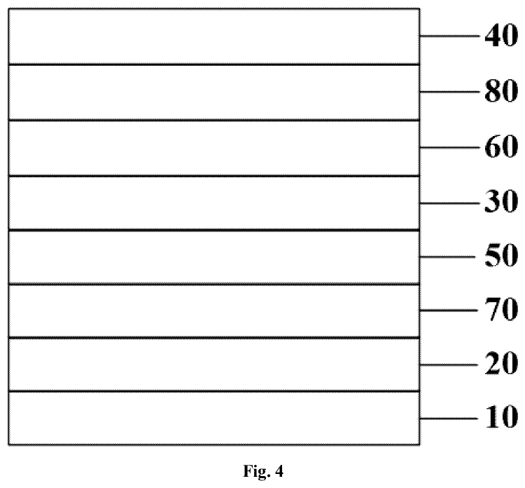

In a preferred embodiment, as shown in FIG. 4, a hole injection layer 70 is further provided between the hole transport layer 50 and the anode 20. The configuration of the hole injection layer 70 is beneficial to further improving the hole injection efficiency, and thus further improving the luminous efficiency of OLED devices.

In order to further improve the hole injection efficiency and thus further improve the luminous efficiency of OLED devices, preferably, the material of the hole injection layer 70 include but not limited to one or more of the group consisting of aromatic amine compounds, carbazole compounds, spirobifluorene compounds, and fluorene compounds.

In a preferred embodiment, as shown in FIG. 4, an electron injection layer 80 is further provided between the electron transport layer 60 and the cathode 40. The configuration of the electron injection layer 80 is beneficial to further improving the electron injection efficiency, and thus further improving the luminous efficiency of OLED devices,

In order to further improve the electron injection efficiency and thus further improve the luminous efficiency of OLED devices, preferably, the material of the electron injection layer 80 includes but not limited to one or more of the group consisting of azine compounds, benzimidazole compounds, phenanthrimidazole compounds, ortho phenanthroline compounds, polyfused ring compounds, spirofluorene compounds, and phosphine oxide compounds.

As the substrate 10 in the present application, a glass substrate 10 commonly used in the art can be used, and the glass substrate 10 has a conductive surface. In a preferred embodiment, the substrate 10 includes but not limited to indium tin oxide (ITO) conductive glass, fluorine-doped Tin Oxide (FTO) conductive glass, indium gallium zinc oxide (IGZO) conductive glass or indium zinc oxide (IZO) conductive glass.

In a preferred embodiment, the cathode 40 is a metal electrode wherein the metal includes but not limited to one or more of the group consisting of Ag, Mg, Yb, Al, Ca, and Au. The cathode 40 of the above type has good conductivity, which is convenient for improving the current efficiency and the luminous efficiency of the OLED device.

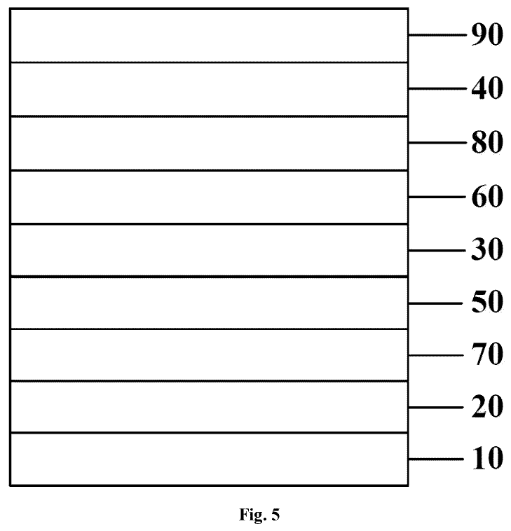

In a preferred embodiment, as shown in FIG. 5, the organic electroluminescent device further comprises an optical cover layer 90, which is disposed on the surface of the cathode 40 on the side away from the substrate 10, and the material of the optical cover layer 90 includes one or more of the compounds shown in Formula (A) and Formula (B):

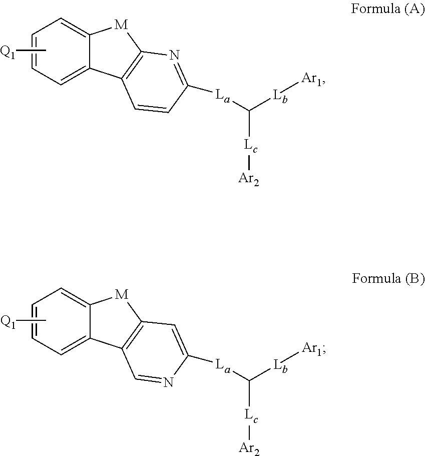

wherein M includes but not limited to O or S, and Q₁ includes but not limited to a hydrogen atom or a deuterium atom, and Lₐ, L_{b} and L_{c} each independently include but not limited to C₆-C₂₀ arylene; Ar₁ and Ar₂ are the same, and Ar₁ and Ar₂ include but not limited to any one of the following structures:

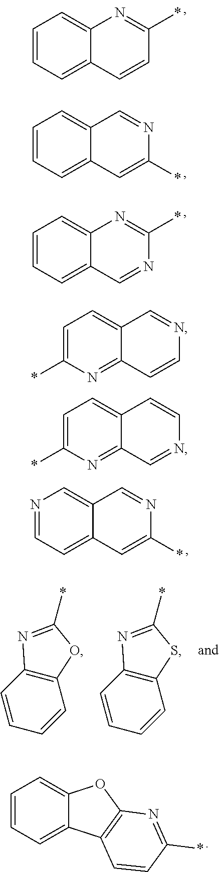

The compound represented by the formula (I) and the compound represented by the formula (II) have low extinction coefficients and high refractive indices in the visible light region; and providing the optical coating layer 90 having the above compound on the surface of the cathode 40 on the side away from the substrate 10 is advantageous in improving the light extraction efficiency and the current efficiency of the OLED device; in addition, the optical coating layer 90 made of the above compound has high stability and excellent durability.

In order to further improve the light extraction efficiency and further improve the current efficiency of the OLED device, preferably, Lₐ, L_{b}, and L_{c} each independently include but not limited to phenylene or naphthylene.

The second aspect of the present application also provides a display device comprising the organic electroluminescent device provided in the present application, and the display device includes but not limited to a tablet phone, a wearable display device, a tablet computer, a laptop computer, a medical display device, a foldable display device, a vehicle-mounted display device, a virtual reality or augmented reality display device. The OLED device provided in the present application has high exciton utilization rate and luminous efficiency, and can significantly reduce power consumption when applied to an OLED display device.

The present application will be described in further detail below with reference to particular examples, which are not to be construed as limiting the scope of protection claimed herein.

### Device Example 1

A method for preparing an OLED device, comprising the following steps:
(1) cutting ITO conductive glass into a size of 50 mm×50 mm×0.7 mm, ultrasonicating in isopropyl alcohol and deionized water for 30 min, respectively, and then cleaning under ozone exposure for 10 min to obtain substrate 10; wherein the ITO conductive glass includes an indium tin oxide conductive surface having a thickness of 10 nm;
(2) placing the substrate 10 in a vacuum deposition apparatus, and co-evaporating the p-type doping material Compound 1 and the hole transport material Compound 2 on the indium tin oxide conductive surface side of the substrate 10 to obtain a hole injection layer 70 having a thickness of 5 nm; wherein the weight ratio of Compound 1 and Compound 2 is 3:97; the chemical structure of each raw material used is as follows:

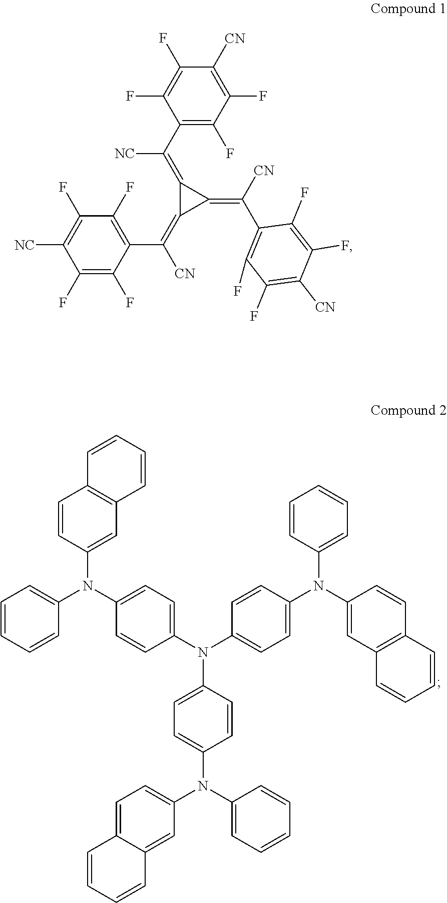 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1]

(3) vacuum depositing (or vacuum evaporating) the hole transport material Compound 3 on the surface of the hole injection layer 70 on the side away from the ITO conductive glass to obtain a first hole transport layer 50 having a thickness of 100 nm; the chemical structure of the raw materials used is as follows:

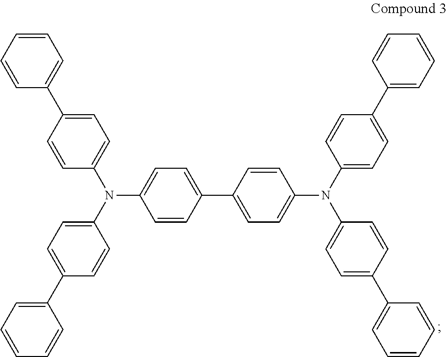 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

(4) vacuum depositing the hole transport material Compound HH18 on the surface of the first hole transport layer 50 on the side away from the ITO conductive glass to obtain a second hole transport layer 50 having a thickness of 5 nm;
(5) vacuum depositing a host material (Compound HH18 and Compound EH7), an exciton utilizing agent (Compound X76), and a guest light-emitting material (Compound E2) on the surface of the second hole transport layer 50 on the side away from the ITO conductive glass to obtain an organic light-emitting layer 30 having a thickness of 30 nm; wherein the weight ratio of Compound HH18, Compound EH7, Compound X85 and Compound E2 is 54:25:20:1;
(6) vacuum depositing an electron transport material Compound EH7 on the surface of the organic light-emitting layer 30 on the side away from the ITO conductive glass to obtain an electron transport layer 60 having a thickness of 5 nm;
(7) vacuum depositing an electron injection materials Compound 8 and Compound 9 with a weight ratio of 1:1 on the surface of the electron transport layer 60 on the side away from the ITO conductive glass, to obtain an electron injection layer 80 having a thickness of 30 nm; the chemical structure of each raw material used is as follows:

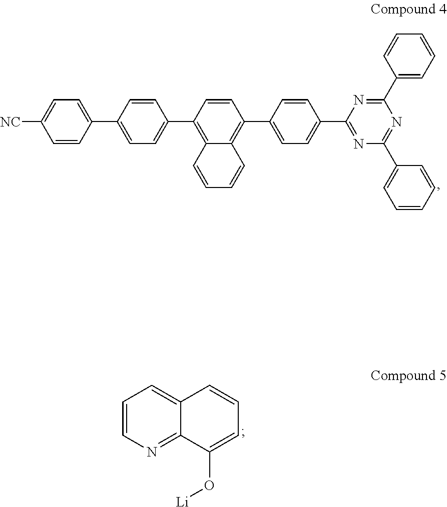

(8) vacuum depositing a magnesium-silver electrode with the weight ratio of metallic magnesium to metallic silver being 1:9 on the surface of the electron injection layer 80 away from the ITO conductive glass, to obtain a cathode 40 having a thickness of 10 nm;
(9) vacuum depositing Compound 6 on the surface of the cathode 40 on the side away from the ITO conductive glass to obtain an optical coating layer 90 having a thickness of 65 nm; the chemical structure of the Compound 6 is as follows:

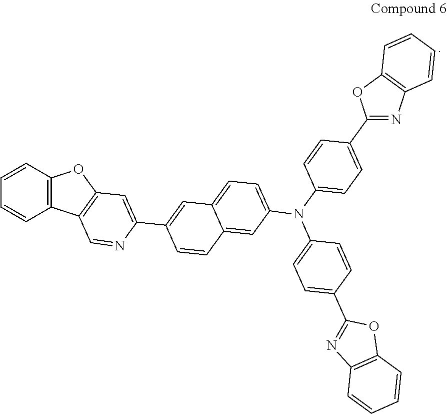 [SMILES: c1ccc2oc(-c3ccc(N(c4ccc(-c5nc6ccccc6o5)cc4)c4ccc5cc(-c6cc7oc8ccccc8c7cn6)ccc5c4)cc3)nc2c1]

### Device Comparative Example 1

It differs from Device Example 1 in that: Compound EH7 in step (5) and step (6) is replaced with Comparative Compound 1 having the chemical structure as follows:

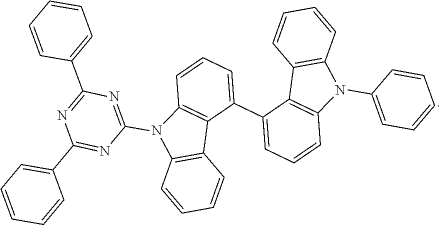 [SMILES: c1ccc(-c2nc(-c3ccccc3)nc(-n3c4ccccc4c4c(-c5cccc6c5c5ccccc5n6-c5ccccc5)cccc43)n2)cc1]

The bond dissociation energy of the anionic state of Comparative Compound 1 calculated by B3LYP/6-31G* was 2.26 eV.

### Device Comparative Example 2

It differs from Device Example 1 in that Compound X76 in step (5) is replaced with Comparative Compound 2 having the chemical structure as follows:

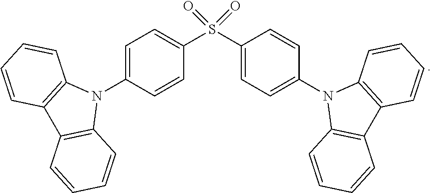 [SMILES: O=S(=O)(c1ccc(-n2c3ccccc3c3ccccc32)cc1)c1ccc(-n2c3ccccc3c3ccccc32)cc1]

The bond dissociation energy of the anionic state of Comparative Compound 3 calculated by B3LYP/6-31G* was 1.29 eV.

The bond dissociation energy data in the anionic state of the material of the organic light-emitting layer 30 according to Device Example 1 and Device Comparative Examples 1 to 4 of the present application are shown in Table 1.

TABLE 1

| | | Bond dissociation energy |
|---|---|---|
| | | of anionic state |
| | Compound | (eV) |
| Device Example 1 | Compound EH7 | 2.62 |
| | Compound X76 | 3.70 |
| Device Comparative | Comparative | 2.26 |
| Example 1 | Compound 1 | |
| Device Comparative | Comparative | 1.29 |
| Example 2 | Compound 2 | |

The luminescence performance of the OLED devices prepared in Device Example 1 and Device Comparative Examples 1 and 2 of the present application was tested. The test results are shown in Table 2. The blue light index and the device lifetime of Device Example 1 was set to 100%, the blue light index was the ratio of device current efficiency to CIEy. The test conditions were a current density of 10 mA/cm².

TABLE 2

| | Blue Light | Device |
|---|---|---|
| | Index (BI) | Lifetime LT90 |
| | cd · A⁻¹y⁻¹ (%) | h (%) |
| Device Example 1 | 100 | 100 |
| Device Comparative Example 1 | 87 | 17 |
| Device Comparative Example 2 | 92 | 5 |

Compared with other ranges, by limiting the minimum value of bond dissociation energy of the host material and exciton utilizing agent in the organic light-emitting layer 30 within the specific range described above, the stability of molecules in anionic state, electrically neutral state and cationic state can be enhanced, and the degradation pathway of each material in triplet-triplet annihilation and triplet-polaron annihilation process can be effectively inhibited, thereby improving the stability of each material in the working process of the organic electroluminescent device and achieving a longer lifetime of the device.

It should be noted that before the above-described Device Example 1, the inventors first conducted experiments on the electroluminescence spectral characteristics.

### Test Example 1

A method for preparing an OLED testing device, comprising the following steps: (1) to (4), steps (1) to (4) were the same as those in the above Device Example 1, respectively; (5) vacuum depositing to form a first light-emitting functional layer on the surface of the second hole transport layer 50 away from the ITO conductive glass using Compound HH18 and Compound EH7 as host materials and Compound X88 as exciton utilizing agent, wherein the weight ratio of Compound HH18, Compound EH7 and Compound X88 was 45:45:10, that is, the doping Concentration of Compound X88 in the first light-emitting functional layer was 10 wt %; (6) to (9), steps (6) to (9) were the same as those in the above Device Example 1, respectively.

A color spectroradiometer CS-2000A (Konica Minolta, Japan) was used to measure the electroluminescence spectrum of the above OLED testing device, wherein the maximum luminous intensity was denoted as E₁, and a wavelength on short wavelength side corresponding to a luminous intensity of 60% E₁ was denoted as λ_{EL}, λ_{EL}=455 nm.

### Test Example 2

A method for preparing an OLED testing device, comprising the following steps: (1) to (4), steps (1) to (4) were the same as those in the above Device Example 1, respectively; (5) vacuum depositing to form a second light-emitting functional layer on the surface of the second hole transport layer 50 away from the ITO conductive glass using Compound HH18 and Compound EH7 as host materials and Compound E2 as guest light-emitting material, wherein the weight ratio of Compound HH18, Compound EH7 and Compound E2 was 50:49:1, that is, the doping concentration of Compound E2 was 1 wt %; (6) to (9), steps (6) to (9) were the same as those in the above Device Example 1, respectively.

A color spectroradiometer CS-2000A (Konica Minolta, Japan) was used to measure the electroluminescence spectrum of the above OLED testing device, wherein the maximum luminous intensity was E₂, and a wavelength on short wavelength side corresponding to a luminous intensity of 60% E₂ was denoted as λ_{EL}′, λ_{EL}′=455 nm.

### Test Comparative Example 1

A method for preparing an OLED testing device, comprising the following steps: (1) to (4), steps (1) to (4) were the same as those in the above Device Example 1, respectively; (5) vacuum depositing to form a third light-emitting functional layer on the surface of the second hole transport layer 50 away from the ITO conductive glass using Compound HH18 and Compound EH7 as host materials and replacing the guest light-emitting material in Test Example 1 with Comparative Compound 3, wherein the doping concentration of Comparative Compound 3 was 1 wt %, and the chemical structure of Comparative Compound 3 was as follows:

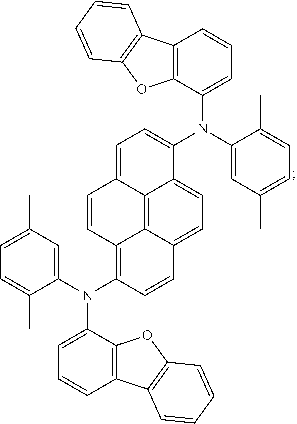 [SMILES: Cc1ccc(C)c(N(c2ccc3ccc4c(N(c5cc(C)ccc5C)c5cccc6c5oc5ccccc56)ccc5ccc2c3c54)c2cccc3c2oc2ccccc23)c1]

(6) to (9), steps (6) to (9) were the same as those in the above Example 1, respectively.

A color spectroradiometer CS-2000A (Konica Minolta, Japan) was used to measure the electroluminescence spectrum of the above OLED testing device, wherein the maximum luminous intensity was E₃, and a wavelength on short wavelength side corresponding to a luminous intensity of 60% E₃ was denoted as λ_{EL}^{C}, λ_{EL}^{C}=449 nm.

By comparison, it can be seen that λ_{EL}=λ_{EL}^{C} satisfies the above-described relationship of the present application, but λ_{EL}>λ_{EL}^{C} does not satisfy the above-described relationship of the present application, which indicates that there is a higher chance of energy transfer from the exciton utilizing agent Compound X88 to the guest light-emitting material Compound E2; In contrast, the exciton utilizing agent Compound X88 and the guest light-emitting material Comparative Compound 3 do not satisfy the above-described relationship, and the chance of energy transfer from the exciton utilizing agent X88 to the guest light-emitting material Comparative Compound 3 is relatively low.

### Device Example 2

It differs from Device Example 1 in that the weight ratio of Compound HH18, Compound EH7, Compound X88, and Compound E2 was 45:44:10:1.

### Device Comparative Example 3

It differs from Device Example 1 in that: Compound E2 in step (5) was replaced with Comparative Compound 3, and the weight ratio of Compound HH18, Compound EH7, Compound X88 and Comparative Compound 3 was 45:44:10:1. The chemical structure of Comparative Compound 3 is shown hereinbefore.

The luminescence performance of the OLED devices prepared in Device Example 2 and Device Comparative Example 3 in the present application was tested. The test results are shown in Table 3. The blue light index and the device lifetime of Device Example 2 was set to 100%, the blue light index was the ratio of device current efficiency to CIEy. The test conditions were a current density of 10 mA/cm².

TABLE 3

| | Blue Light | Device |
|---|---|---|
| | Index (BI) | Lifetime LT90 |
| | cd · A⁻¹y⁻¹ (%) | h (%) |
| Device Example 2 | 100 | 100 |
| Device Comparative Example 3 | 35 | 150 |

### Device Comparative Example 4

It differs from Device Example 1 in that: Compound E2 in step (5) was replaced with Comparative Compound 4, and the weight ratio of Compound HH18, Compound EH7, Compound X88 and Comparative Compound 4 was 45:44:10:1. The chemical structure of Comparative Compound 4 was as follows:

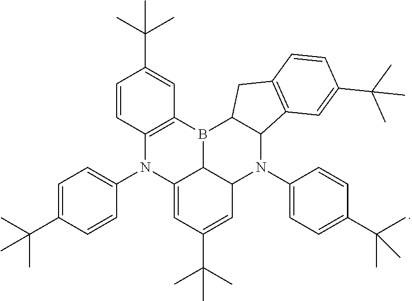 [SMILES: CC(C)(C)C1=CC2C3B(c4cc(C(C)(C)C)ccc4N(c4ccc(C(C)(C)C)cc4)C3=C1)C1Cc3ccc(C(C)(C)C)cc3C1N2c1ccc(C(C)(C)C)cc1]

The exciton utilizing agent and the guest light-emitting material used in Device Example 2 and Device Comparative Example 4 of the present application were respectively vapor deposited on the surface of the silicon wafer by way of vapor deposition to obtain a sample to be tested with a thickness of 50 nm. The HOMO energy level was tested by AC2 photoelectron spectroscopy. The test data are shown in Table 4.

TABLE 4

| Compound | HOMO (eV) |
|---|---|
| Compound HH18 | −5.46 |
| Compound EH7 | −5.91 |
| Compound X88 | −5.15 |
| Compound E2 | −5.42 |
| Comparative Compound 4 | −4.98 |

As can be seen from Table 4, the guest light-emitting material Compound E2 has a deeper HOMO energy level than the exciton utilizing agent Compound X88, and the difference between the HOMO energy level (H₂) of the exciton utilizing agent Compound X88 and the HOMO energy level (H₁) of the guest light-emitting material Compound E2 is 0.27 eV, satisfying the above-mentioned relationship of the present application: 0 eV≤H₂−H₁≤0.5 eV. However, Comparative Compound 4 has a shallower HOMO energy level than the exciton utilizing agent Compound X88, which does not satisfy the above-described relationship.

The luminescence performance of the OLED devices prepared in Device Example 2 and Device Comparative Example 4 in the present application was tested. The test results are shown in Table 5. The blue light index and the device lifetime of Device Example 2 was set to 100%, the blue light index was the ratio of device current efficiency to CIEy. The test conditions were a current density of 10 mA/cm².

TABLE 5

| | Blue Light | Device |
|---|---|---|
| | Index (BI) | Lifetime LT90 |
| | cd · A⁻¹y⁻¹ (%) | h (%) |
| Device Example 2 | 100 | 100 |
| Device Comparative Example 4 | 43 | 13 |

From the data in Table 5, it can be seen that the blue light index of Device Comparative Example 3 is significantly reduced compared to Device Example 2, which indicates that more efficient energy transfer from the exciton utilizing agent Compound X88 to the guest light-emitting material Compound E2, while no efficient energy transfer is formed between the exciton utilizing agent Compound X88 and the guest light-emitting material Comparative Compound 3, which is consistent with the data of the experiments on electroluminescence spectral characteristics.

According to the analysis of Tables 4 and 5, it can be seen that Comparative Compound 4 in Device Comparative Example 4 has a shallower HOMO energy level than the exciton utilizing agent Compound X88. When the HOMO energy level of the guest light-emitting material becomes shallower than the HOMO of the exciton utilizing agent, the guest light-emitting material will become a strong hole potential well and hinder the transport of holes, thereby improving the triplet exciton group on the guest light-emitting material and increasing the chance of triplet-triplet annihilation and triplet-polaron annihilation of excitons on the guest light-emitting material, thereby further leading to a decrease in luminous efficiency and a shorter lifetime of the OLED device. The guest light-emitting material Compound E2 used in Device Example 2 has a deeper HOMO energy level than the exciton utilizing agent Compound X88, which can effectively inhibit the physical process of the guest light-emitting material becoming a hole potential well, reduce the chance of triplet-triplet annihilation and triplet-polaron annihilation of excitons on the guest light-emitting material, thereby improving the utilization ratio of triplet excitons of the blue light-emitting material, further improving the luminous efficiency and lifetime of the OLED device, and significantly reducing the power consumption when applied to the OLED display device.

It should be noted that the terms “first”, “second”, and the like in the description and claims of the present application are used to distinguish similar objects, and are not necessarily used to describe a specific order or sequence. It should be understood that the terms so used are interchangeable where appropriate so that the embodiments of the present application described herein, for example, can be implemented in an order other than those described herein.

The foregoing merely provides some preferred embodiments of the present application, and is not intended to limit the present application, which may be subject to various modifications and variations to those skilled in the art. Any modification/variation, equivalent substitution, improvement, etc. made within the spirit and principles of the present application should be included within the protection scope of the present application.

What is claimed is:

1. An organic electroluminescent device, wherein the organic electroluminescent device comprises a substrate (10), an anode (20), an organic light-emitting layer (30) and a cathode (40) disposed in sequence, wherein the organic light-emitting layer (30) comprises a host material, a guest light-emitting material and an exciton utilizing agent, and the host material comprises a hole-type host material and an electron-type host material, and the minimum values of bond dissociation energies of the electron-type host material and the exciton utilizing agent in an anionic state, an electrically neutral state and a cationic state are each independently ≥2.6 eV, and HOMO energy level of the guest light-emitting material is H₁, HOMO energy level of the exciton utilizing agent is H₂, and H₁ and H₂ satisfy the relationship: 0 eV≤H₂−H₁≤0.5 eV.

2. The organic electroluminescent device according to claim 1, wherein H₁ and H₂ satisfy the relationship: 0.1 eV≤H₂−H₁≤0.4 eV.

3. The organic electroluminescent device according to claim 1, wherein H₁ and H₂ satisfy the relationship: 0.15 eV≤H₂−H₁≤0.35 eV.

4. The organic electroluminescent device according to claim 1, wherein LUMO energy level of the guest light-emitting material is L₁, LUMO energy level of the exciton utilizing agent is L₂, and L₁ and L₂ satisfy the relationship: 0.10 eV≤L₂−L₁≤0.50 eV.

5. The organic electroluminescent device according to claim 4, wherein L₁ and L₂ satisfy the relationship: 0.20 eV≤L₂−L₁≤0.40 eV.

6. The organic electroluminescent device according to claim 4, wherein preferably, L₁ and L₂ satisfy the relationship: 0.25 eV≤L₂−L₁≤0.35 eV.

7. The organic electroluminescent device according to claim 1, wherein singlet energy level S₁ of the guest light-emitting material and triplet energy level T₁ of the exciton utilizing agent satisfy the relationship equation: T₁>S₁.

8. The organic electroluminescent device according to claim 1, wherein HOMO energy level of the hole-type host material is H₃, and H₁, H₂, and H₃ satisfy the relationship: H₁−H₃≥0 eV, H₂−H₃≥0.15 eV.

9. The organic electroluminescent device according to claim 8, wherein H₁, H₂ and H₃ satisfy the relationship: H₁−H₃≥0.05 eV, H₂−H₃≥0.20 eV.

10. The organic electroluminescent device according to claim 1, wherein bond dissociation energies of the electron-type host material and the exciton utilizing agent in the anionic state, the electrically neutral state and the cationic state are each independently ≥2.8 eV;
preferably, the bond dissociation energies of the electron-type host material in the anionic state, the electrically neutral state and the cationic state are ≥3.0 eV;
preferably, the bond dissociation energies of the exciton utilizing agent in the anionic state, the electrically neutral state and the cationic state are each independently ≥3.0 eV.

11. The organic electroluminescent device according to claim 1, wherein the hole-type host material is selected from one or more of compounds represented by general formulae (I) and (II): 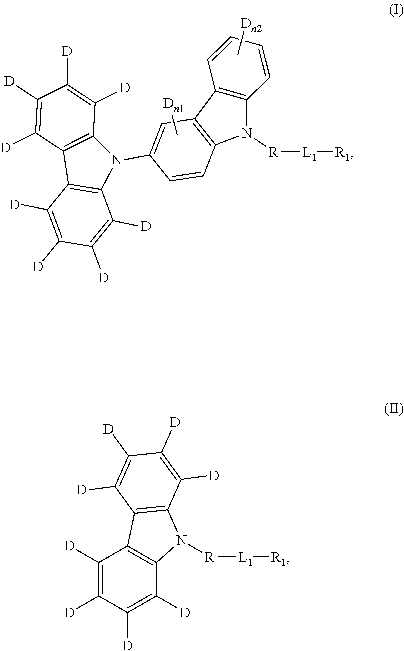
wherein R is selected from a connecting bond or a phenylene group substituted by at least one deuterium atom,
L₁ is selected from a connecting bond, a phenylene group, or a phenylene group substituted by at least one deuterium atom,
R₁ is selected from 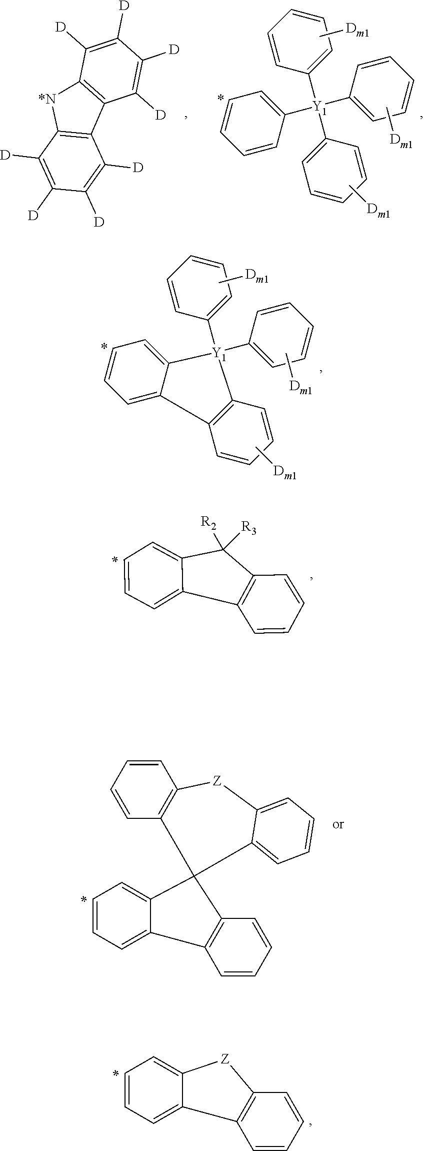
wherein Y₁ is selected from Si or Ge, and m1 represents a substitution by any one of 0 to 5 integer deuterium atoms in the corresponding benzene ring structure, m2 represents a substitution by any one of 0 to 4 integer deuterium atoms in the corresponding benzene ring structure, R₂ and R₃ are each independently selected from C₁-C₆ alkyl or C₆-C₂₀ aryl groups, Z is selected from a connecting bond, O or S;
n1 represents a substitution by any one of 0 to 3 integer deuterium atoms in the corresponding benzene ring structure, and n2 represents substitution by any one of 0 to 4 integer deuterium atoms in the corresponding benzene ring structure;
preferably, R is selected from a connecting bond, 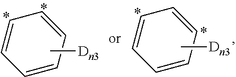
and n3 represents a substitution by any one of 0 to 4 integer deuterium atoms in the corresponding benzene ring structure, preferably 0 or 4 deuterium atoms;
preferably, the hole-type host material has one or more of the compounds represented by general formulae (Ia), (Ib), (Ic), (Id) and (IIa): 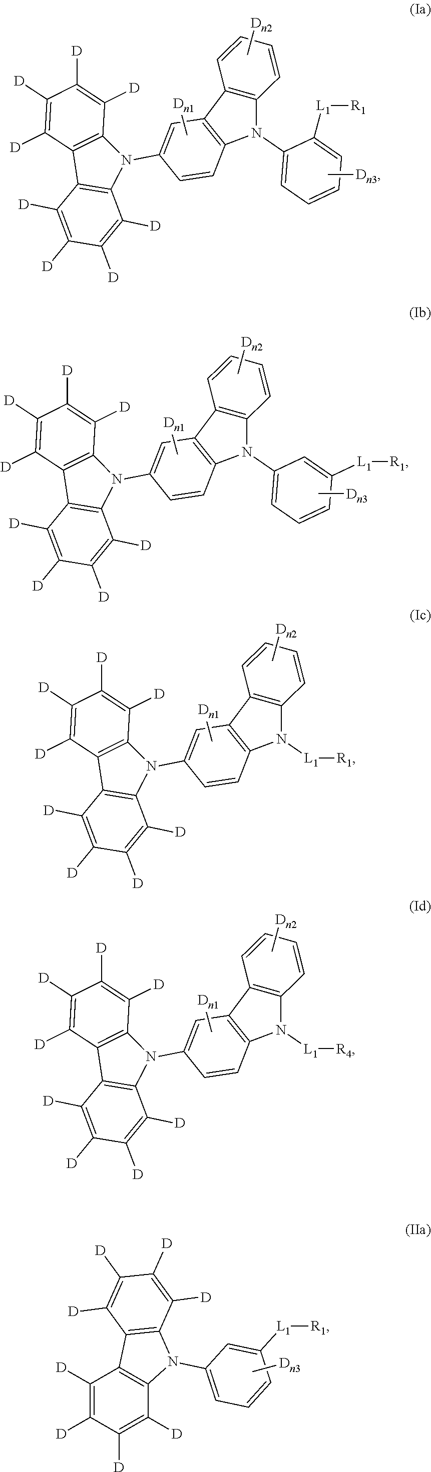
wherein R₁ is selected from 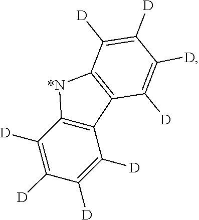
R₄ is selected from 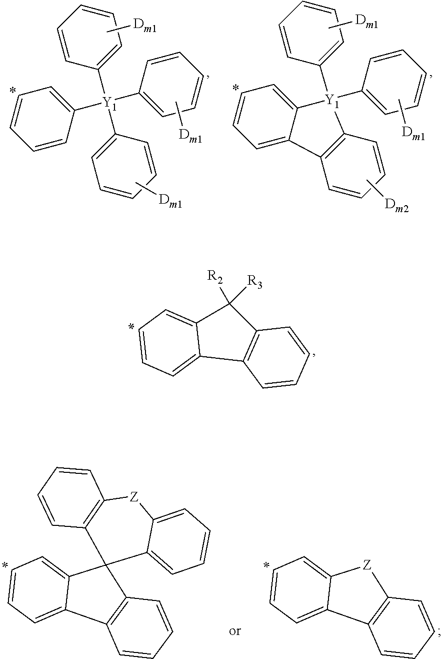
more preferably, L₁ is selected from a connecting bond, a phenylene group, or a phenylene group substituted with 4 deuterium atoms, and n1 represents a substitution by 0 or 3 deuterium atoms in the corresponding benzene ring structure, and n2 and n3 each independently represent a substitution by 0 or 4 deuterium atoms in the corresponding benzene ring structure, and R₂ and R₃ are each independently selected from methyl or phenyl;
more preferably, the hole-type host material is selected from one or more of Compound HH1 to Compound HH29: 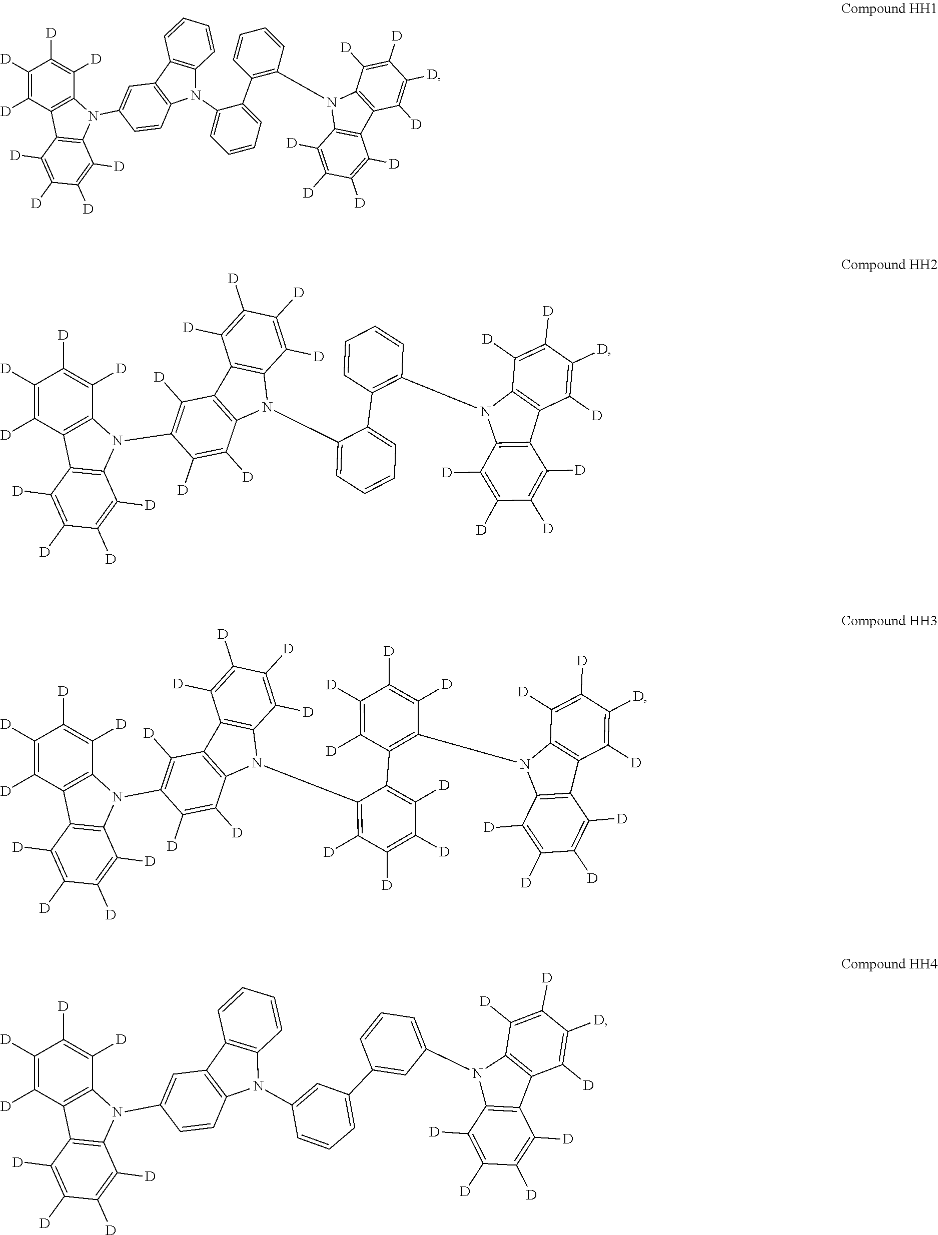 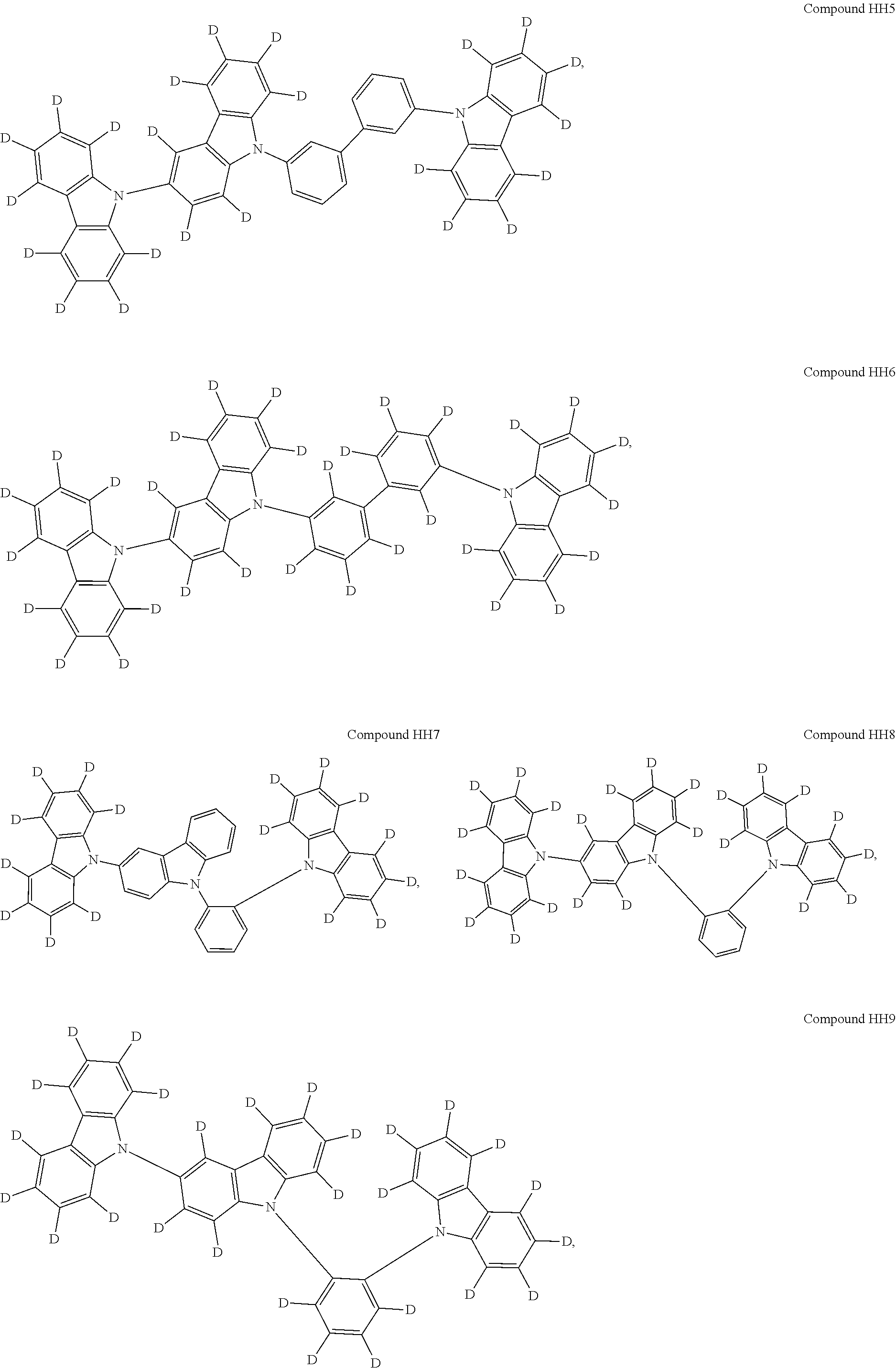 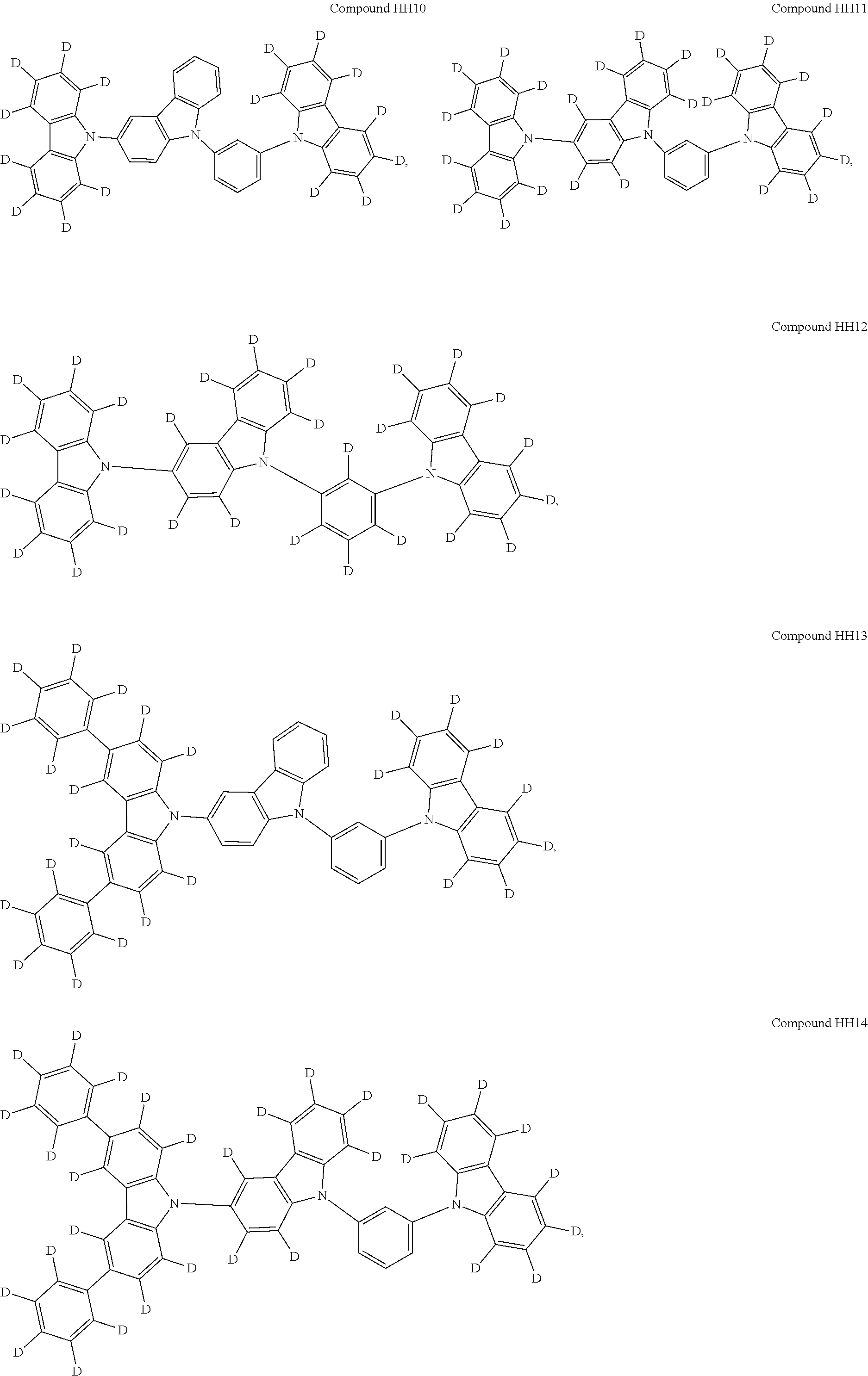 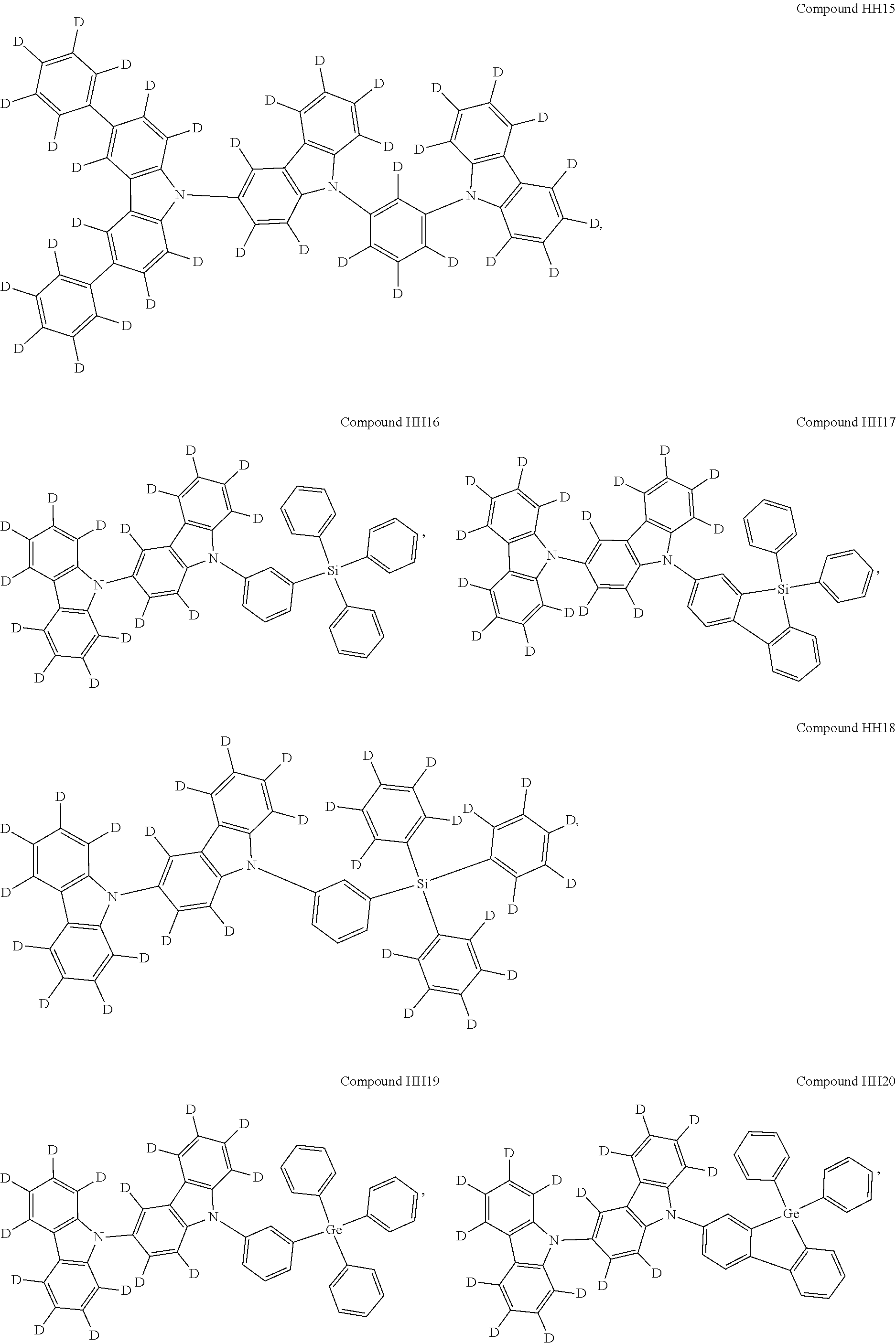 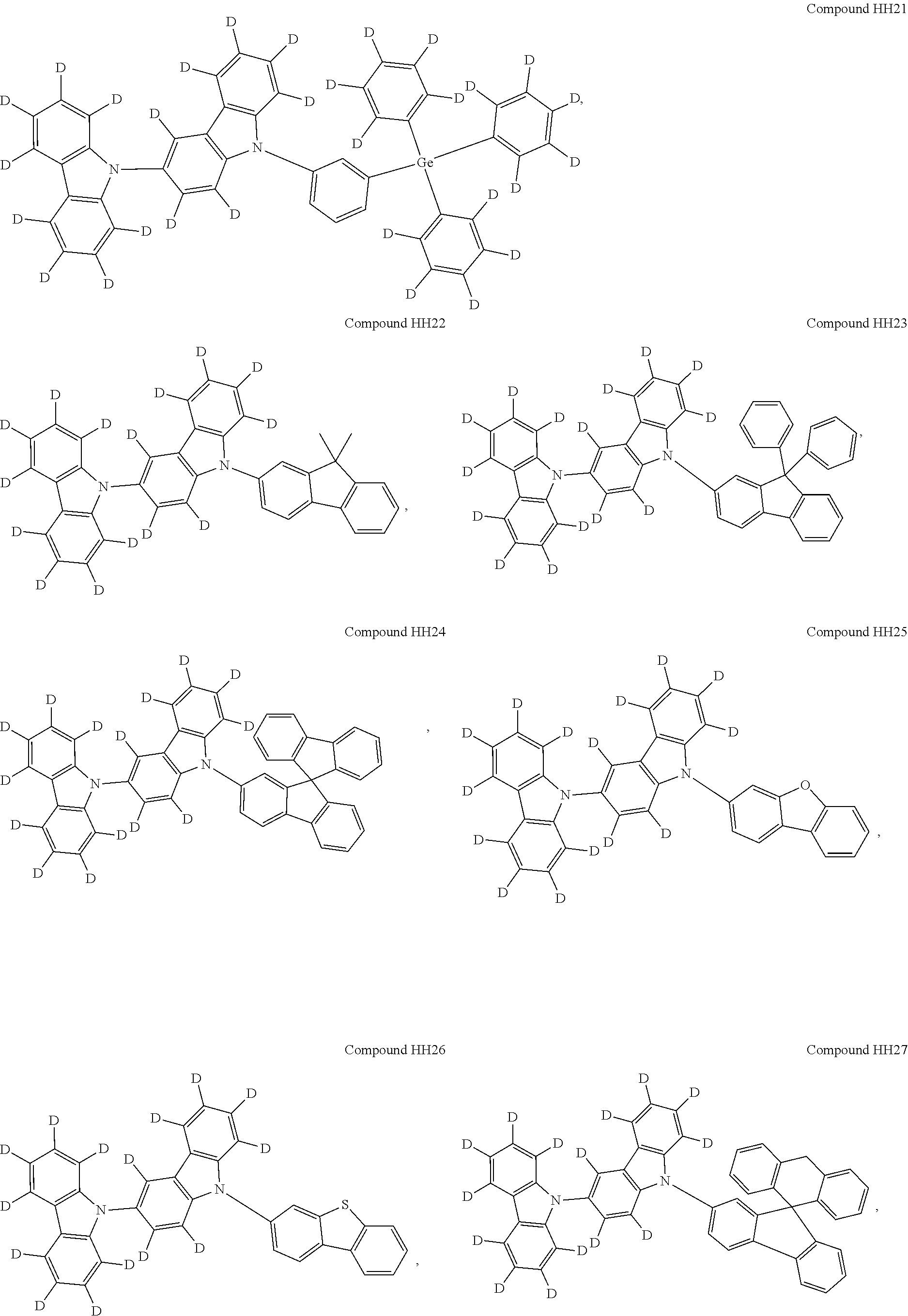 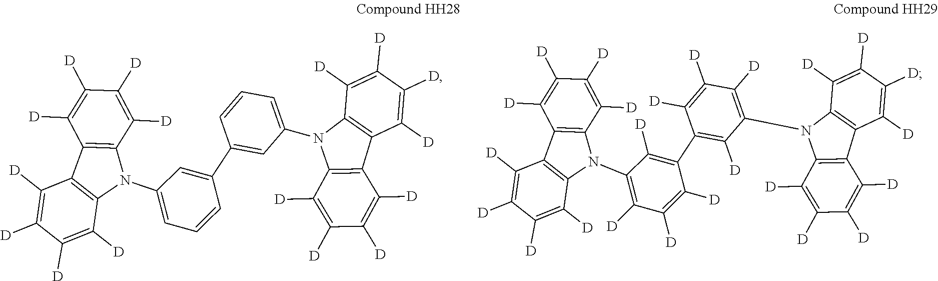
preferably, the electron-type host material has one or more of the compounds represented by general formulae (III) and (XIV): 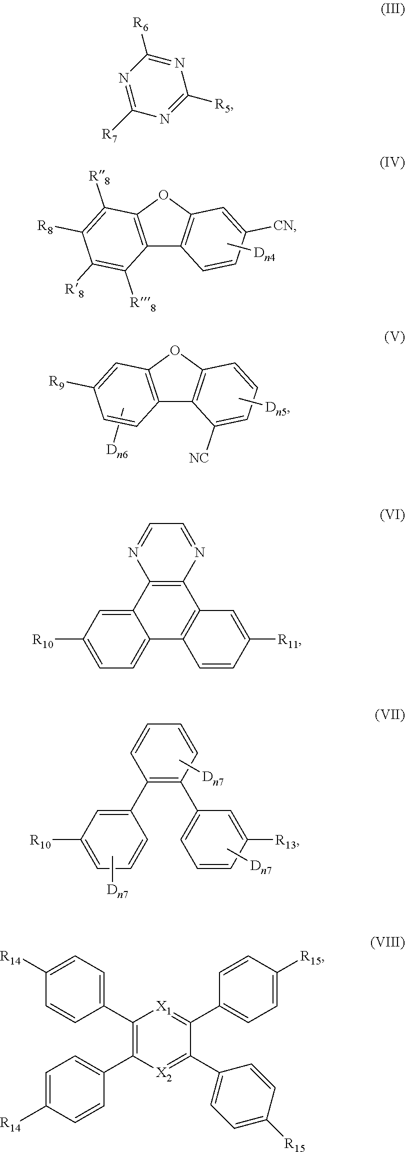 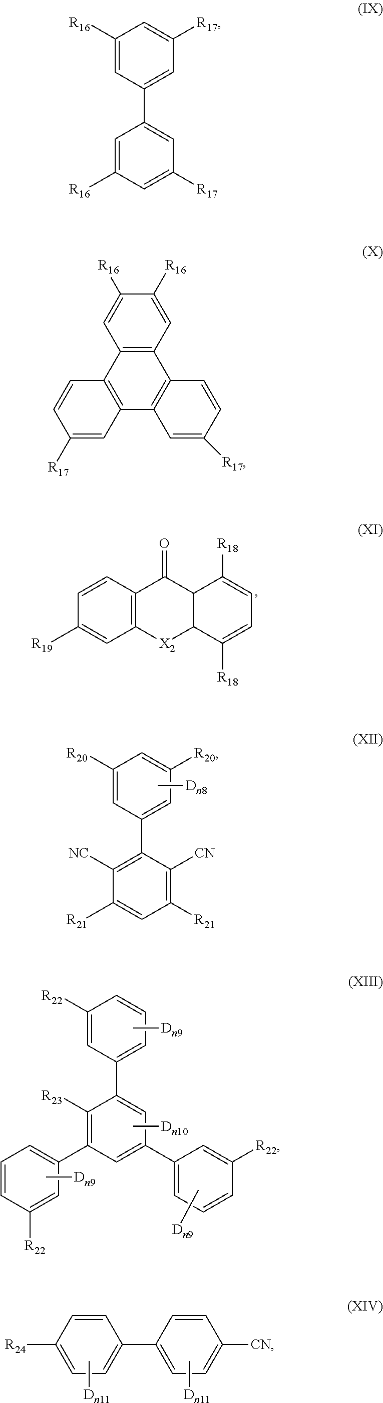
wherein R₅, R₆, and R₇ are each independently selected from C₆-C₂₀ aryl, C₆-C₂₀ aryl substituted with at least one deuterium atom, 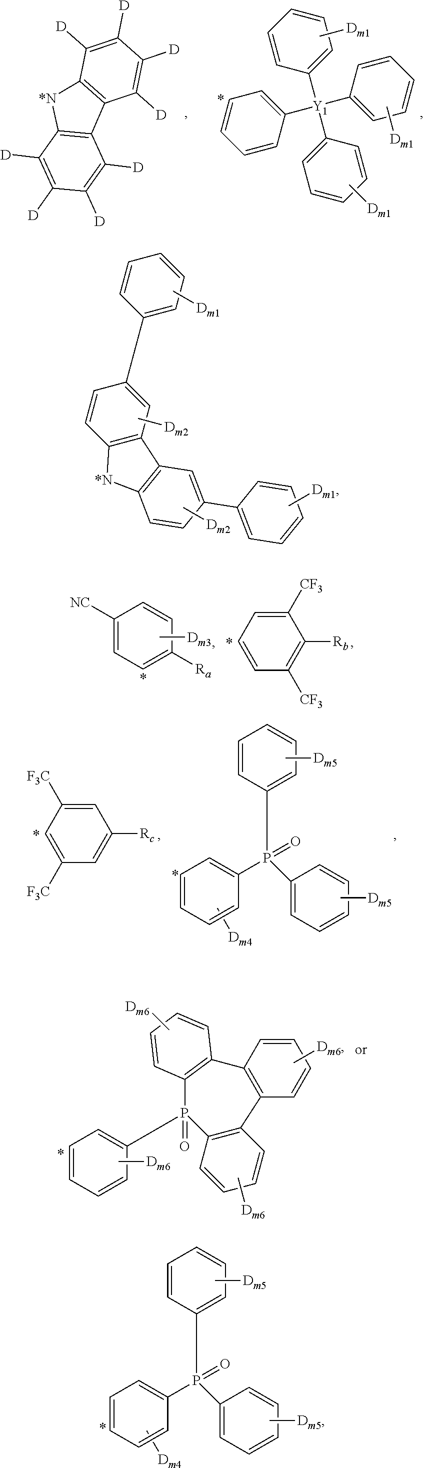
and wherein Y₂ is selected from Si or Ge, wherein Rₐ is selected from 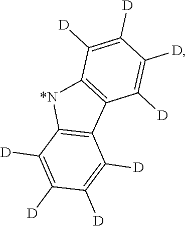
R_{b} and R_{c} are each independently selected from hydrogen, 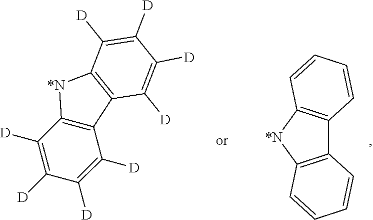
m1 and m5 represent a substitution by any one of 0 to 5 integer deuterium atoms in the corresponding benzene ring structure, and m2 and m3 represent a substitution by any one of 0 to 3 integer deuterium atoms in the corresponding benzene ring structure, and m4 and m6 represent a substitution by any one of 0 to 4 integer deuterium atoms in the corresponding benzene ring structure;
R₈, R′₈, R″₈, and R′″₈ are each independently hydrogen, deuterium, or 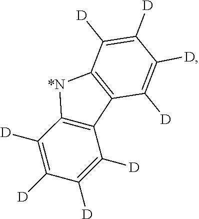
and R₈, R′₈, R″₈, and R′″₈ are not 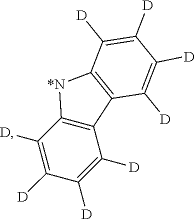
at the same time, and n4 represents a substitution by any one of 0 to 3 integer deuterium atoms in the corresponding benzene ring structure;
R₉ is selected from hydrogen, deuterium, or 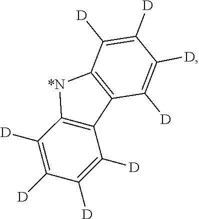
and n5 and n6 represent substitution by any one of 0 to 3 integer deuterium atoms in the corresponding benzene ring structure;
R₁₀ and R₁₁ are each independently selected from 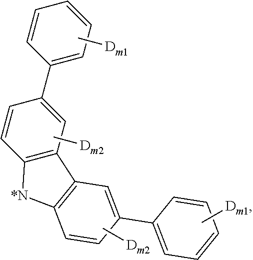
preferably 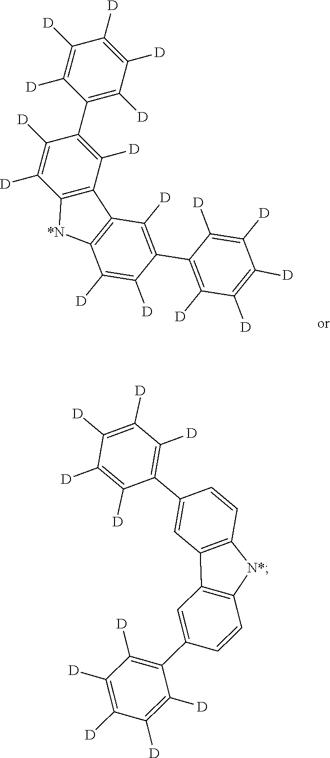
R₁₂ and R₁₃ are each independently selected from 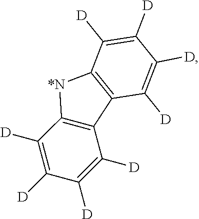
n7 represents a substitution by any one of 0 to 4 integer deuterium atoms in the corresponding benzene ring structure;
X₁ is selected from C or N, and R₁₄ and R₁₅ are each independently selected from —CF₃, —CN, or 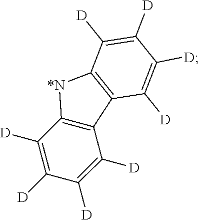
R₁₆ and R₁₇ are each independently selected from —CN or 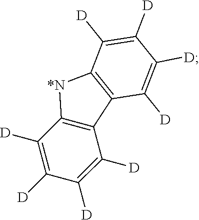
X₂ is selected from O, S or *C═O, and R₁₈ is selected from 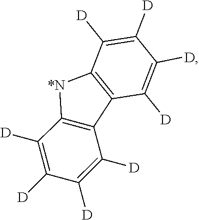
and R₁₉ is selected from hydrogen, 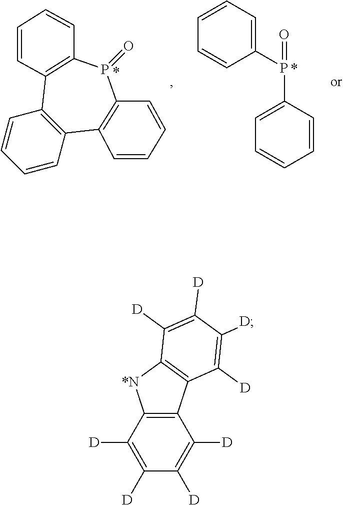
R₂₀ is selected from 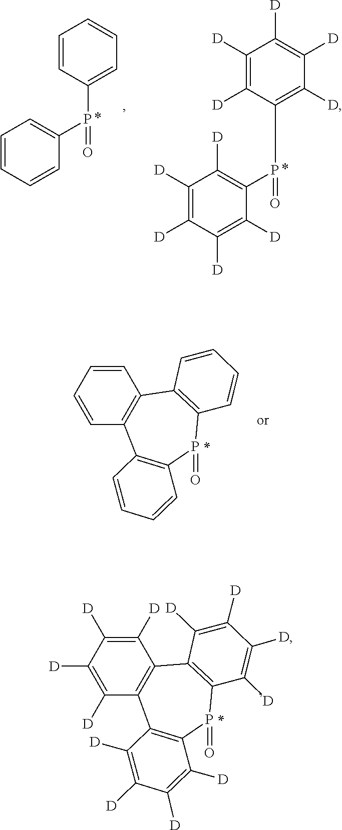
and R₂₁ is selected from 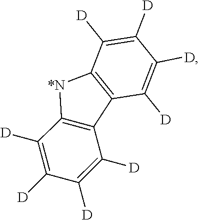
and n8 represents a substitution by any one of 0 to 3 integer deuterium atoms in the corresponding benzene ring structure;
R₂₂ is selected from 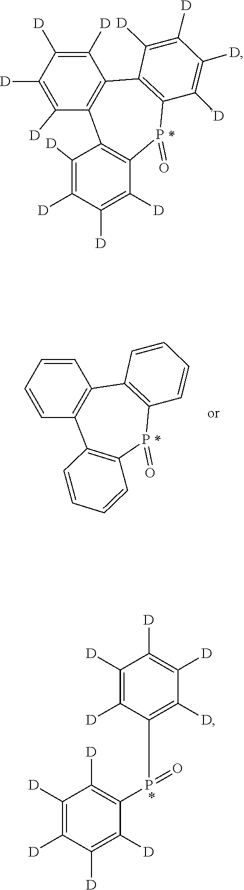
and R₂₃ is selected from hydrogen, —CN or deuterium, and n9 represents a substitution by any one of 0 to 4 integer deuterium atoms in the corresponding benzene ring structure, and n10 represents a substitution by any one of 0 to 2 integer deuterium atoms in the corresponding benzene ring structure;
R₂₄ is selected from 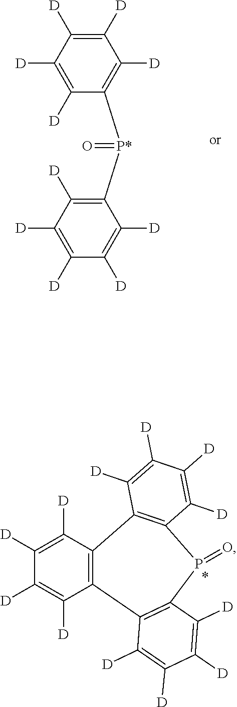
and n11 represents a substitution by any one of 0 to 2 integer deuterium atoms in the corresponding benzene ring structure;
more preferably, the electron-type host material is selected from one or more of Compound EH1 to Compound EH80:

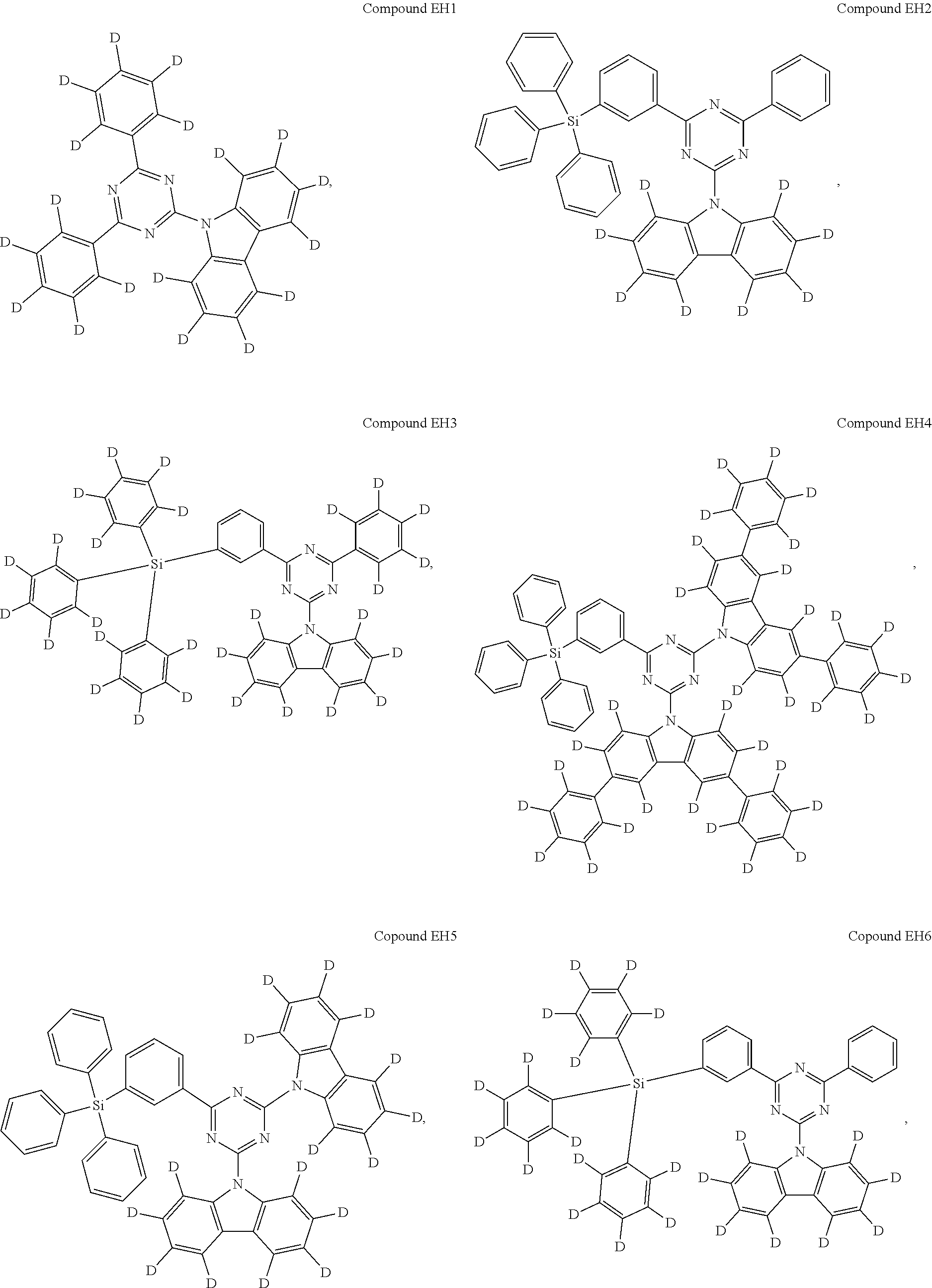

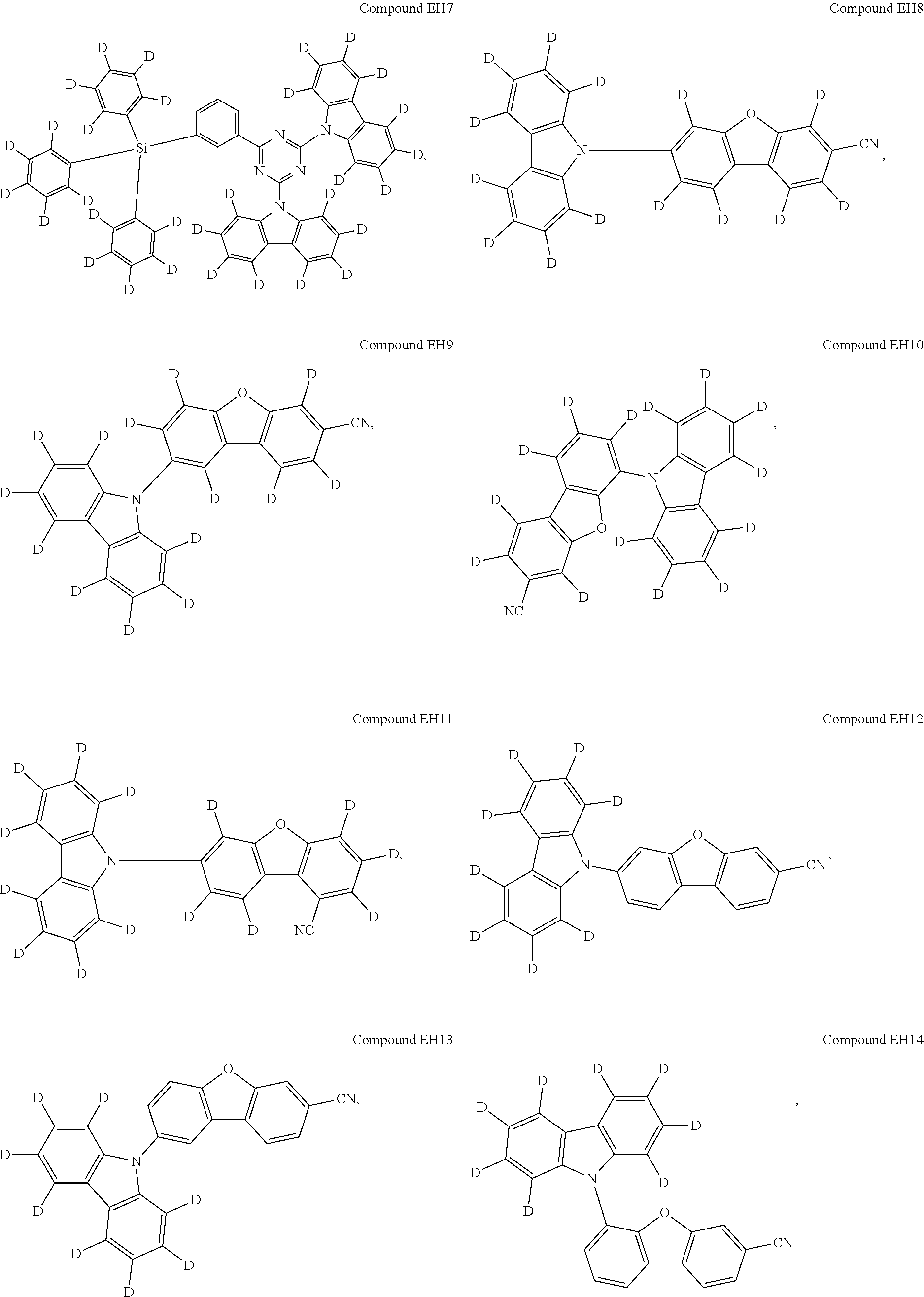

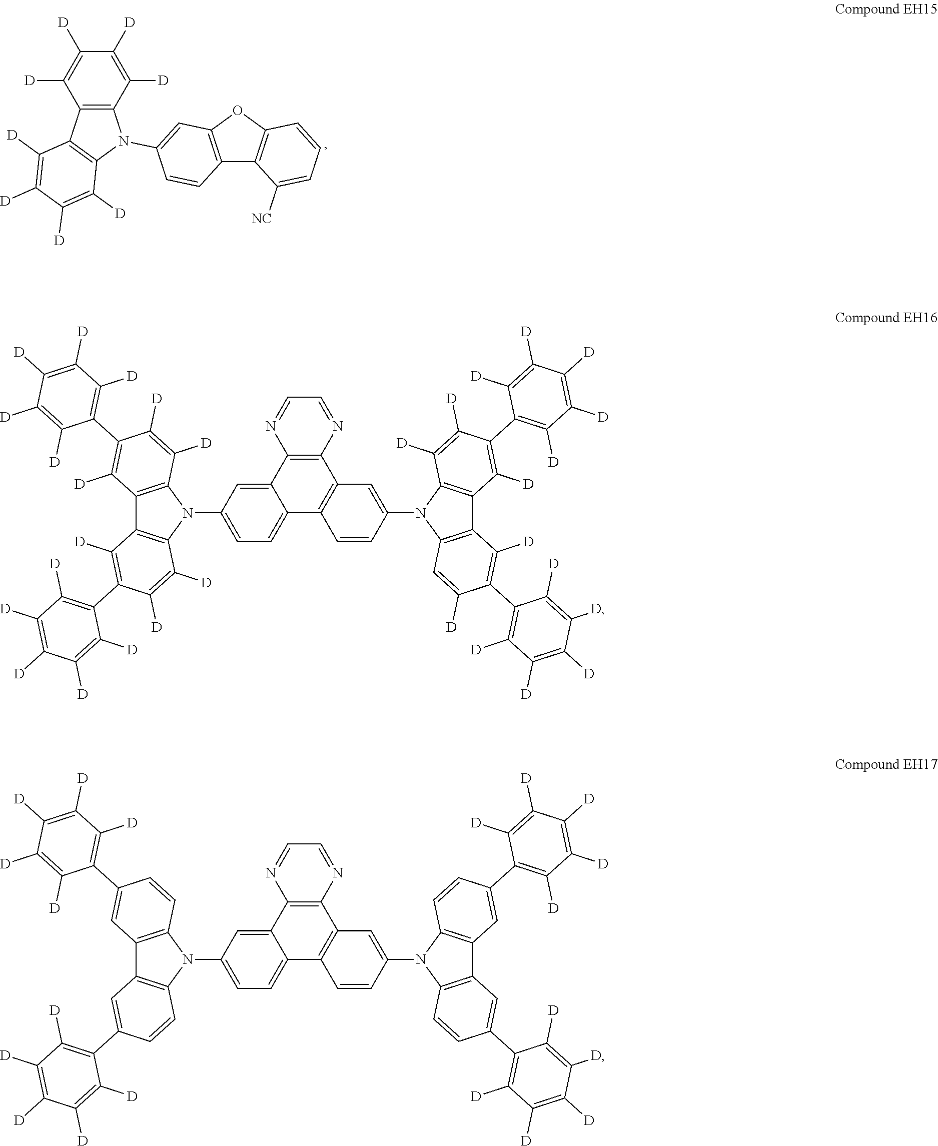

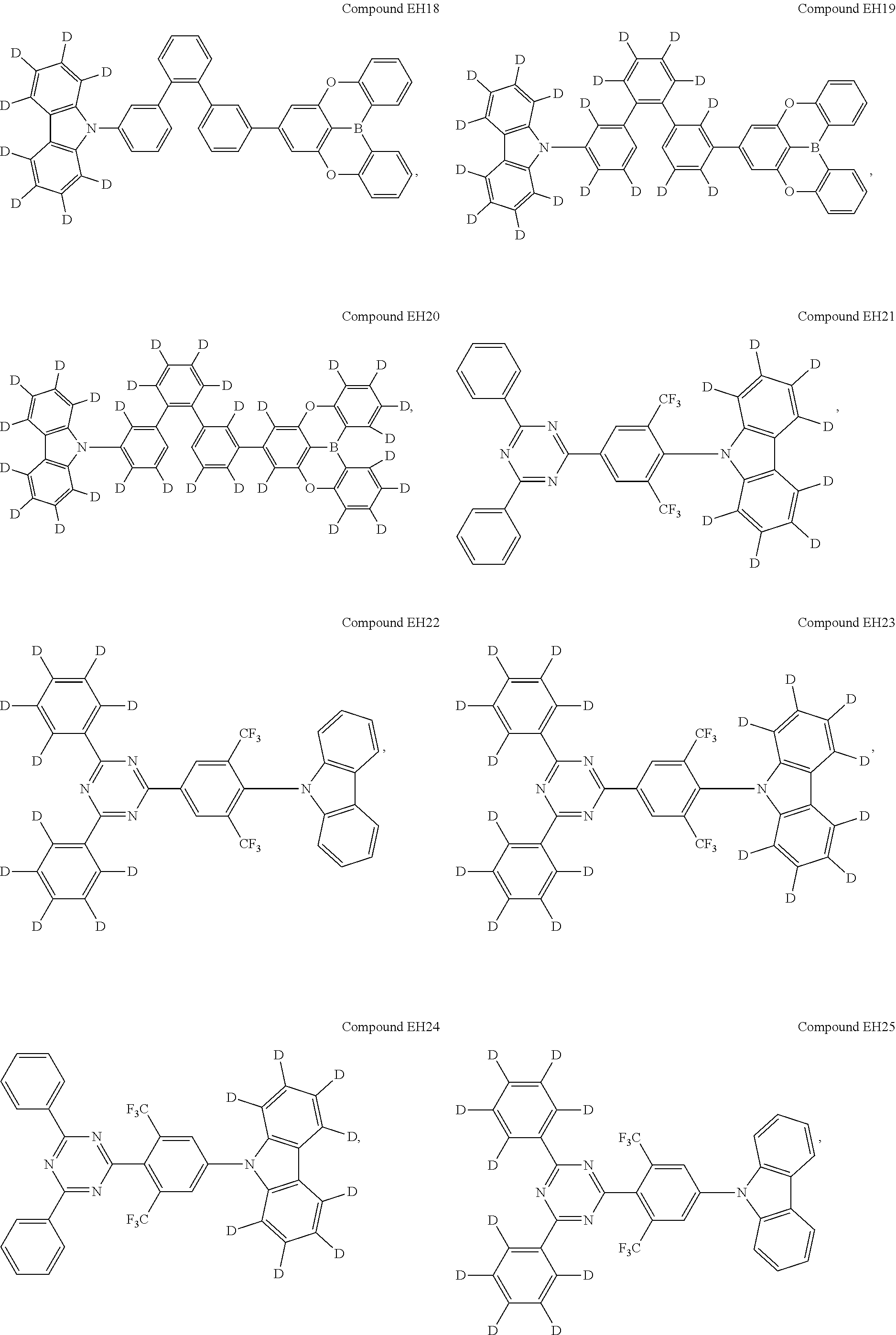

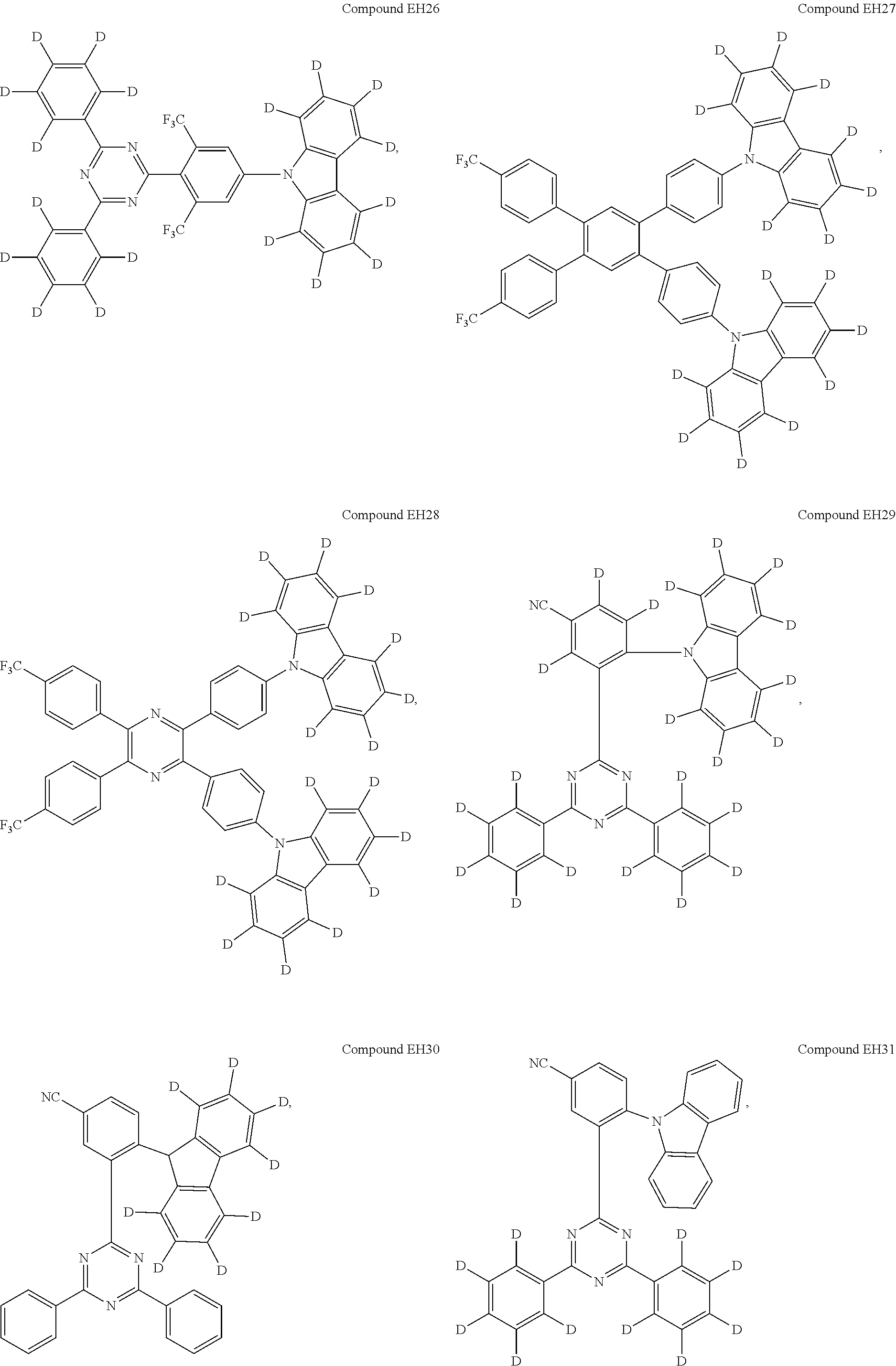

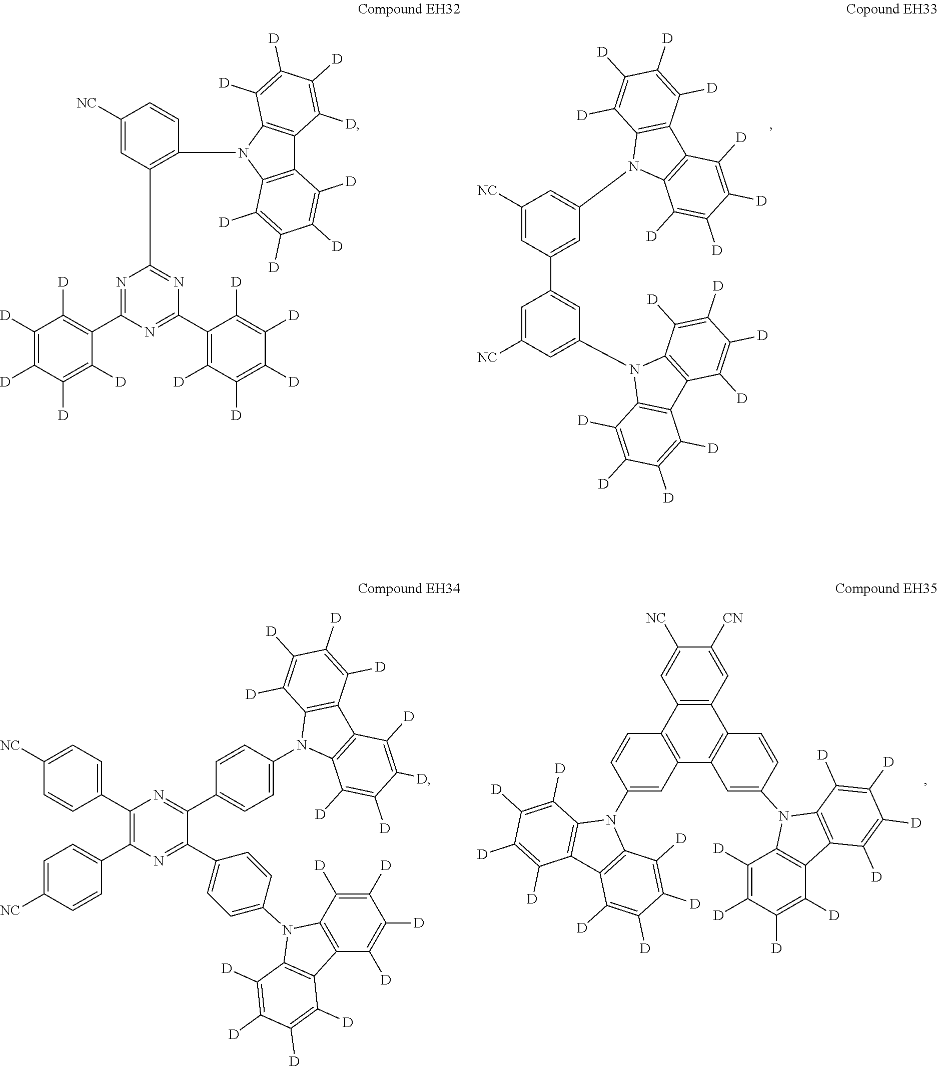

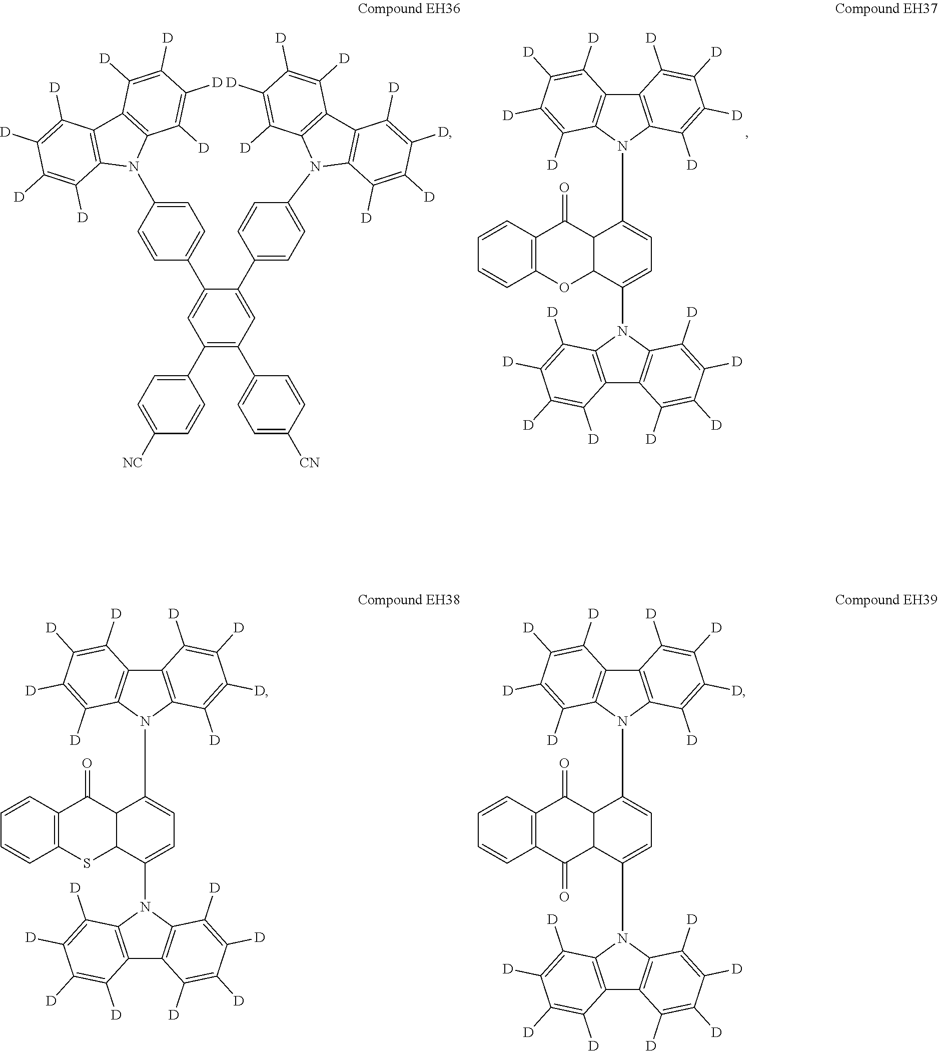

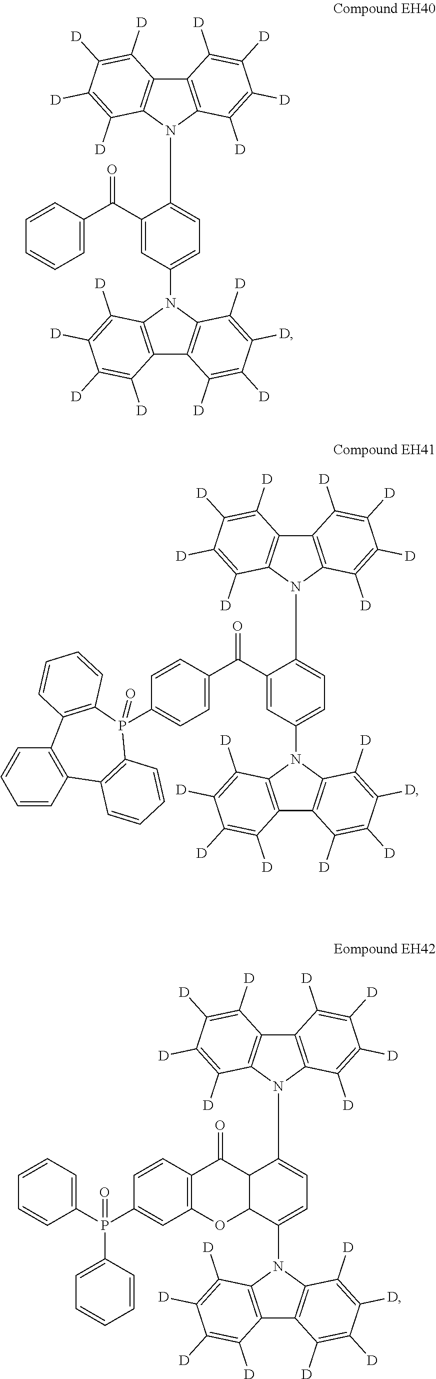

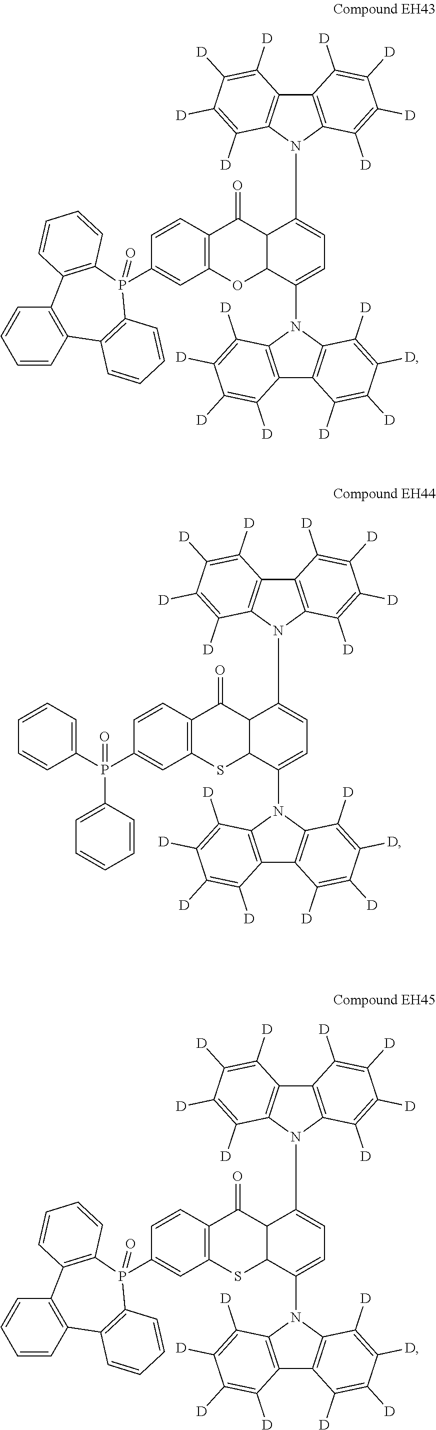

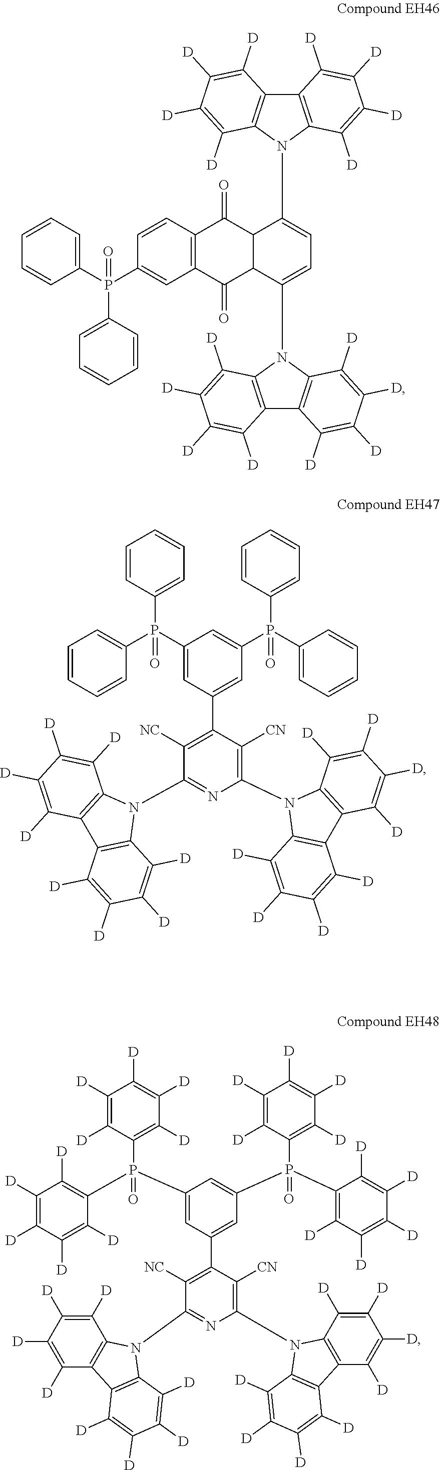

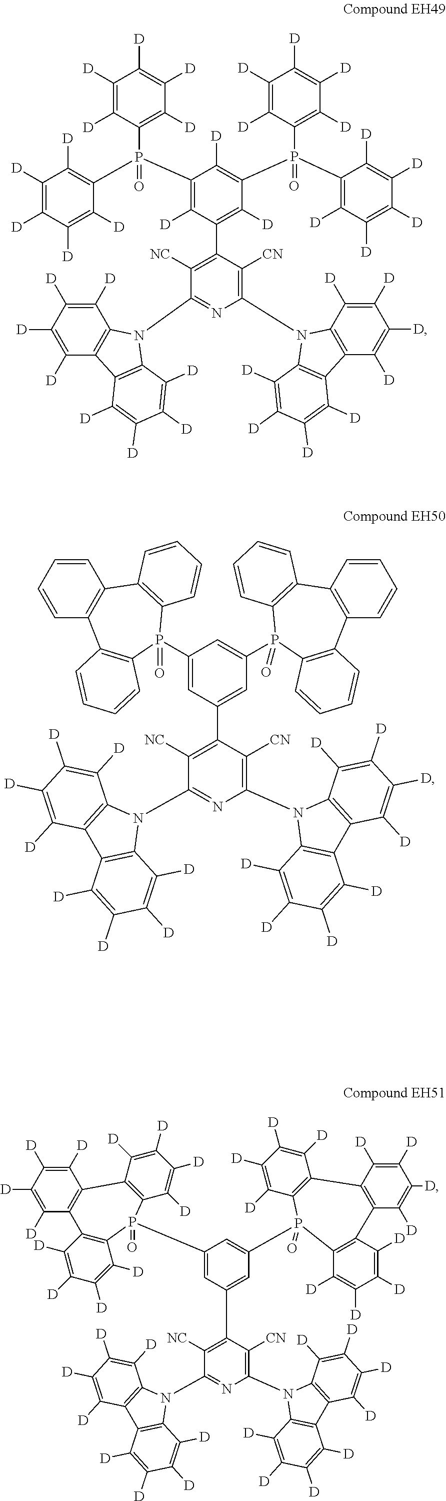

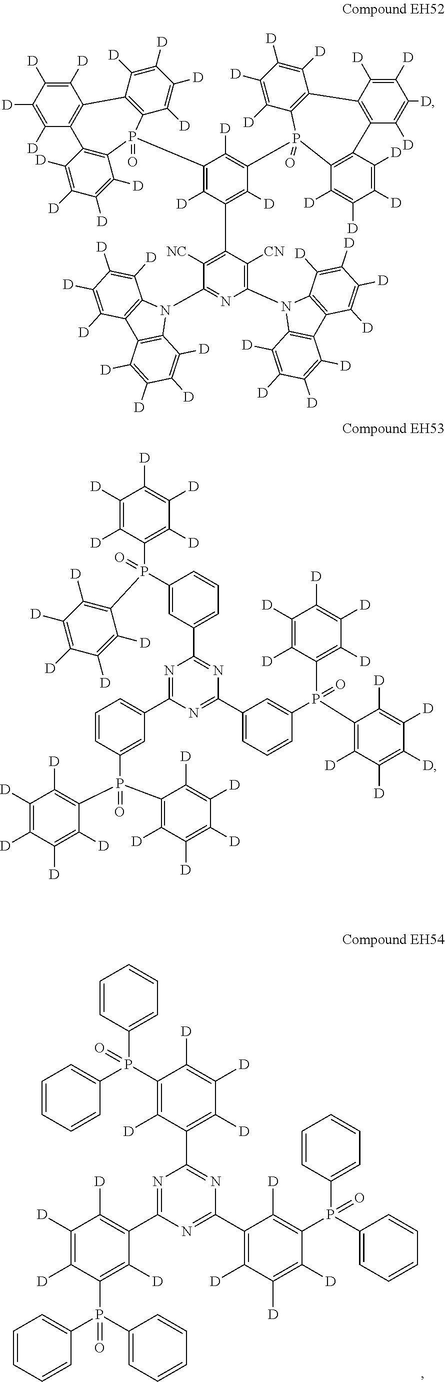

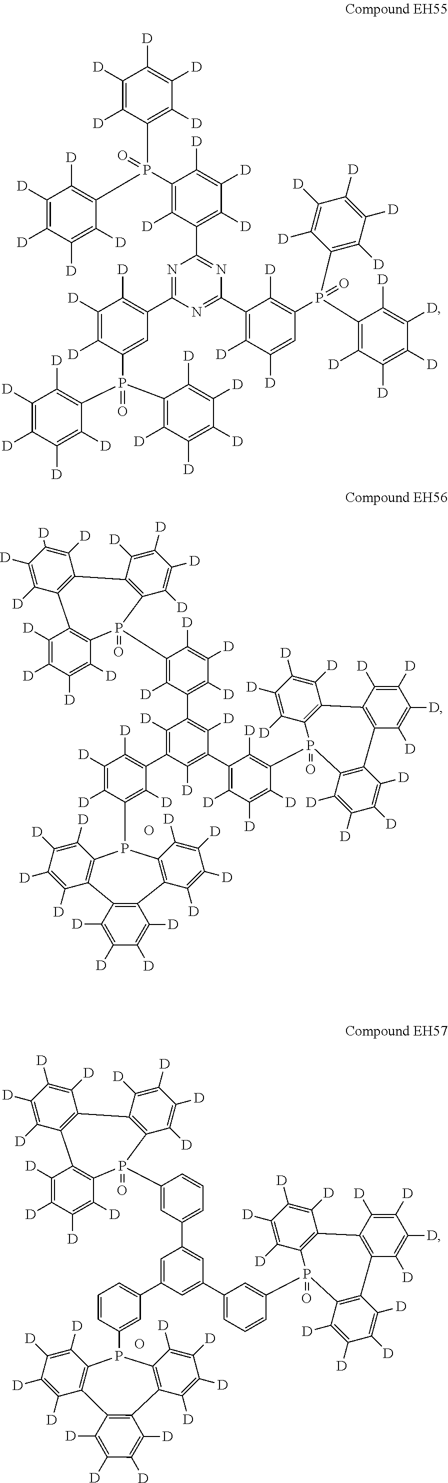

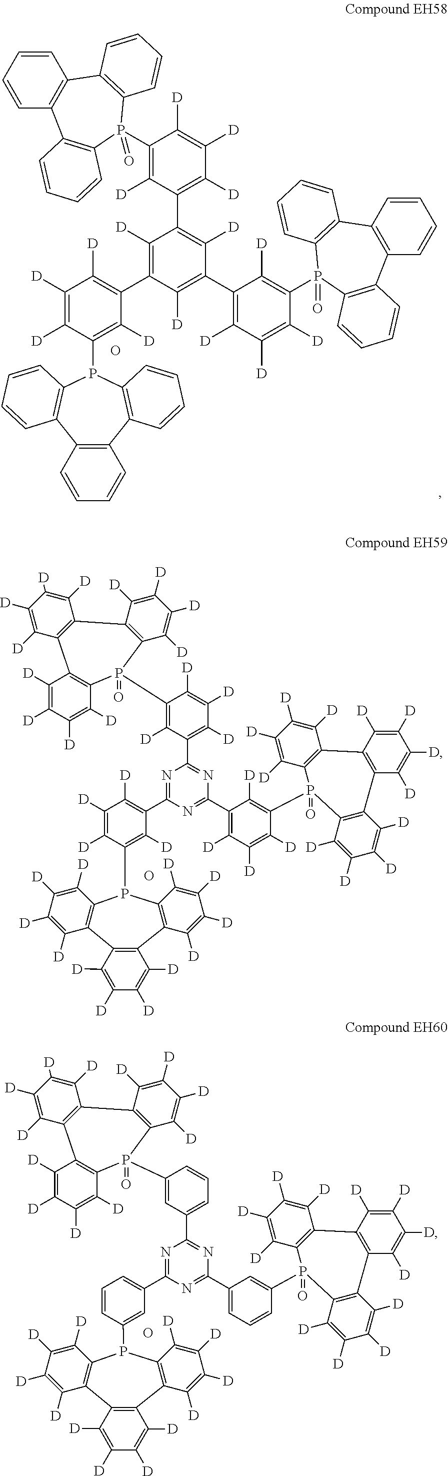

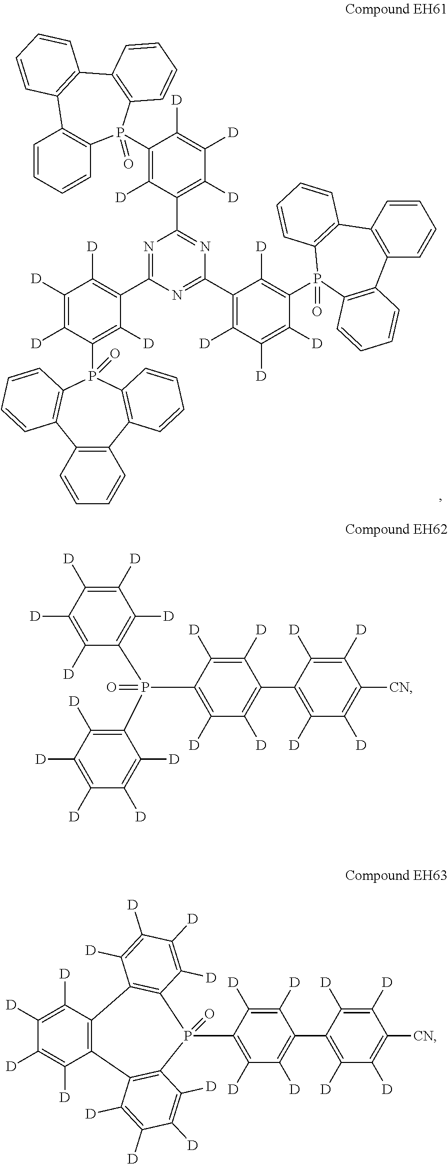

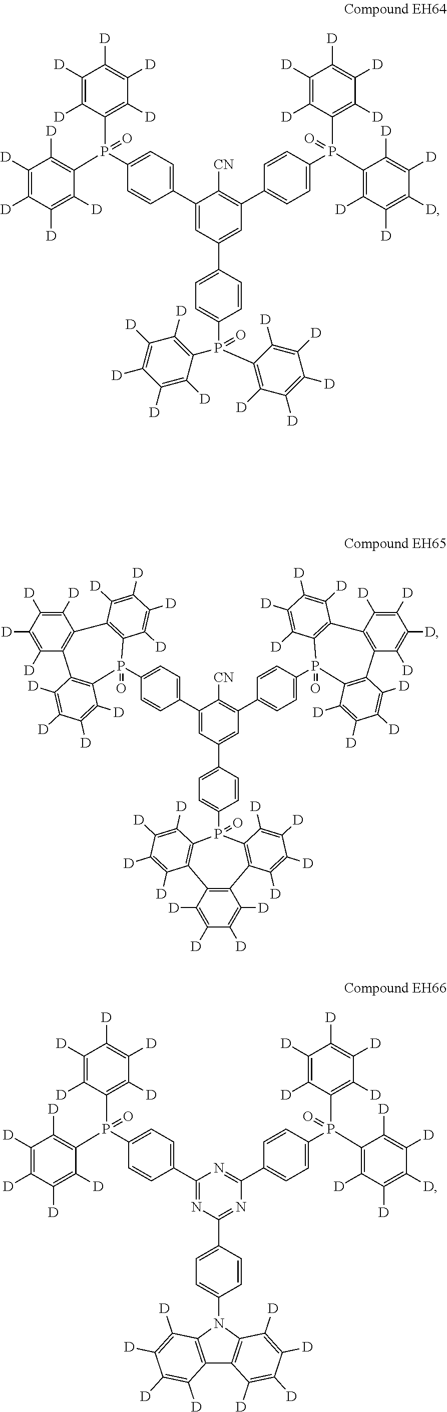

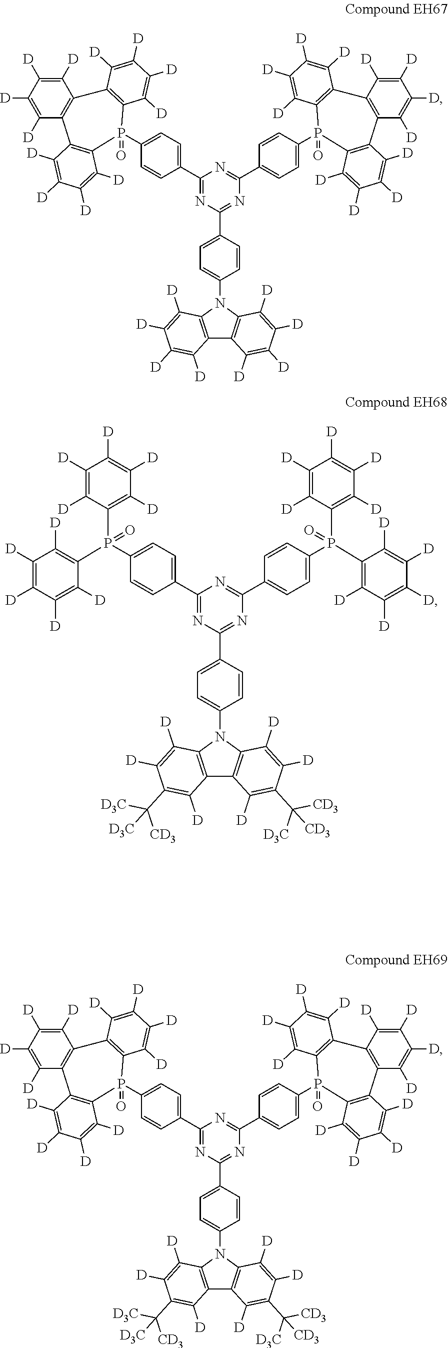

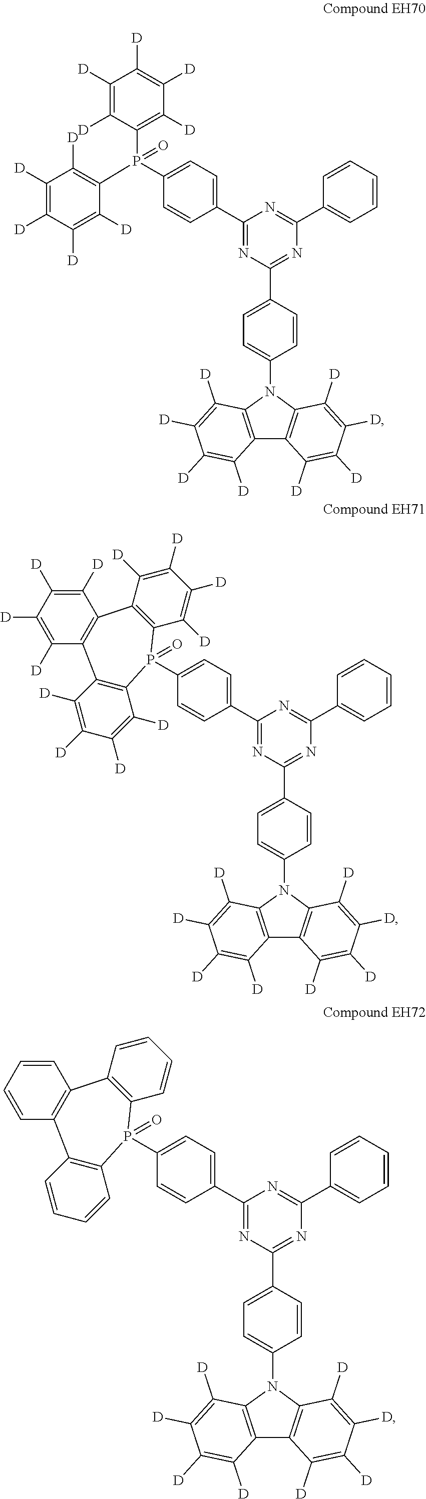

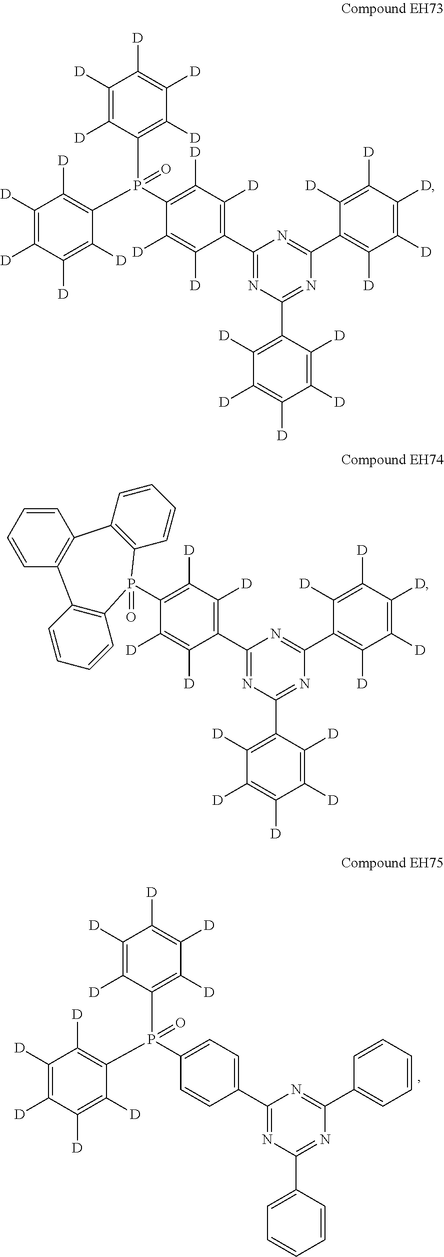

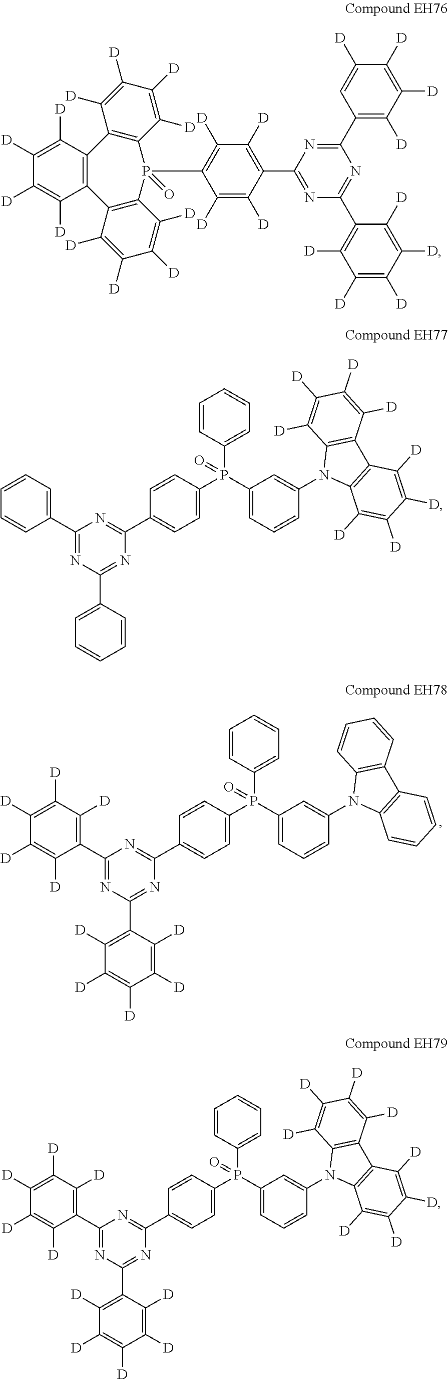

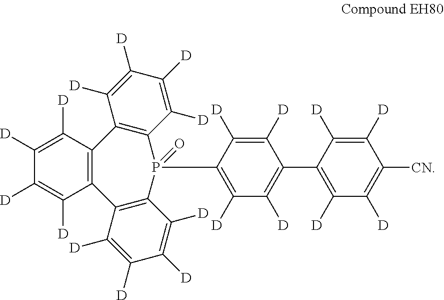 [SMILES: [2H]c1c([2H])c([2H])c2c(c1[2H])-c1c([2H])c([2H])c([2H])c([2H])c1P(=O)(c1c([2H])c([2H])c(-c3c([2H])c([2H])c(C#N)c([2H])c3[2H])c([2H])c1[2H])c1c([2H])c([2H])c([2H])c([2H])c1-2]

12. The organic electroluminescent device according to claim 1, wherein the guest light-emitting is selected from a fluorescent luminescent material;
preferably, the guest light-emitting material is a multiple resonance organic compound, further preferably a boron-nitrogen multiple resonance organic compound and/or an indolocarbazole multiple resonance organic compound.

13. The organic electroluminescent device according to claim 1, wherein the guest light-emitting material is selected from one or more of compounds represented by general formula (XV): 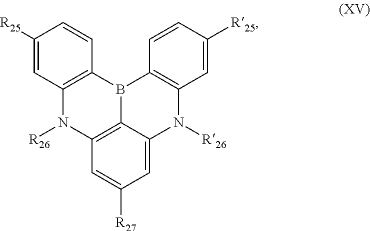
wherein R₂₅ and R′₂₅ are each independently selected from 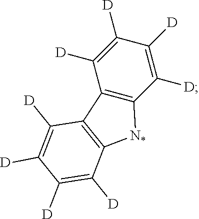
R₂₆ and R′₂₆ are each independently selected from 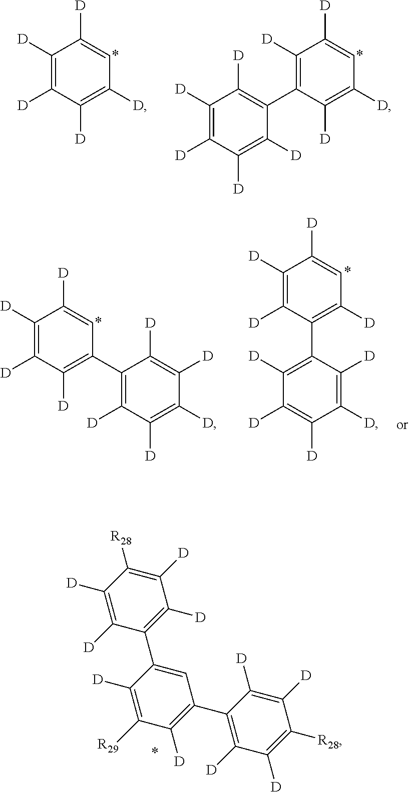
wherein R₂₈ and R₂₉ are each independently selected from deuterium or 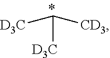 [SMILES: [2H]C([2H])([2H])C(C([2H])([2H])[2H])C([2H])([2H])[2H]]
R₂₇ is selected from hydrogen or 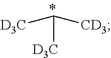 [SMILES: [2H]C([2H])([2H])C(C([2H])([2H])[2H])C([2H])([2H])[2H]]
preferably, R₂₆ and R′₂₆ is selected from 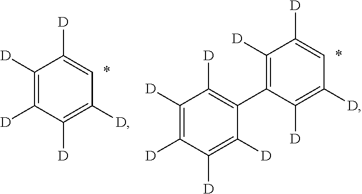 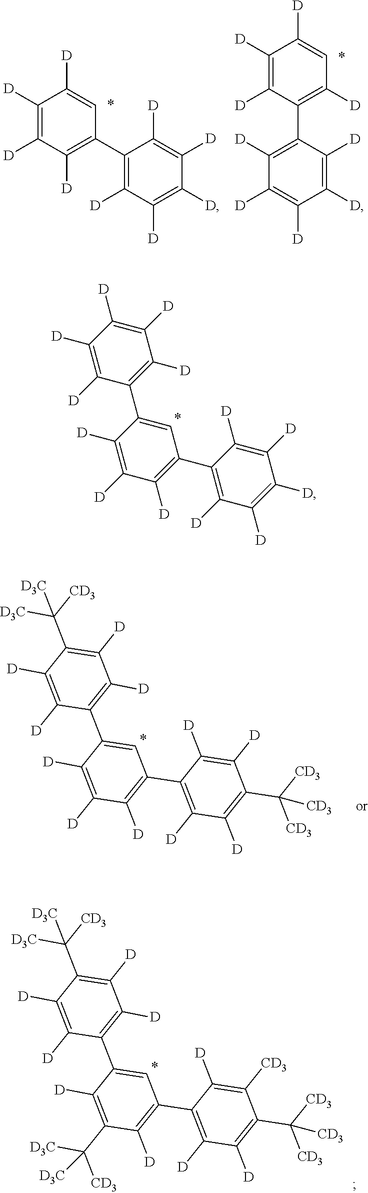
preferably, the guest light-emitting material is selected from one or more of Compound E1 to Compound E9:

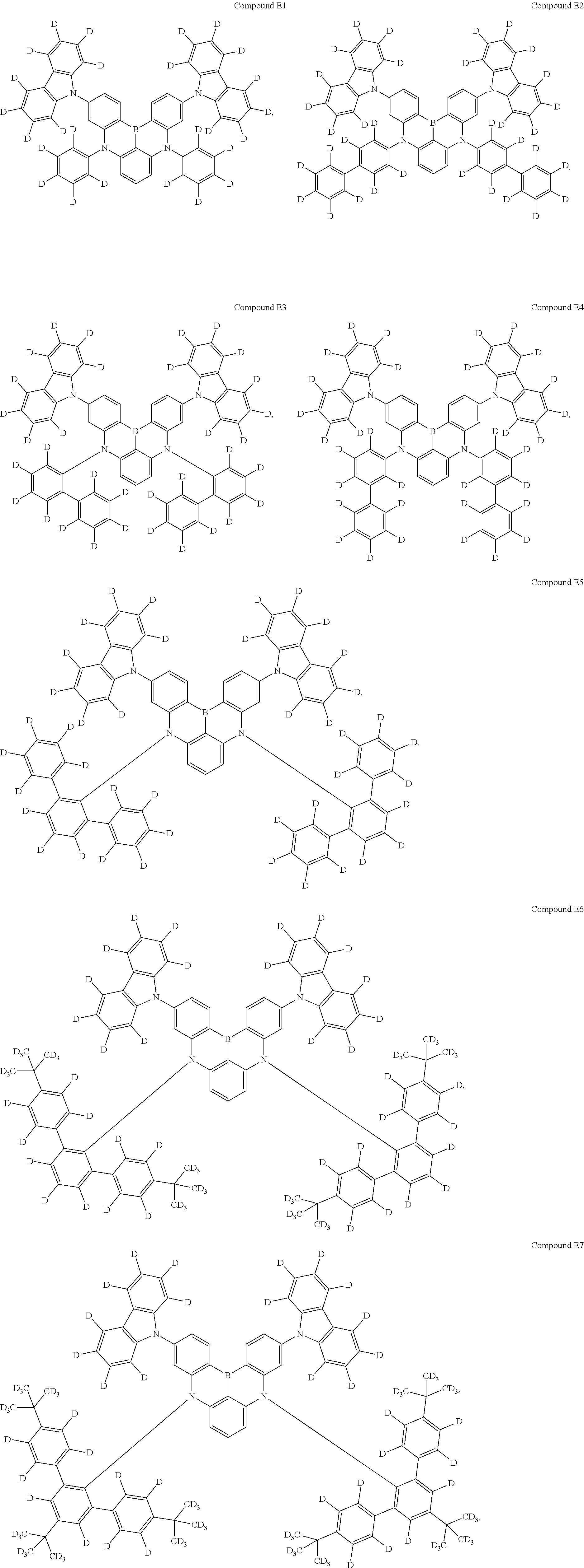

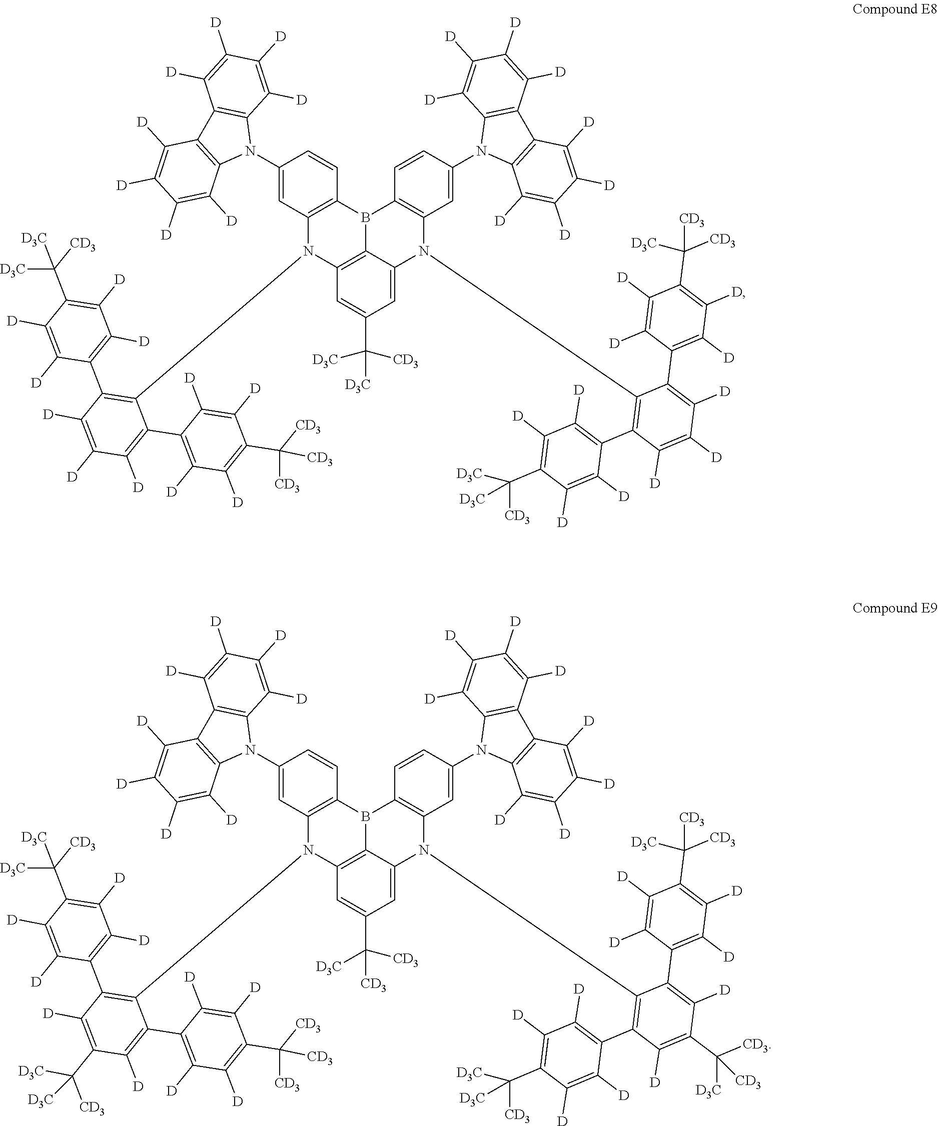

14. The organic electroluminescent device according to claim 1, wherein the exciton utilizing agent is selected from a metal complex and/or a thermally activated delayed fluorescence material;
preferably, the exciton utilizing agent is selected from iridium organic complexes and/or platinum organic complexes.

15. The organic electroluminescent device according to claim 1, wherein the exciton utilizing agent is selected from one or more of compounds represented by general formulae (XVI) and (XVII): 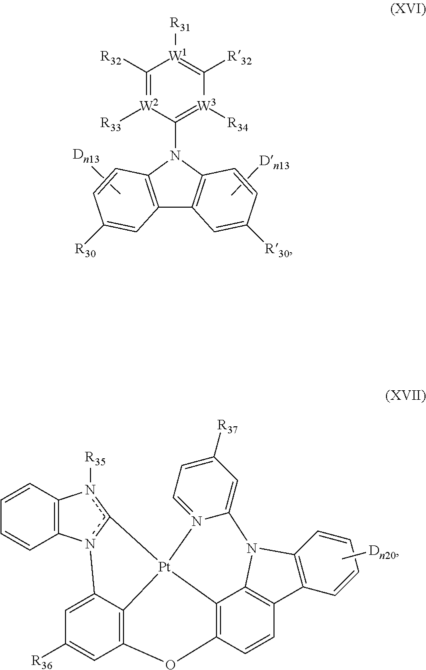
wherein in formula (XVI), W¹, W², and W³ are each independently selected from C or N, and when W¹ is N, R₃₁ is empty, and when W² is N, R₃₃ is empty, and when W³ is N, R₃₄ is empty;
R₃₀ and R′₃₀ are each independently selected from deuterium, hydrogen, C₆-C₂₀ aryl, C₆-C₂₀ aryl substituted with at least one deuterium atom, C₁-C₁₀ alkyl substituted with at least one deuterium atom, or 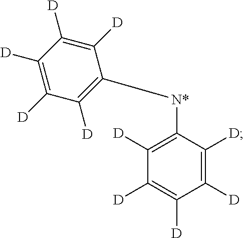
R₃₁ is selected from hydrogen, cyano, 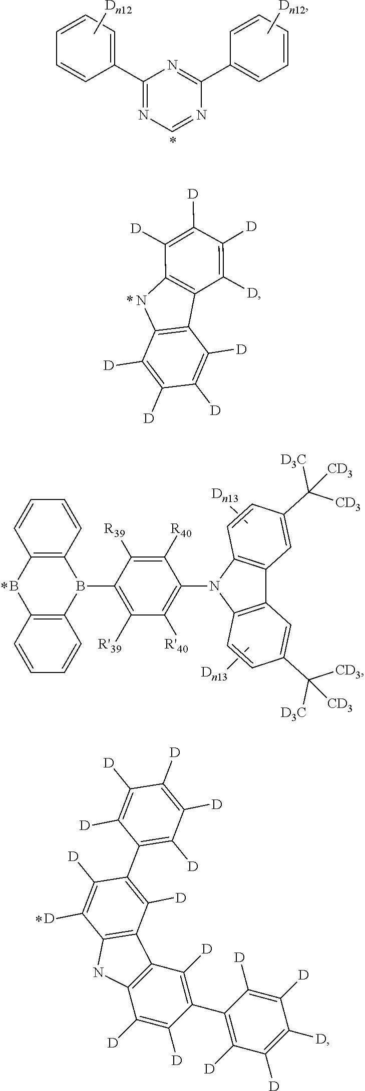 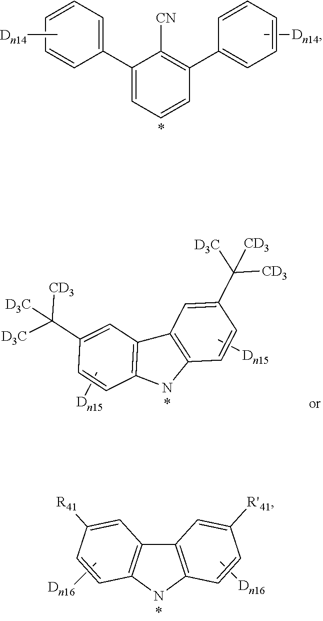
wherein n12 and n14 represent substitution by any one of 0 to 5 integer deuterium atoms in the corresponding benzene ring structure, preferably 0 or 5; n13, n′13, n15 and n16 represent that substitution by any one of 0 to 3 integer deuterium atoms in the corresponding benzene ring structure, preferably 0 or 3; R₃₉ and R′₃₉ are each independently selected from C₁-C₁₀ alkyl groups, or C₁-C₁₀ alkyl groups substituted with at least one deuterium atom, preferably deuterated methyl or methyl; R₄₀ and R′₄₀ are each independently selected from hydrogen or deuterium; R₄₁ and R′₄₁ are selected from C₆-C₂₀ aryl, C₆-C₂₀ aryl substituted with at least one deuterium atom, C₁-C₁₀ alkyl, or C₁-C₁₀ alkyl substituted with at least one deuterium atom, preferably phenyl, deuterated phenyl, methyl, deuterated methyl or deuterated tert-butyl;
R₃₂ and R′₃₂ are each independently selected from hydrogen, deuterium, cyano, C₁-C₁₀ alkyl, C₁-C₁₀ alkyl substituted with at least one deuterium atom, C₆-C₂₀ aryl, C₆-C₂₀ aryl substituted with at least one deuterium atom, C₆-C₂₀ aryl substituted with a cyano group, or phenyl substituted with C₁-C₁₀ alkyl, 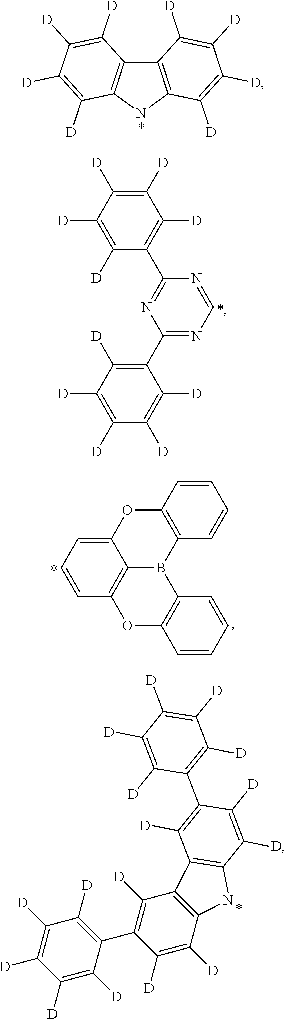 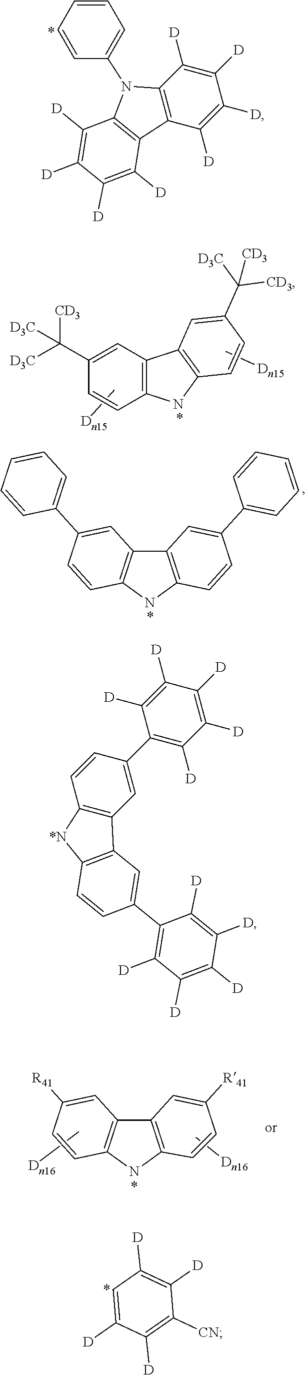
R₃₃ and R₃₄ are selected from hydrogen, cyano, C₆-C₂₀ aryl, cyano substituted C₆-C₂₀ aryl, 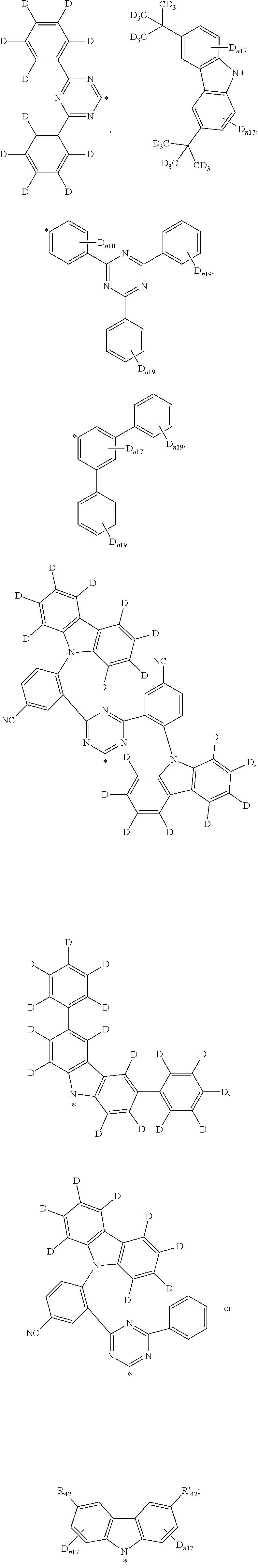
wherein n17 represents a substitution by any one of 0 to 3 integer deuterium atoms in the corresponding benzene ring, n18 represents a substitution by any one of 0 to 4 integer deuterium atoms in the corresponding benzene ring, n19 represents a substitution by any one of 0 to 5 integer deuterium atoms in the corresponding benzene ring, and R₄₂ and R′₄₂ are each independently selected from C₆-C₂₀ aryl, C₆-C₂₀ aryl substituted with at least one deuterium atom, C₁-C₁₀ alkyl, or C₁-C₁₀ alkyl substituted with at least one deuterium atom, R₄₂ and R′₄₂ are preferably phenyl, deuterated phenyl, methyl, deuterated methyl, or deuterated tert-butyl;
R₃₅ is selected from 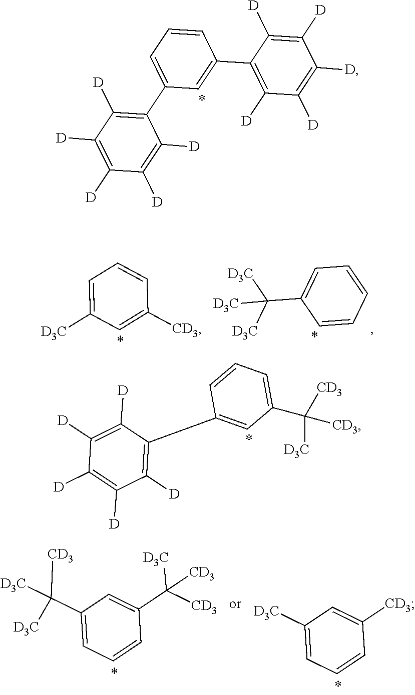
in the general formula (XVII), R₃₆ is selected from *CD₃, 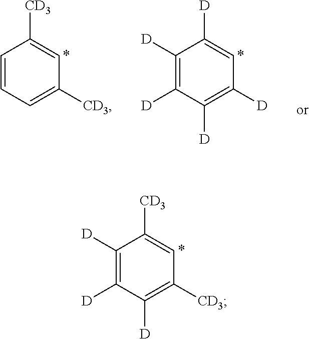
and R₃₇ is selected from 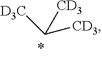 [SMILES: [2H]C([2H])([2H])C(C([2H])([2H])[2H])C([2H])([2H])[2H]]
and n20 represents a substitution by any one of 0 to 4 integer deuterium atoms in the corresponding benzene ring, preferably 0 or 4;
preferably, R₃₀ and R′₃₀ are each independently selected from a deuterium atom, a hydrogen atom, a phenyl group, 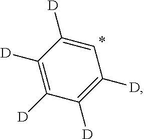
*CD₃, deuterated tert-butyl, 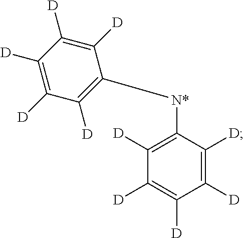
R₃₁ is selected from a hydrogen atom, a cyano group, 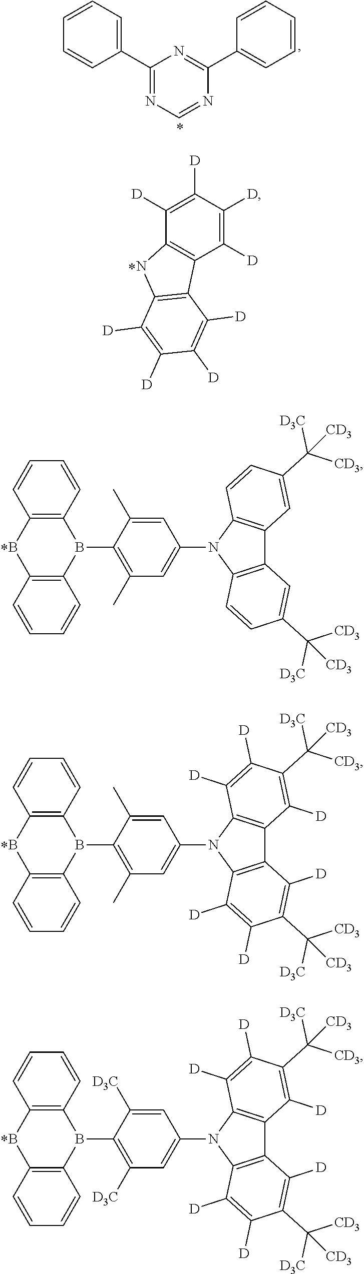 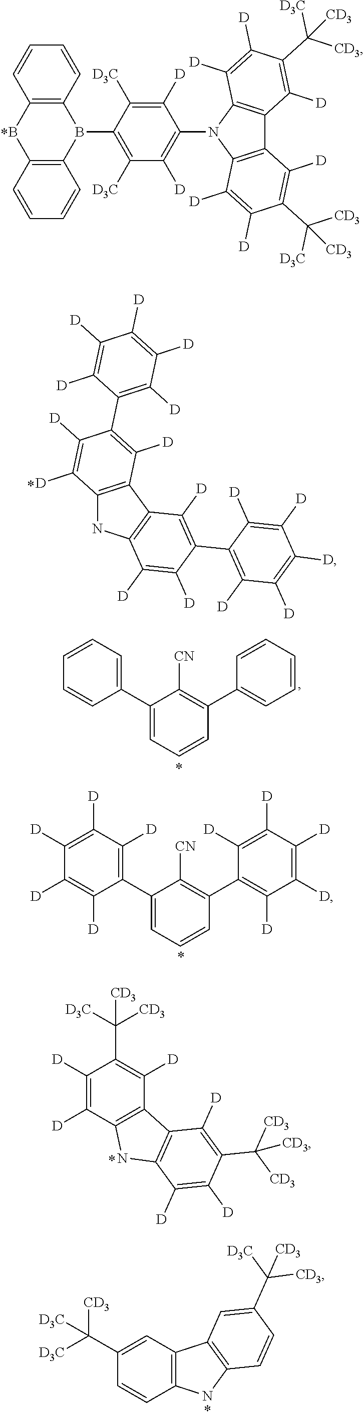 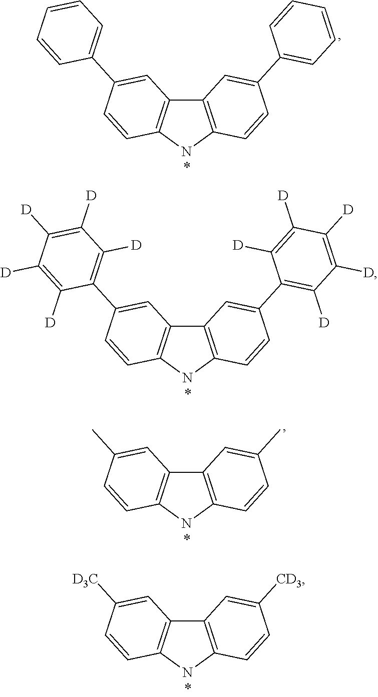
R₃₂ and R′₃₂ are each independently selected from a hydrogen atom, a deuterium atom, a cyano group, a methyl group, a deuterated methyl group, a phenyl group, a deuterated phenyl group, a cyano-substituted phenyl group, a tert-butyl-substituted phenyl group, 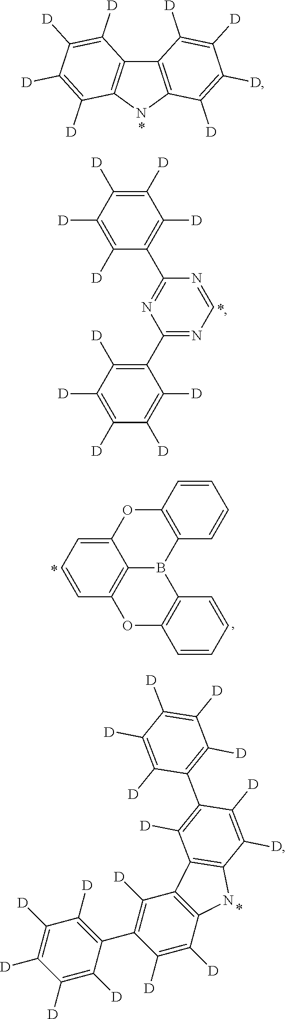 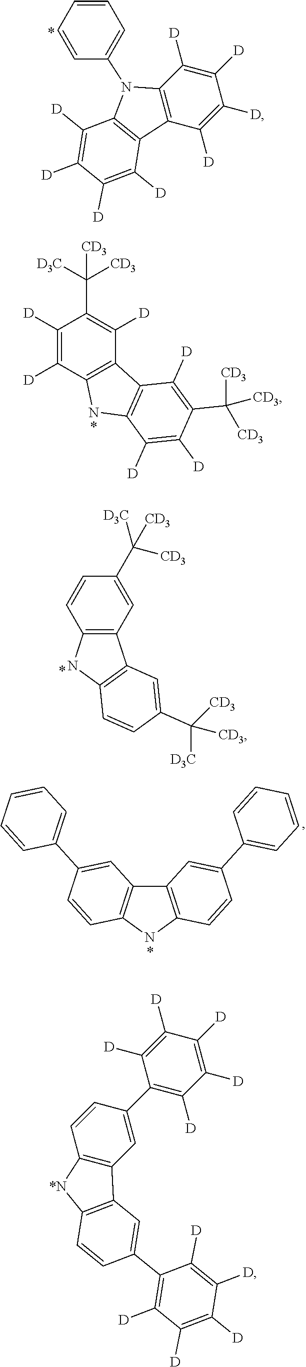 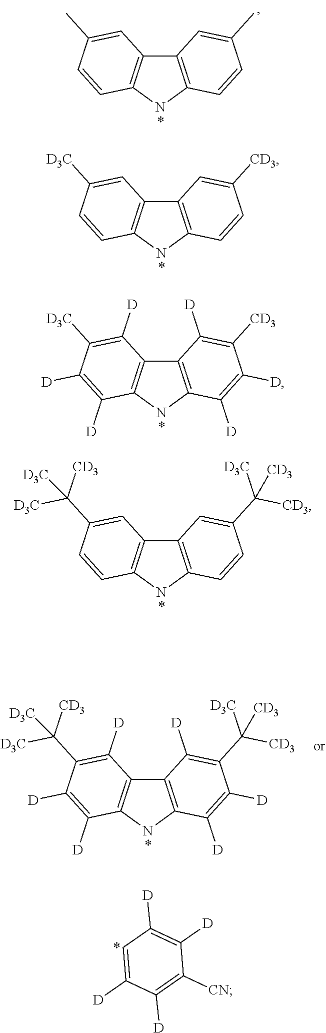
R₃₃ and R₃₄ are selected from hydrogen, cyano, phenyl, cyano-substituted phenyl, 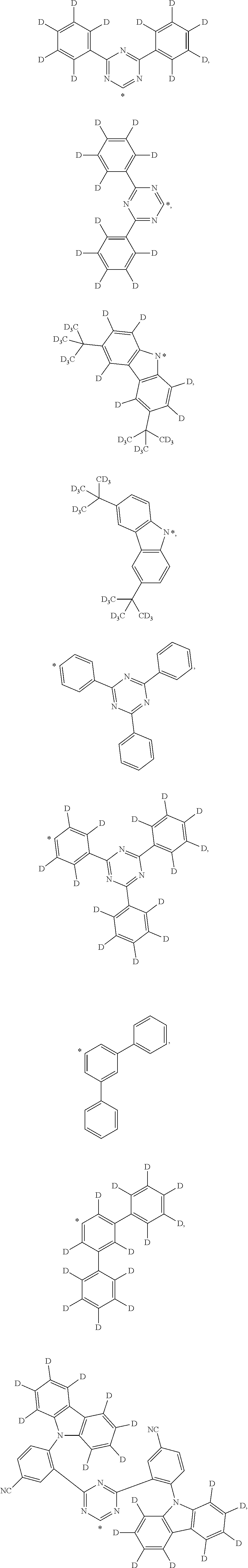 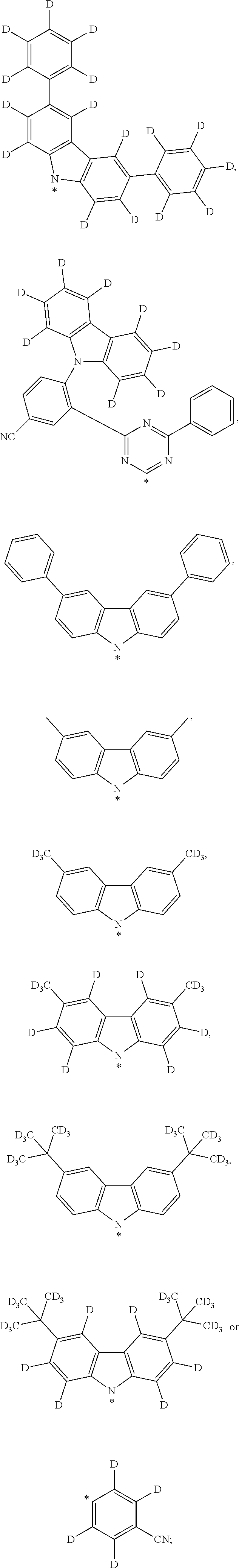
more preferably, the exciton utilizing agent is selected from one or more of Compound X1 to Compound X90:

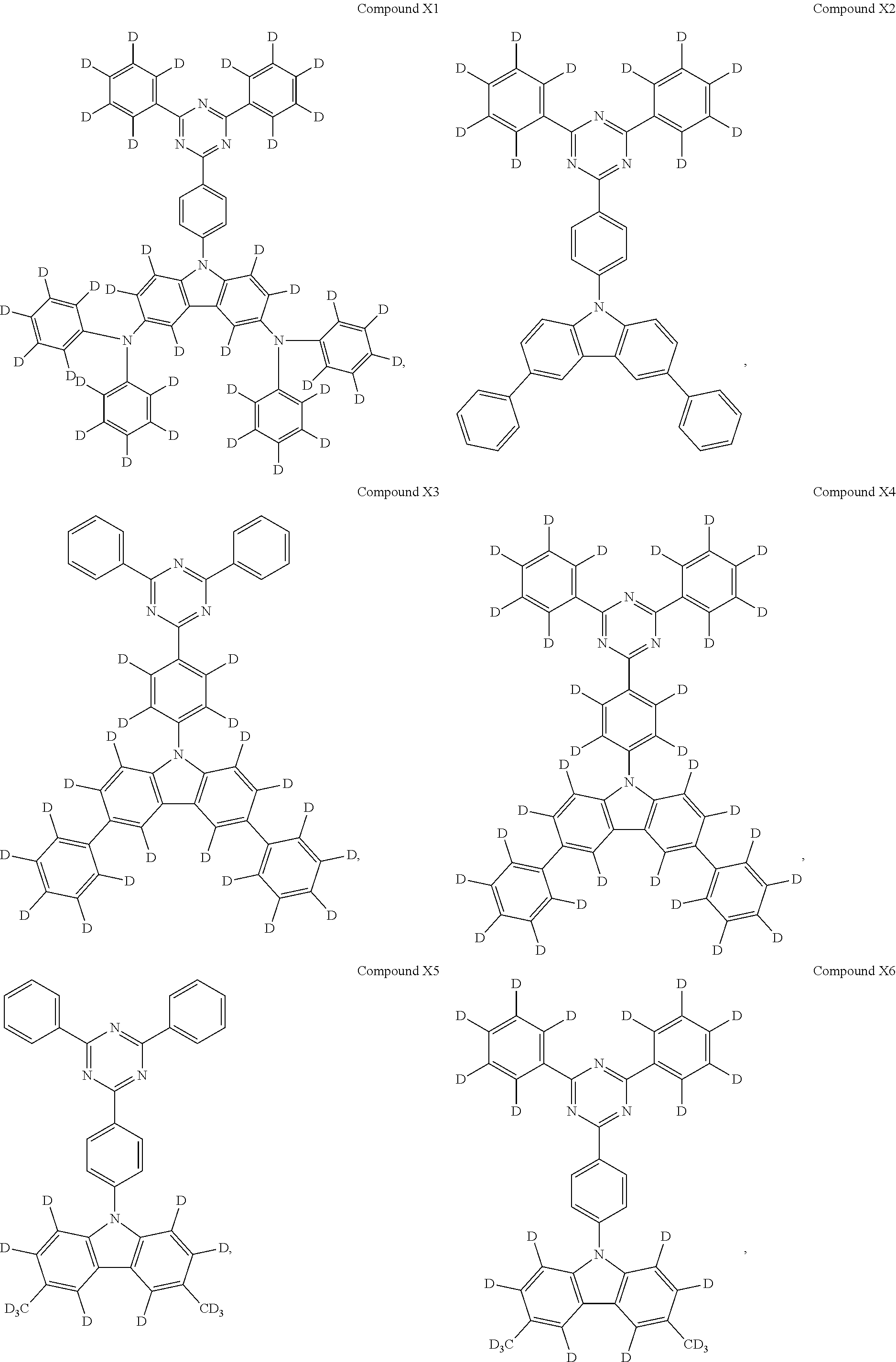

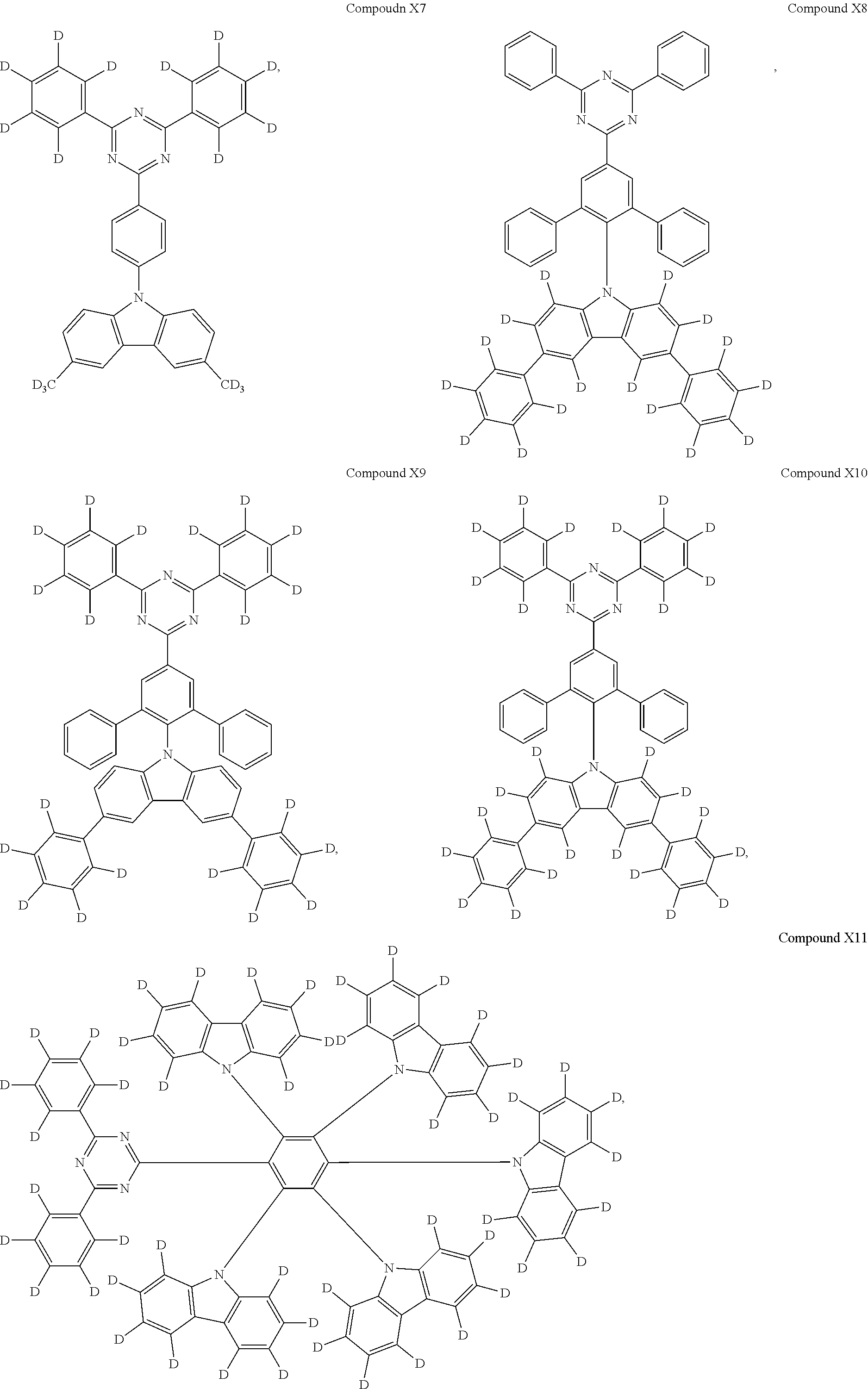

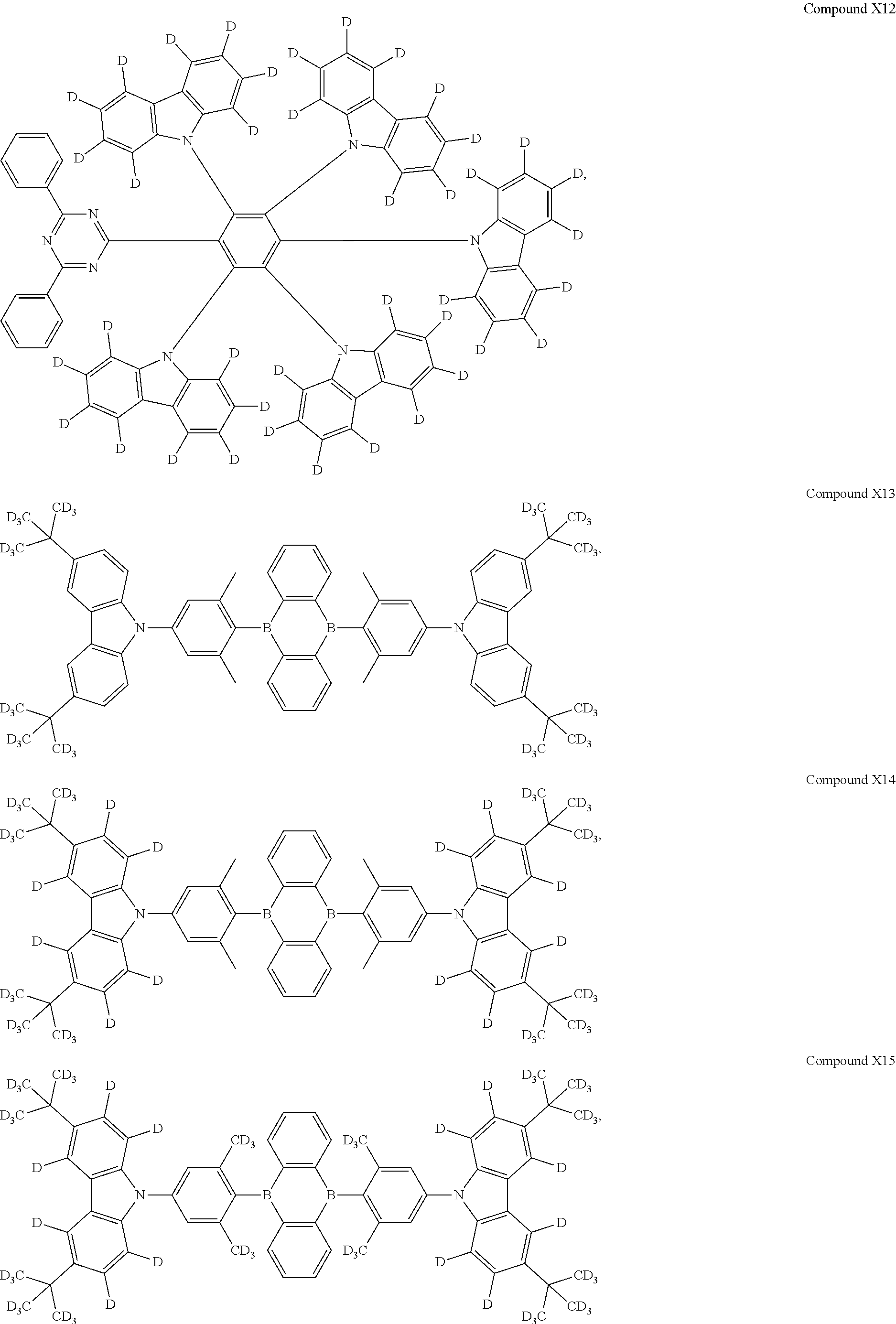

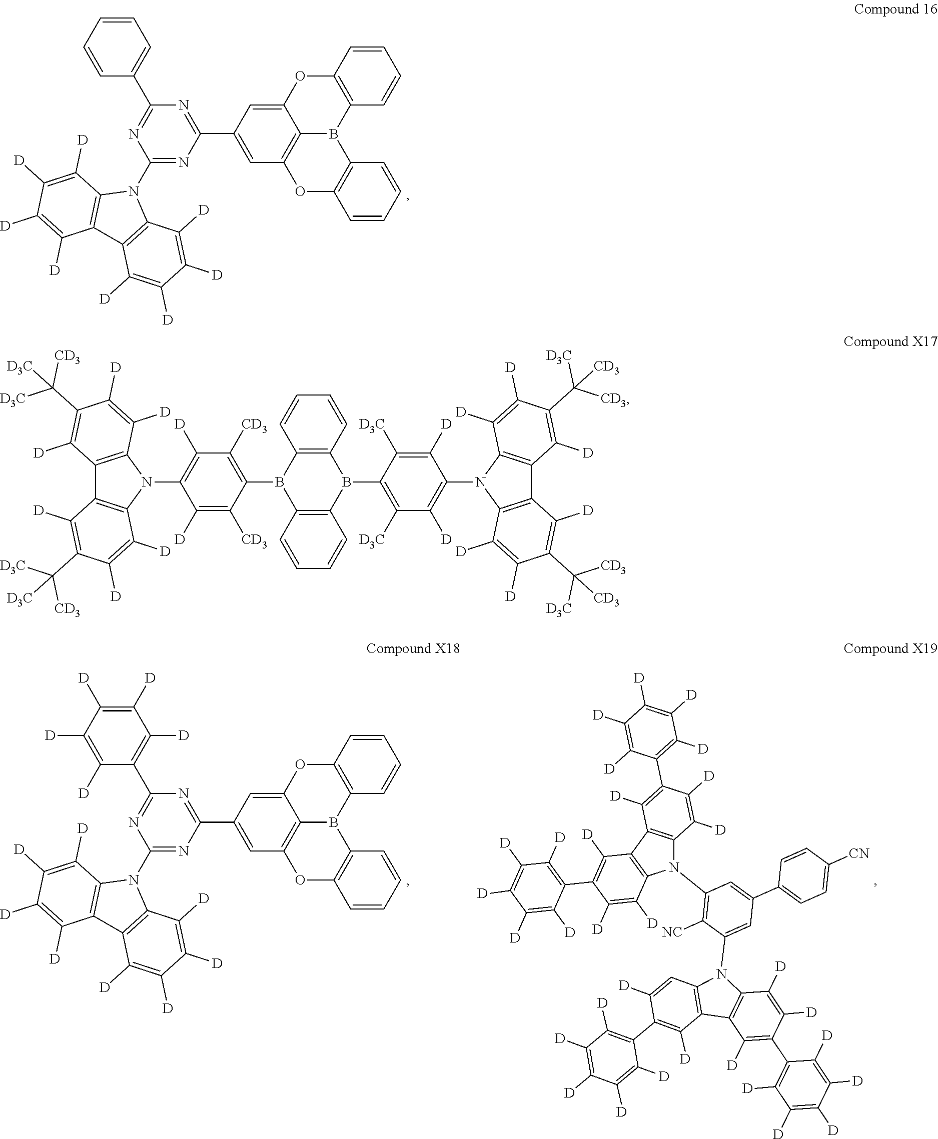

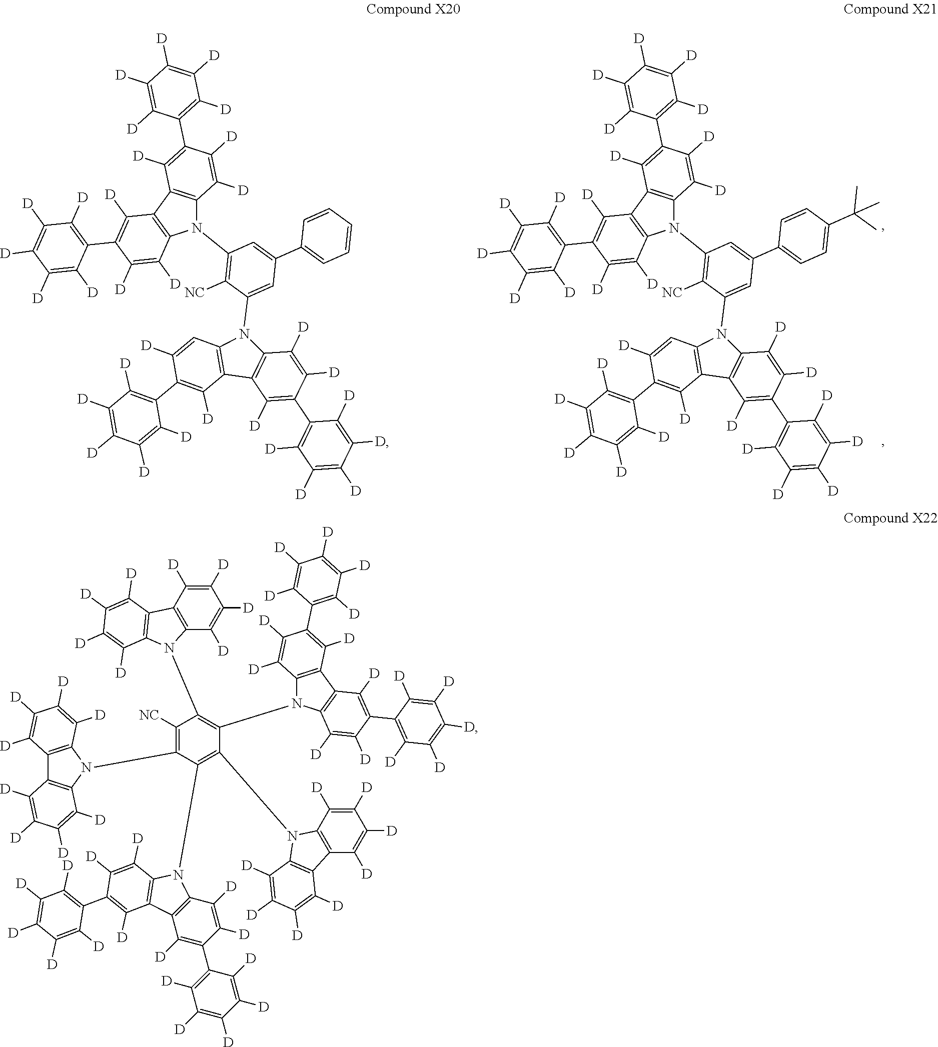

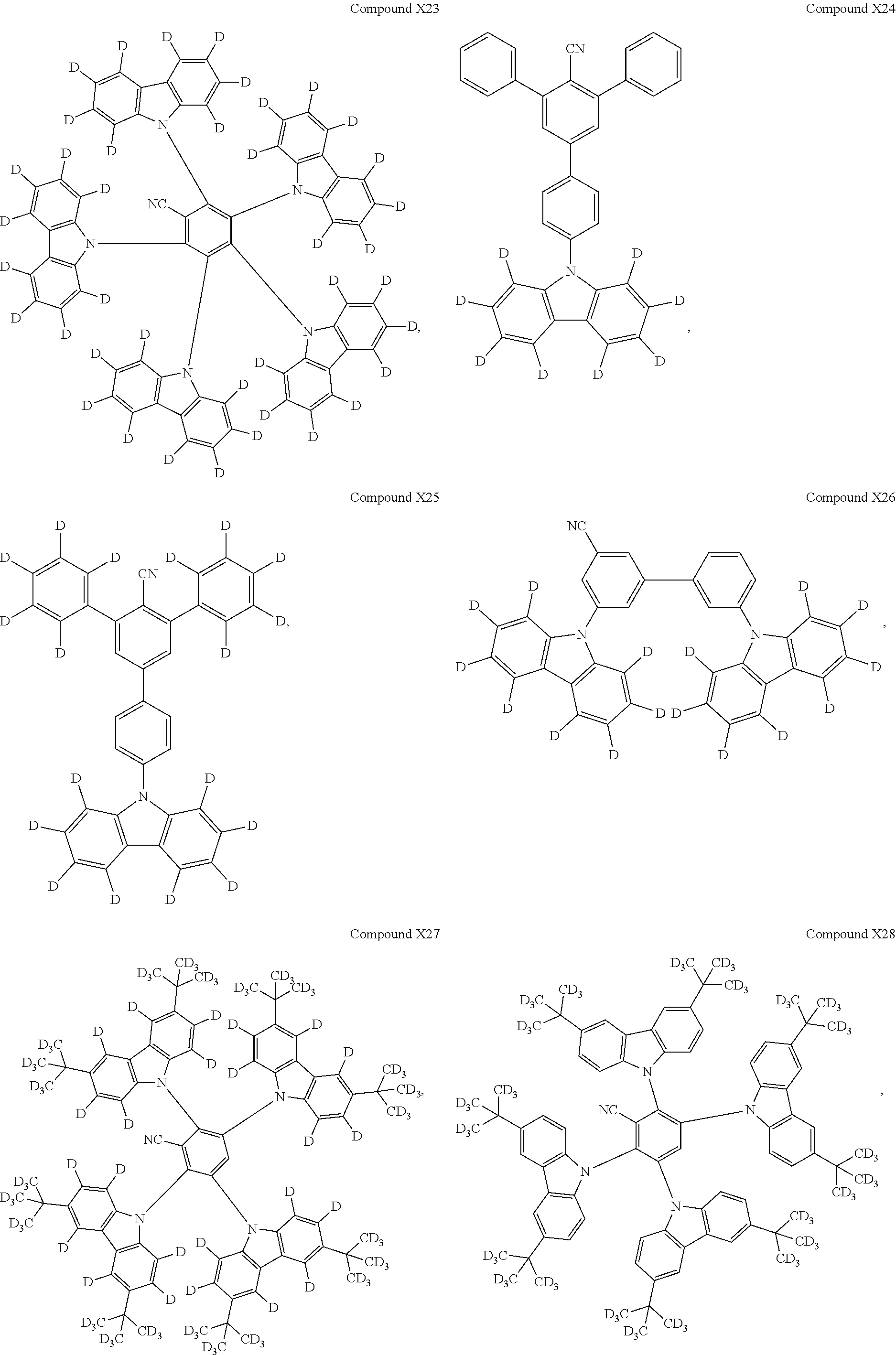

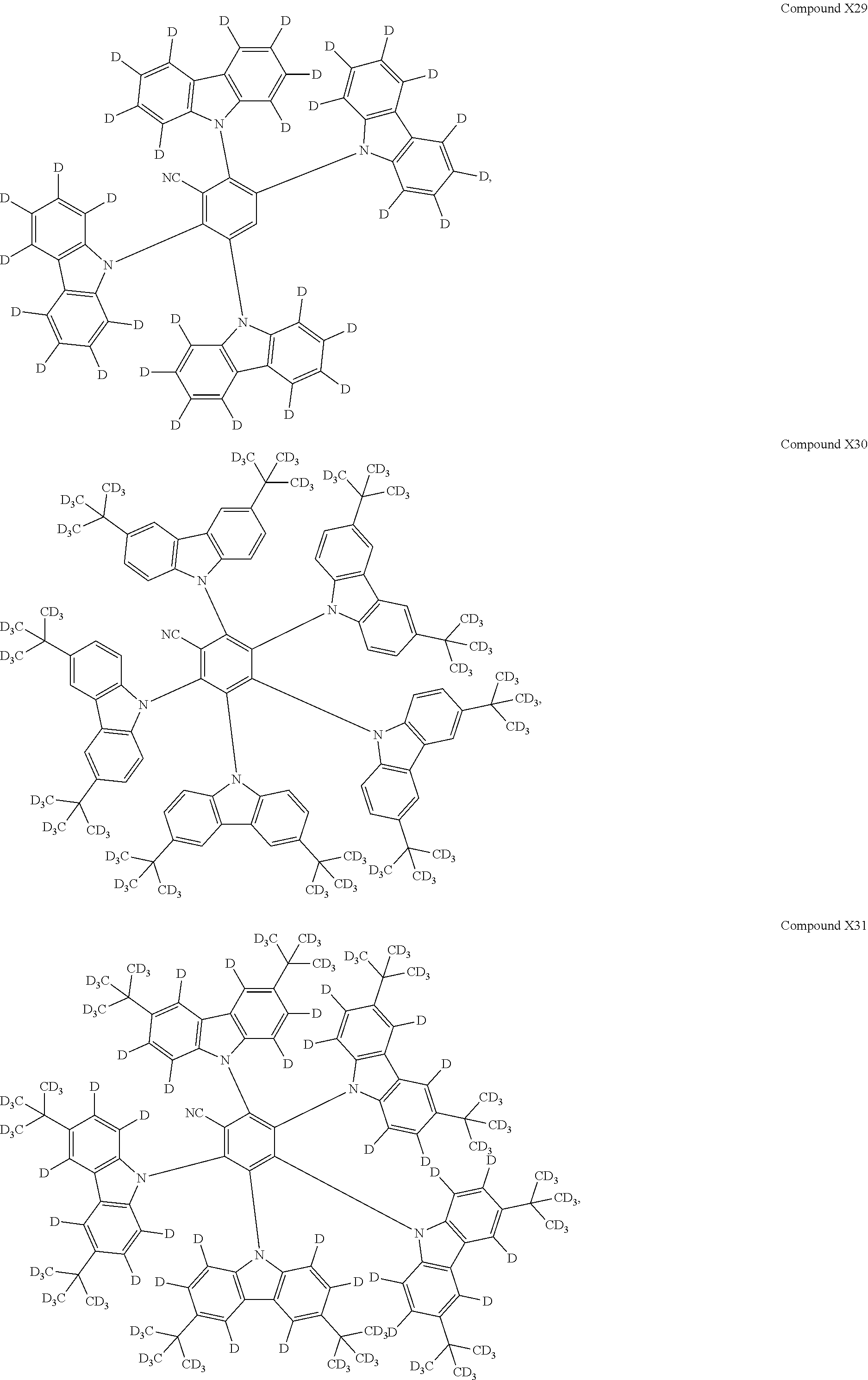

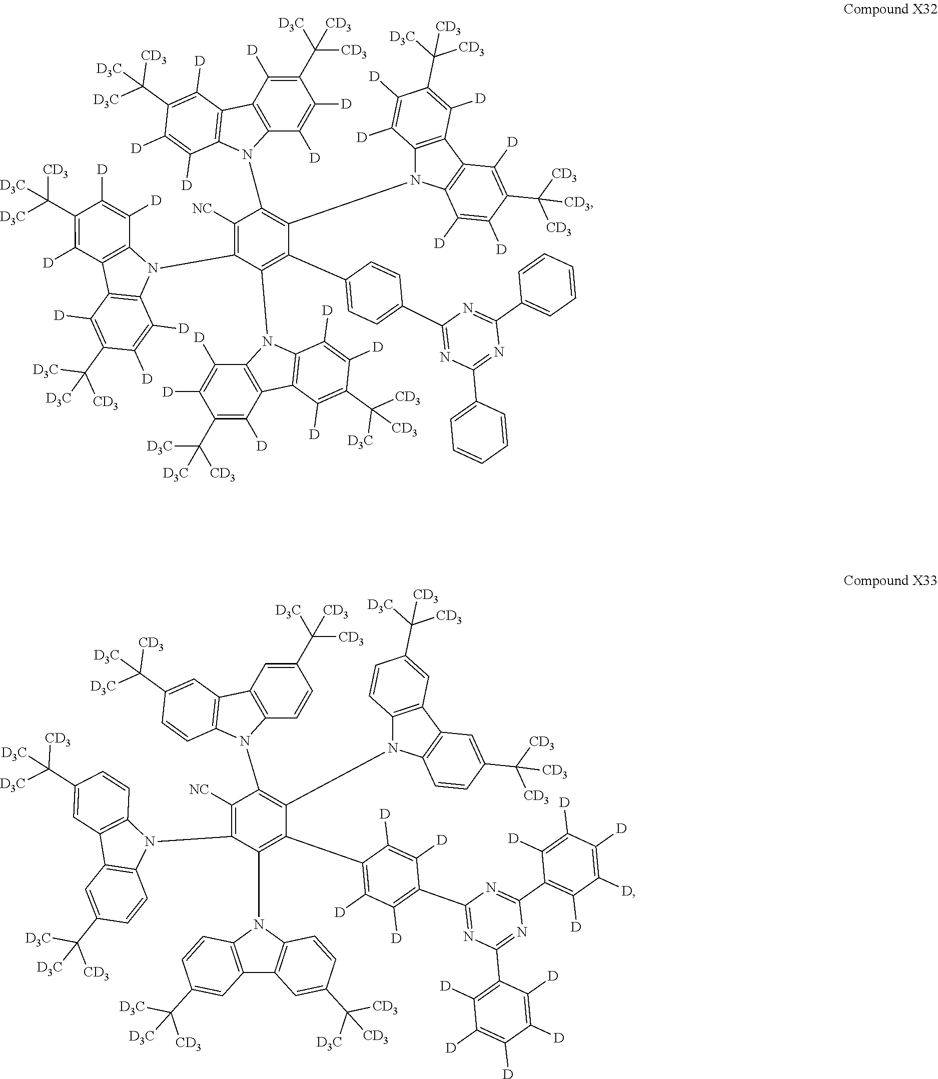

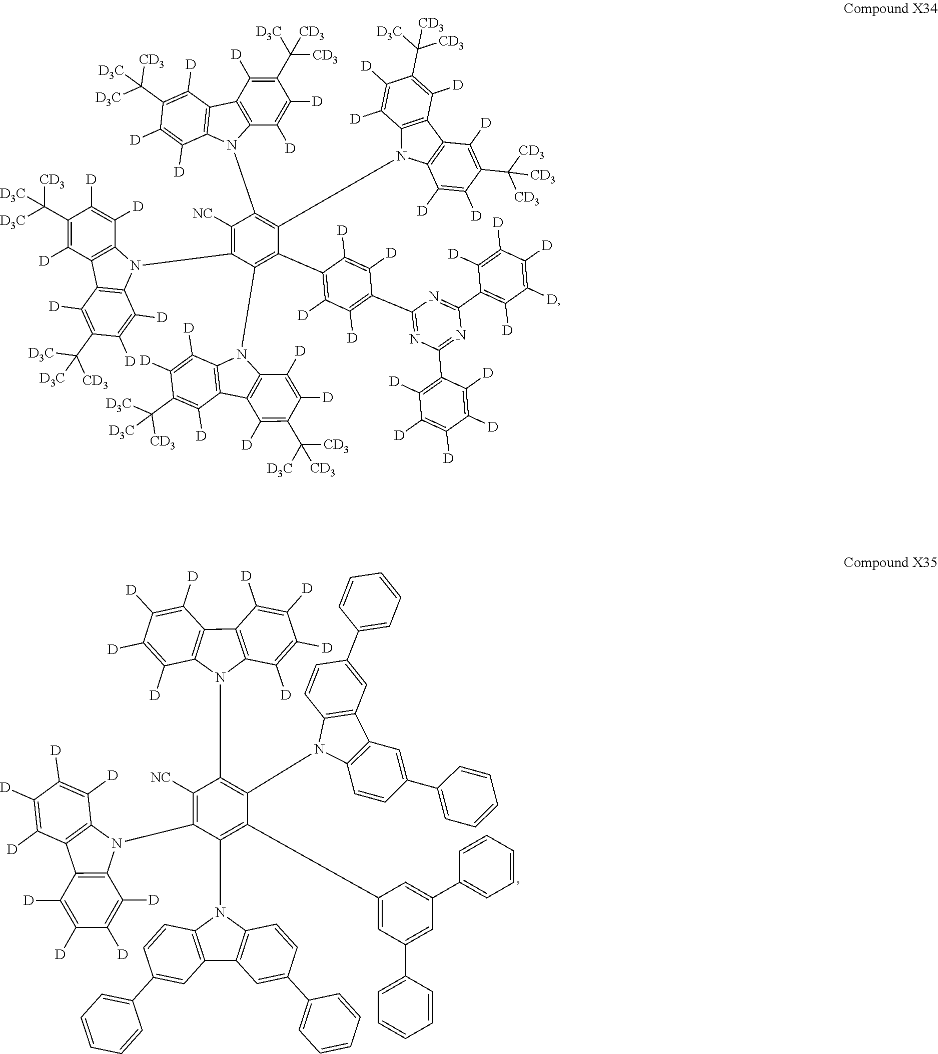

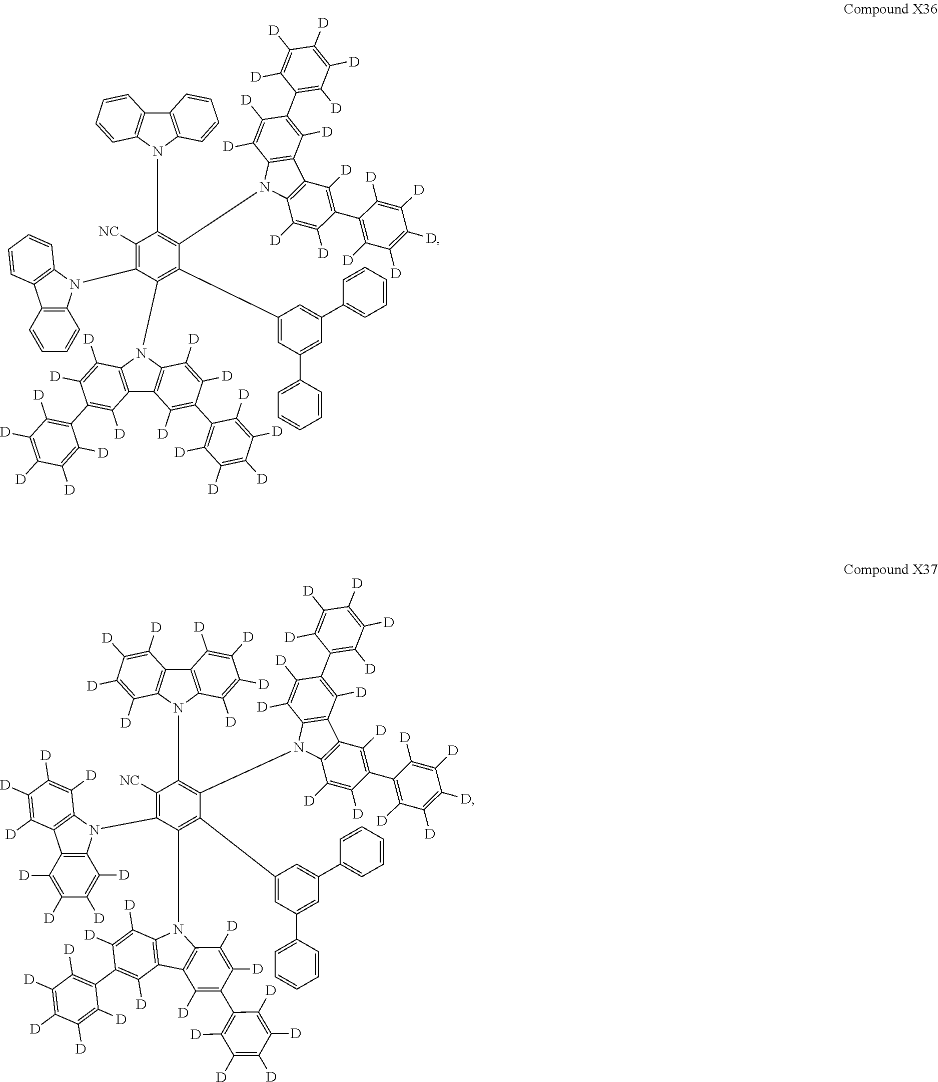

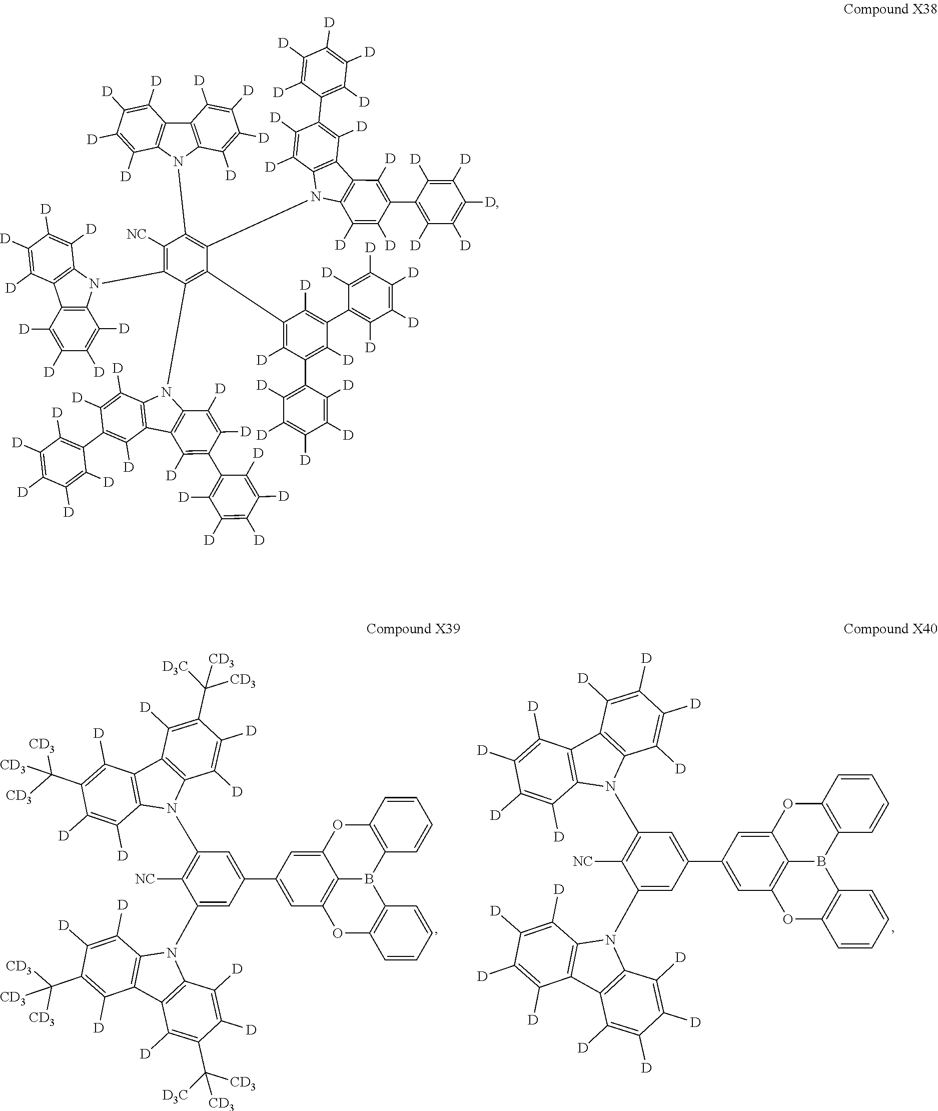

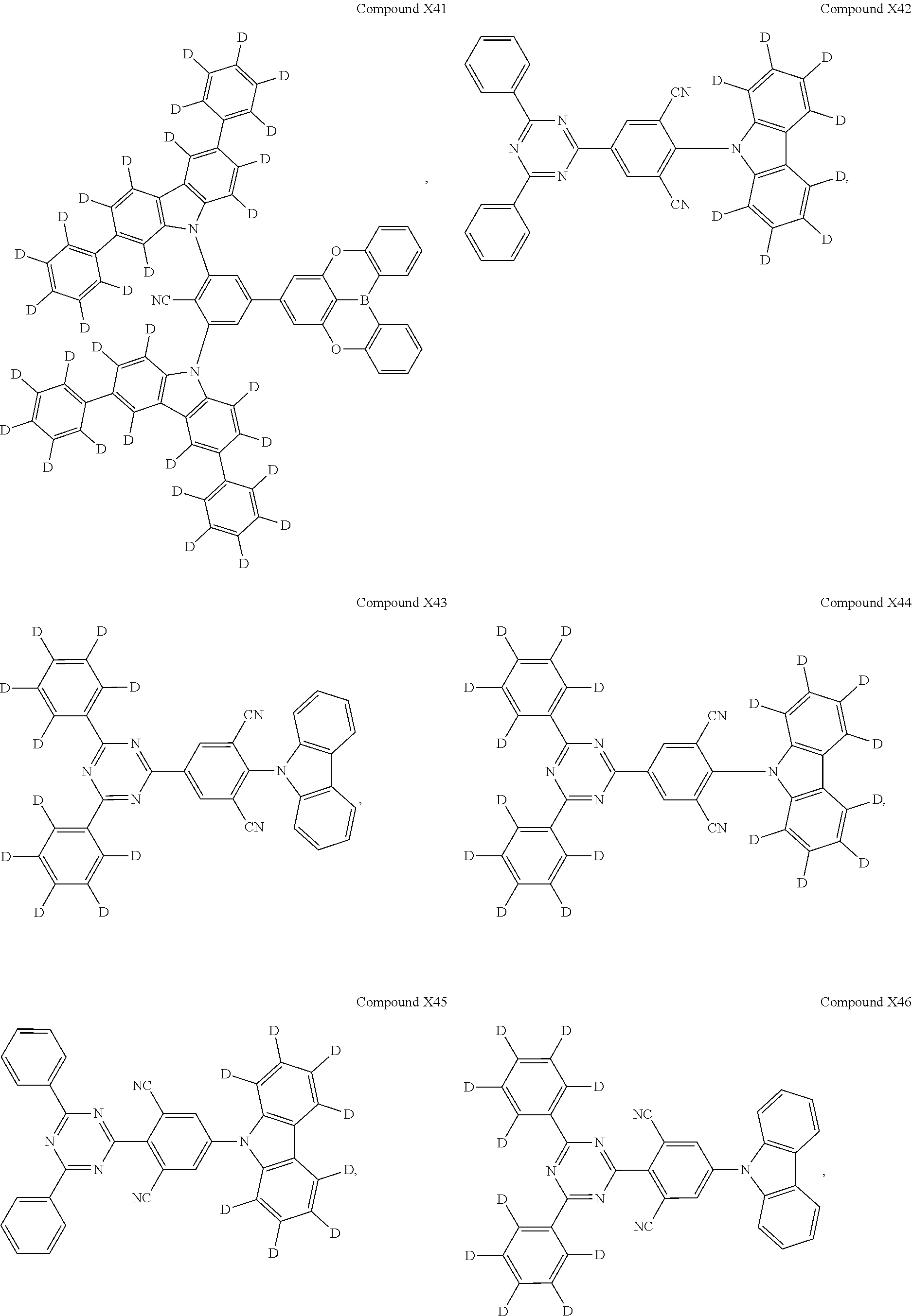

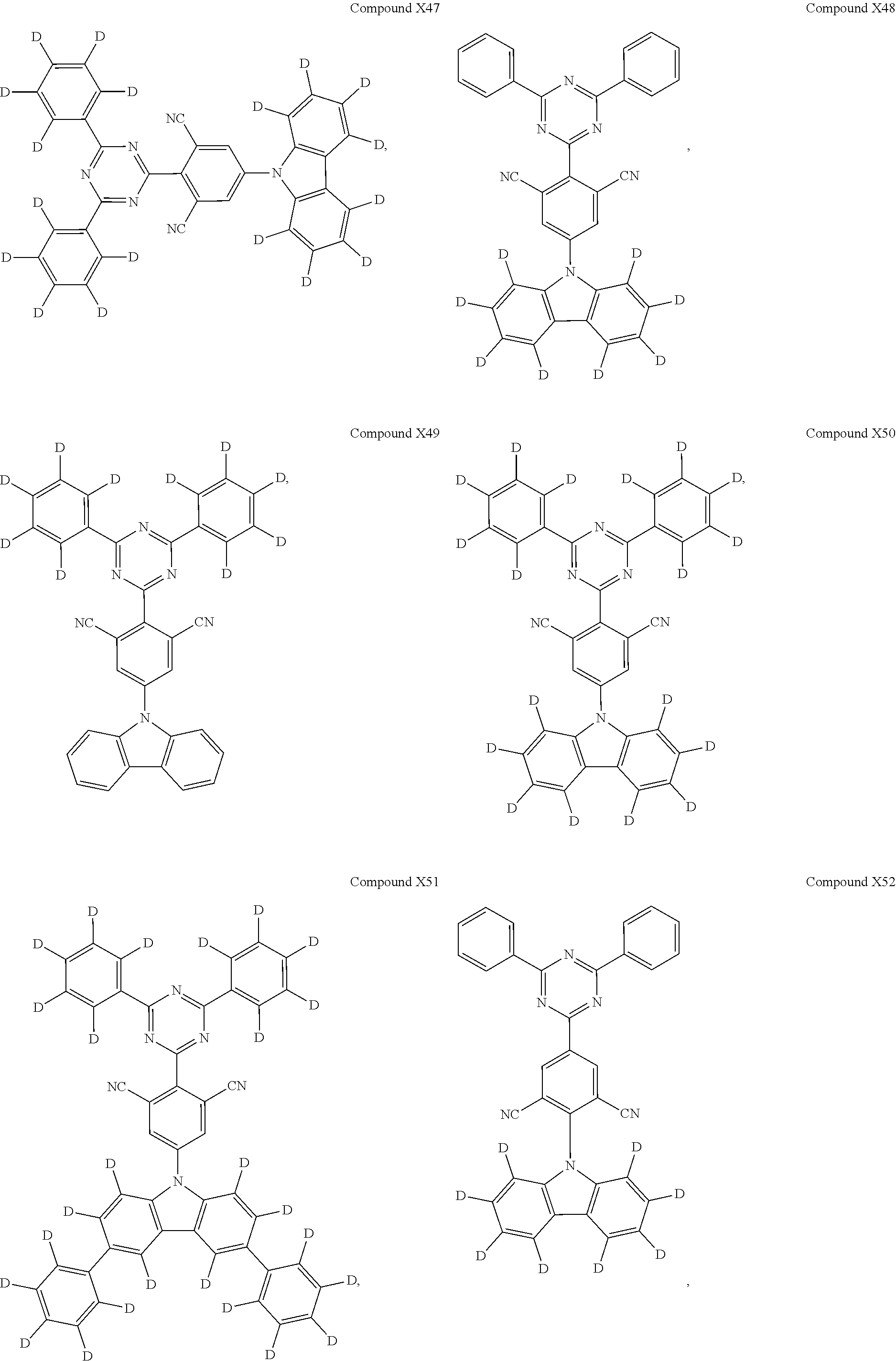

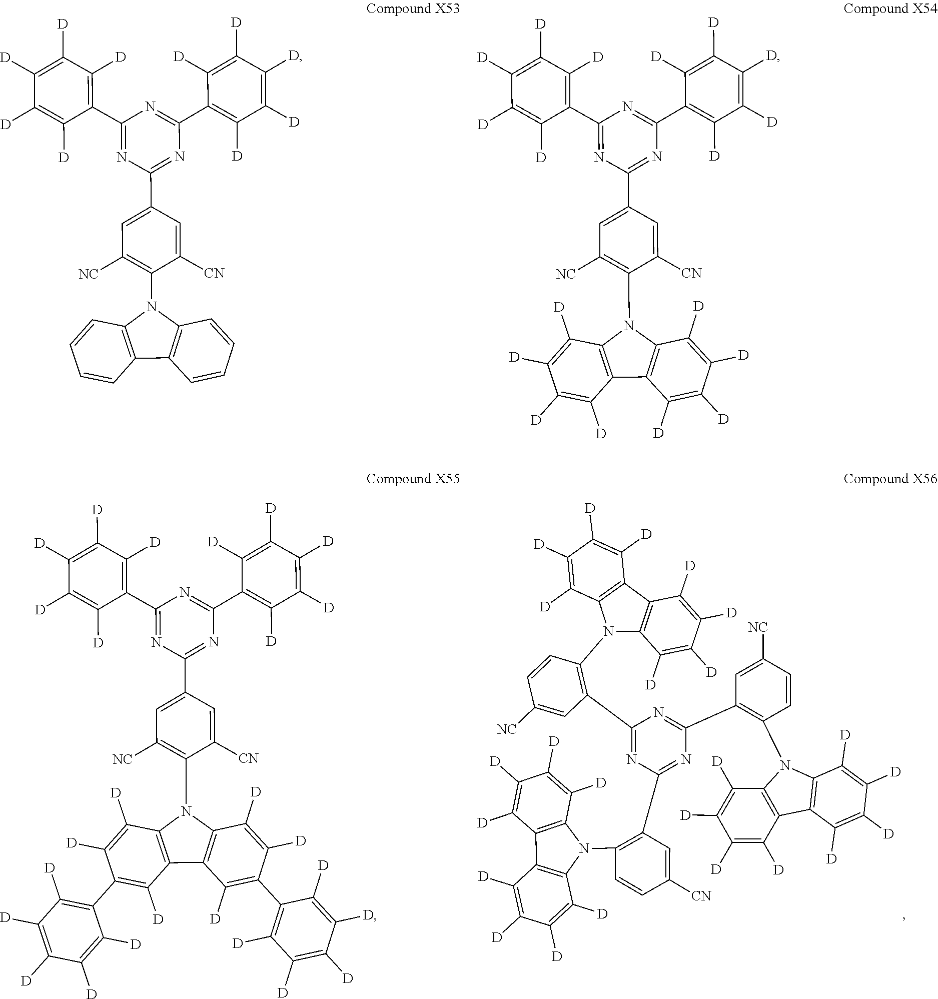

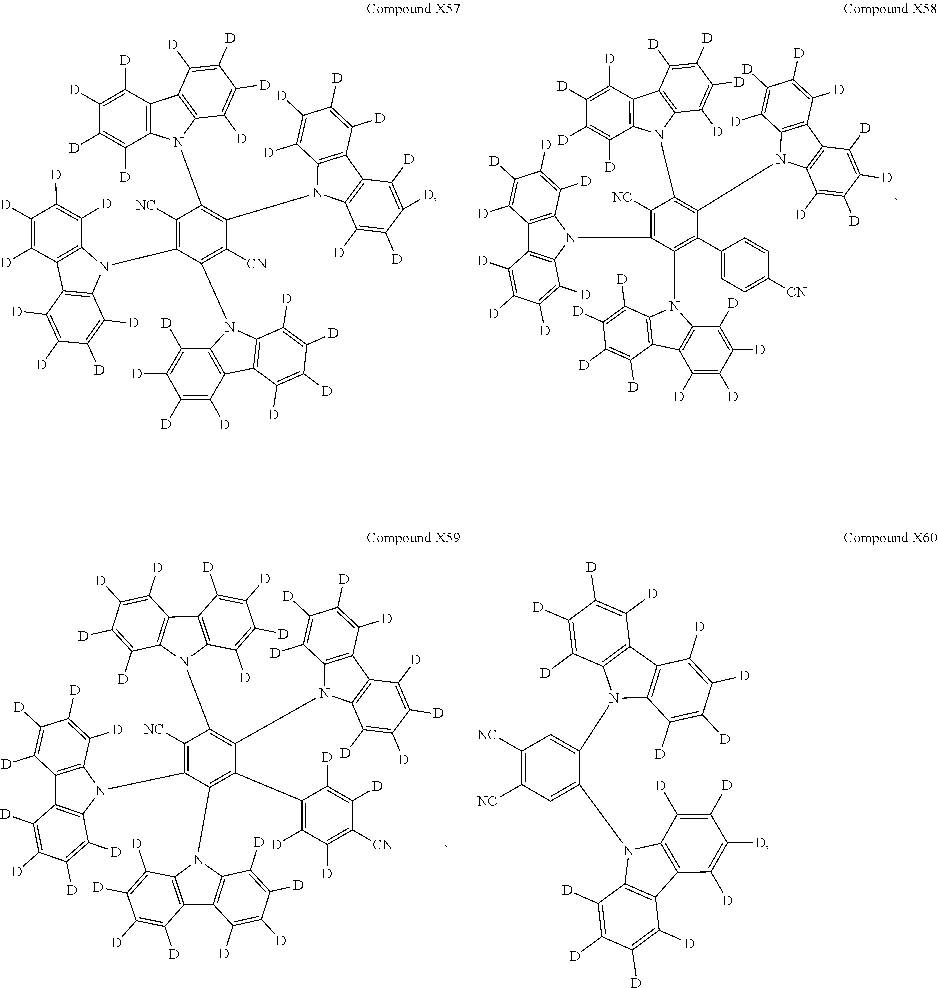

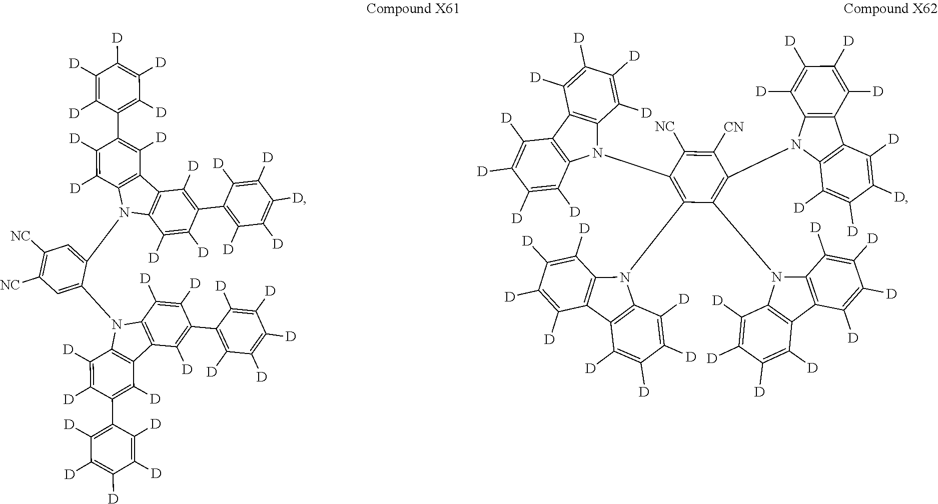

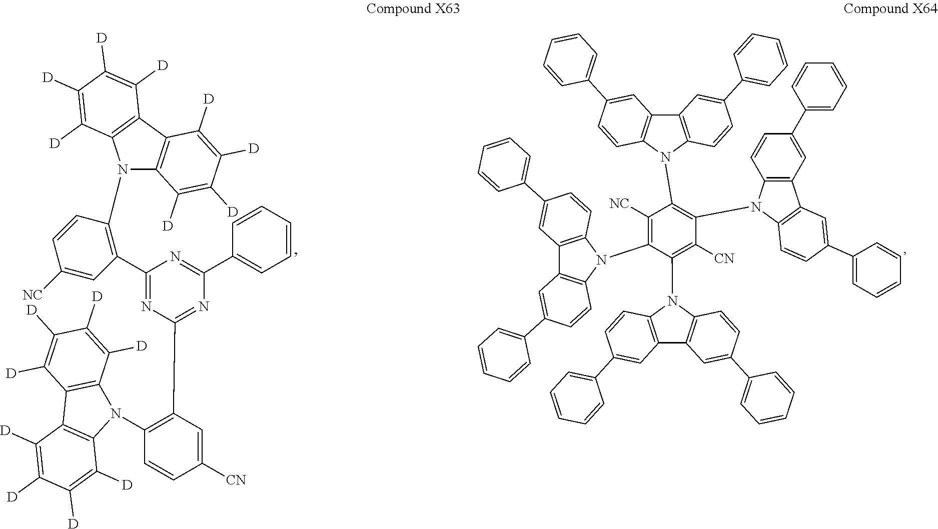 [SMILES: [2H]c1c([2H])c([2H])c2c(c1[2H])c1c([2H])c([2H])c([2H])c([2H])c1n2-c1ccc(C#N)cc1-c1nc(-c2ccccc2)nc(-c2cc(C#N)ccc2-n2c3c([2H])c([2H])c([2H])c([2H])c3c3c([2H])c([2H])c([2H])c([2H])c32)n1 ; N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

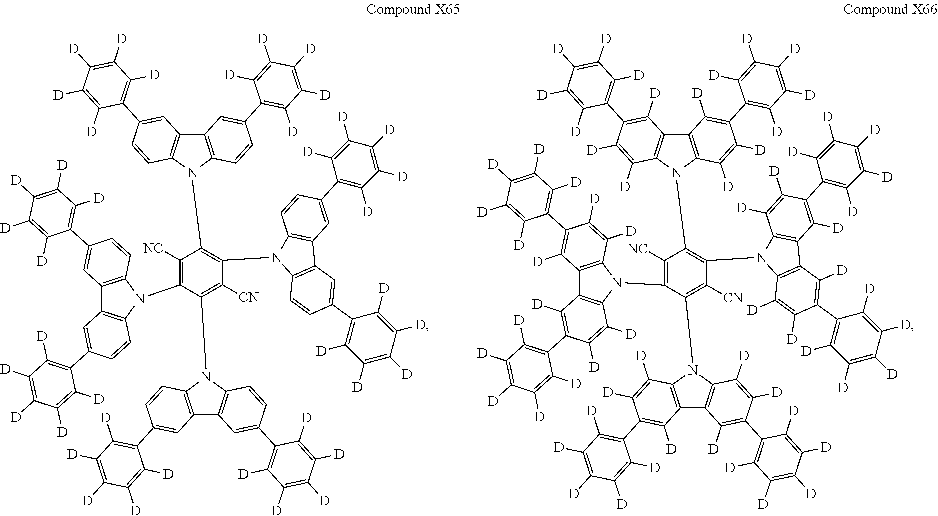

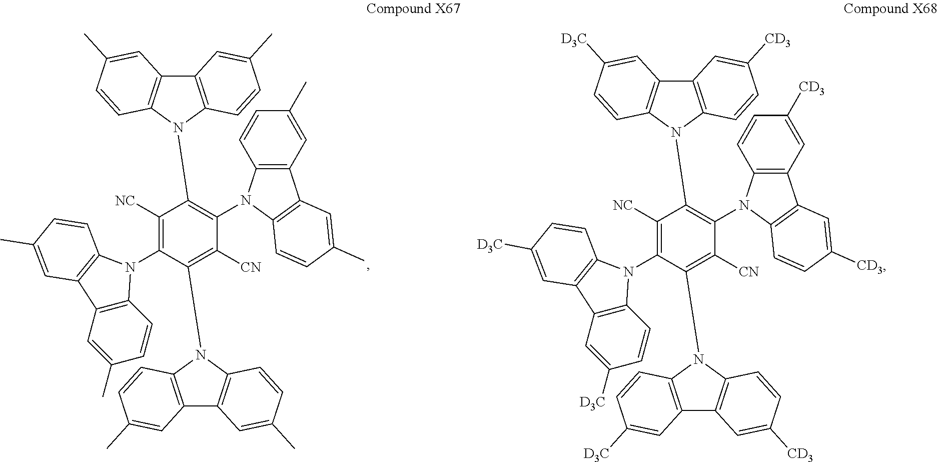

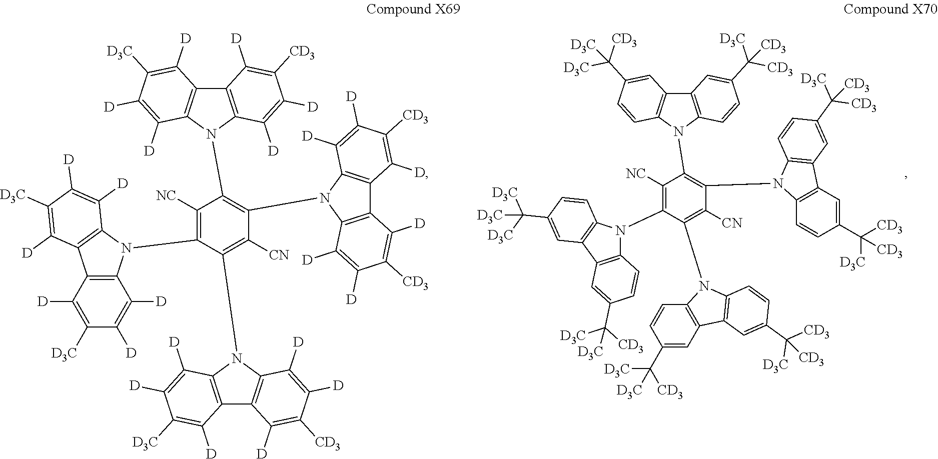

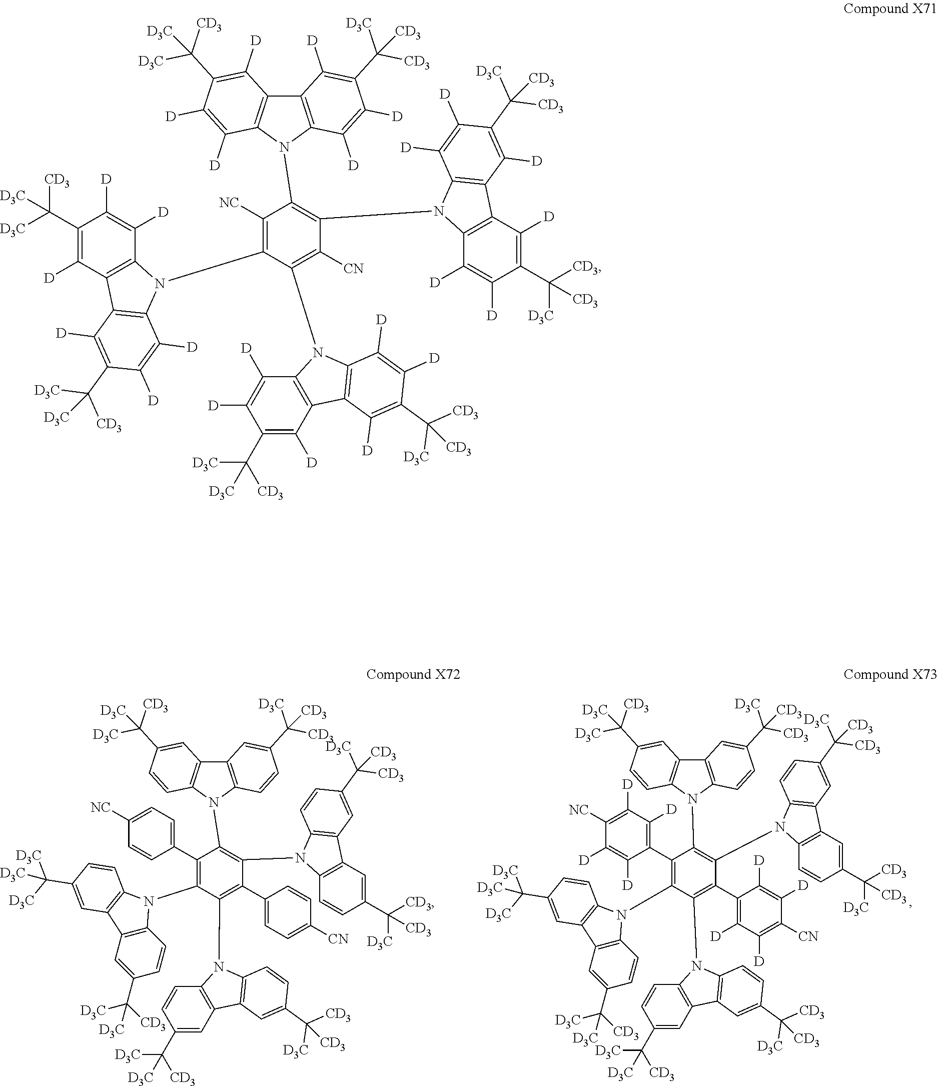

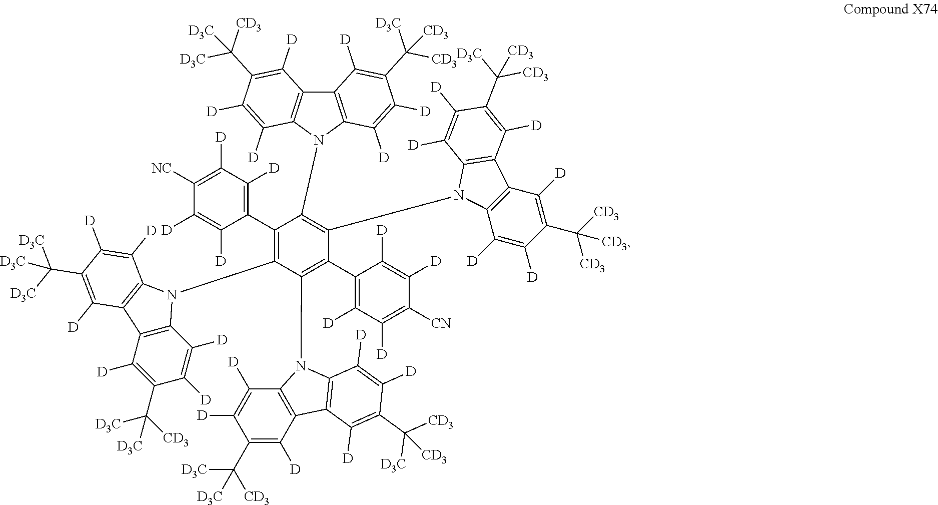

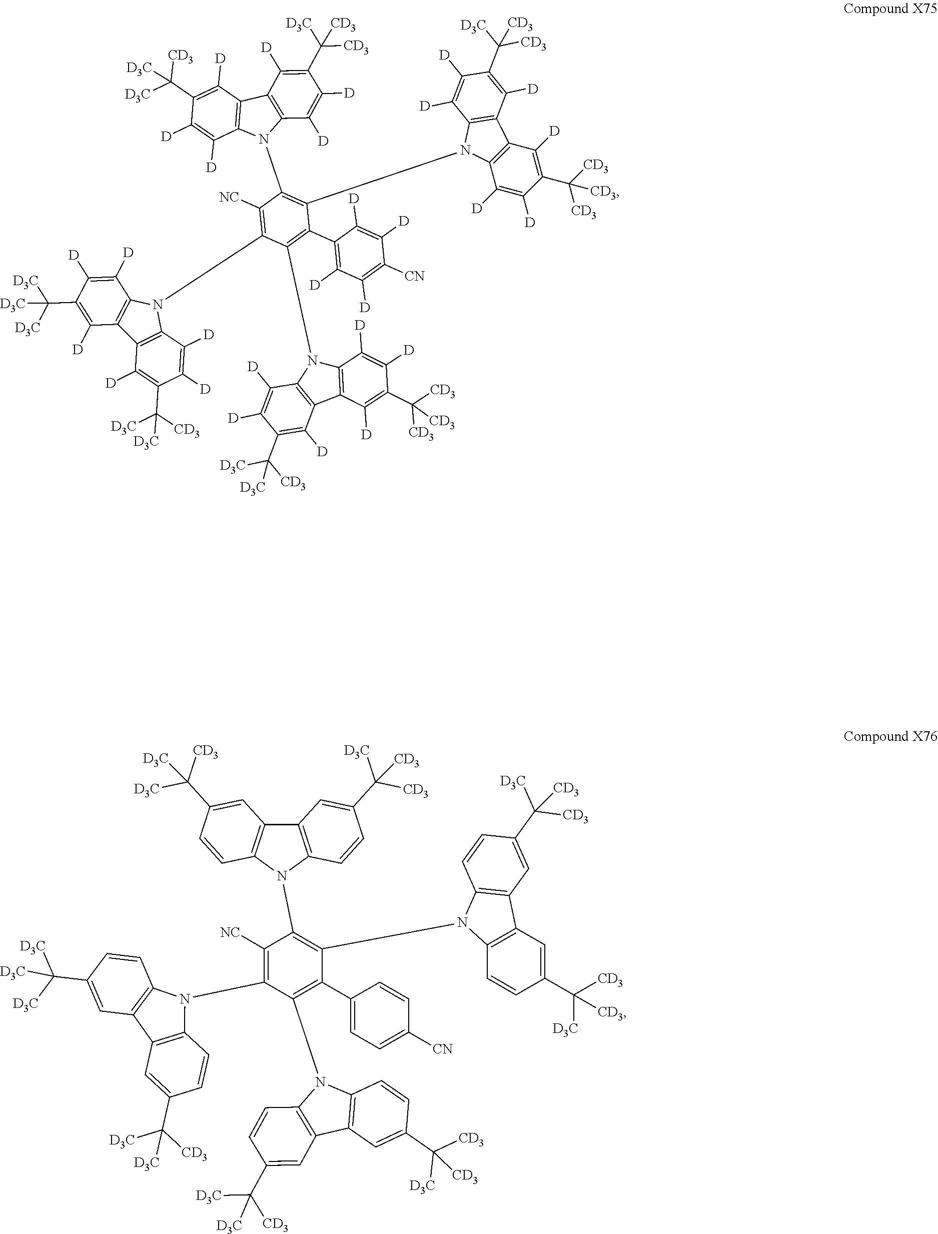

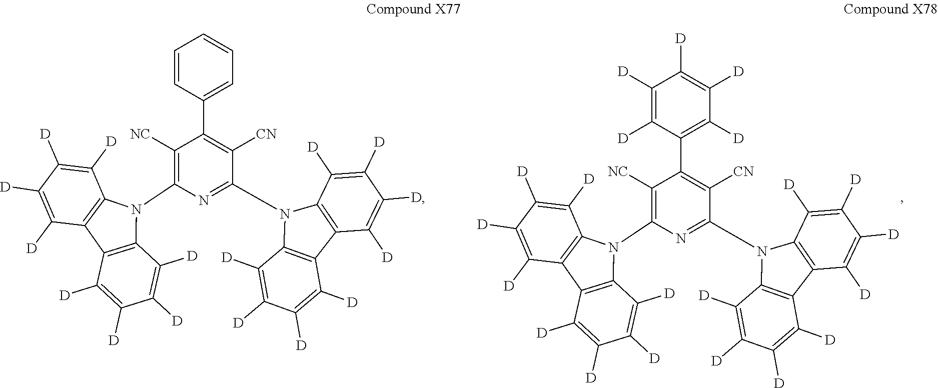

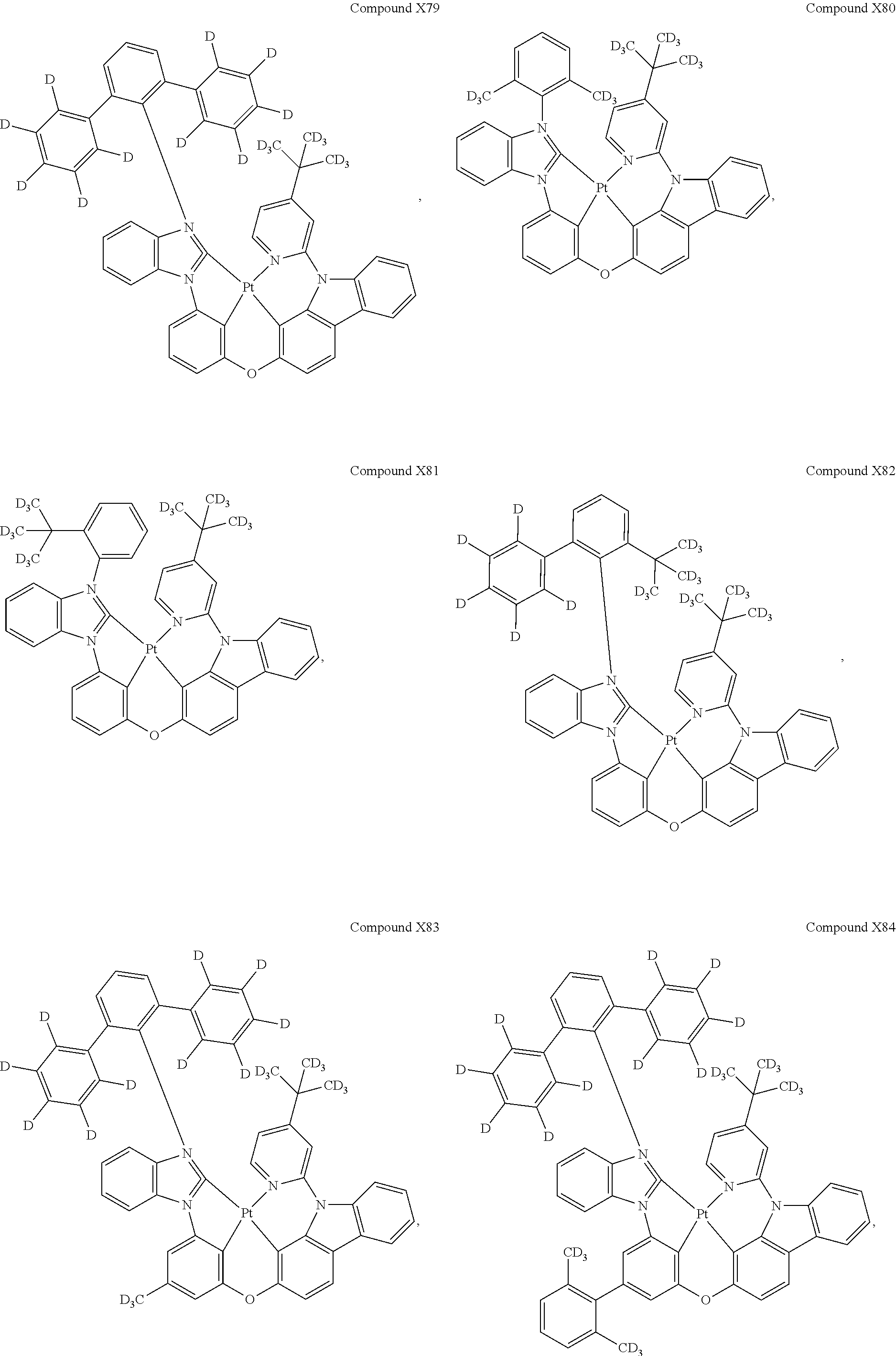

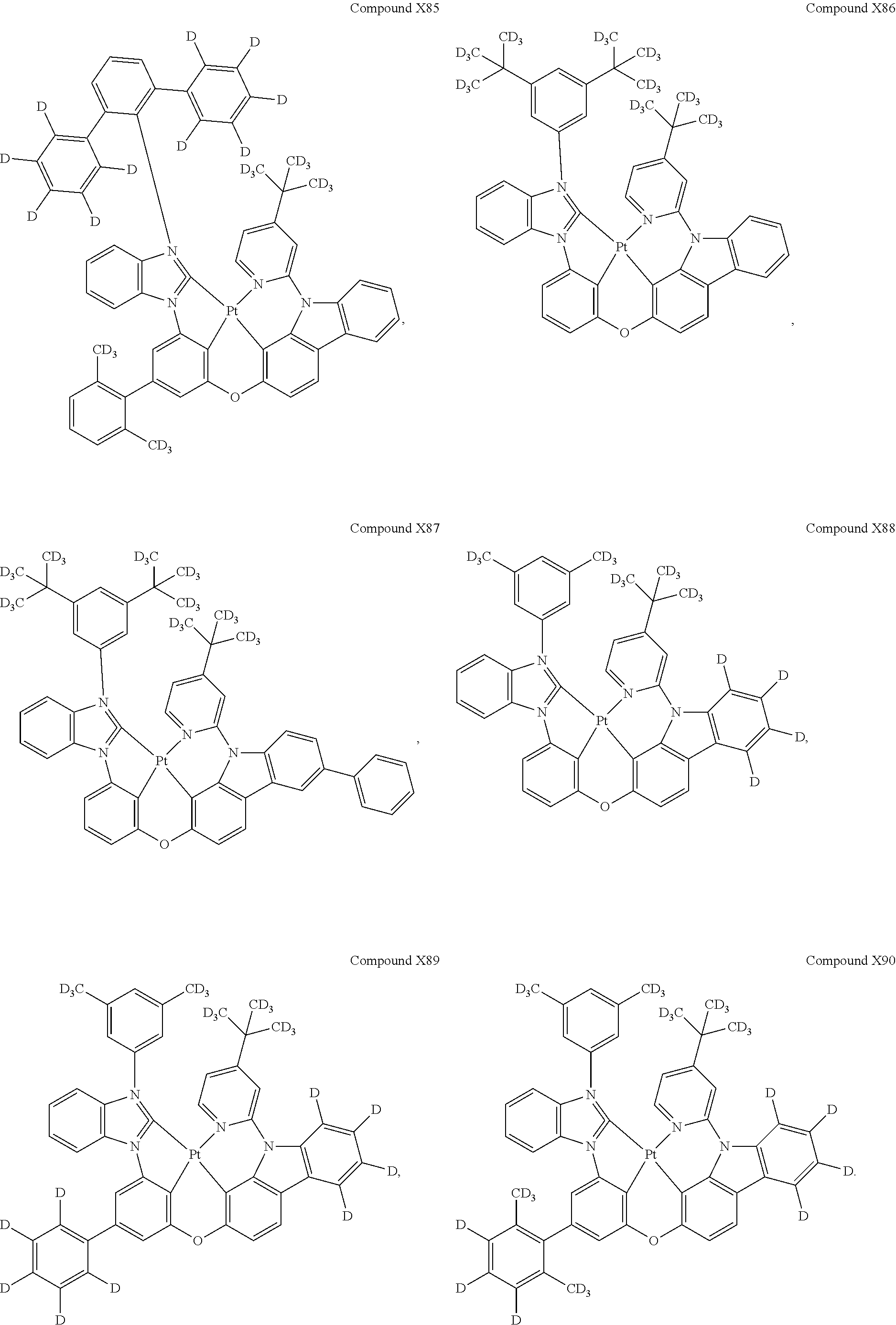

16. The organic electroluminescent device according to claim 1, wherein in first light-emitting functional layer composed of the exciton utilizing agent and the host material, the exciton utilizing agent has a doping concentration of 1 to 30 wt %, corresponding to an electroluminescence spectrum having a maximum luminous intensity denoted as E₁, and a wavelength on short wavelength side corresponding to a luminous intensity of 60% E₁ is λ_{EL}, corresponding to a photoluminescence spectrum having a maximum luminous intensity denoted as E₁′, and a wavelength on short wavelength side corresponding to a luminous intensity of 60% E₁′ is λ_{PL}; in second light-emitting functional layer composed of the host material and the guest light-emitting material, the guest light-emitting material has a doping concentration of 0.1 to 3 wt %, corresponding to an electroluminescence spectrum having a maximum luminous intensity denoted as E₂, and a wavelength on short wavelength side corresponding to a luminous intensity of 60% E₂ is λ_{EL}′, corresponding to a photoluminescence spectrum having a maximum luminous intensity denoted as E₂′, and a wavelength on short wavelength side corresponding to a luminous intensity of 60% E₂′ is λ_{EL}′; wherein λ_{EL} and λ_{EL}′ satisfy the following relationship: λ_{EL}≤λ_{EL}′, and λ_{PL} and λ_{PL}′ satisfy the following relationship: λ_{PL}≤λ_{PL}′.

17. The organic electroluminescent device according to claim 1, wherein at least one hole transport layer (50) is further provided between the anode (20) and the organic light-emitting layer (30), and at least one electron transport layer (60) is further provided between the cathode (40) and the organic light-emitting layer (30);
preferably, a hole injection layer (70) is further provided between the hole transport layer (50) and the anode (20);
preferably, an electron injection layer (80) is further provided between the electron transport layer (60) and the cathode (40);
preferably, the material of the hole transport layer (50) is selected from one or more of the group consisting of aromatic amine compounds, carbazole compounds, and spirocyclic compounds;
preferably, the material of the electron transport layer (60) is selected from one or more of the group consisting of azine compounds, benzimidazole compounds, phenanthrimidazole compounds, ortho phenanthroline compounds, polyfused ring compounds, spirofluorene compounds, and phosphine oxide compounds.

18. The organic electroluminescent device according to claim 1, wherein the organic electroluminescent device further comprises an optical cover layer (90) disposed on a side surface of the cathode (40) away from the substrate (10), and a material of the optical cover layer (90) comprises one or more of compounds represented by formula (A) and compounds represented by formula (B): 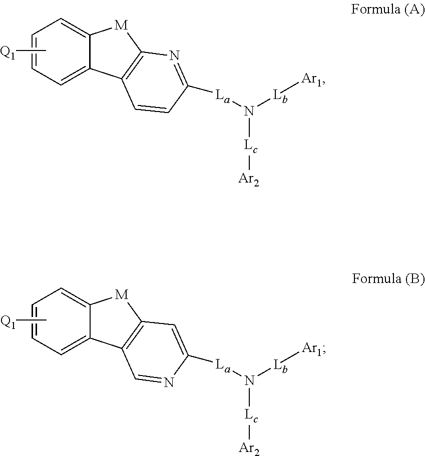
wherein M is selected from O or S, and Q1 is selected from a hydrogen atom or a deuterium atom, and Lₐ, L_{b} and L_{c} are each independently selected from C₆-C₂₀ arylene; Ar₁ and Ar₂ are the same, and Ar₁ and Ar₂ are selected from any one of the following structures:

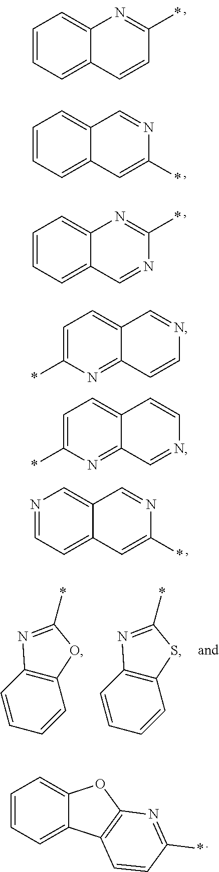

19. The organic electroluminescent device according to claim 18, wherein Lₐ, L_{b} and L_{c} are each independently selected from phenylene or naphthylene.

20. A display device, wherein, the display device comprises the organic electroluminescent device according to claim 1, and the display device is selected from the group consisting of a tablet phone, a wearable display device, a tablet computer, a laptop computer, a medical display device, a foldable display device, a vehicle-mounted display device, a virtual reality display device or an augmented reality display device.
